(19) United States
(12) Patent Application Publication
(10) Pub. No.: US 2024/0377737 A1
(43) Pub. Date: Nov. 14, 2024

(54) CHEMICALLY AMPLIFIED NEGATIVE RESIST COMPOSITION AND PATTERNING PROCESS

(71) Applicant: Shin-Etsu Chemical Co., Ltd., Tokyo (JP)

(72) Inventors: Gentaro Hida, Joetsu-shi (JP); Tomohiro Kobayashi, Joetsu-shi (JP); Takahiro Suzuki, Joetsu-shi (JP)

(73) Assignee: Shin-Etsu Chemical Co., Ltd., Tokyo (JP)

(21) Appl. No.: 18/637,749

(22) Filed: Apr. 17, 2024

(30) Foreign Application Priority Data
Apr. 25, 2023 (JP) 2023-071288

(51) Int. Cl. G03F 7/038; G03F 7/004; G03F 7/32; G03F 7/38

(52) U.S. Cl. CPC G03F 7/0382; G03F 7/0045; G03F 7/325; G03F 7/38

(57) ABSTRACT

A chemically amplified negative resist composition is provided comprising (A) a polymer P having a predetermined structure and comprising repeat units adapted to generate an acid upon exposure, repeat units adapted to change its solubility in a developer by degrading under the action of an acid, and repeat units having phenolic hydroxy group, and (B) a crosslinker X in the form of a melamine compound, a glycoluril compound, a urea compound or an epoxy compound substituted with at least one selected from a methylol group, an alkoxymethyl group and an acyloxymethyl group.

### CROSS-REFERENCE TO RELATED APPLICATIONS

This non-provisional application claims priority under 35 U.S.C. § 119(a) on Patent Application No. 2023-071288 filed in Japan on Apr. 25, 2023, the entire contents of which are hereby incorporated by reference.

### TECHNICAL FIELD

This invention relates to a chemically amplified negative resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation.

As the feature size reduces, image blurs due to acid diffusion become a problem. To insure resolution for fine patterns with a processed size of 45 nm or less, not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

In forming a pattern having a narrower pitch than the wavelength of exposure light, it is effective to utilize the interference lithography. In particular, the interference of high contrast light between X-direction lines and Y-direction lines generates black spots with high contrast. Non-Patent Document 2 describes that a hole pattern with excellent critical dimension uniformity (CDU) can be formed by combining the interference lithography with a negative resist composition. Non-Patent Document 2 uses a negative resist composition comprising a crosslinker capable of inducing reaction between polymer molecules with the aid of an acid. This chemically amplified negative resist composition suffers from problems including pattern collapse and degradation of CDU or line width roughness (LWR) which are caused by image blur due to the acid diffusion (as mentioned above).

The fabrication of negative tone patterns by organic solvent development is a prior art technique employed from the past. Non-Patent Document 3 describes that xylene and the like are used as the developer for a resist composition based on cyclized rubber, and anisole is used as the developer for an initial chemically amplified resist composition based on poly-tert-butoxycarbonyloxystyrene.

Patent Document 1 discloses that a negative pattern is formed by using a polymethacrylate having a carboxy group substituted with an acid labile group as the base polymer to formulate a chemically amplified resist composition, exposing it to ArF excimer laser light, and developing in an organic solvent. This organic solvent development process, combined with immersion lithography through an optical system with a NA in excess of 1 or double patterning lithography, is used in the fabrication of microelectronic devices of sub-20-nm node.

In recent years, the advancement of photomask techniques has led to development of bright masks for EUV lithography, and the hole pattern formation has induced an increase in demand for negative resist compositions that are advantageous in formation of optical images.

Negative tone patterns are also advantageous in formation of isolated patterns and pillar patterns by EUV lithography. Since the mask used herein has a greater proportion of light-shielded regions, there is the merit that patterns are unsusceptible to the influence of defects in the mask blank.

The organic solvent development causes less swell than the alkaline aqueous solution development, sometimes leading to better values of CDU or LWR. The organic solvent development, however, has the problem of low resolution because the dissolution contrast is lower than that of the alkaline aqueous solution development. Development of a resist capable of forming patterns having an improved dissolution contrast while maintaining resolution is necessary even for organic solvent development.

Patent Document 1 discloses an alkaline aqueous solution developing positive resist composition containing a polymer comprising repeat units derived from an onium salt of a polymerizable unsaturated bond-containing sulfonic acid for suppressing the acid diffusion. The so called polymer-bound acid generator is capable of generating a polymer type sulfonic acid upon exposure and characterized by a very short distance of acid diffusion. Sensitivity may be enhanced by increasing a proportion of the acid generator. In the case of acid generators which are additives, as the amount of acid generator added is increased, a higher sensitivity is achievable, but the acid diffusion distance is also increased. Since the acid diffusion is non-uniform, increased acid diffusion leads to degraded LWR and CDU. With respect to a balance of sensitivity, LWR and CDU, the polymer-bound acid generator has a high capability.

However, since the polymer-bound acid generator is macromolecular, it has extremely low solubility in a developer adapted for the organic solvent development. Therefore, the polymer-bonded acid generator has been considered difficult to use for a negative resist composition adapted for the organic solvent development. For introduction of a polymer-bound acid generator into a negative resist composition adapted for the organic solvent development, the polymer-bound acid generator has been required to exhibit sufficient solubility in a developing organic solvent.

### CITATION LIST

Patent Document 1: JP No. 4425776
Non-Patent Document 1: Proc. SPIE Vol. 5377, p. 255 (2004)
Non-Patent Document 2: IEEE IEDM Tech. Digest 61 (1996)
Non-Patent Document 3: Proc. SPIE Vol. 7274, p. 72740N (2009)

### SUMMARY OF THE INVENTION

It is desired to develop a negative resist composition adapted for the organic solvent development, which is capable of forming patterns exhibiting high dissolution contrast and high resolution and having good CDU and LWR performance. It is desired to develop a negative resist composition adapted for the organic solvent development in which a polymer-bound acid generator exhibiting higher solubility in an organic solvent than a normal acid generator is applied.

An object of the invention is to provide a chemically amplified negative resist composition capable of forming patterns with high dissolution contrast and excellent CDU and LWR performance, and a pattern forming process using the same.

The inventors have found that a chemically amplified negative resist composition obtained using a polymer comprising repeat units having a solubilizing acid labile group in a side chain, as a polymer-bound acid generator, and a crosslinker has high contrast and excellent resolution, does not suffer from generation of residues in unexposed regions, and has improved LWR and CDU performance.

In one aspect, the invention provides a chemically amplified negative resist composition.

The preferred chemically amplified negative resist composition comprises (A) a polymer P comprising repeat units having one of the following formulae (A1) to (A4), which are adapted to generate an acid upon exposure, repeat units having formula (B) which are adapted to change its solubility in a developer by degrading under the action of an acid, and repeat units having the following formula (C) which have a phenolic hydroxy group, and

(B) a crosslinker X in the form of a melamine compound, a glycoluril compound, a urea compound or an epoxy compound substituted with at least one selected from a methylol group, an alkoxymethyl group and an acyloxymethyl group.

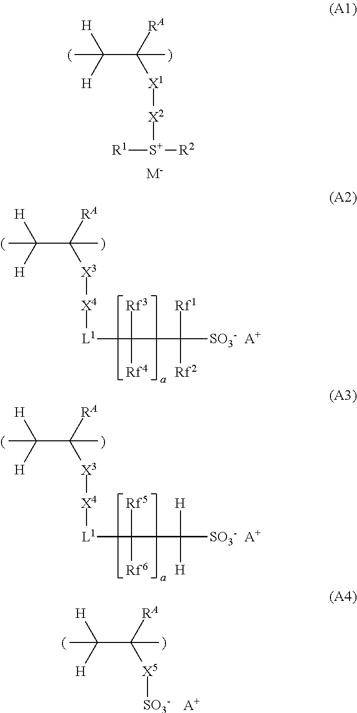

Herein R^{A} is each independently a hydrogen atom, a fluorine atom, a methyl group, or a trifluoromethyl group,
X¹ is a single bond or a phenylene group,
X² is *—C(═O)—O—X²¹—, *—C(═O)—NH—X²¹— or *—O—X²¹—, X²¹ is a C₁-C₆ aliphatic hydrocarbylene group, a phenylene group, or a divalent group obtained by combining the foregoing, which may contain a carbonyl group, an ester bond, an ether bond or a hydroxy group,
X³ is each independently a single bond, a phenylene group, a naphthylene group or *—C(═O)—O—X³¹—, X³¹ is a C₁-C₁₀ aliphatic hydrocarbylene group, a phenylene group, or a naphthylene group, and the aliphatic hydrocarbylene group may contain at least one selected from a hydroxy group, an ether bond, an ester bond or a lactone ring,
X⁴ is each independently a single bond or *—X⁴¹—C(═O)—O—, X⁴¹ is a C₁-C₂₀ hydrocarbylene group which may contain a heteroatom,
X⁵ is a single bond, a methylene group, an ethylene group, a phenylene group, a fluorinated phenylene group, a phenylene group substituted with a trifluoromethyl group, *—C(═O)—O—X⁵¹—, *—C(═O)—N(H)—X⁵¹—, or *—O—X⁵¹, X⁵¹ is a C₁-C₆ aliphatic hydrocarbylene group, a phenylene group, a fluorinated phenylene group, or a phenylene group substituted with a trifluoromethyl group, and may contain a carbonyl group, an ester bond, an ether bond or a hydroxy group,
the asterisk (*) designates a point of attachment to the carbon atom in the backbone,
R¹ and R² are each independently a C₁-C₂₀ hydrocarbyl group which may contain a heteroatom, R¹ and R² may bond together to form a ring with the sulfur atom to which they are attached,
L¹ is a single bond, an ether bond, an ester bond, a carbonyl group, a sulfonic ester bond, a carbonate bond, or a carbamate bond,
Rf¹ and Rf² are each independently a fluorine atom, or a C₁-C₆ fluorinated saturated hydrocarbyl group,
Rf³ and Rf⁴ are each independently a hydrogen atom, a fluorine atom, or a C₁-C₆ fluorinated saturated hydrocarbyl group,
Rf⁵ and Rf⁶ are each independently a hydrogen atom, a fluorine atom, or a C₁-C₆ fluorinated saturated hydrocarbyl group, excluding that all Rf⁵ and Rf⁶ are hydrogen atom at the same time,
M⁻ is a non-nucleophilic counter ion,
A⁺ is an onium cation, and
a is an integer of 0 to 3.

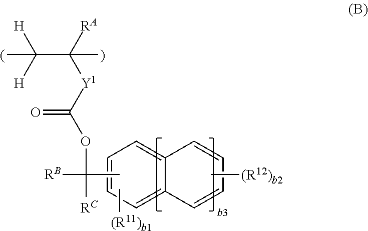

Herein R^{A} is a hydrogen atom, a fluorine atom, a methyl group, or a trifluoromethyl group,
Y¹ is a single bond, a phenylene group, a naphthylene group or *—C(═O)—O—Y¹¹—, Y¹¹ is a C₁-C₂₀ aliphatic hydrocarbylene group, a phenylene group, or a naphthylene group, and the hydrocarbylene group may contain at least one selected from a hydroxy group, an ether bond, an ester bond or a lactone ring, the asterisk (*) designates a point of attachment to the carbon atom in the backbone,
R^{B} and R^{C} are each independently a C₁-C₁₀ hydrocarbyl group which may contain a heteroatom, and R^{B} and R^{C} may bond together to form a ring with the carbon atom to which they are attached,
R¹¹ is a fluorine atom, a C₁-C₅ fluorinated saturated hydrocarbyl group, or a C₁-C₅ fluorinated saturated hydrocarbyloxy group,
R¹² is a C₁-C₁₀ hydrocarbyl group which may contain a heteroatom,
b1 is an integer of 0 to 2, b2 is an integer of 0 to 5, and b3 is an integer of 0 to 2.

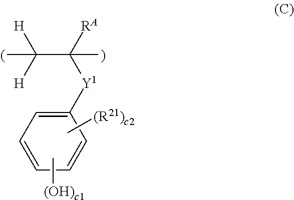

Herein R^{A} is a hydrogen atom, a fluorine atom, a methyl group, or a trifluoromethyl group,
Y² is a single bond or *—C(═O)—O—, the asterisk (*) designates a point of attachment to the carbon atom in the backbone,
R²¹ is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom,
c1 is an integer of 1 to 4, and c2 is an integer of 0 to 4, provided that the sum of c1+c2 is 1 to 5.

In a preferred embodiment, b1 is 1 or 2.

In a preferred embodiment, polymer P further comprises repeat units comprising a lactone ring.

In a preferred embodiment, the chemically amplified negative resist composition further comprises an onium salt type quencher represented by the following formula (Q1) or (Q2).

R³¹—SO₃⁻Mq⁺ (Q1)

R³²—CO₂⁻Mq⁺ (Q2)

Herein R³¹ is a hydrogen atom or a C₁-C₄₀ hydrocarbyl group which may contain a heteroatom, exclusive of the hydrocarbyl group in which the hydrogen atom bonded to the carbon atom at α-position of the sulfo group is substituted by fluorine atom or fluoroalkyl group,
R³² is a hydrogen atom, or a C₁-C₄₀ hydrocarbyl group which may contain a heteroatom, and
Mq⁺ is an onium cation.

In a preferred embodiment, the chemically amplified negative resist composition further comprises an organic solvent.

In a preferred embodiment, the chemically amplified negative resist composition further comprises a surfactant.

In another aspect, the invention provides a process for forming a pattern comprising steps of applying the chemically amplified negative resist composition defined herein to a substrate to form a resist film thereon, exposing the resist film to high-energy radiation, and developing the exposed resist film in a developer including an organic solvent.

In a preferred embodiment, the process comprises the step of heating the resist film after the exposure and before the development.

### Advantageous Effects of the Invention

The polymer-bound acid generator comprising repeat units represented by formula (B) and having an acid labile group exhibits high solvent solubility, and does not suffer from generation of residues in unexposed regions after development. The polymer-bound acid generator is low in acid diffusion property, and therefore has high dissolution contrast and LWR and CDU performance. In addition, since a crosslinker is contained in the composition, the polymer chains are crosslinked by an acid generated from the acid generator in the exposed regions, so that the exposed regions have a high molecular weight, leading to a further decrease in acid diffusion distance of the acid generator. Since the difference in dissolution rate between the unexposed and exposed regions increases, high dissolution contrast is achieved, and it is possible to obtain patterns having high rectangularity, low LWR, and improved CDU.

### BRIEF DESCRIPTION OF THE DRAWINGS

FIG. 1 shows contrast curves of resist films of Examples 3 to 17 and Comparative Examples 3 to 7.

### DETAILED DESCRIPTION OF THE INVENTION

### [Chemically Amplified Resist Composition]

One embodiment of the invention is a chemically amplified resist composition comprising (A) a polymer P comprising repeat units adapted to generate an acid upon exposure, repeat units adapted to change its solubility in a developer by degrading under the action of an acid, and repeat units having phenolic hydroxy group, and (B) a crosslinker X in the form of a melamine compound, a glycoluril compound, a urea compound or an epoxy compound substituted with at least one selected from a methylol group, an alkoxymethyl group and an acyloxymethyl group.

### [(A) Polymer P]

Component (A) or Polymer P functions as a base polymer. Polymer P comprises repeat units adapted to generate an acid upon exposure, specifically, repeat units represented by the following formula (A1), which are also referred to as repeat units A1, repeat units represented by the following formula (A2), which are also referred to as repeat units A2, repeat units represented by the following formula (A3), which are also referred to as repeat units A3, or repeat units represented by the following formula (A4), which are also referred to as repeat units A4.

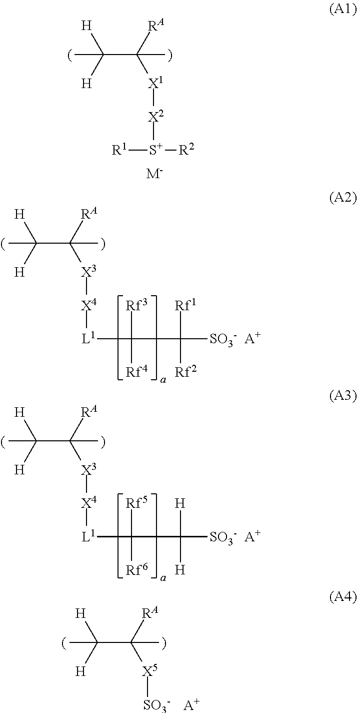

In formulae (A1) to (A4), R^{A} is each independently a hydrogen atom, a fluorine atom, a methyl group, or a trifluoromethyl group. X¹ is a single bond or a phenylene group, X² is *—C(═O)—O—X²¹—, *—C(═O)—NH—X²¹— or *—O—X²¹—, X²¹ is a C₁-C₆ aliphatic hydrocarbylene group, a phenylene group, or a divalent group obtained by combining the foregoing, which may contain a carbonyl group, an ester bond, an ether bond or a hydroxy group, X³ is each independently a single bond, a phenylene group, a naphthylene group or *—C(═O)—X³¹—, X³¹ is a C₁-C₁₀ aliphatic hydrocarbylene group, a phenylene group, or a naphthylene group, and the aliphatic hydrocarbylene group may contain at least one selected from a hydroxy group, an ether bond, an ester bond or a lactone ring, X⁴ is each independently a single bond or *—X⁴¹—C(═O)—O—, X⁴¹ is a C₁-C₂₀ hydrocarbylene group which may contain a heteroatom, X⁵ is a single bond, a methylene group, an ethylene group, a phenylene group, a fluorinated phenylene group, a phenylene group substituted with a trifluoromethyl group, *—C(═O)—O—X⁵—, *—C(═O)—N(H)—X⁵—, or *—O—X⁵, X⁵¹ is a C₁-C₆ aliphatic hydrocarbylene group, a phenylene group, a fluorinated phenylene group, or a phenylene group substituted with a trifluoromethyl group, and may contain a carbonyl group, an ester bond, an ether bond or a hydroxy group, the asterisk (*) designates a point of attachment to the carbon atom in the backbone,

The aliphatic hydrocarbylene group X²¹, X³¹ and X⁵¹ may be straight, branched or cyclic. Examples thereof include C₁-C₂₀ alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, hexane-1,6-diyl, heptane-1,7-diyl, octane-1,8-diyl, nonane-1,9-diyl, and decane-1,10-diyl; C₃-C₂₀ cycloalkanediyl groups such as cyclopropanediyl, cyclobutane-1,1-diyl, cyclopentanediyl, and cyclohexanediyl; C₄-C₂₀ polycyclic saturated hydrocarbylene groups such as adamantanediyl and norbornanediyl; and divalent groups obtained by combining the foregoing.

The hydrocarbylene group X⁴¹ may be saturated or unsaturated and straight, branched or cyclic. Examples of the hydrocarbylene group are shown below, but not limited thereto.

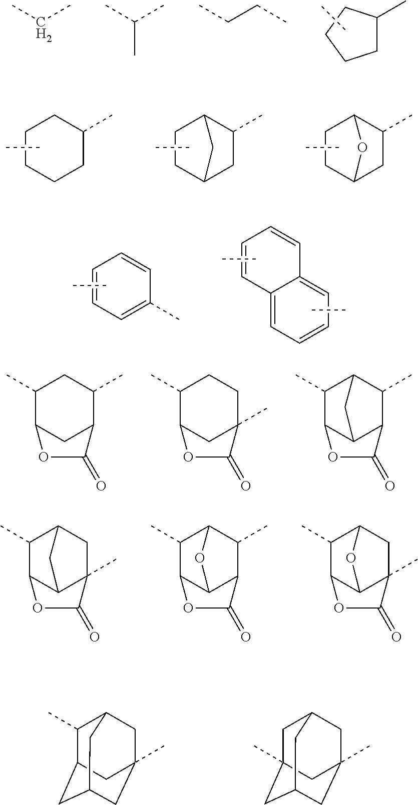

Herein the broken line denotes a valence bond.

In formula (A1), R¹ to R² are each independently a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl and tert-butyl groups; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl and adamantyl groups; C₂-C₂₀ alkenyl groups such as vinyl, allyl, propenyl, butenyl and hexenyl groups; C₃-C₂₀ cyclic unsaturated hydrocarbyl groups such as a cyclohexenyl group; C₆-C₂₀ aryl groups such as phenyl, naphthyl and thienyl groups; C₇-C₂₀ aralkyl groups such as benzyl, 1-phenylethyl and 2-phenylethyl groups; and combinations thereof. The aryl groups are preferred. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like.

R¹ and R² may bond together to form a ring with the sulfur atom to which they are attached, Examples thereof include groups having the following formulae. In the following formulae, the broken line designates a point of attachment to X².

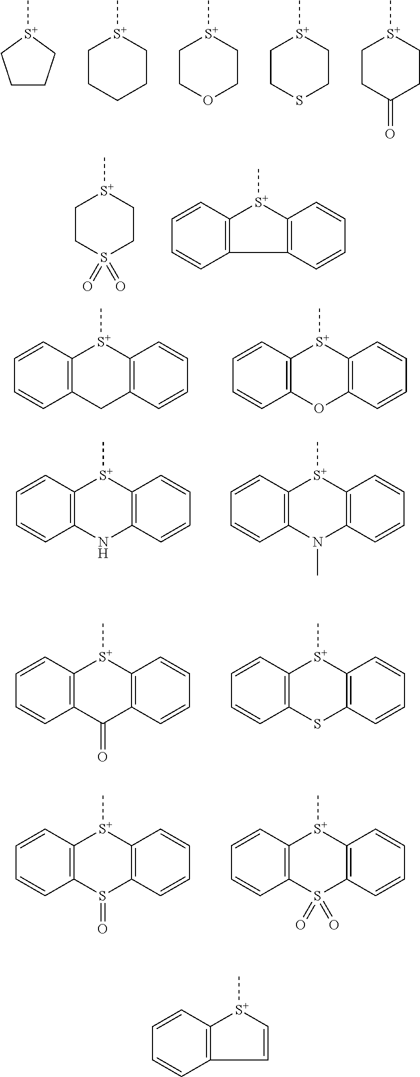

Examples of the cation in repeat unit A1 are shown below, but not limited thereto. Herein, R^{A} is as defined above.

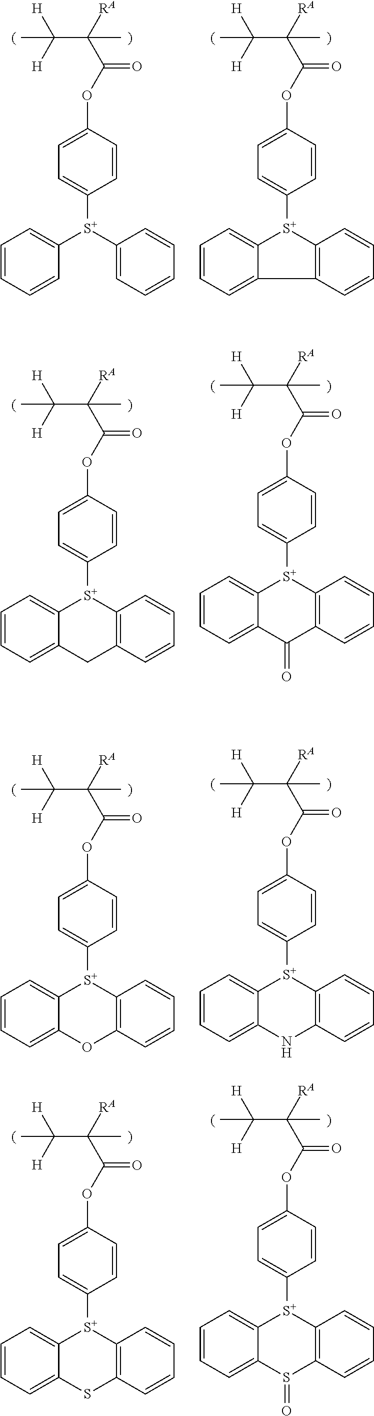

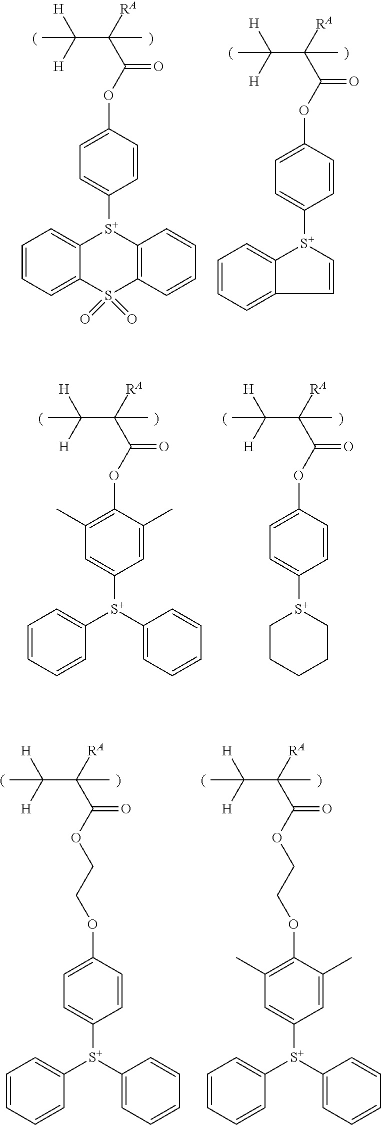

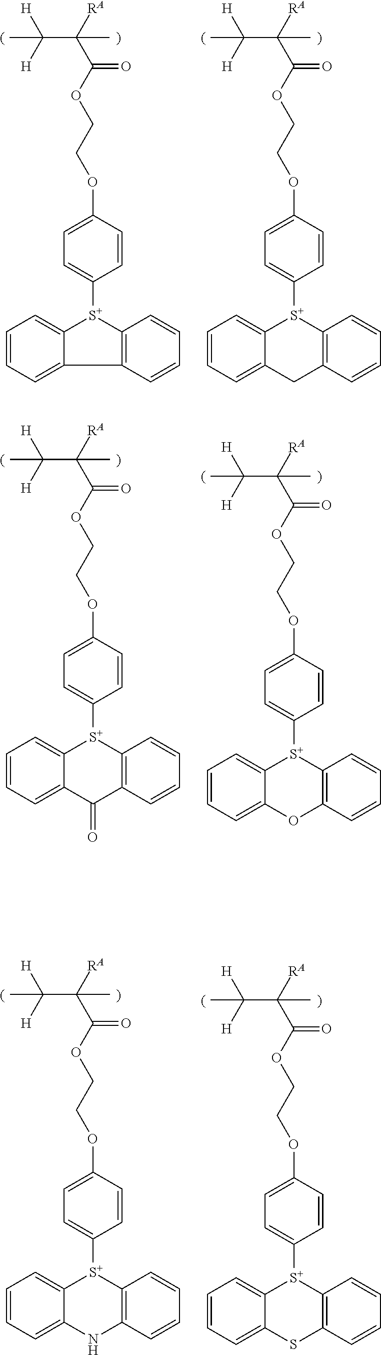

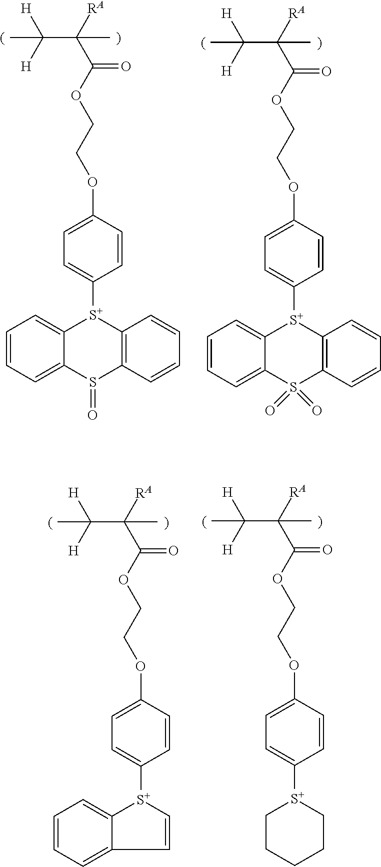

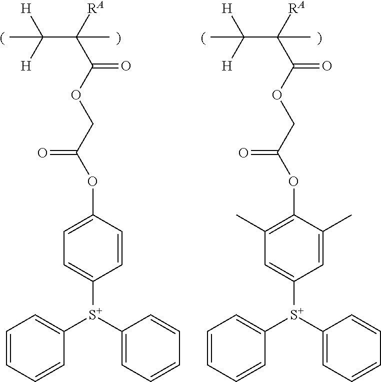

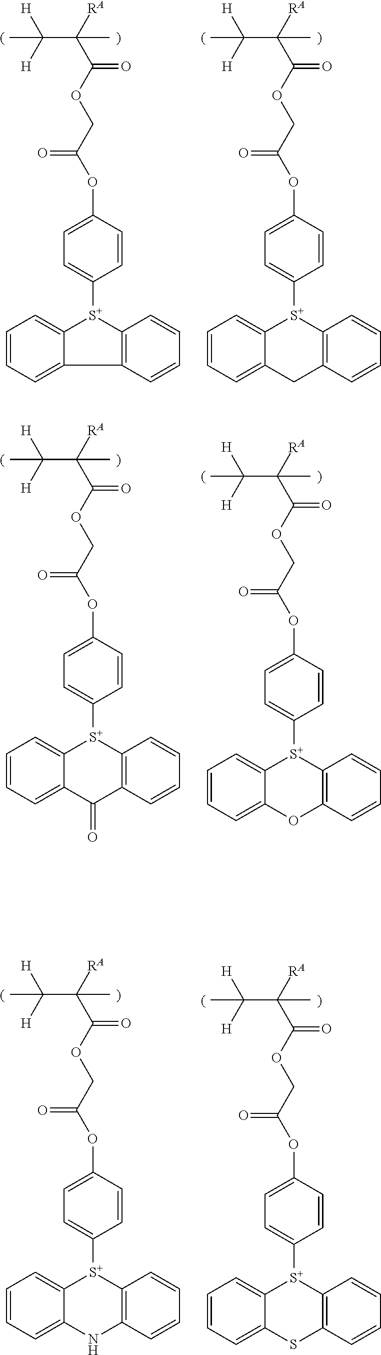

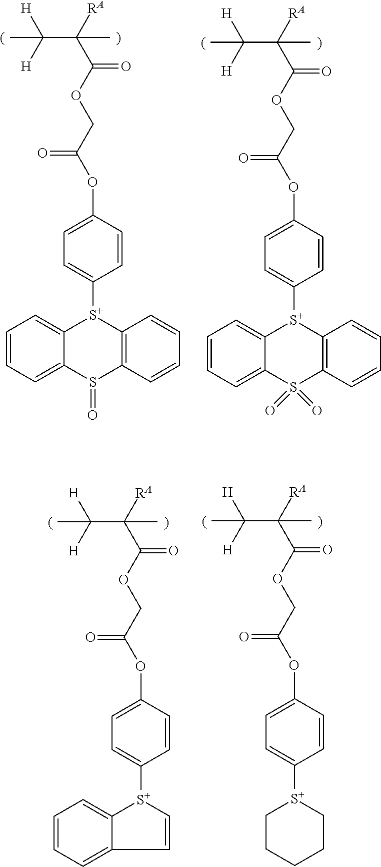

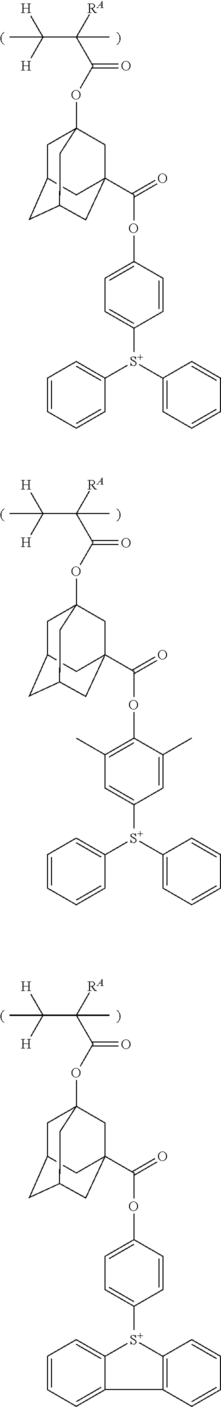

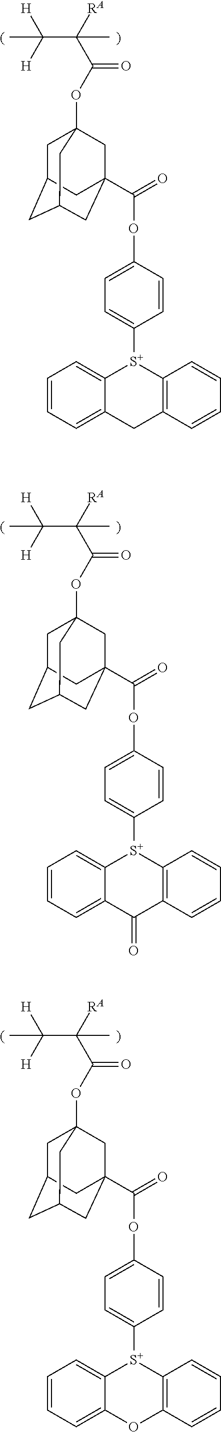

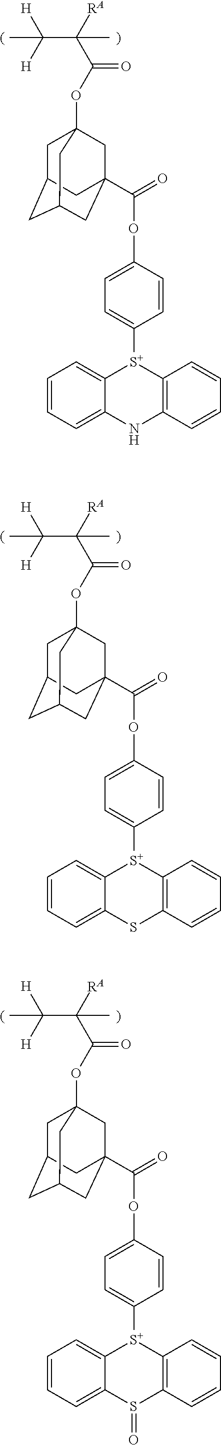

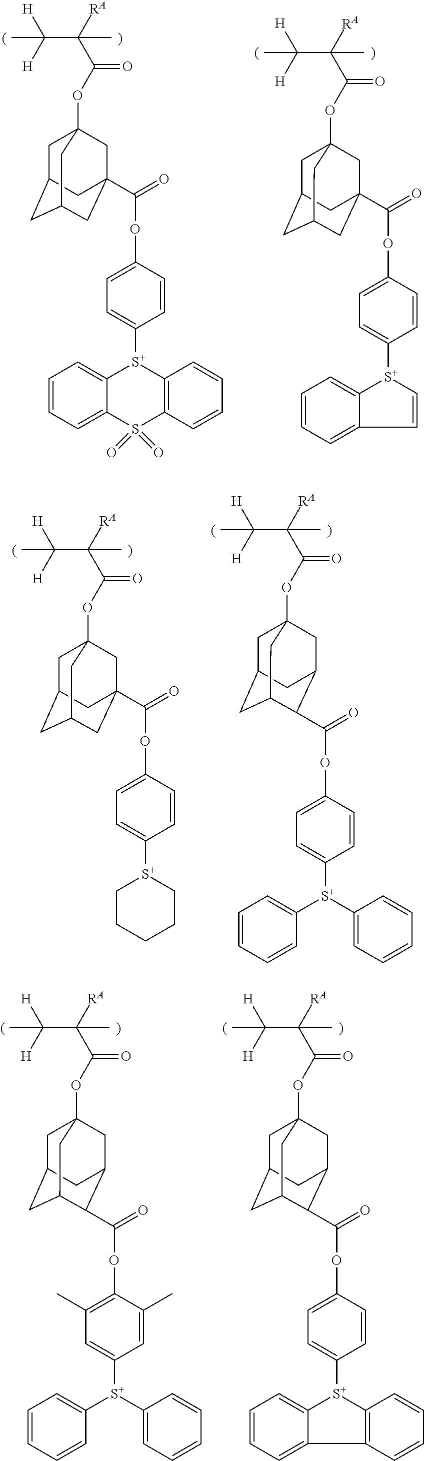

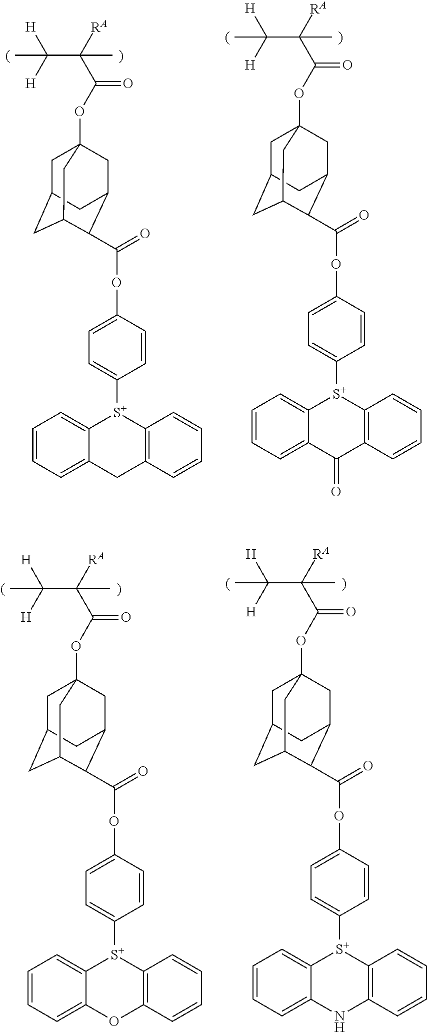

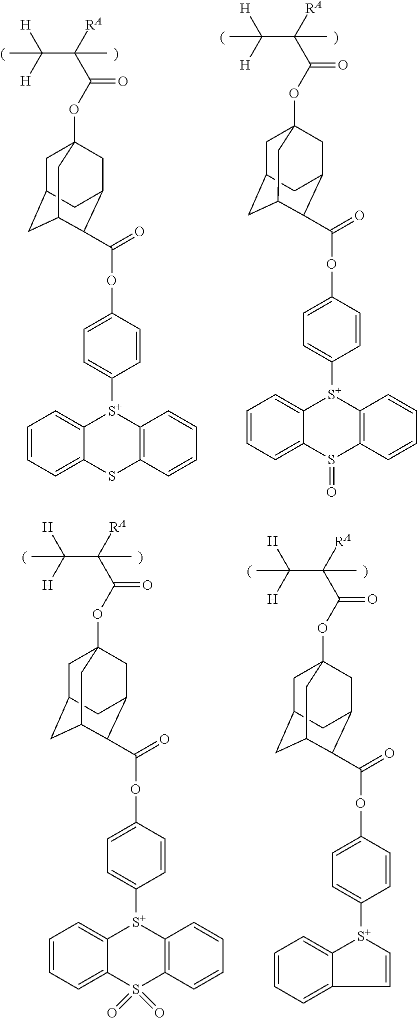

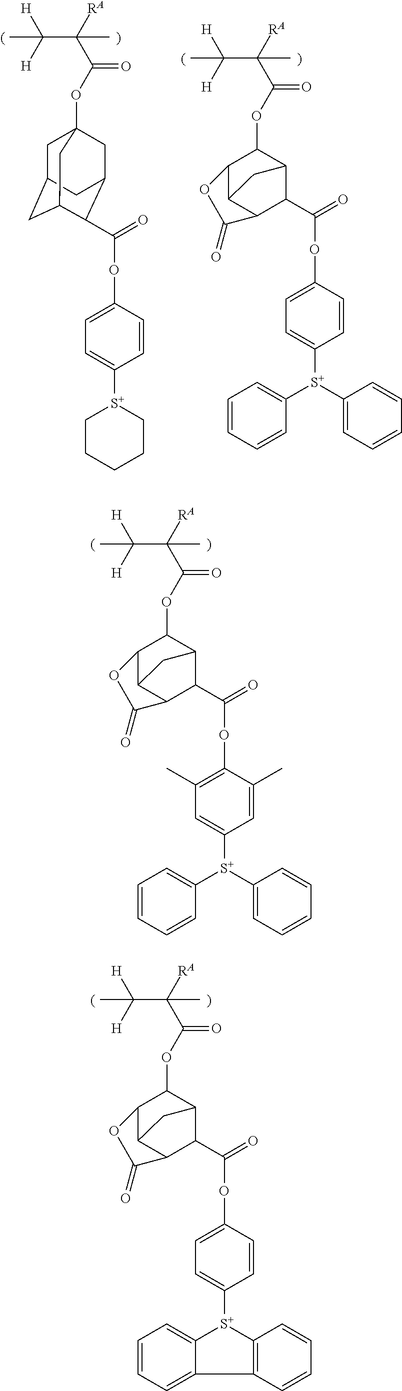

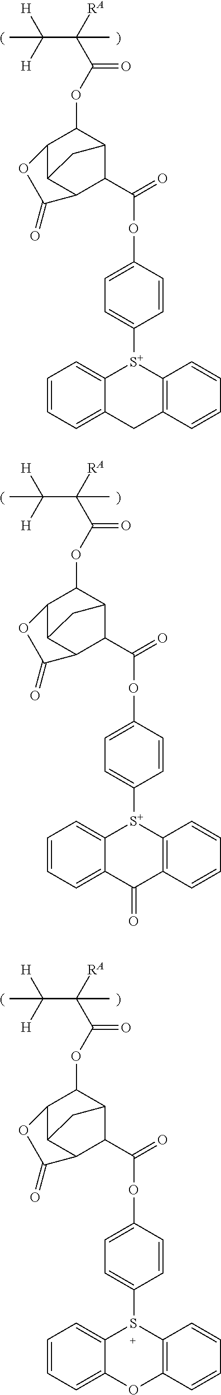

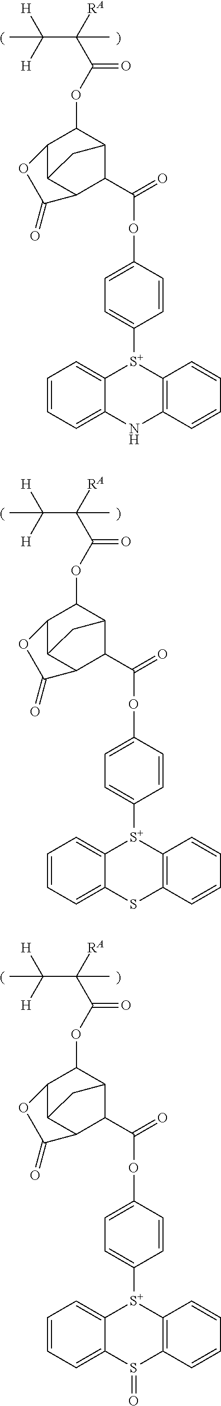

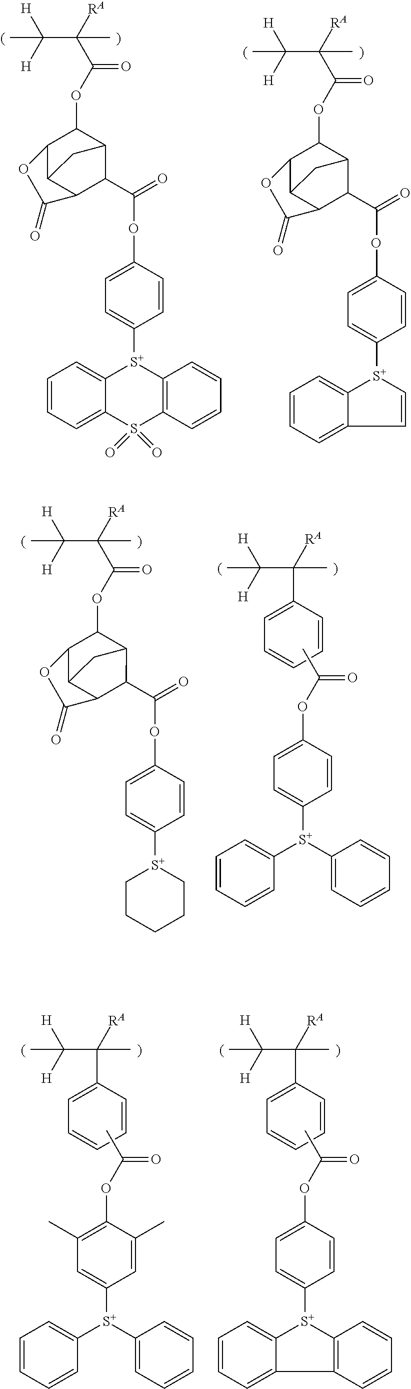

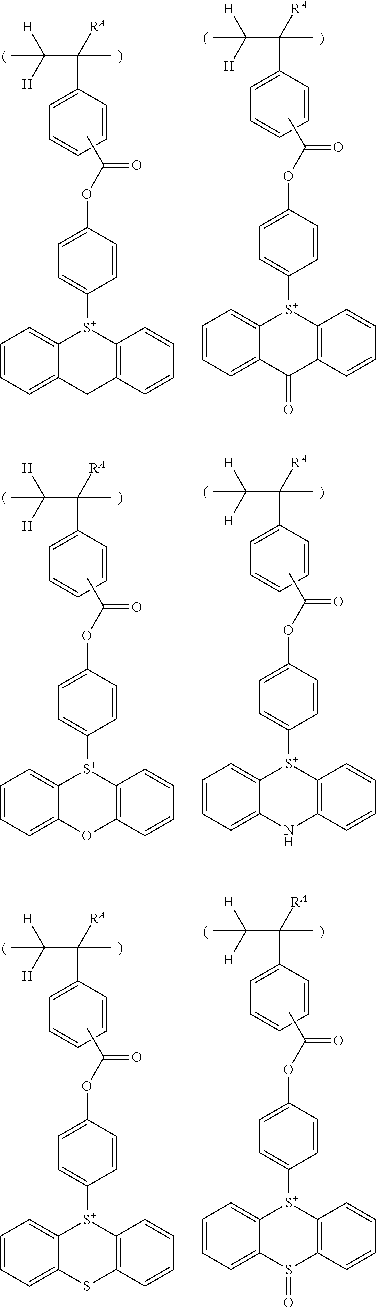

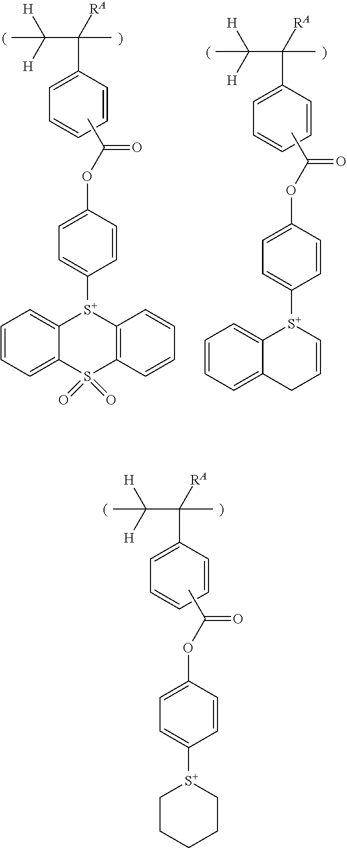

In formula (A1), M⁻ is a non-nucleophilic counter ion. Examples of the non-nucleophilic counter ion include halide ions such as chloride ions and bromide ions; fluoroalkyl sulfonate ions such as triflate ions, 1,1,1-trifluoroethane sulfonate ions and nonafluorobutane sulfonate ions; aryl sulfonate ions such as tosylate ions, benzene sulfonate ions, 4-fluorobenzenesulfonate ions and 1,2,3,4,5-pentafluorobenzenesulfonate ions; alkyl sulfonate ions such as mesylate ions and butanesulfonate ions; imide ions such as bis(trifluoromethylsulfonyl)imide ions, bisperfluoroethylsulfonyl)imide ions, and bis(perfluorobutylsulfonyl)imide ions; and tris(trifluoromethylsulfonyl)methide ions and trisperfluoroethylsulfonyl)methide ions.

Also included are sulfonate anions having fluorine substituted at α-position as represented by the formula (A1-1) and sulfonate anions having fluorine substituted at α-position and trifluoromethyl at β-position as represented by the formula (A1-2).

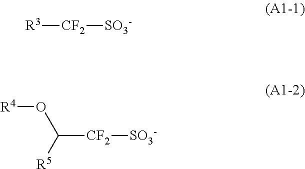

In formula (A1-1), R³ is a hydrogen atom or a C₁-C₃₀ hydrocarbyl group, a C₂-C₃₀ hydrocarbylcarbonyloxy group, or a C₂-C₃₀ hydrocarbyloxycarbonyl group, which may contain a halogen atom, ether bond, ester bond, carbonyl moiety, or lactone ring. The hydrocarbyl group and hydrocarbyl moiety of the hydrocarbylcarbonyloxy and hydrocarbyloxycarbonyl groups may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl and icocyl groups; C₃-C₃₀ cyclic saturated hydrocarbyl groups such as cyclopentyl, cyclohexyl, 1-adamantyl, 2-adamantyl, 1-adamantylmethyl, norbornyl, norbornylmethyl, tricyclodecyl, tetracyclodecyl, tetracyclodecylmethyl and dicyclohexylmethyl groups; C₂-C₃₀ unsaturated aliphatic hydrocarbyl groups such as allyl and 3-cyclohexenyl groups; C₆-C₃₀ aryl groups such as phenyl, 1-naphthyl and 2-naphthyl groups; C₇-C₃₀ aralkyl groups such as benzyl and diphenylmethyl groups; and combinations thereof. Of these, aliphatic groups are preferred as R³. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl groups.

In formula (A1-2), R⁴ is a hydrogen atom or a C₁-C₃₀ hydrocarbyl group, or C₂-C₃₀ hydrocarbylcarbonyl group, which may contain a halogen atom, ether bond, ester bond, carbonyl moiety, or lactone ring. R⁵ is a hydrogen atom, a fluorine atom, or a C₁-C₆ fluorinated saturated hydrocarbyl group. the hydrocarbyl group and the hydrocarbyl moiety of the hydrocarbylcarbonyloxy group may be saturated or unsaturated and straight, branched or cyclic. Examples of the hydrocarbyl group are as exemplified above as a hydrocarbyl group R³ in formula (A1-1). A trifluoromethyl group is preferred as R⁵.

Examples of the sulfonate anion represented by formula (A1-1) or (A1-2) are shown below, but not limited thereto. In the following formulae, R⁵ is as defined above, and Ac is an acetyl group.

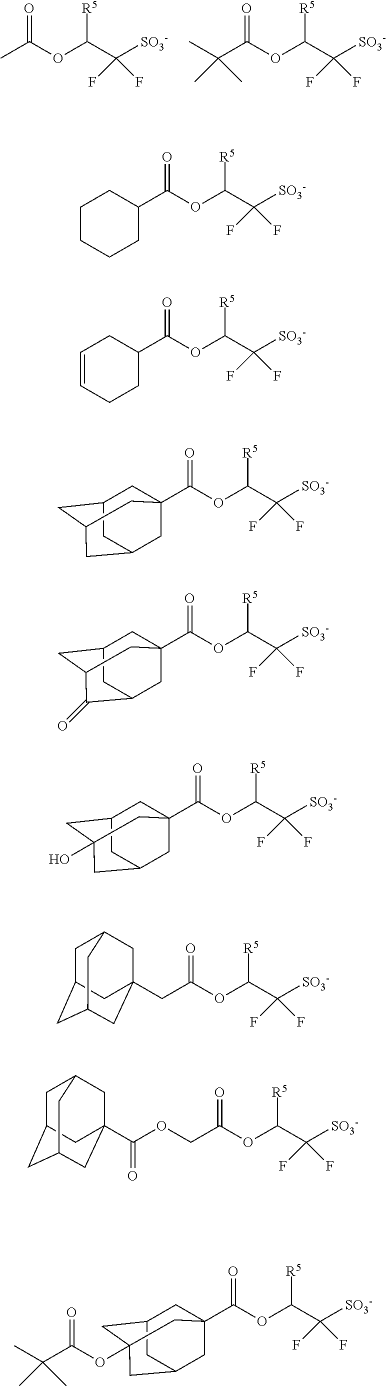

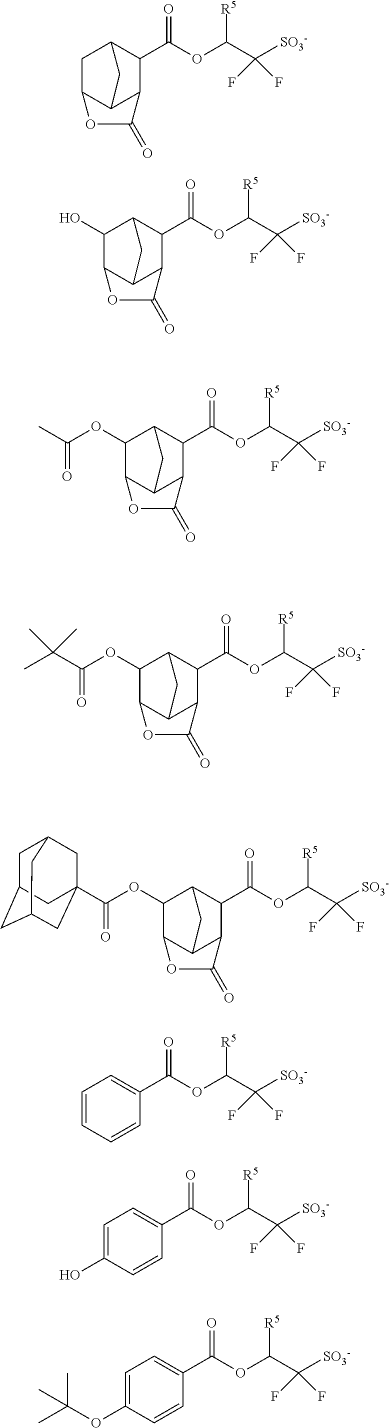

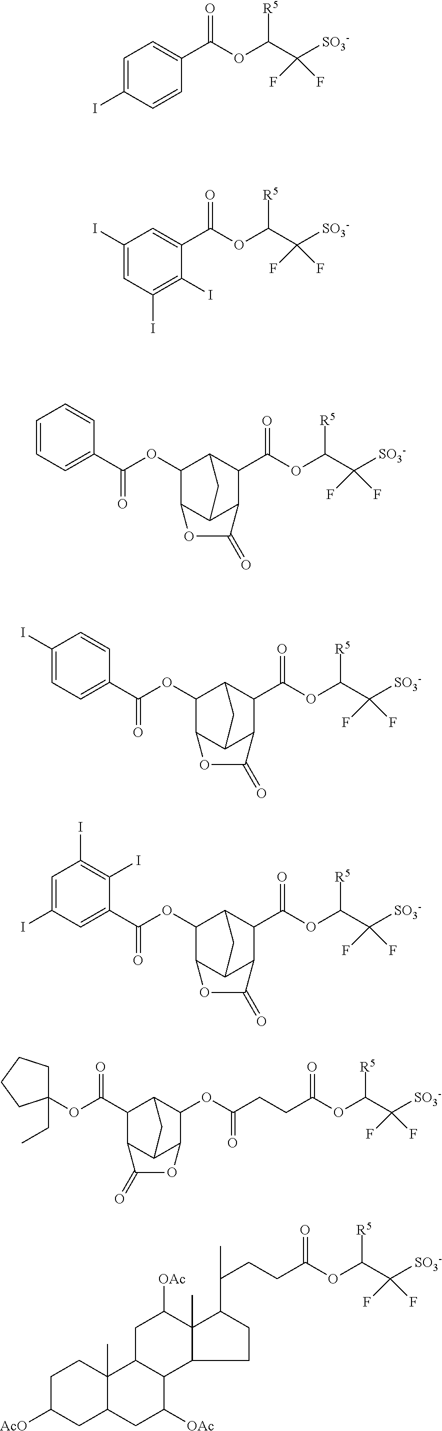

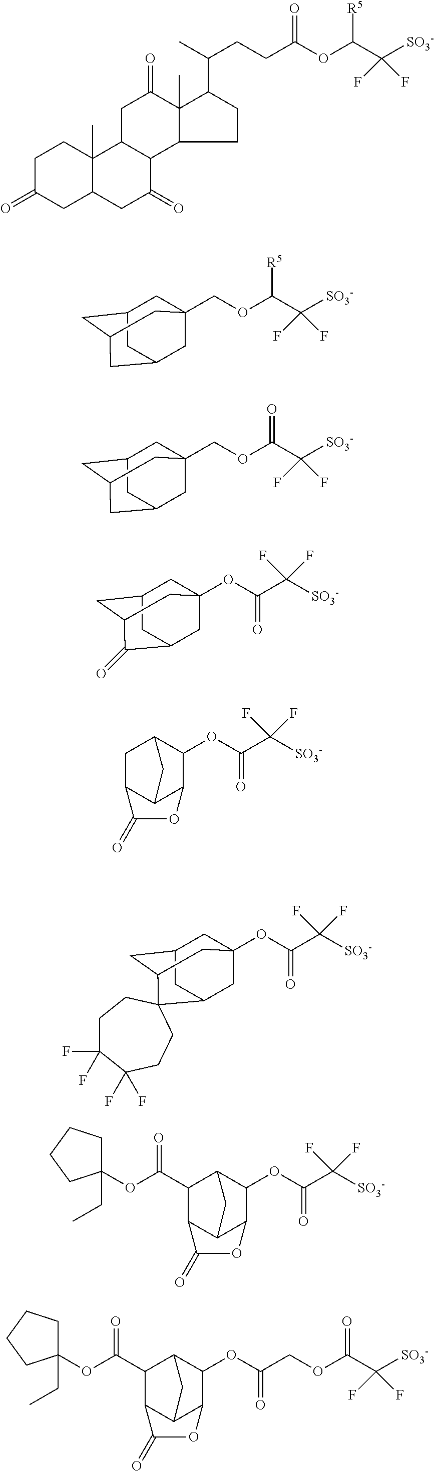

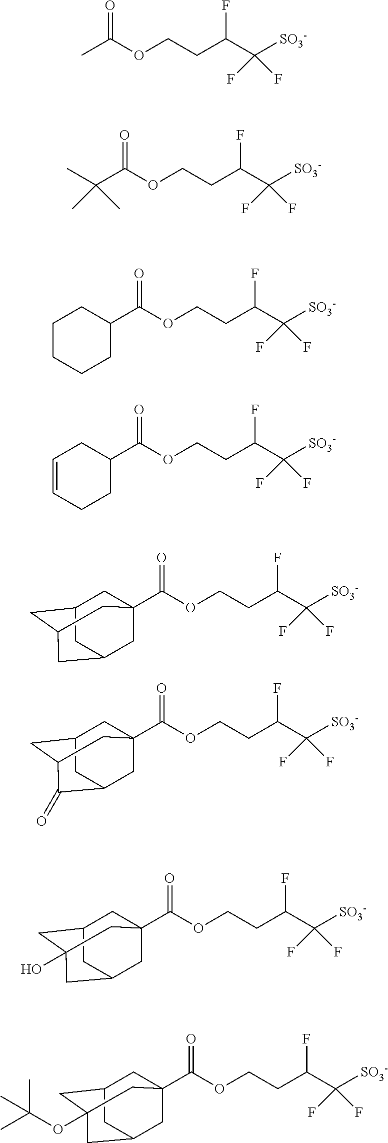

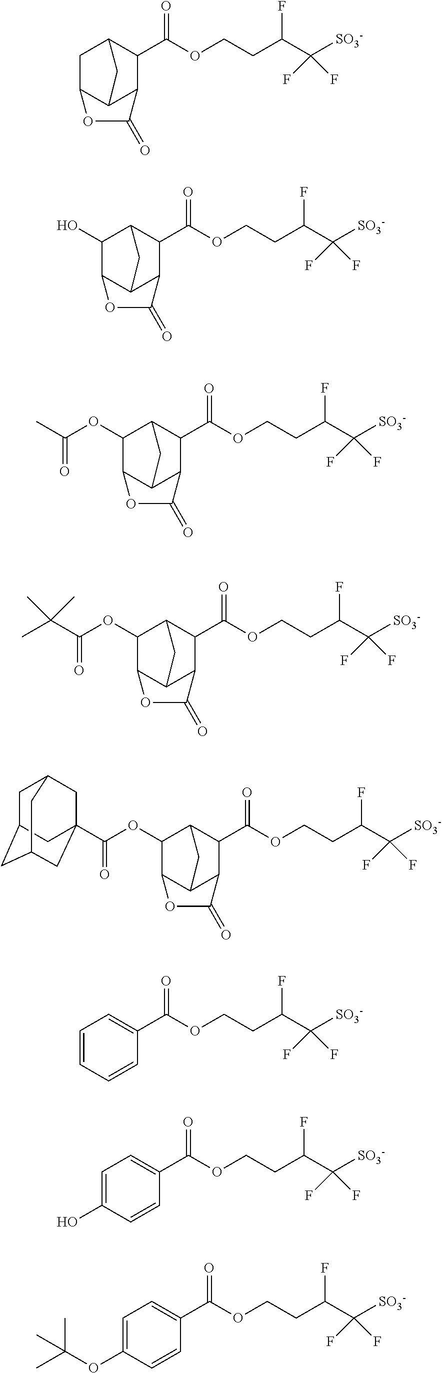

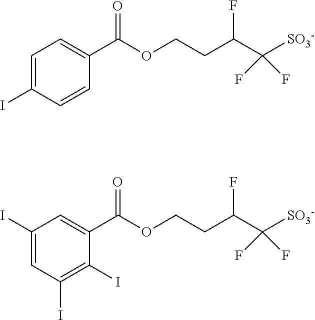

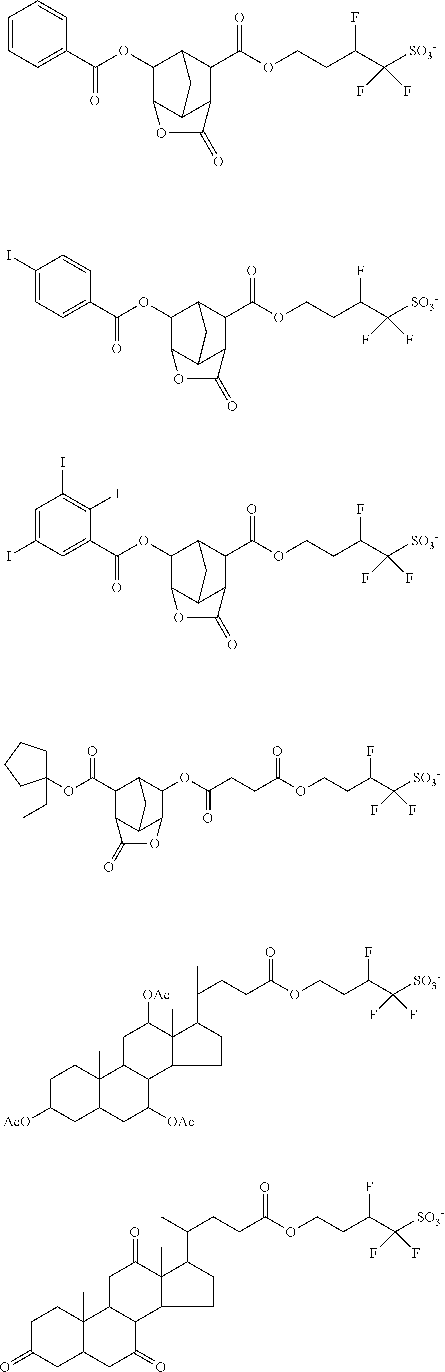

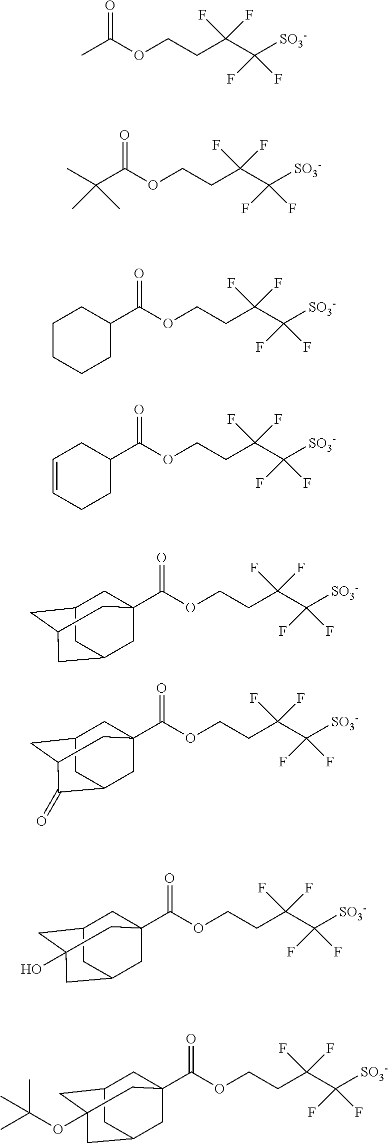

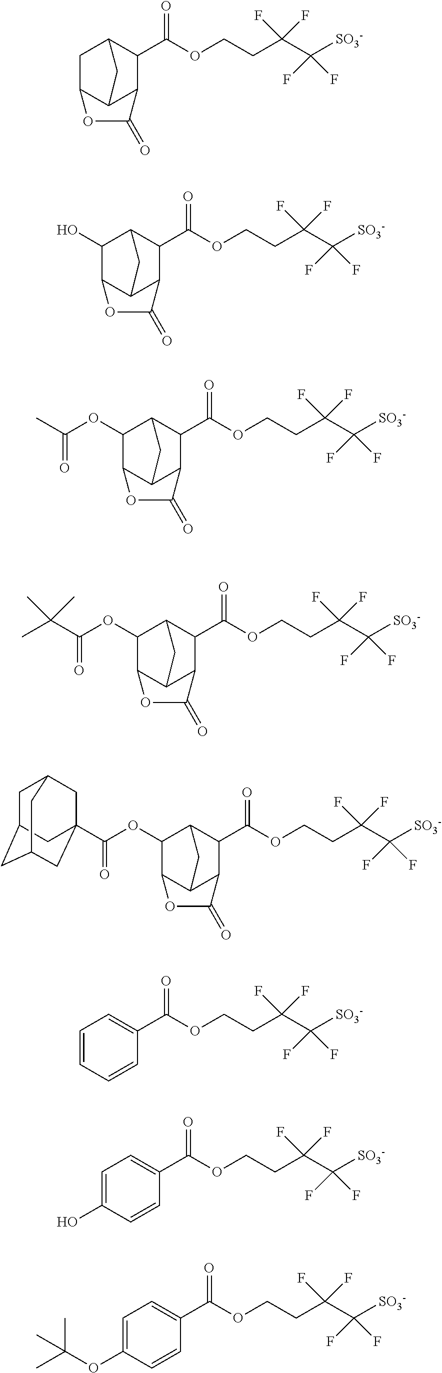

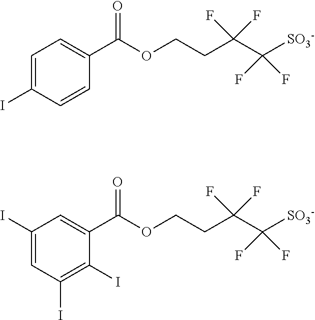

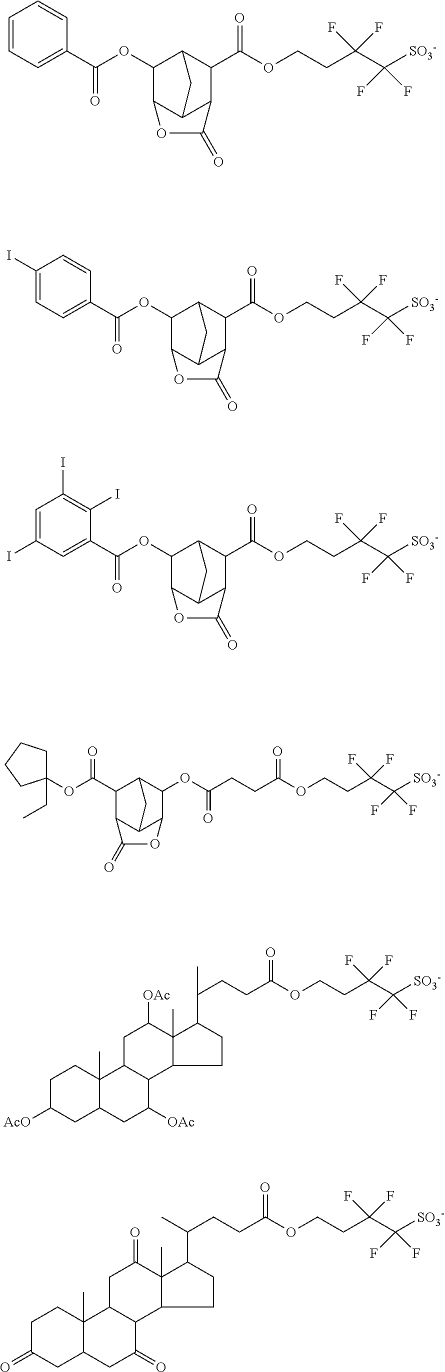

In formulae (A2) and (A3), L¹ is a single bond, an ether bond, an ester bond, a carbonyl group, a sulfonic ester bond, a carbonate bond, or a carbamate bond. From he aspect of synthesis, L¹ is preferably an ether bond, ester bond or carbonyl group, more preferably ester bond or carbonyl group.

In formula (A2), Rf¹ and Rf² are each independently a fluorine atom, or a C₁-C₆ fluorinated saturated hydrocarbyl group. It is preferred for enhancing the strength of the generated acid that both Rf¹ and Rf² be fluorine. Rf³ and Rf⁴ are each independently a hydrogen atom, a fluorine atom, or a C₁-C₆ fluorinated saturated hydrocarbyl group. It is preferred for enhancing the solvent solubility that at least one of Rf³ and Rf⁴ be trifluoromethyl.

In formula (A3), Rf⁵ and Rf⁶ are each independently a hydrogen atom, a fluorine atom, or a C₁-C₆ fluorinated saturated hydrocarbyl group. Not all Rf⁵ and Rf⁶ are hydrogen atom at the same time. It is preferred for enhancing the solvent solubility that at least one of Rf⁵ and Rf⁶ be trifluoromethyl.

In formulae (A2) and (A3), a is an integer of 0 to 3, preferably 1.

Examples of the anion in repeat unit A2 are shown below, but not limited thereto. Herein, R^{A} is as defined above.

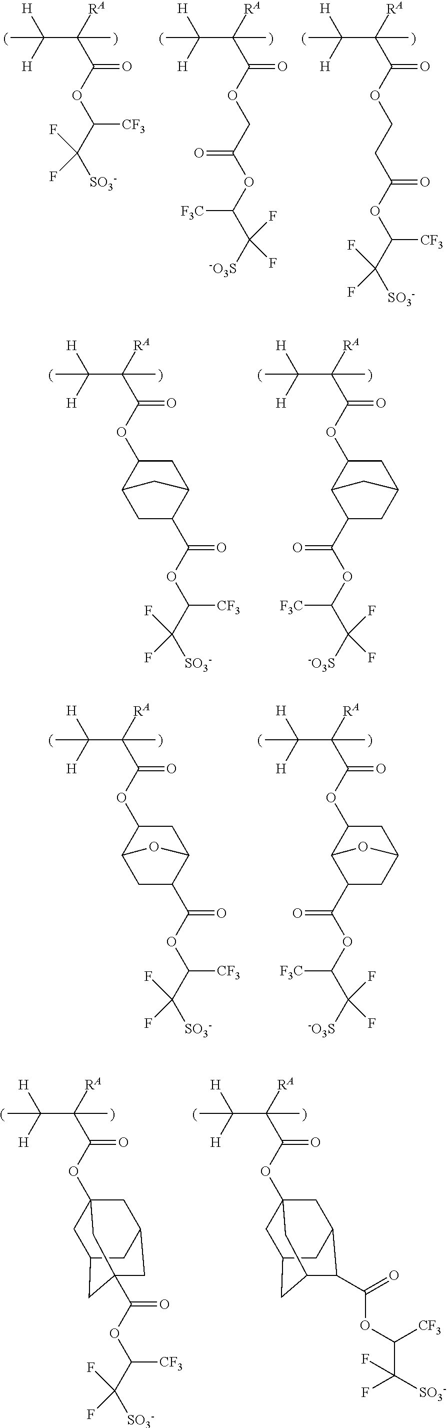

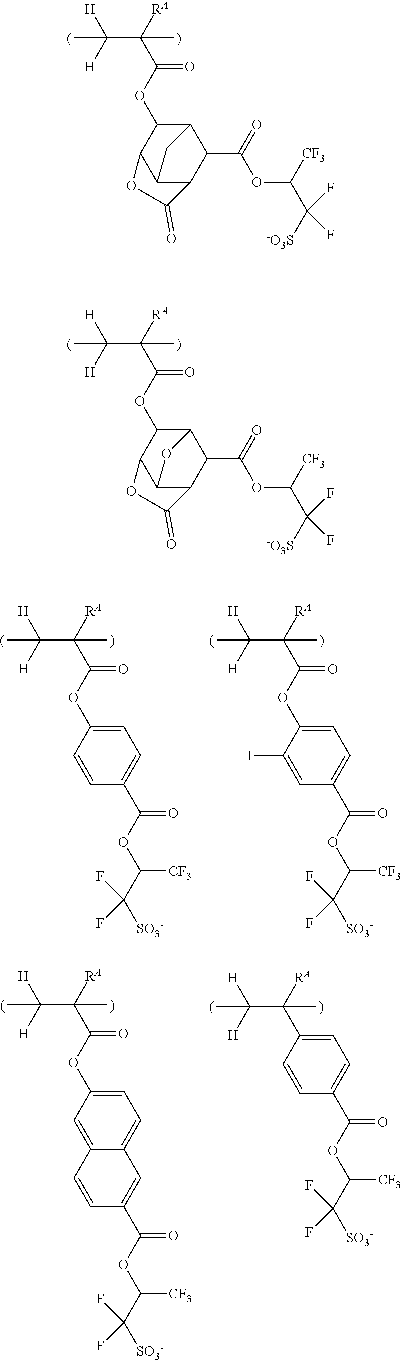

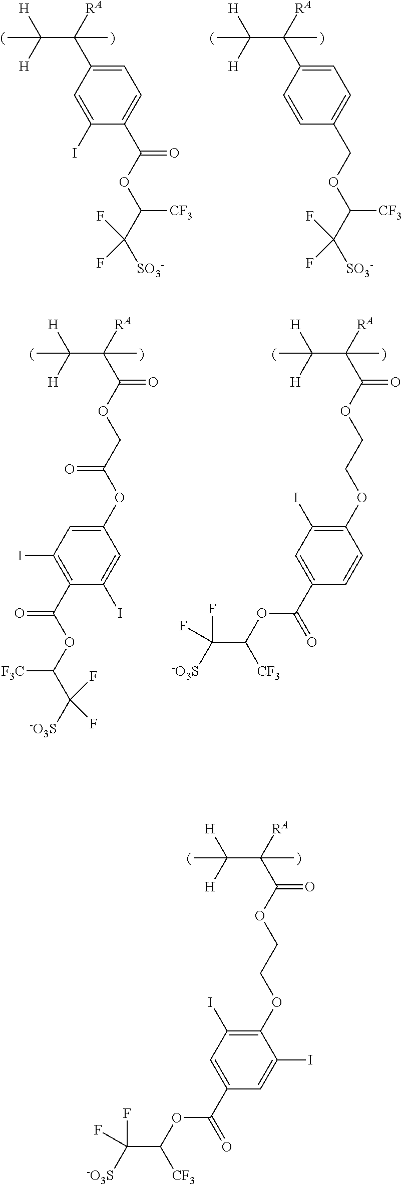

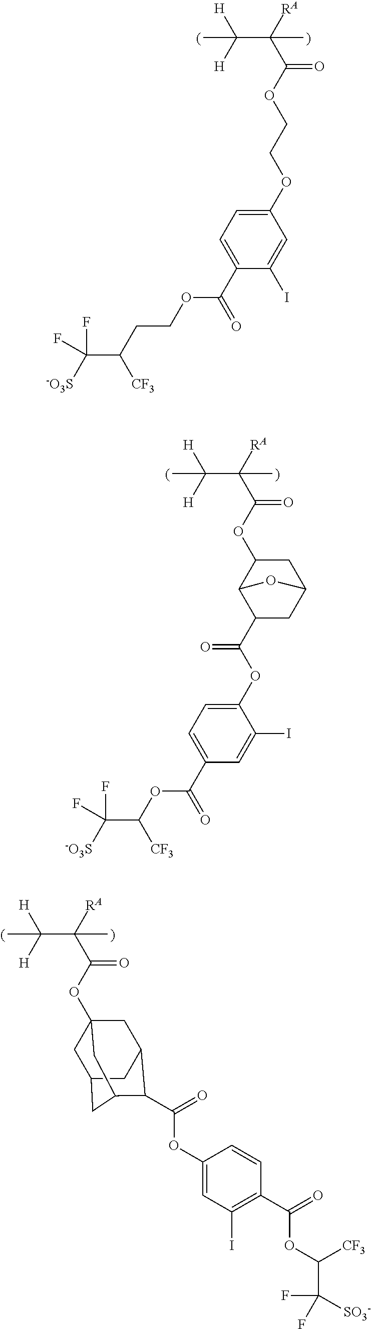

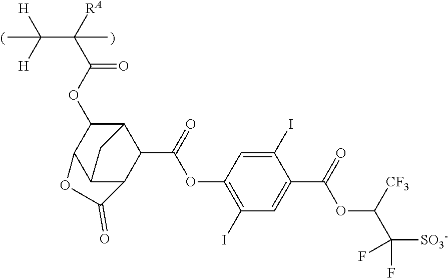

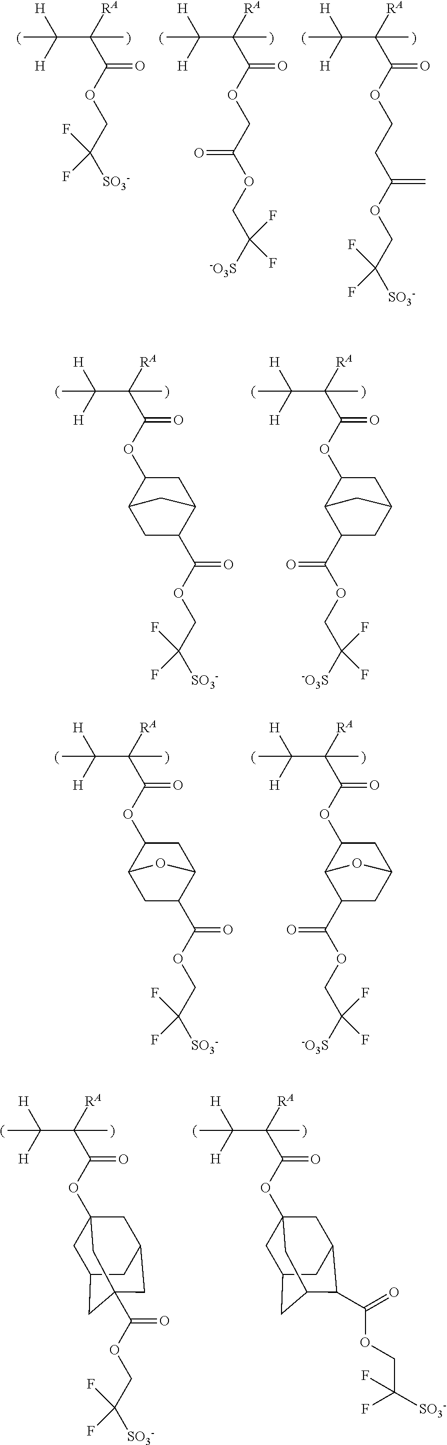

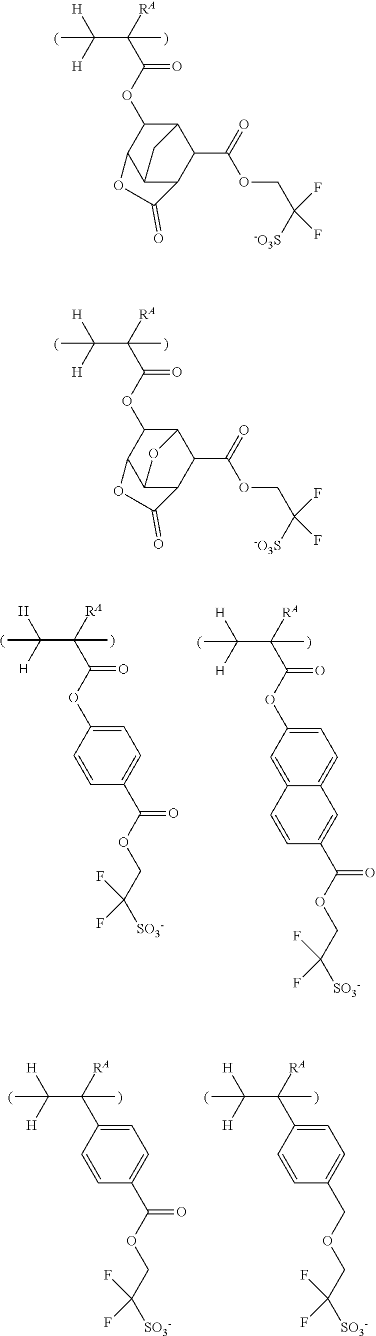

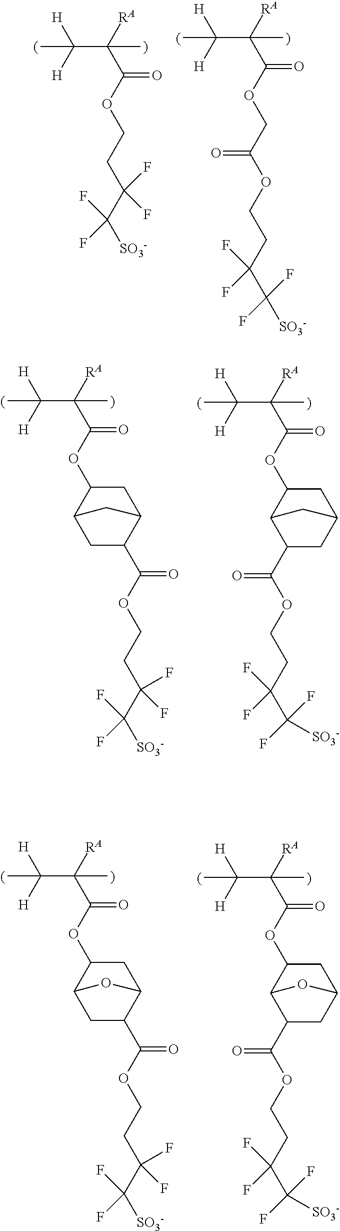

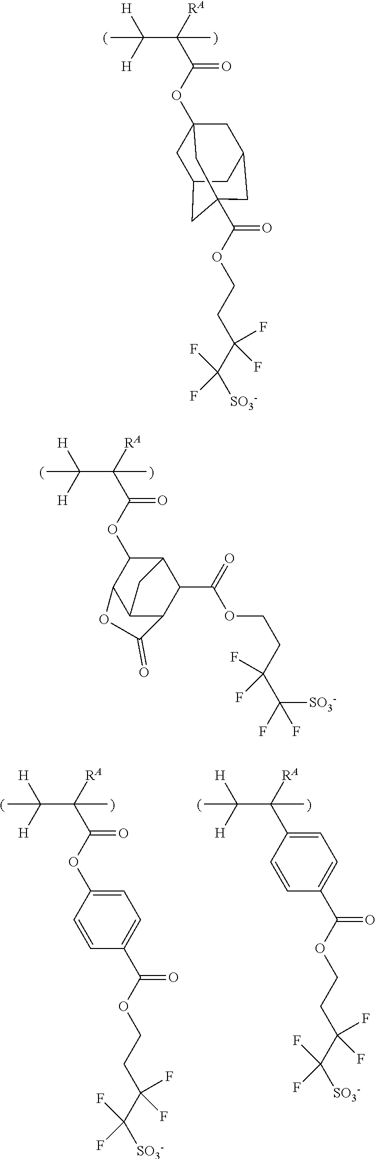

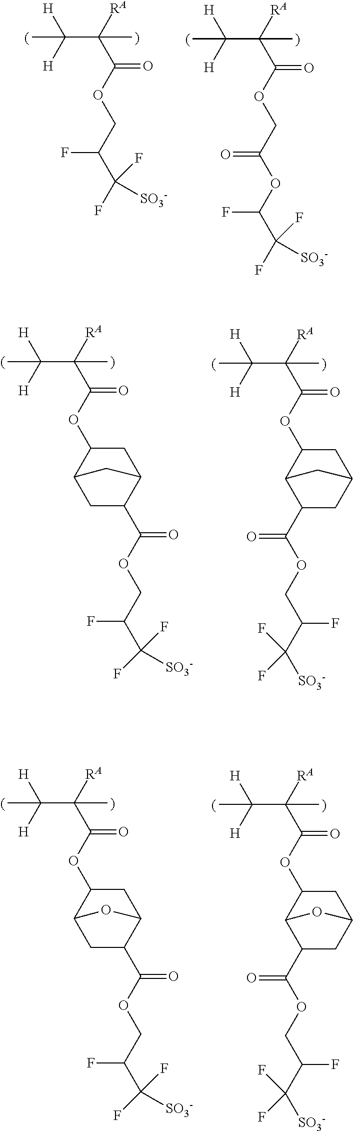

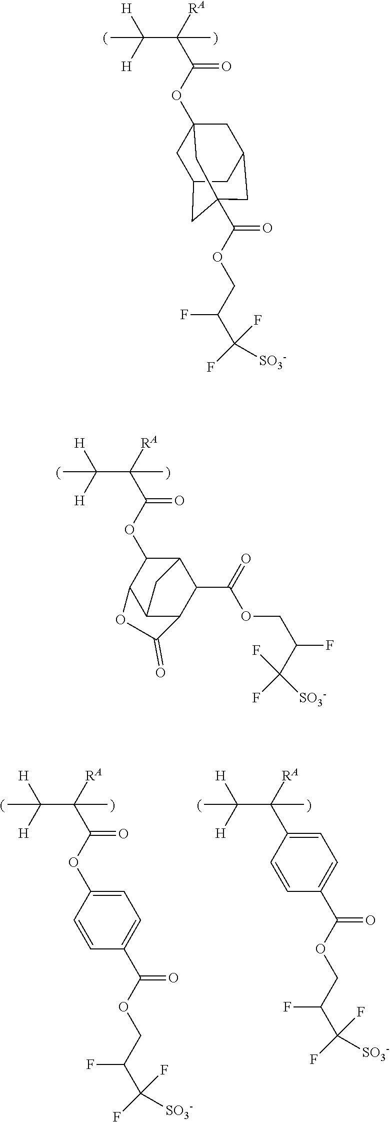

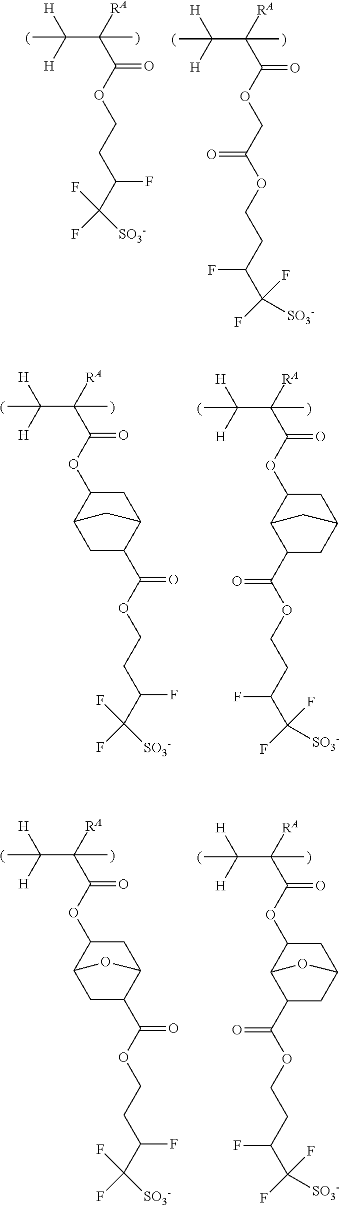

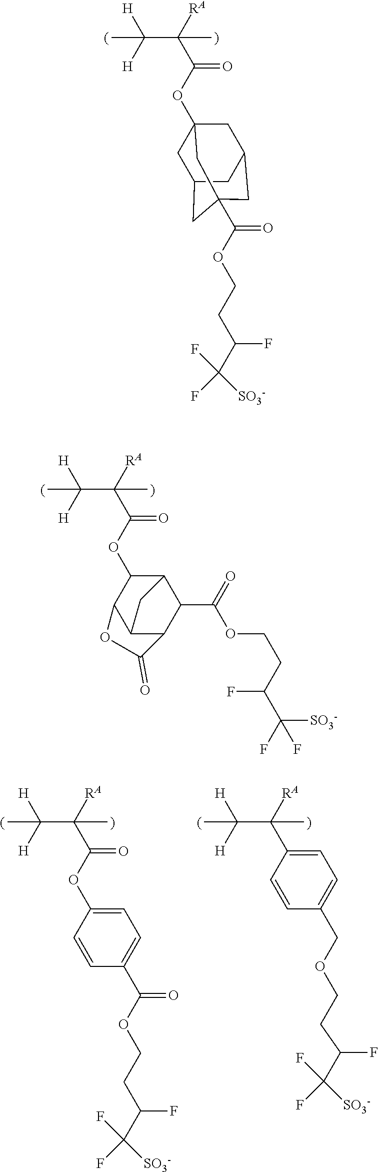

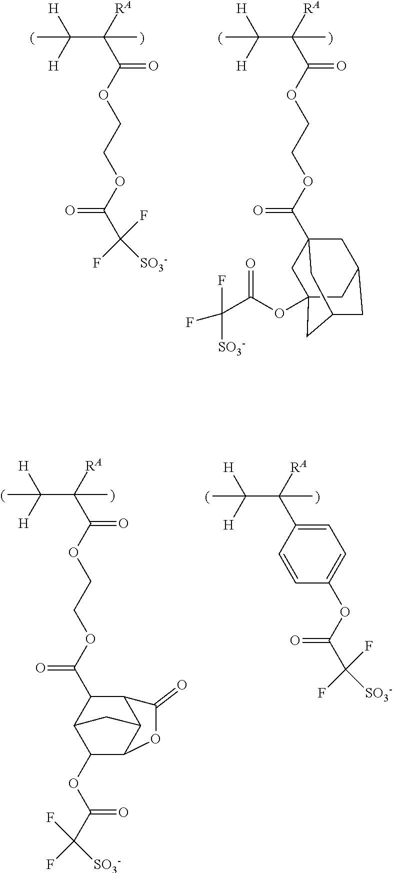

Examples of repeat unit A3 are shown below, but not limited thereto. Herein, R^{A} is as defined above.

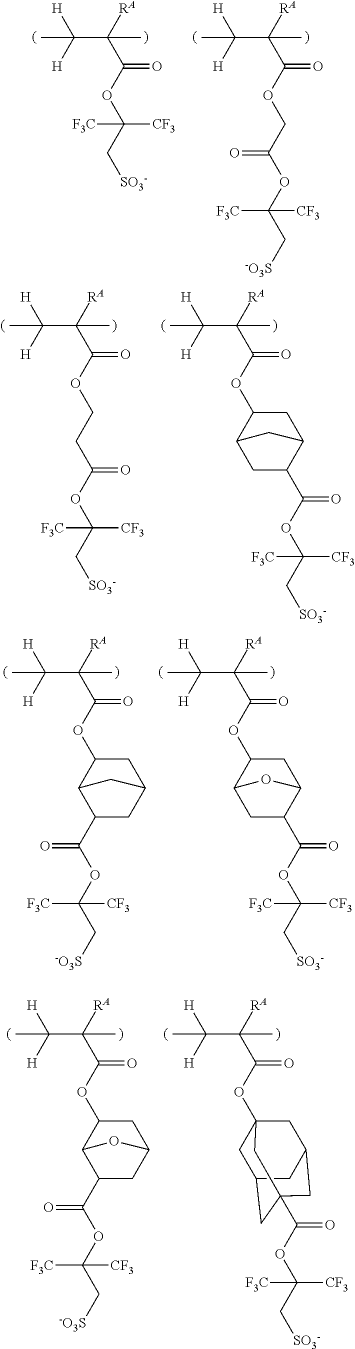

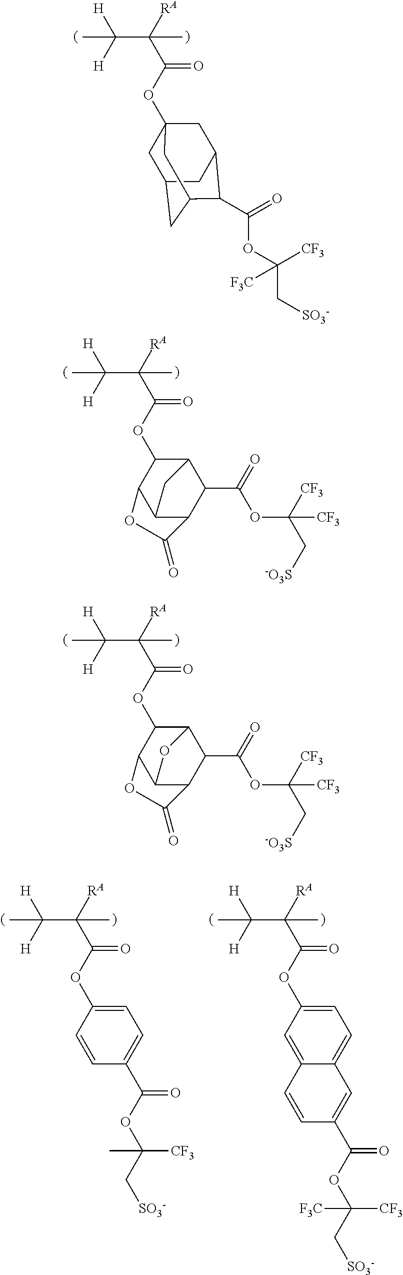

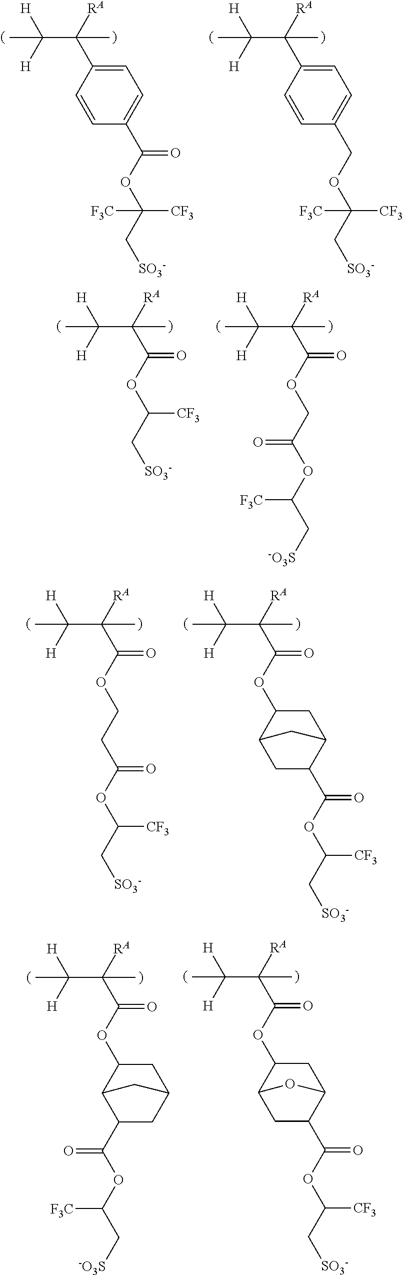

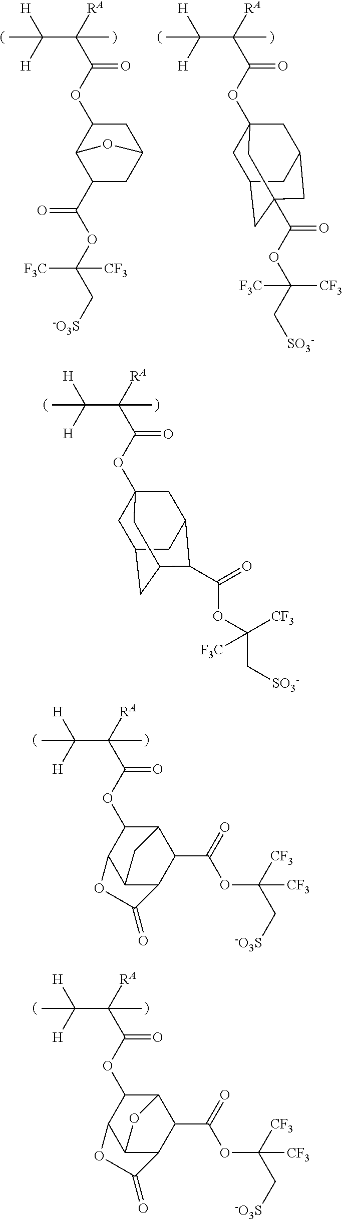

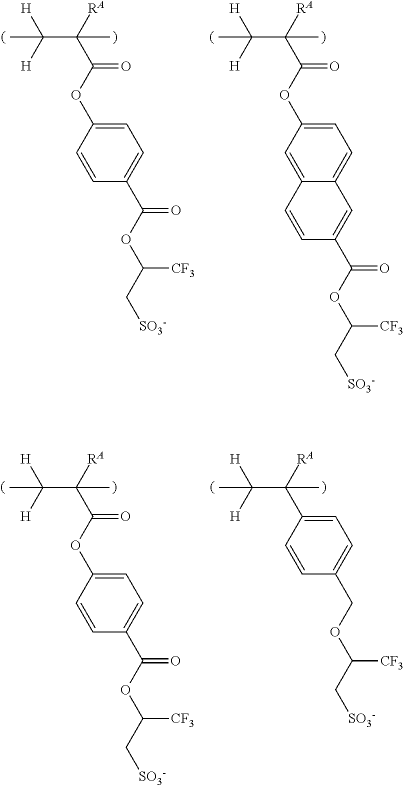

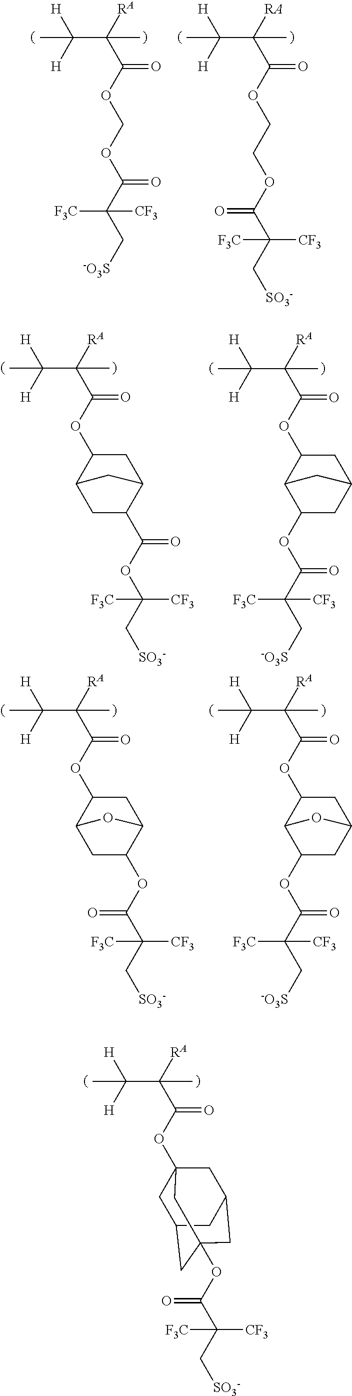

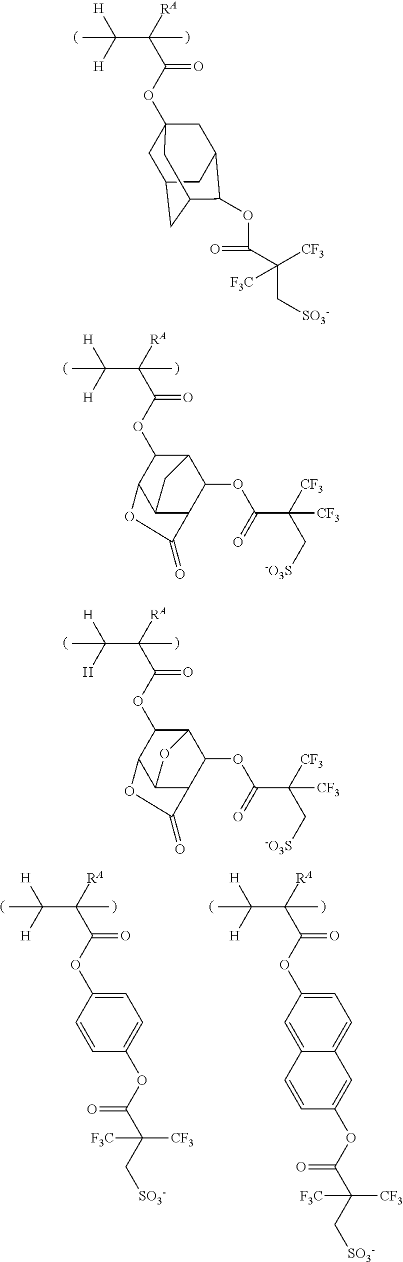

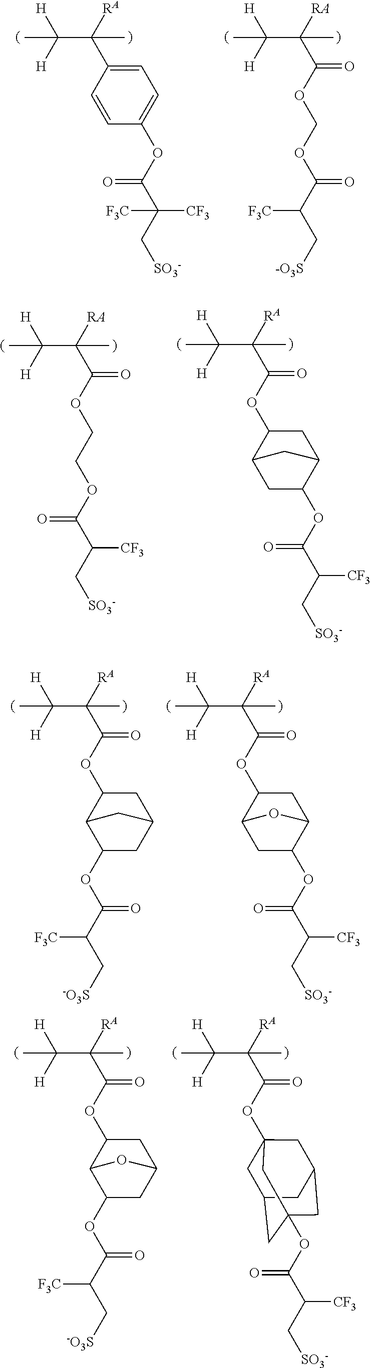

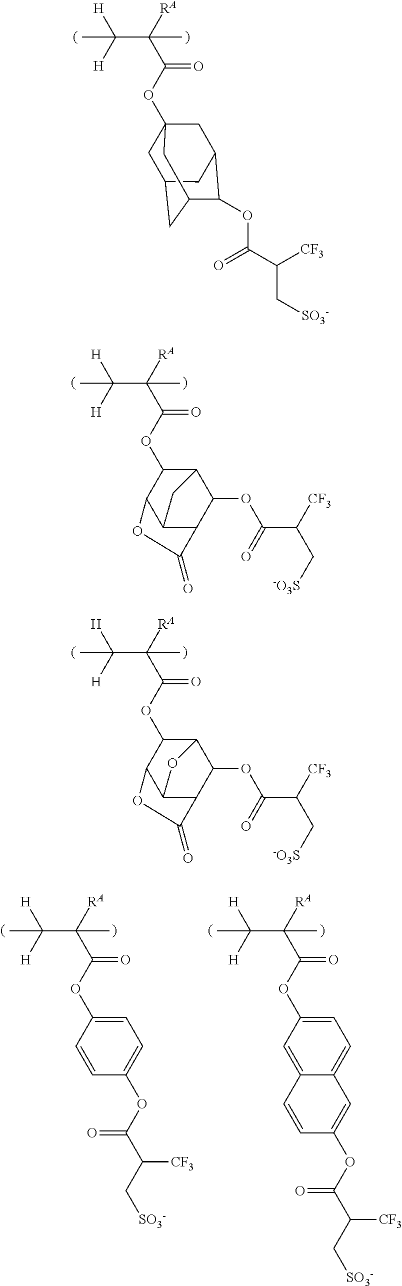

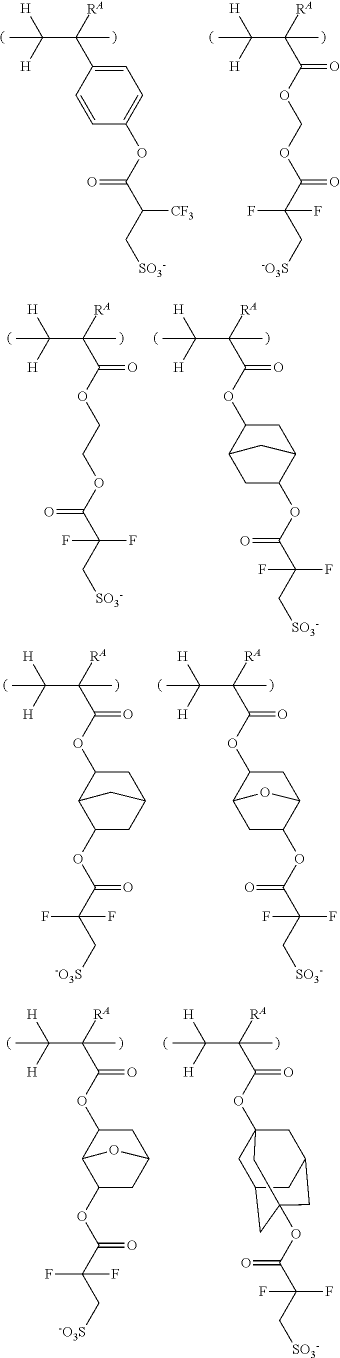

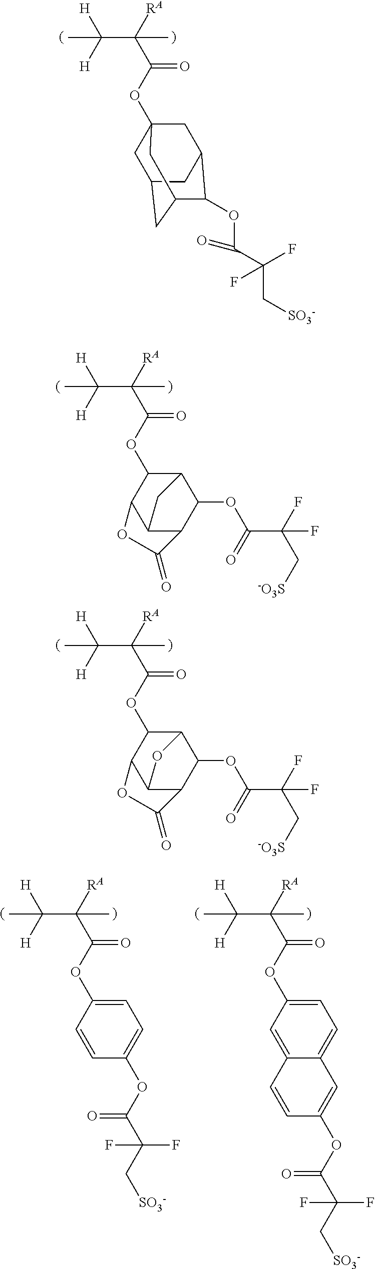

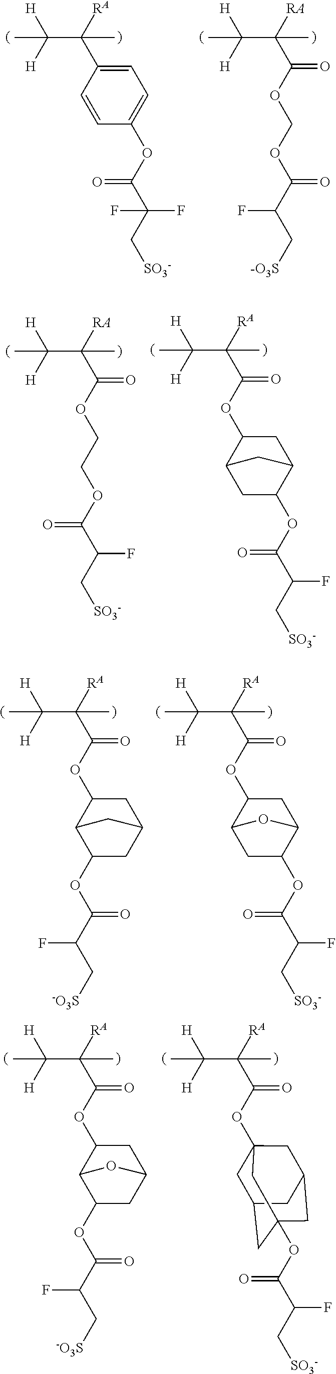

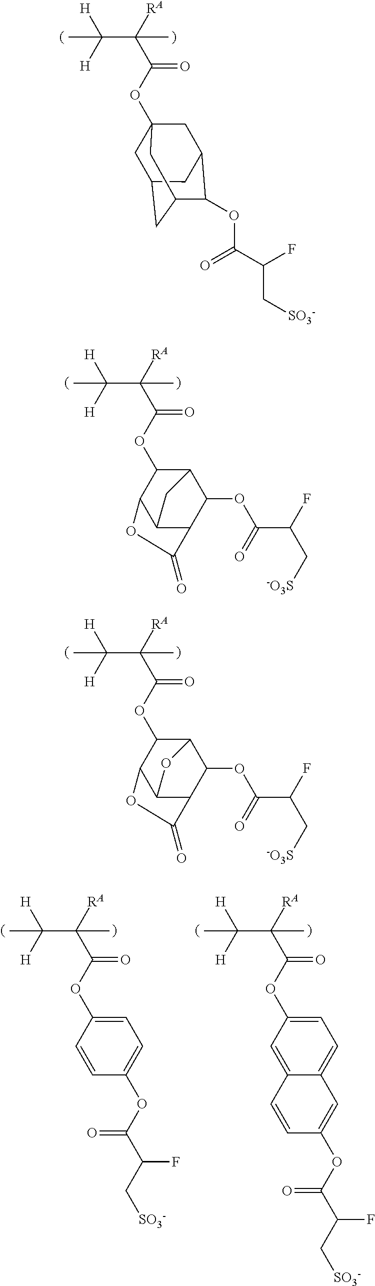

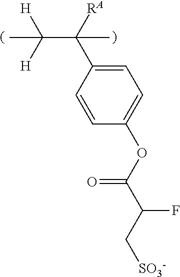

Examples of repeat unit A4 are shown below, but not limited thereto. Herein, R^{A} is as defined above.

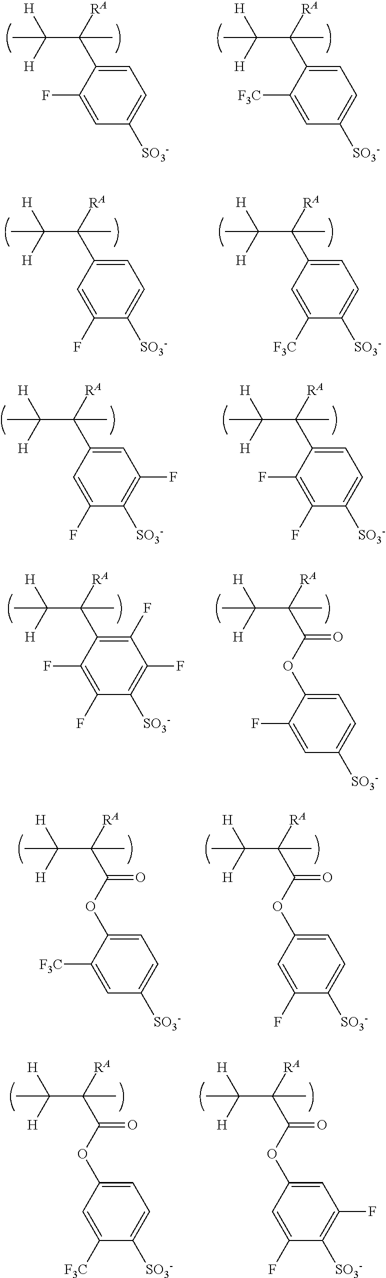

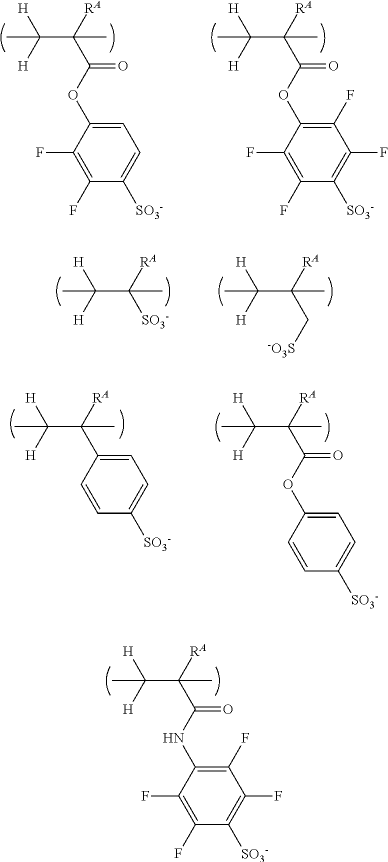

In formulae (A2) to (A4), A⁺ is an onium cation. Suitable onium cations include sulfonium, iodonium and ammonium cations, with the sulfonium and iodonium cations being preferred. More preferred are sulfonium cations having the formula (cation-1) and iodonium cations having the formula (cation-2).

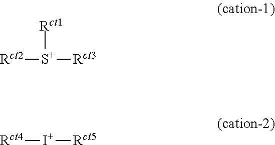

In formulae (cation-1) and (cation-2), R^{ct1} to R^{ct5} are each independently a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl and tert-butyl groups; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl and adamantyl groups; C₂-C₂₀ alkenyl groups such as vinyl, allyl, propenyl, butenyl and hexenyl groups; C₃-C₂₀ cyclic unsaturated hydrocarbyl groups such as a cyclohexenyl group; C₆-C₂₀ aryl groups such as phenyl, naphthyl and thienyl groups; C₇-C₂₀ aralkyl groups such as benzyl, 1-phenylethyl and 2-phenylethyl groups; and combinations thereof. The aryl groups are preferred. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like.

R^{ct1} and R^{ct2} may bond together to form a ring with the sulfur atom to which they are attached. Examples of the ring include those represented by the following formula.

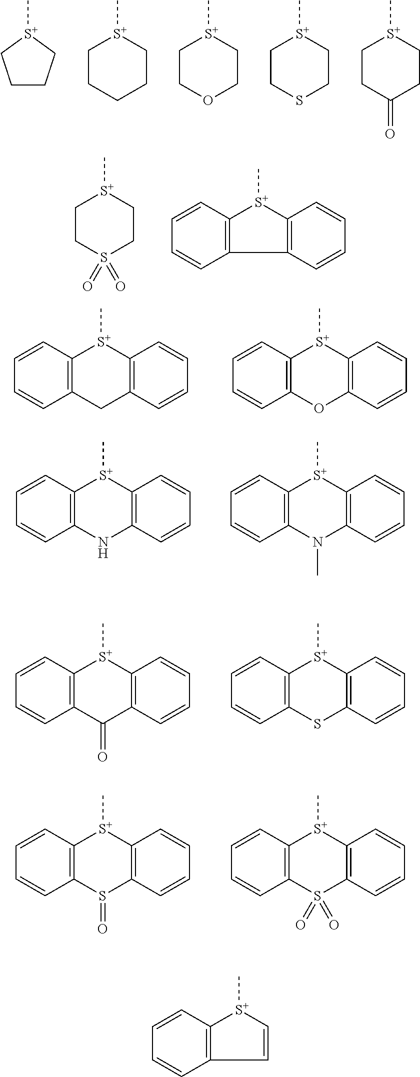

Herein the broken line designates a point of attachment to R^{ct3}.

Examples of the sulfonium cation represented by formula (cation-1) are shown below, but not limited thereto.

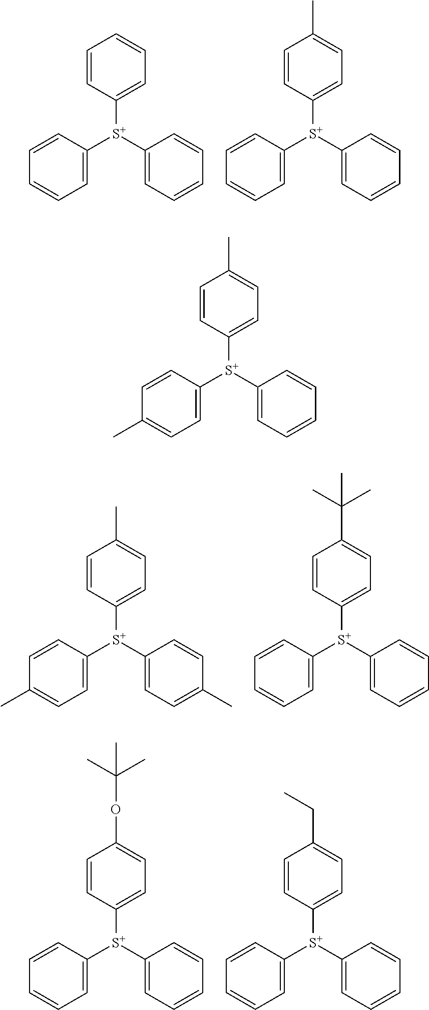

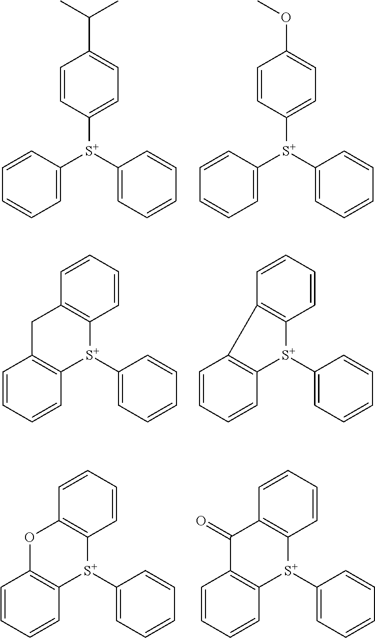 [SMILES: CC(C)c1ccc([S+](c2ccccc2)c2ccccc2)cc1 ; COc1ccc([S+](c2ccccc2)c2ccccc2)cc1 ; c1ccc([S+]2c3ccccc3Cc3ccccc32)cc1 ; c1ccc(-[s+]2c3ccccc3c3ccccc32)cc1 ; c1ccc([S+]2c3ccccc3Oc3ccccc32)cc1 ; O=c1c2ccccc2[s+](-c2ccccc2)c2ccccc12]

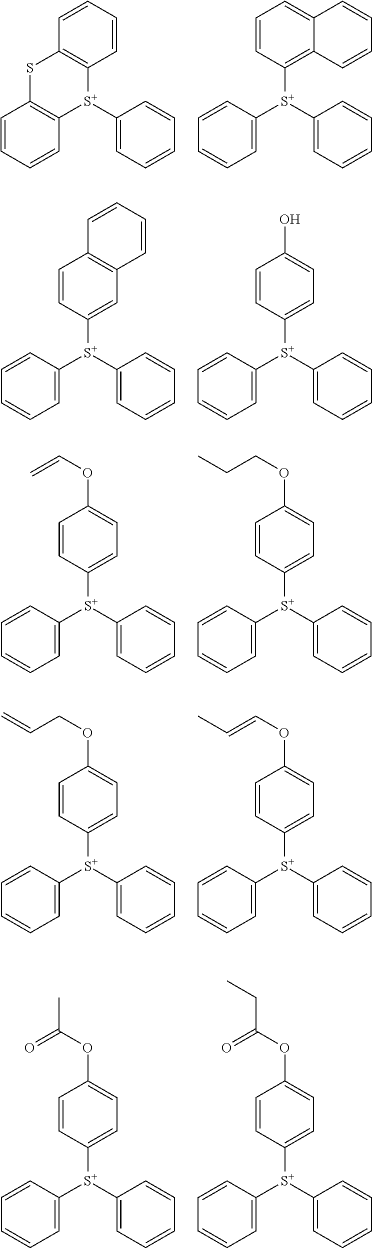

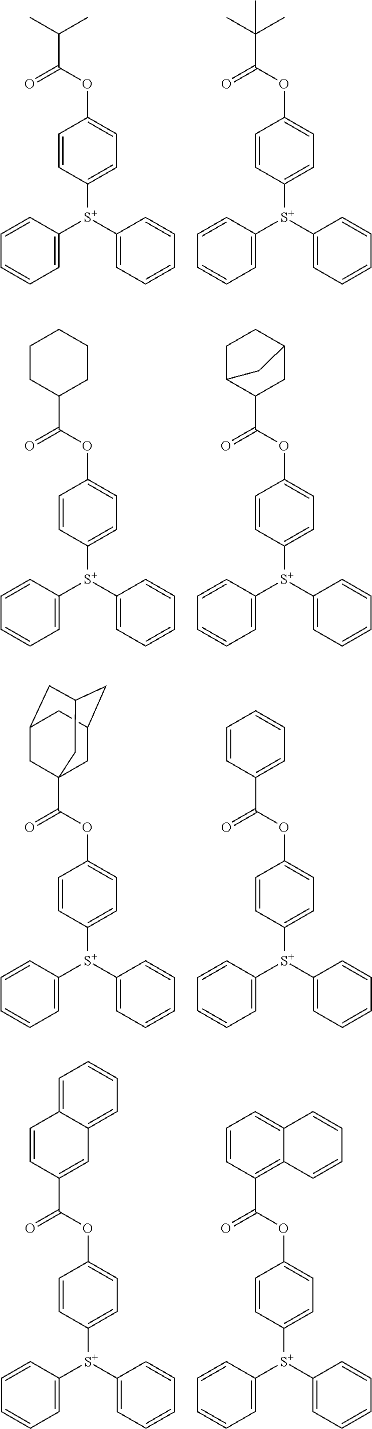

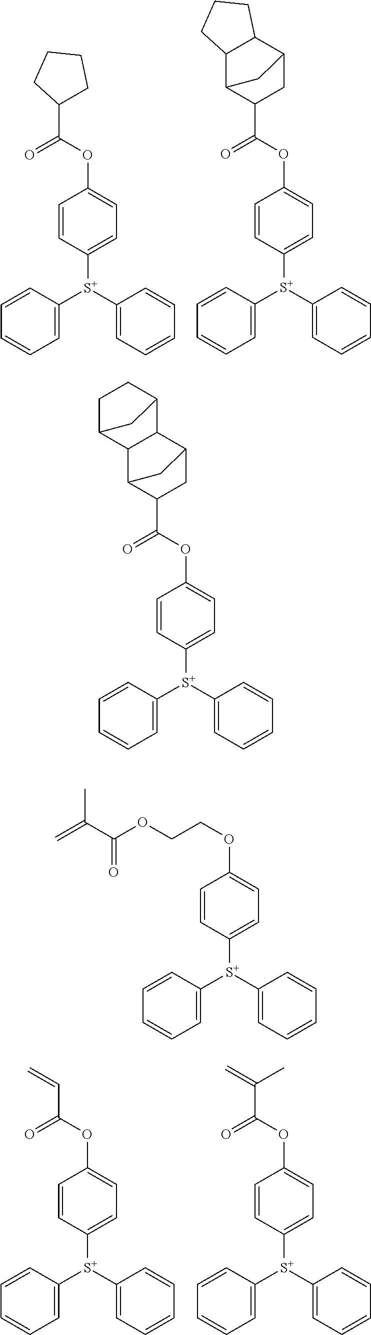 [SMILES: O=C(Oc1ccc([S+](c2ccccc2)c2ccccc2)cc1)C1CCCC1 ; O=C(Oc1ccc([S+](c2ccccc2)c2ccccc2)cc1)C1CC2CC1C1CCCC21 ; O=C(Oc1ccc([S+](c2ccccc2)c2ccccc2)cc1)C1CC2CC1C1C3CCC(C3)C21 ; C=C(C)C(=O)OCCOc1ccc([S+](c2ccccc2)c2ccccc2)cc1 ; C=CC(=O)Oc1ccc([S+](c2ccccc2)c2ccccc2)cc1 ; C=C(C)C(=O)Oc1ccc([S+](c2ccccc2)c2ccccc2)cc1]

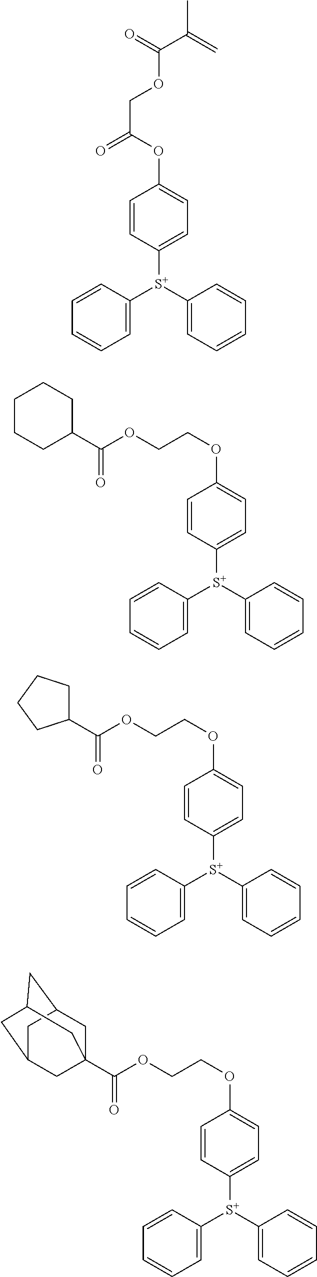 [SMILES: C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2]

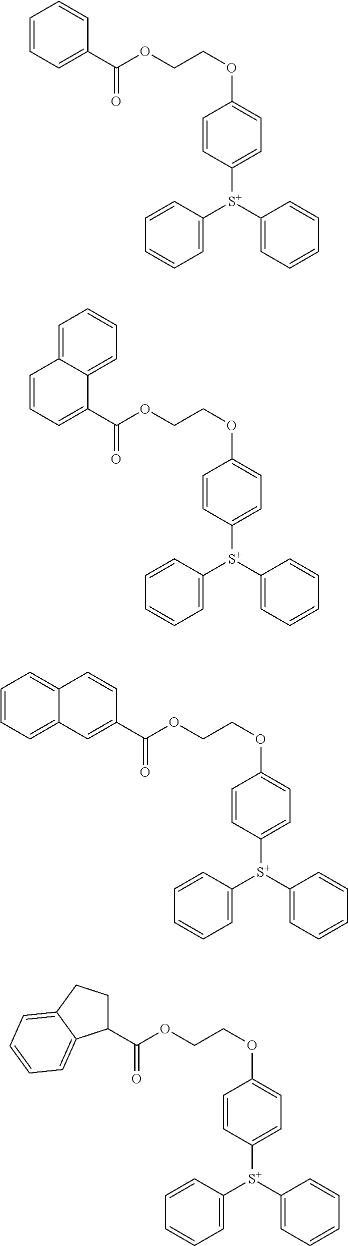 [SMILES: O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

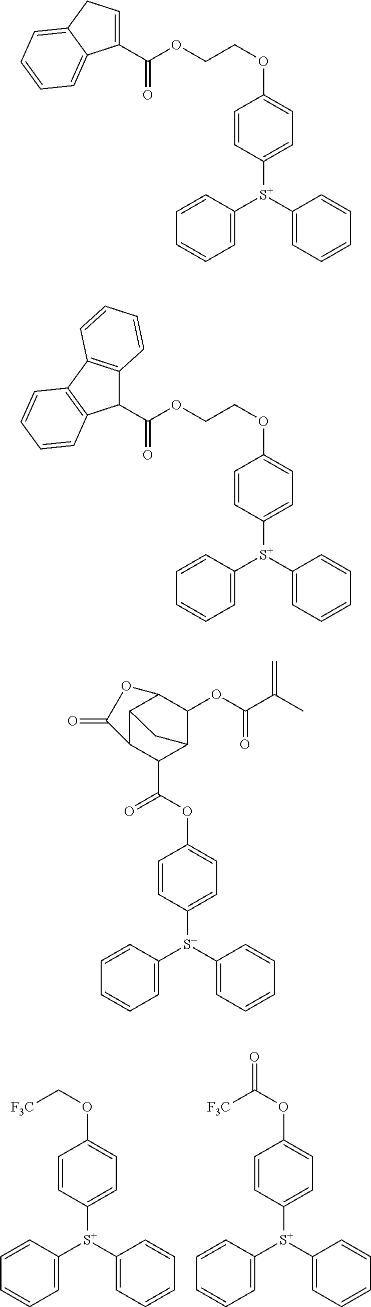 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F]

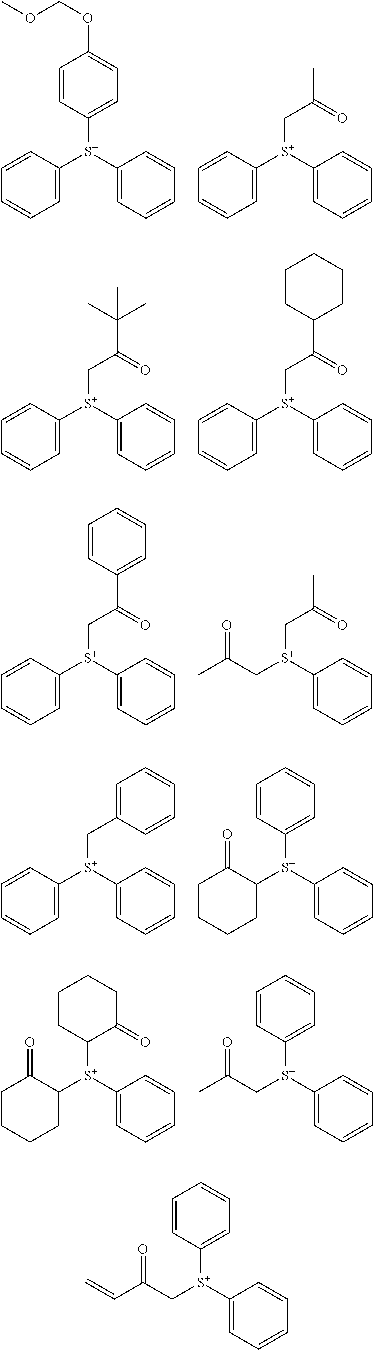

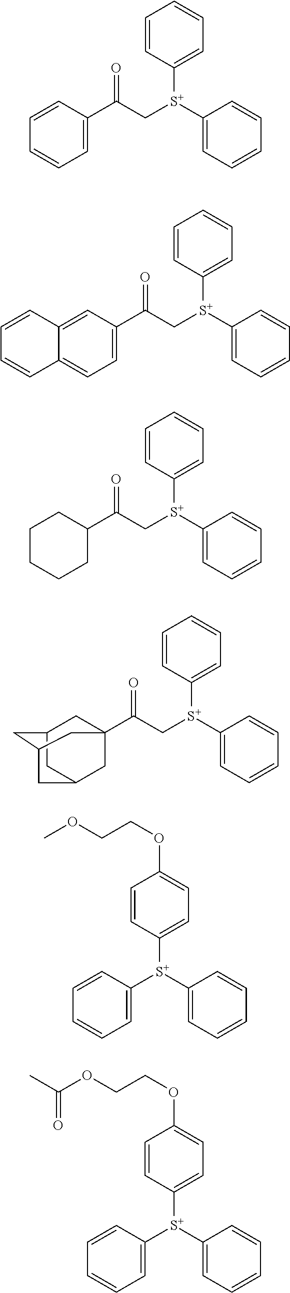 [SMILES: O=C(C[S+](c1ccccc1)c1ccccc1)c1ccccc1 ; O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2 ; COCCOc1ccc([S+](c2ccccc2)c2ccccc2)cc1 ; CC(=O)OCCOc1ccc([S+](c2ccccc2)c2ccccc2)cc1]

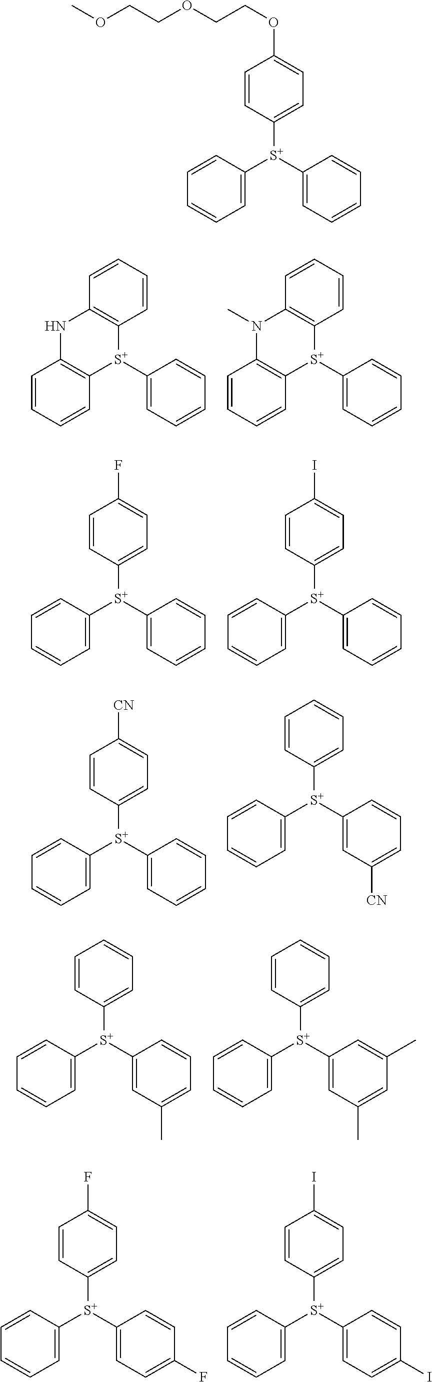

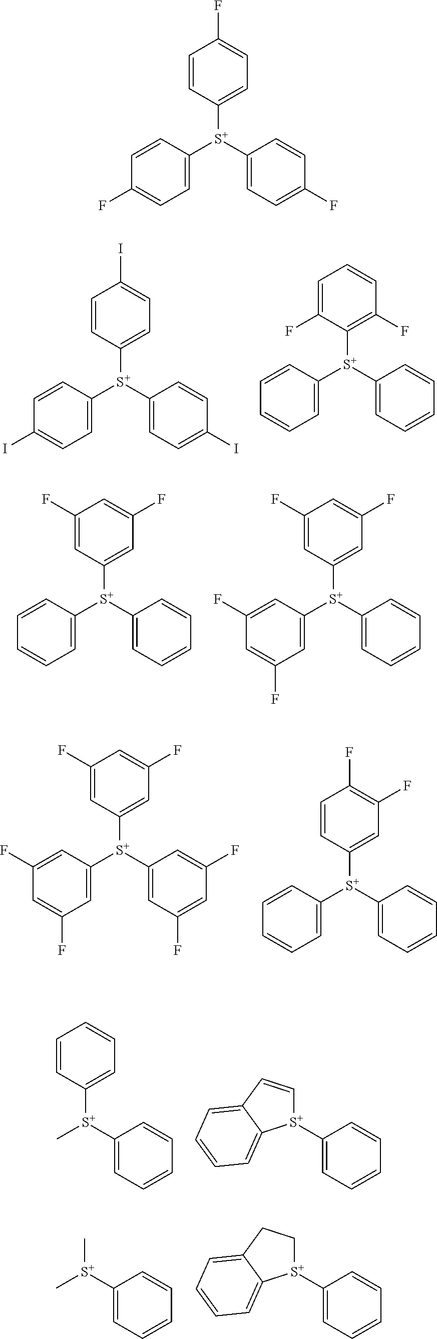

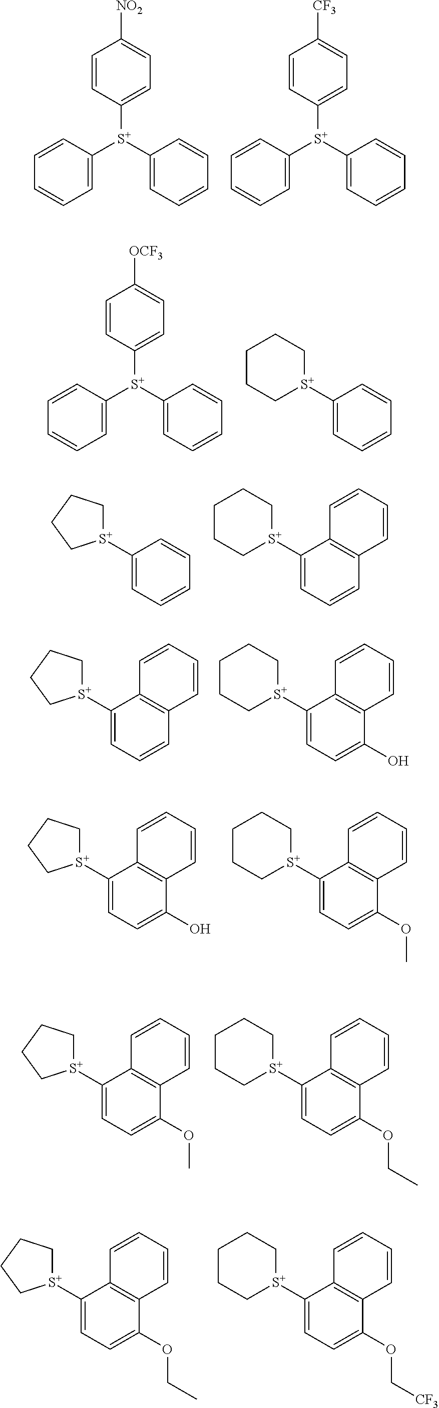

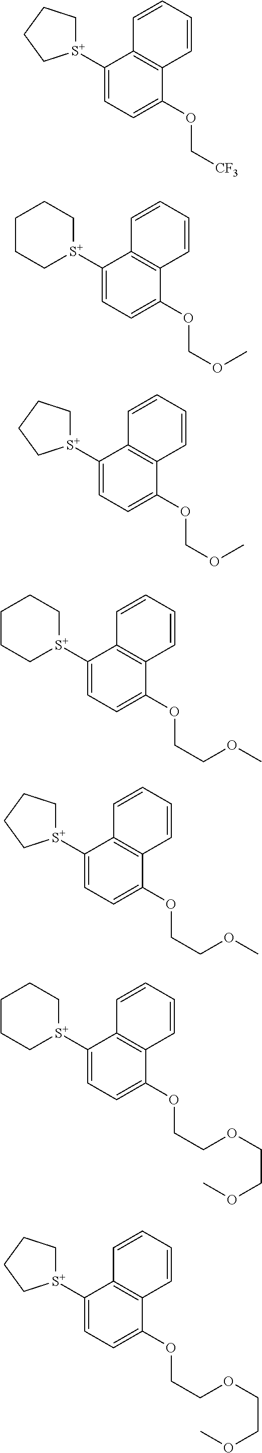

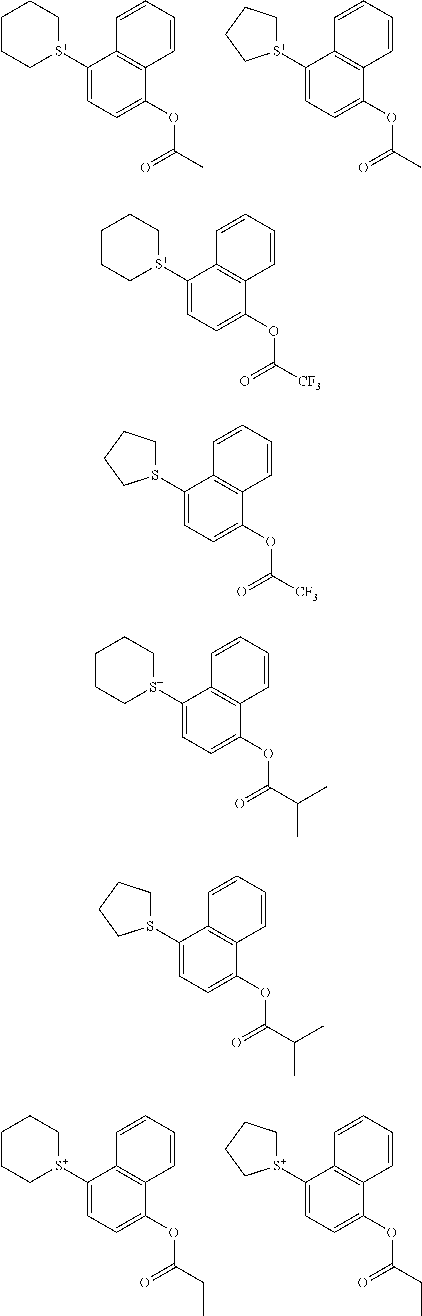

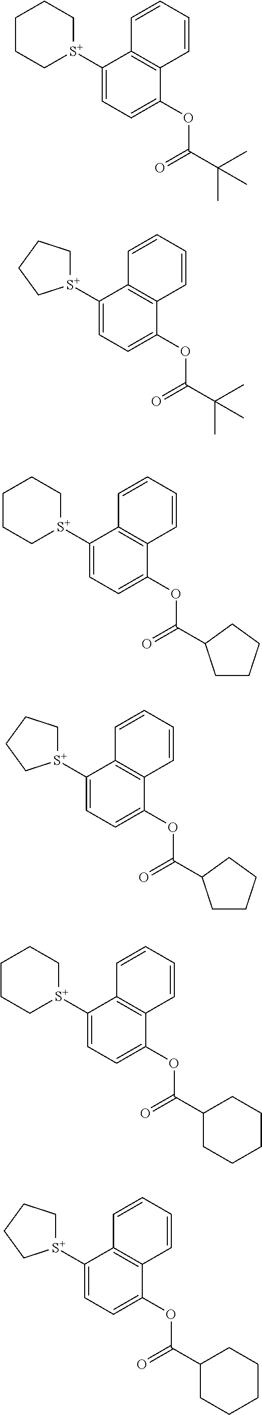 [SMILES: CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1]

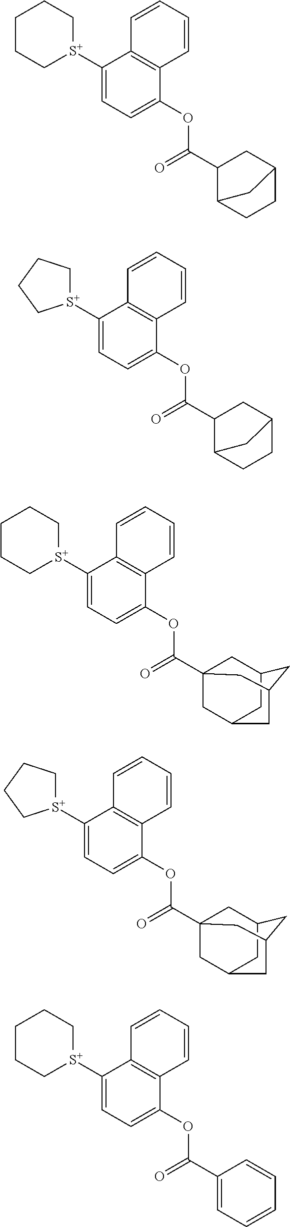 [SMILES: O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; O=C(Oc1ccc([S+]2CCCCC2)c2ccccc12)c1ccccc1]

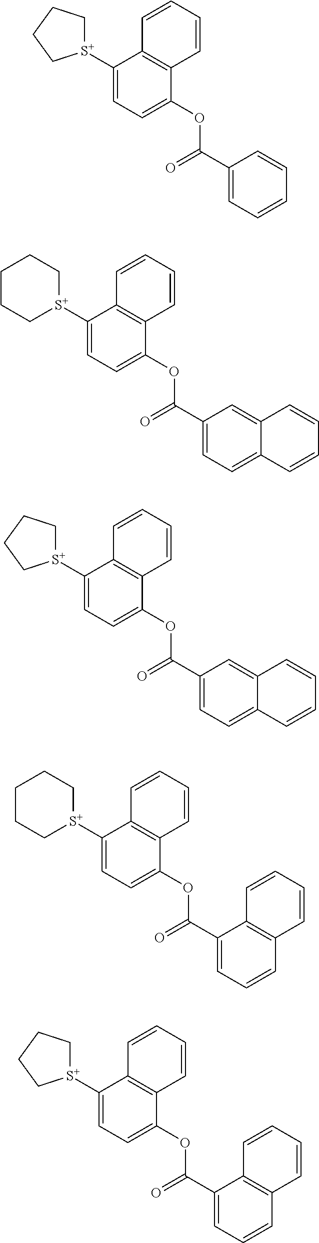 [SMILES: O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12]

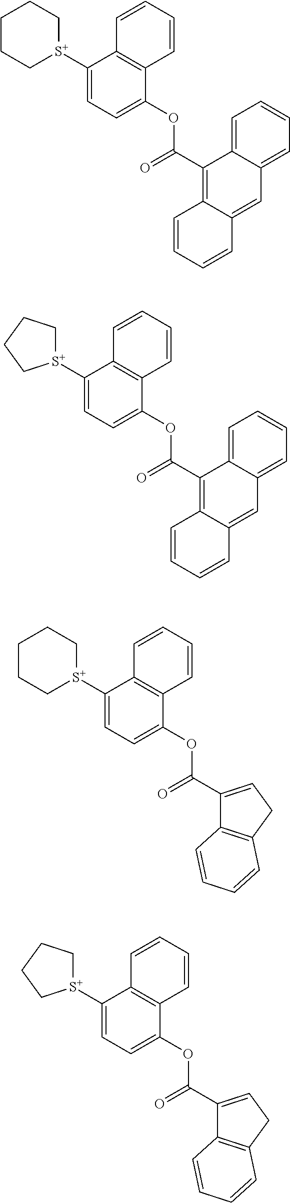 [SMILES: O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21]

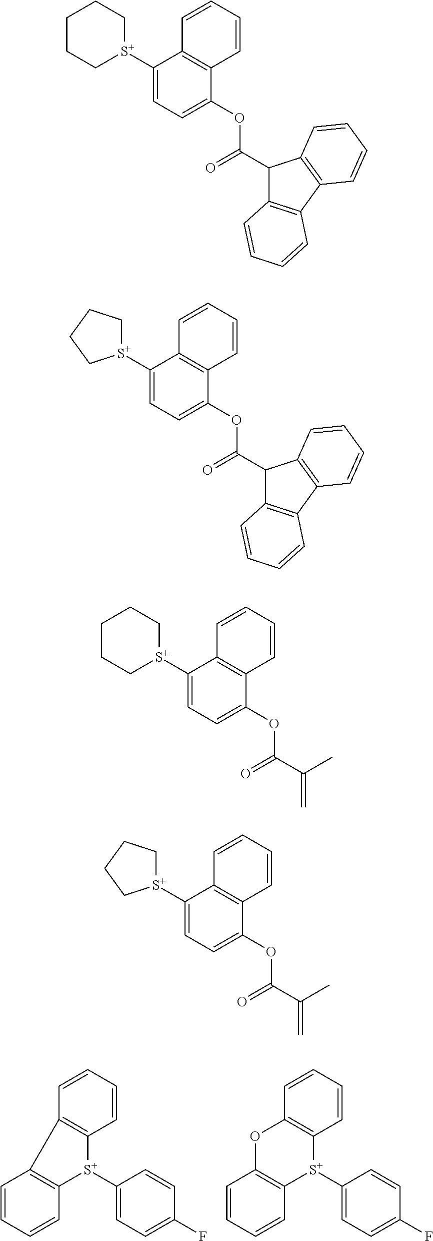 [SMILES: O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21 ; C=C(C)C(=O)Oc1ccc([S+]2CCCCC2)c2ccccc12 ; C=C(C)C(=O)Oc1ccc([S+]2CCCC2)c2ccccc12 ; Fc1ccc(-[s+]2c3ccccc3c3ccccc32)cc1 ; Fc1ccc([S+]2c3ccccc3Oc3ccccc32)cc1]

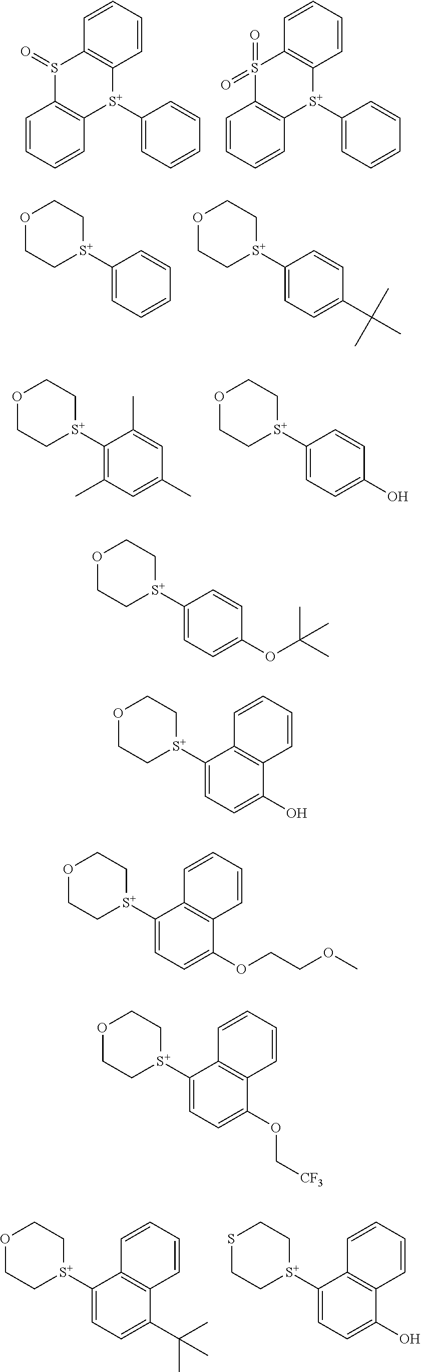

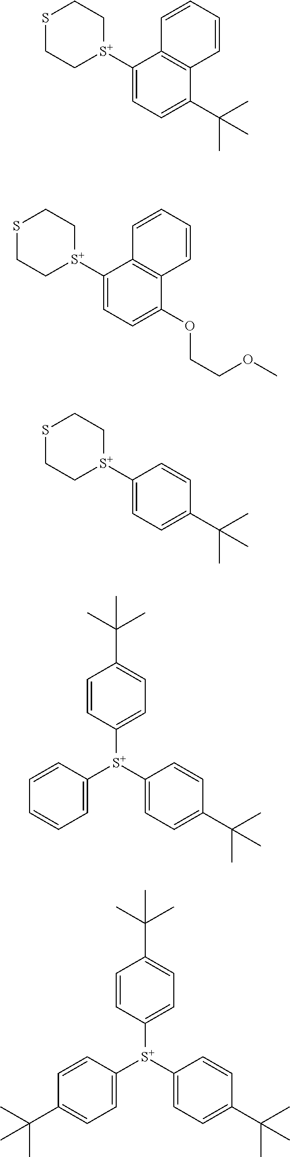

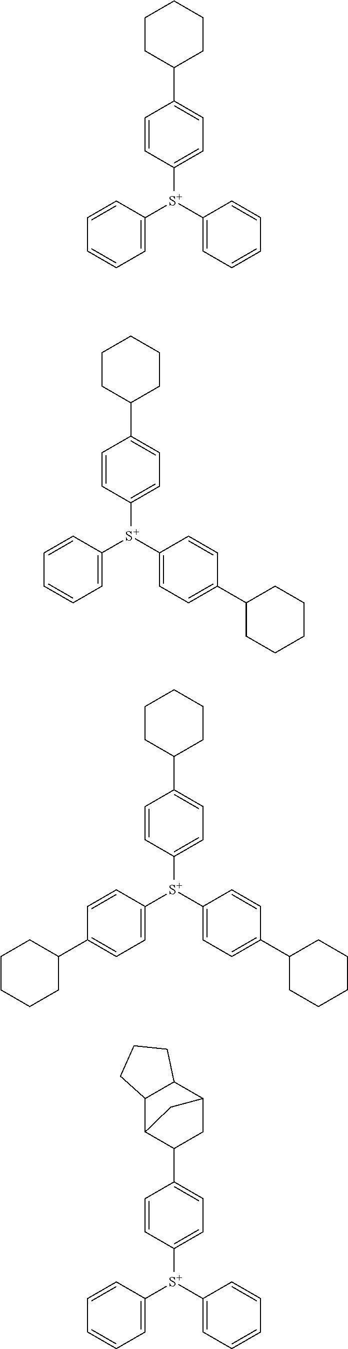 [SMILES: c1ccc([S+](c2ccccc2)c2ccc(C3CCCCC3)cc2)cc1 ; c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1]

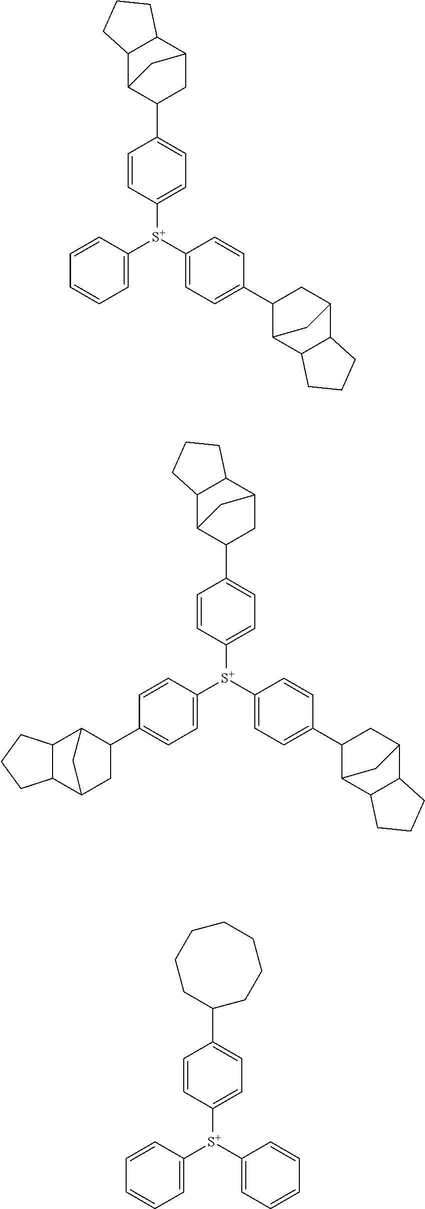 [SMILES: c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1]

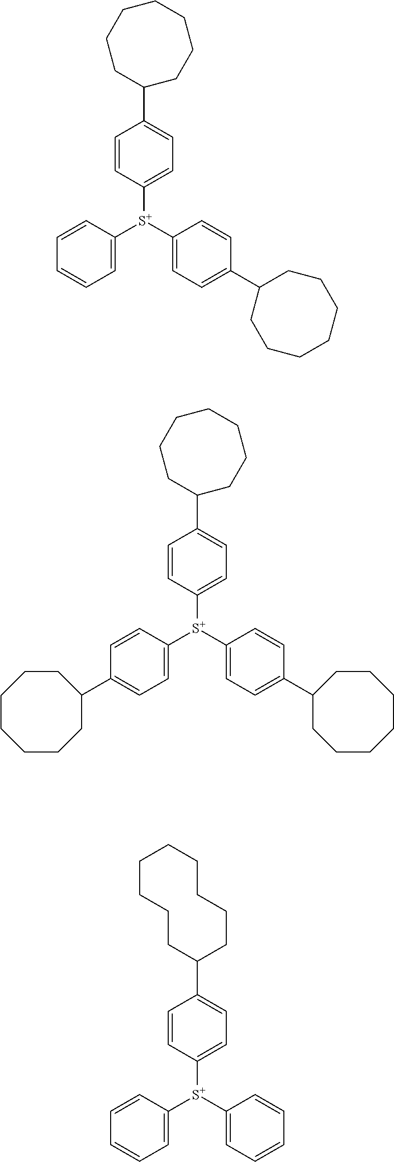 [SMILES: c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1 ; c1ccc([S+](c2ccccc2)c2ccc(C3CCCCCCCCC3)cc2)cc1]

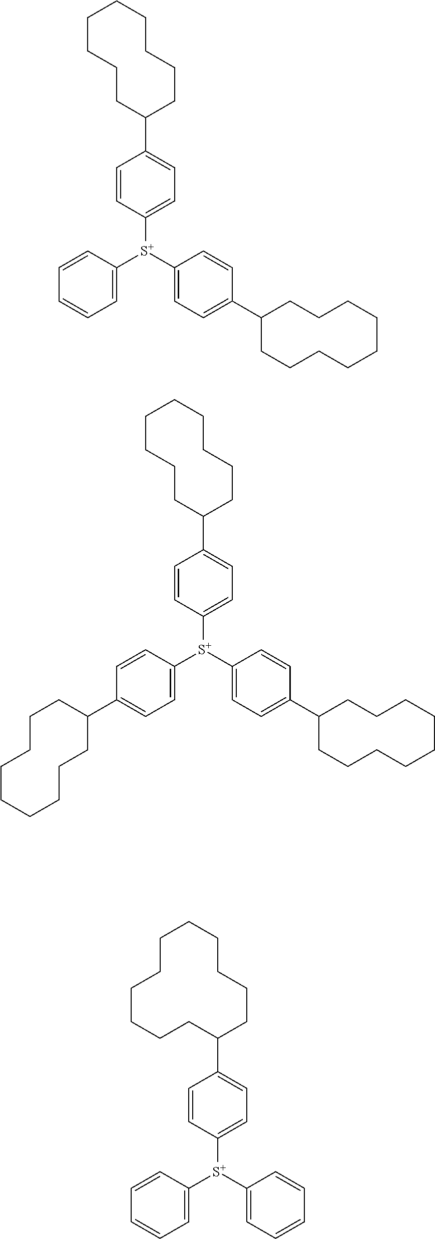 [SMILES: c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1 ; c1ccc([S+](c2ccccc2)c2ccc(C3CCCCCCCCCCC3)cc2)cc1]

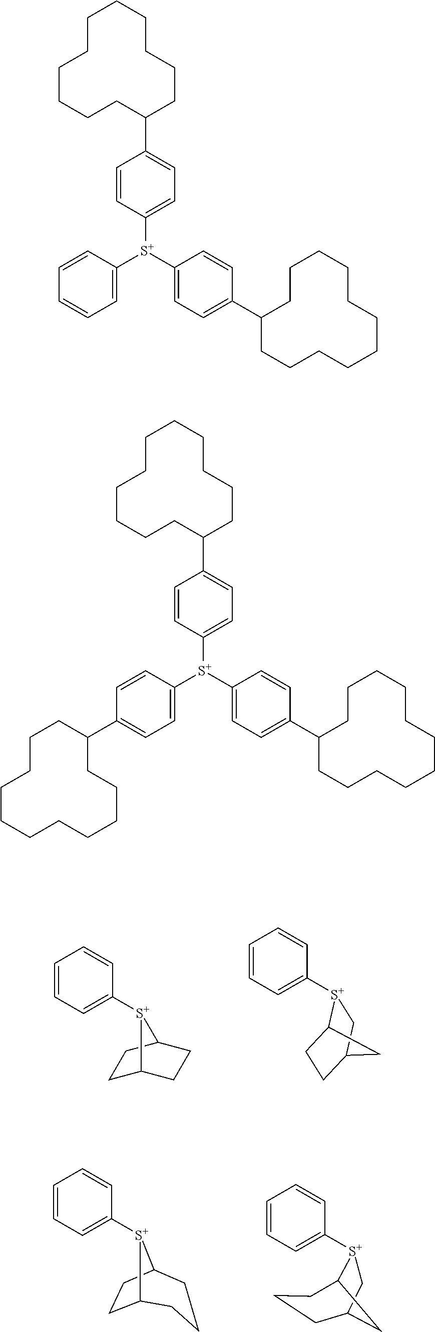 [SMILES: c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; c1ccc([S+]2C3CCC2CC3)cc1 ; c1ccc([S+]2CC3CCC2C3)cc1 ; c1ccc([S+]2C3CCCC2CC3)cc1 ; c1ccc([S+]2CC3CCCC2C3)cc1]

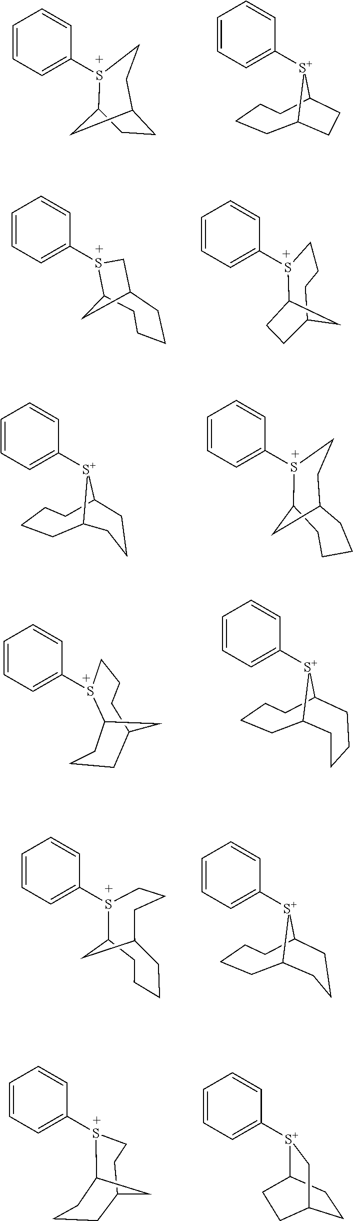

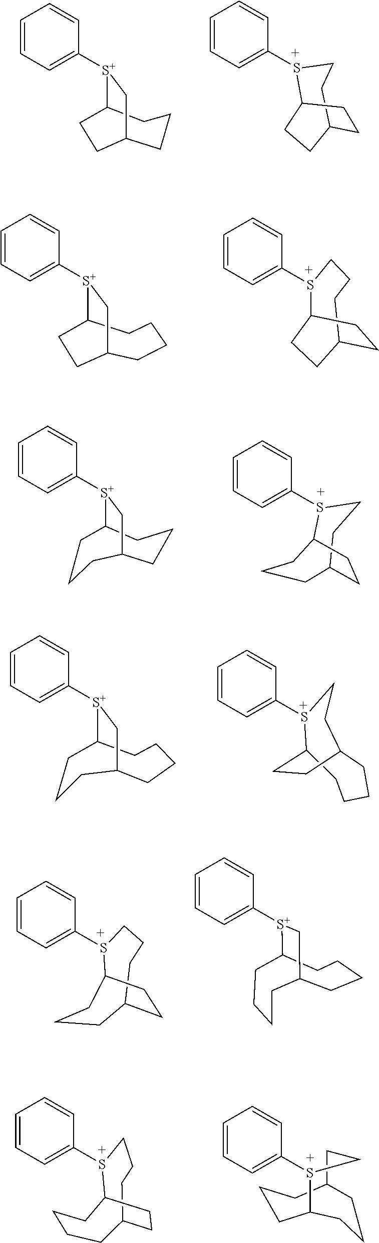

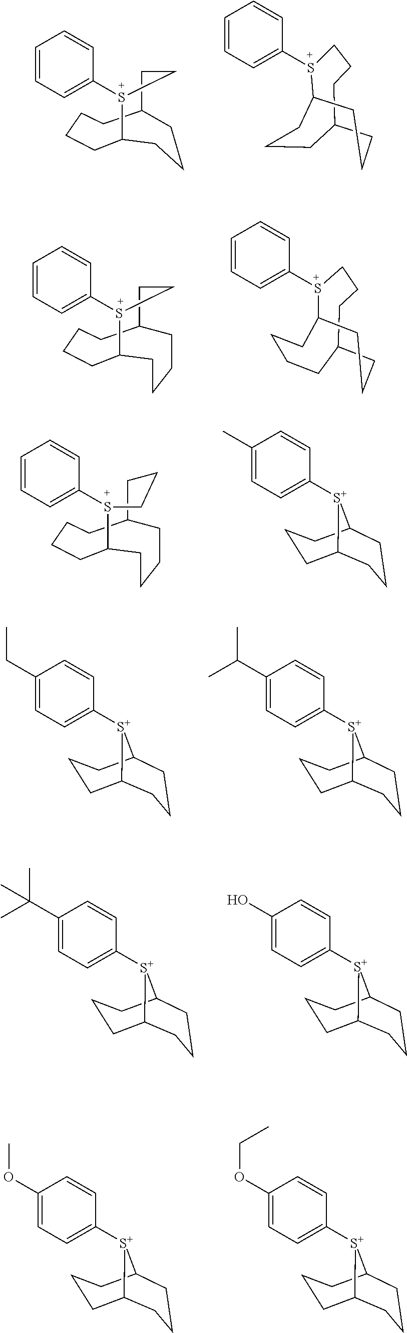

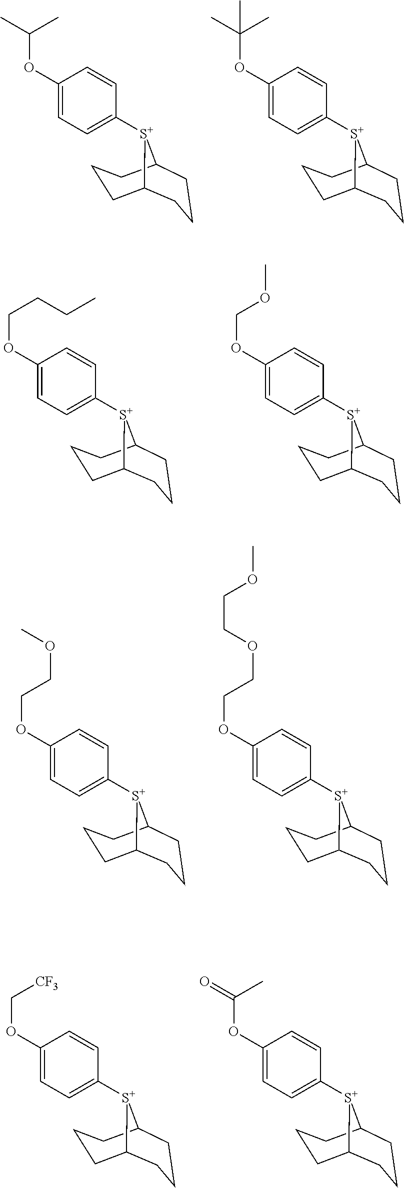

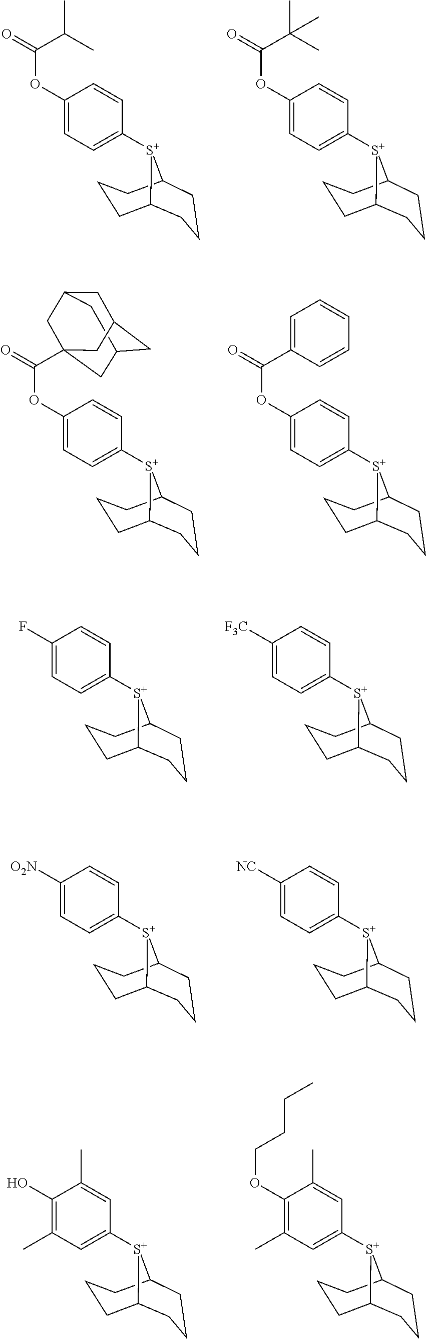

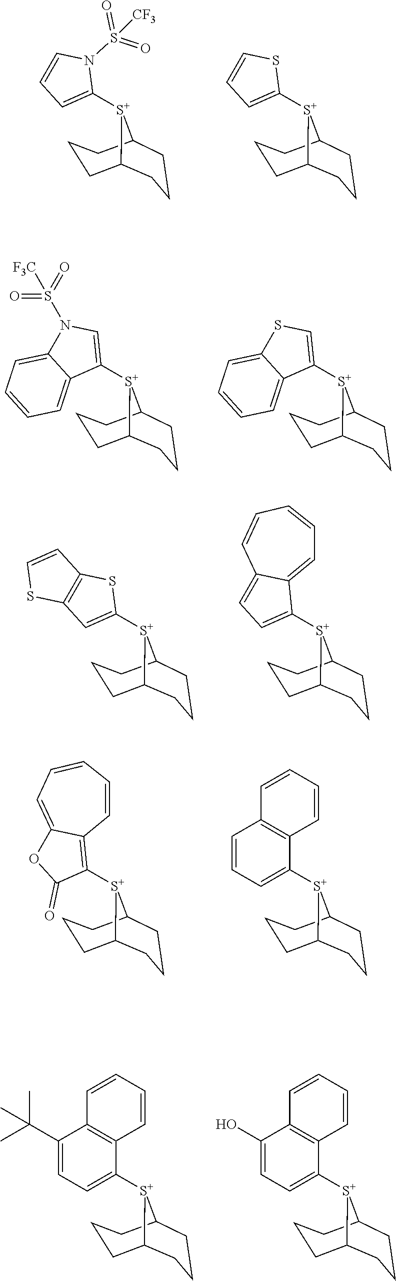

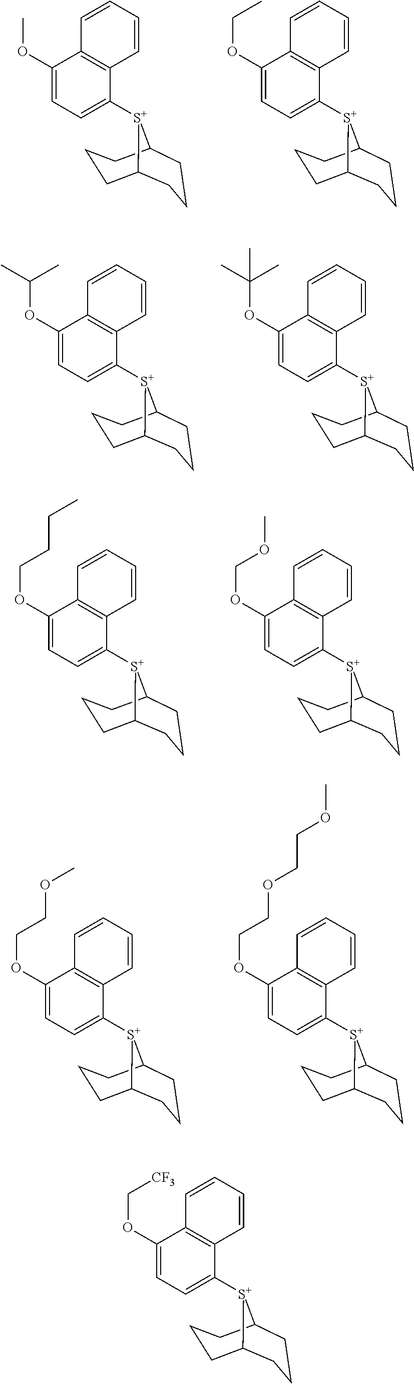

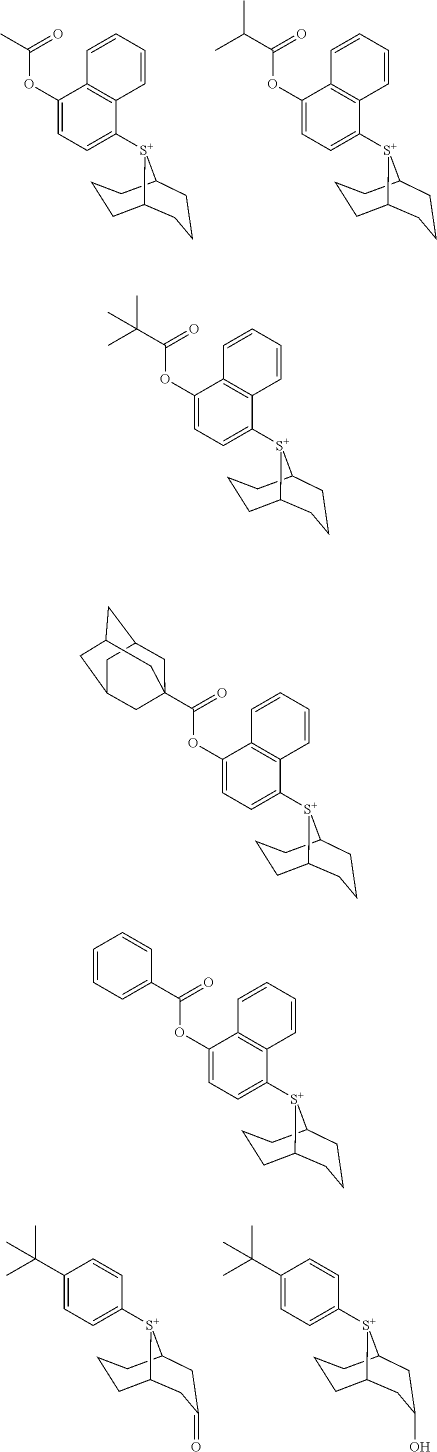

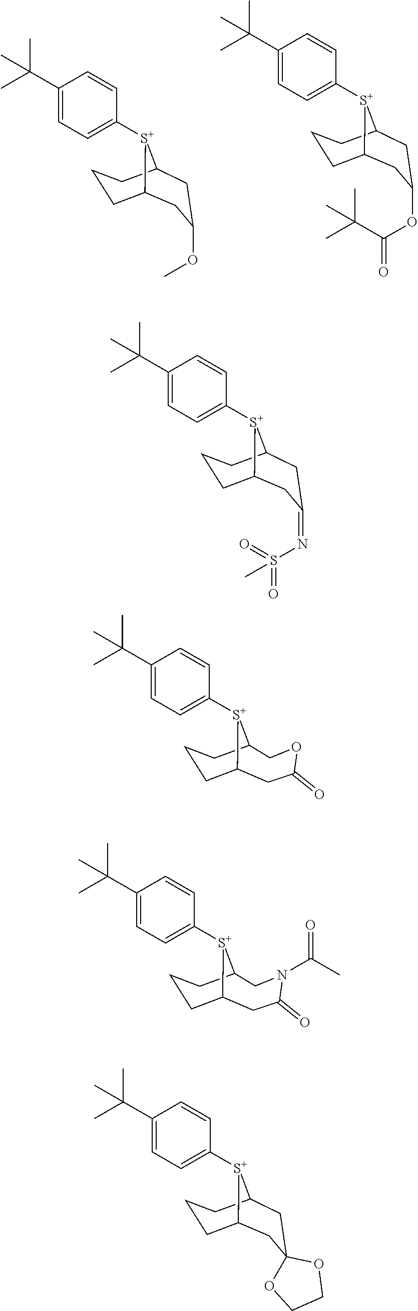

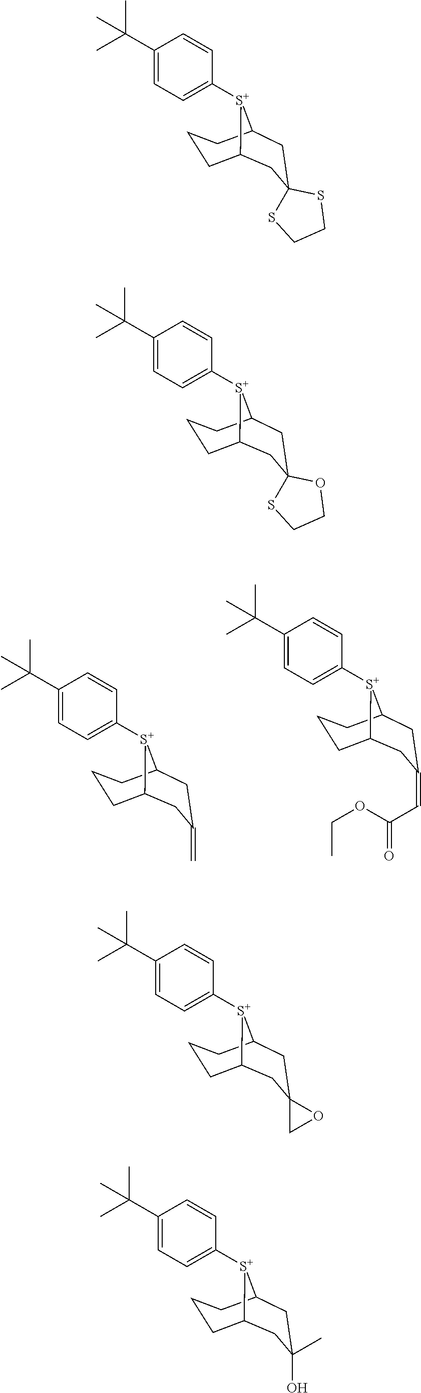 [SMILES: CC(C)(C)c1ccc([S+]2C3CCCC2CC2(C3)SCCS2)cc1 ; CC(C)(C)c1ccc([S+]2C3CCCC2CC2(C3)OCCS2)cc1 ; C=C1CC2CCCC(C1)[S+]2c1ccc(C(C)(C)C)cc1 ; CCOC(=O)C=C1CC2CCCC(C1)[S+]2c1ccc(C(C)(C)C)cc1 ; CC(C)(C)c1ccc([S+]2C3CCCC2CC2(CO2)C3)cc1 ; CC1(O)CC2CCCC(C1)[S+]2c1ccc(C(C)(C)C)cc1]

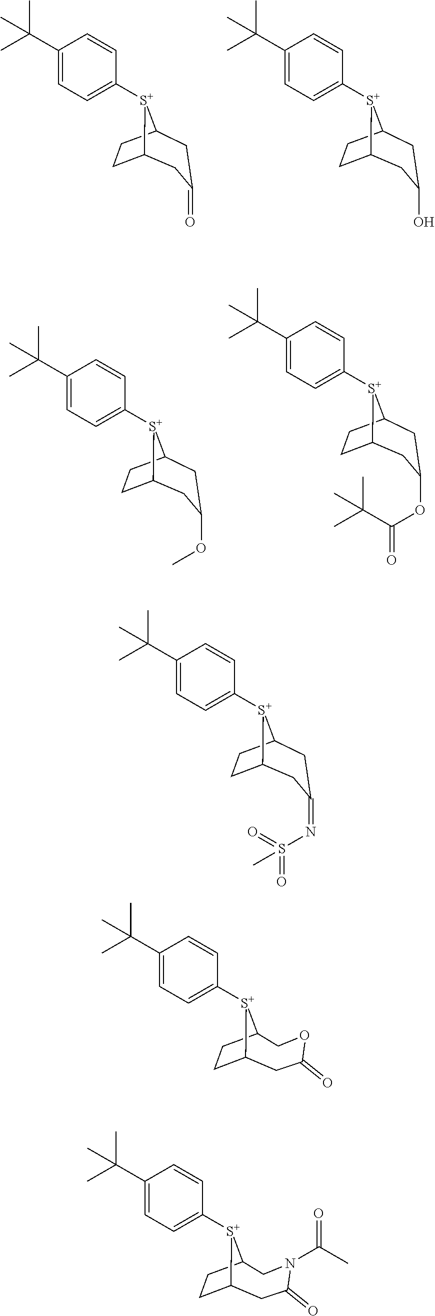

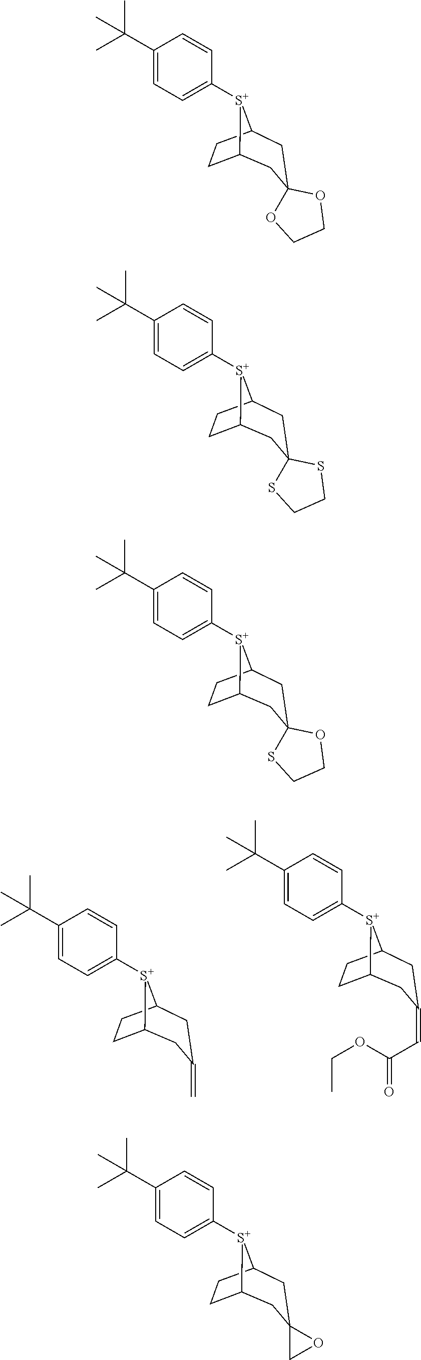 [SMILES: CC(C)(C)c1ccc([S+]2C3CCC2CC2(C3)OCCO2)cc1 ; CC(C)(C)c1ccc([S+]2C3CCC2CC2(C3)SCCS2)cc1 ; CC(C)(C)c1ccc([S+]2C3CCC2CC2(C3)OCCS2)cc1 ; C=C1CC2CCC(C1)[S+]2c1ccc(C(C)(C)C)cc1 ; CCOC(=O)C=C1CC2CCC(C1)[S+]2c1ccc(C(C)(C)C)cc1 ; CC(C)(C)c1ccc([S+]2C3CCC2CC2(CO2)C3)cc1]

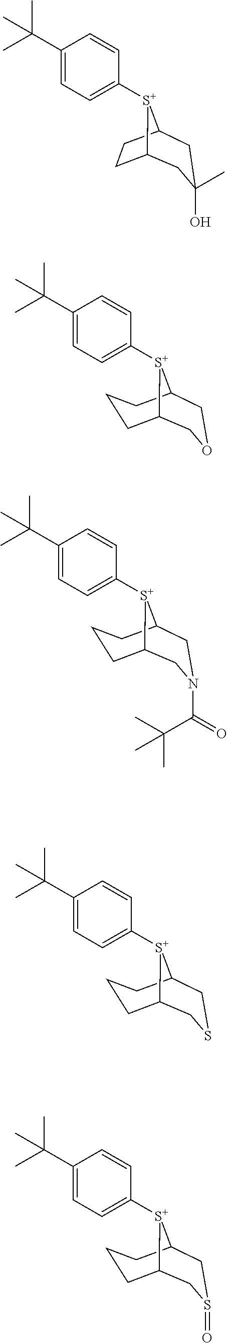

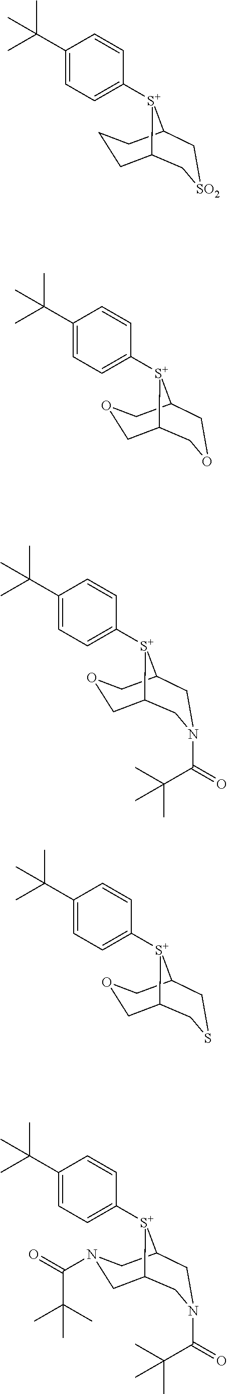 [SMILES: CC(C)(C)c1ccc([S+]2C3CCCC2CS(=O)(=O)C3)cc1 ; CC(C)(C)c1ccc([S+]2C3COCC2COC3)cc1 ; CC(C)(C)C(=O)N1CC2COCC(C1)[S+]2c1ccc(C(C)(C)C)cc1 ; CC(C)(C)c1ccc([S+]2C3COCC2CSC3)cc1 ; CC(C)(C)C(=O)N1CC2CN(C(=O)C(C)(C)C)CC(C1)[S+]2c1ccc(C(C)(C)C)cc1]

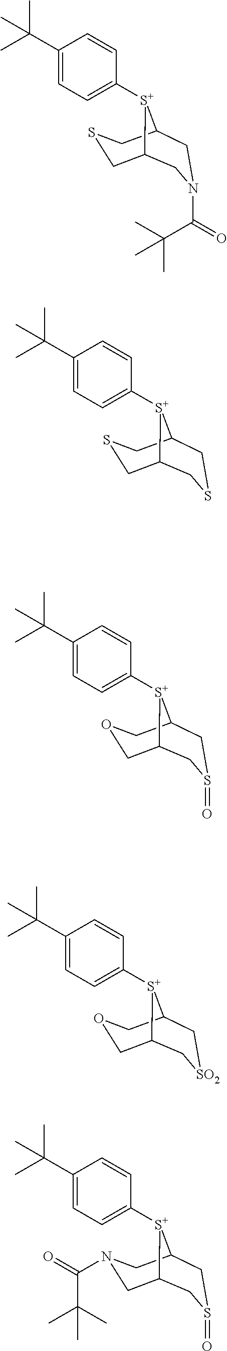 [SMILES: CC(C)(C)C(=O)N1CC2CSCC(C1)[S+]2c1ccc(C(C)(C)C)cc1 ; CC(C)(C)c1ccc([S+]2C3CSCC2CSC3)cc1 ; CC(C)(C)c1ccc([S+]2C3COCC2CS(=O)C3)cc1 ; CC(C)(C)c1ccc([S+]2C3COCC2CS(=O)(=O)C3)cc1 ; CC(C)(C)C(=O)N1CC2CS(=O)CC(C1)[S+]2c1ccc(C(C)(C)C)cc1]

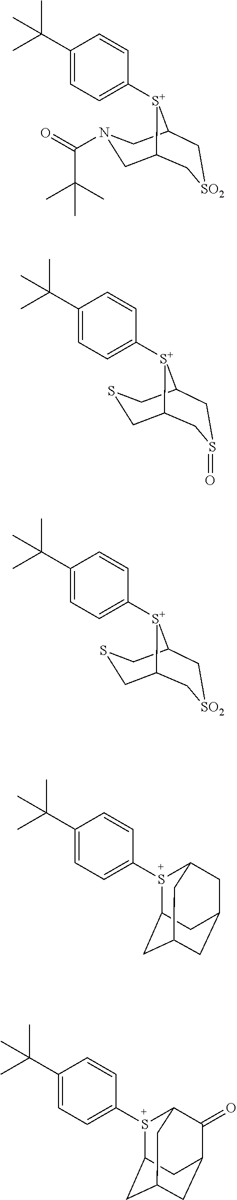

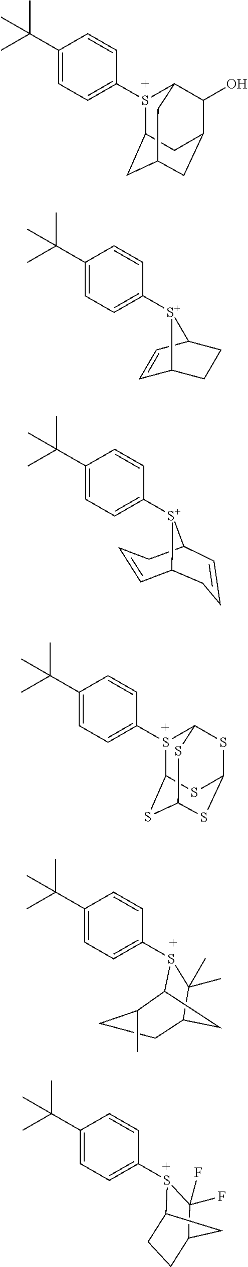

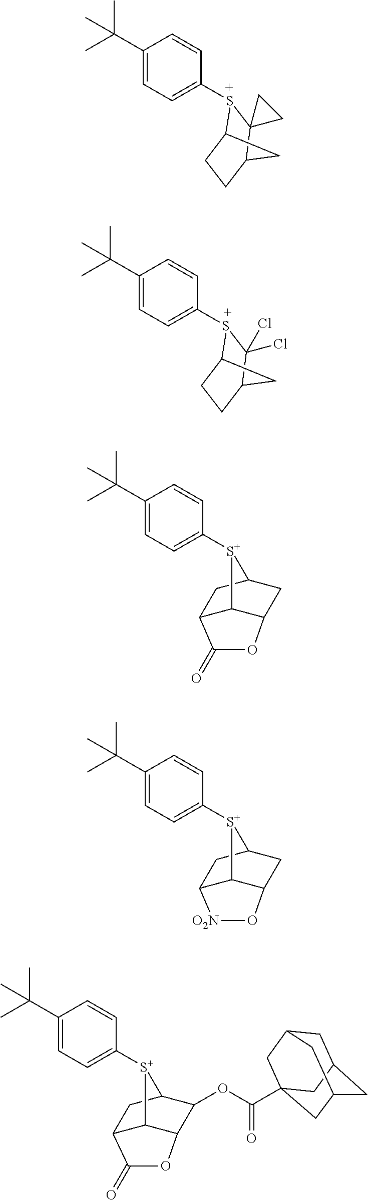

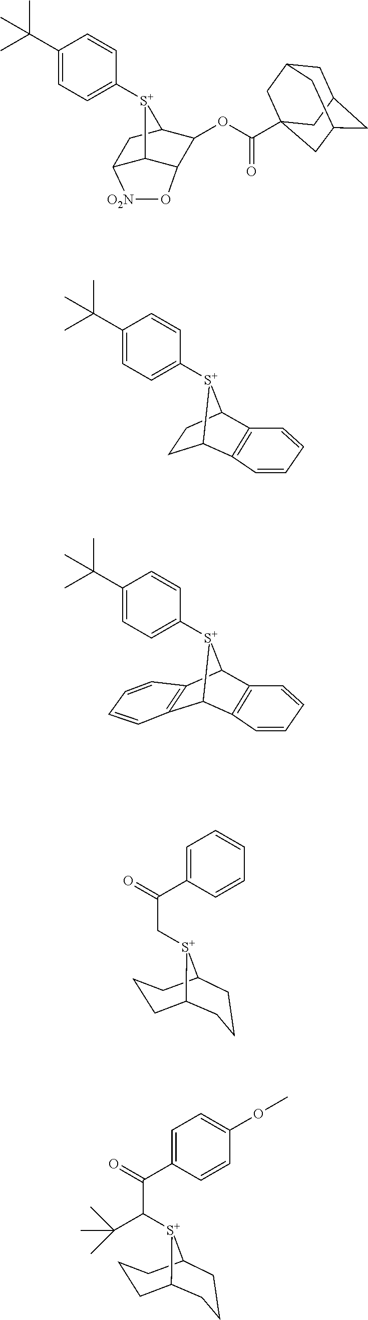

Examples of the iodonium cation represented by formula (cation-2) are shown below, but not limited thereto.

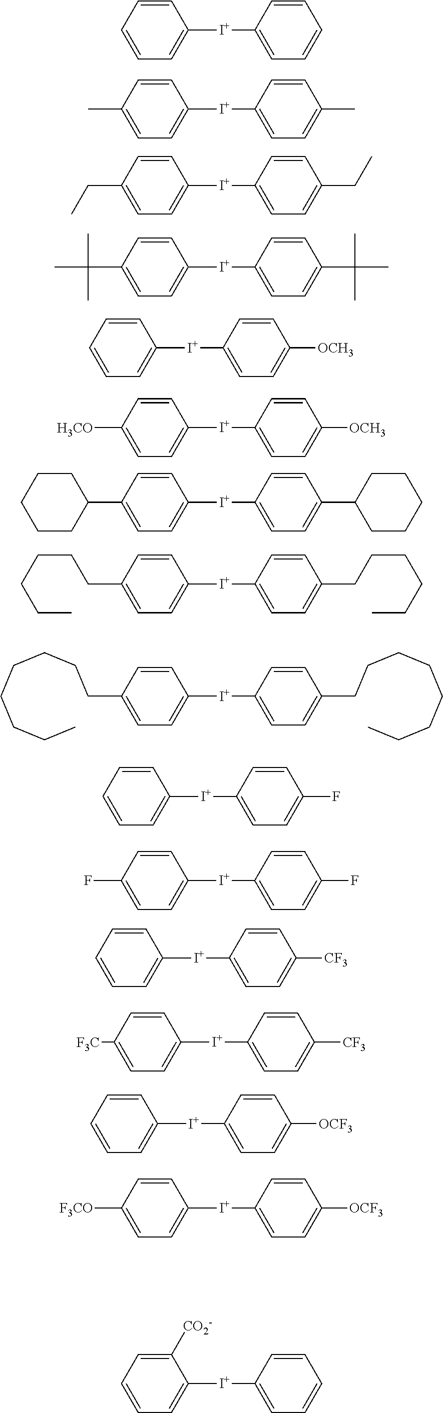

Examples of repeat units A1 to A4 include arbitrary combinations of the anion with the cation.

Of the repeat units adapted to generate an acid upon exposure, repeat units A2, A3 and A4 are preferred in view of acid diffusion control, repeat units A2 and A4 are more preferred in view of the strength of generated acid, and repeat units A2 are most preferred in view of solvent solubility.

The repeat units having an acid labile group containing a fluorine atom-containing aromatic ring in polymer P, which are also referred to as repeat units B, hereinafter, are represented by the following formula (B).

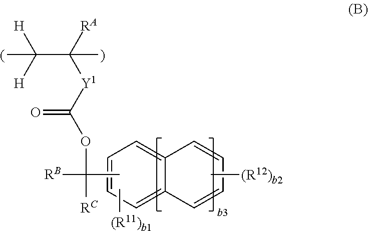

In formula (B), R^{A} is a hydrogen atom, a fluorine atom, a methyl group, or a trifluoromethyl group.

In formula (B), Y¹ is a single bond, a phenylene group, a naphthylene group or *—C(═O)—O—Y¹¹—. Y¹¹ is a C₁-C₂₀ aliphatic hydrocarbylene group, a phenylene group, or a naphthylene group, and the hydrocarbylene group may contain at least one selected from a hydroxy group, an ether bond, an ester bond or a lactone ring, the asterisk (*) designates a point of attachment to the carbon atom in the backbone,

The aliphatic hydrocarbylene group Y¹ may be straight, branched or cyclic. Examples thereof include C₁-C₂₀ alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, hexane-1,6-diyl, heptane-1,7-diyl, octane-1,8-diyl, nonane-1,9-diyl, and decane-1,10-diyl; C₃-C₂₀ cycloalkanediyl groups such as cyclopropanediyl, cyclobutane-1,1-diyl, cyclopentanediyl, and cyclohexanediyl; C₄-C₂₀ polycyclic saturated hydrocarbylene groups such as adamantanediyl and norbornanediyl; and divalent groups obtained by combining the foregoing.

Examples of the structure having formula (B1) wherein Y¹ is a variant are shown below, but not limited thereto. Herein R^{A} is as defined herein. The broken line designates a point of attachment to the carbon atom to which R^{B} and R^{C} in formula (B) are attached.

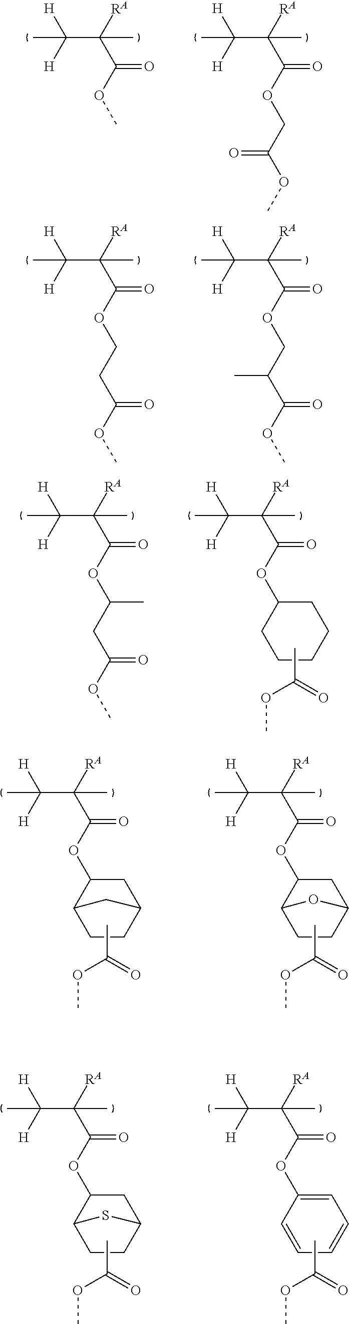

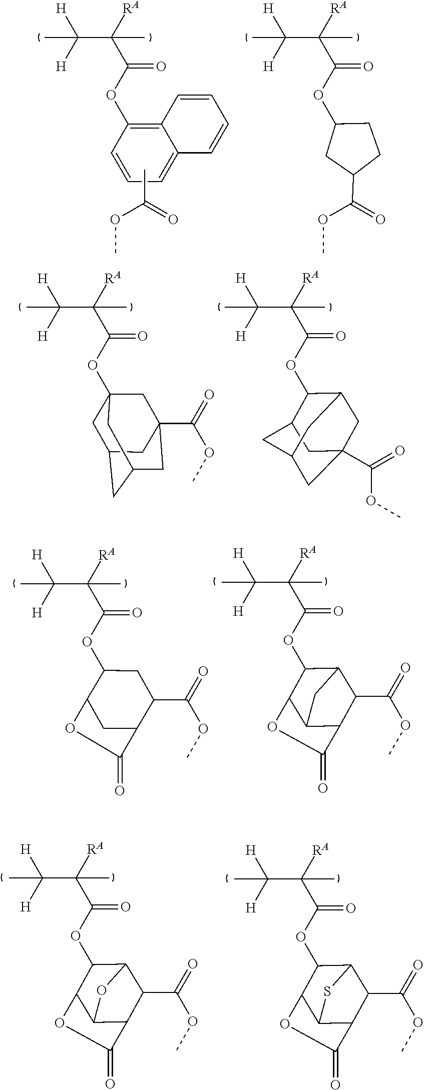

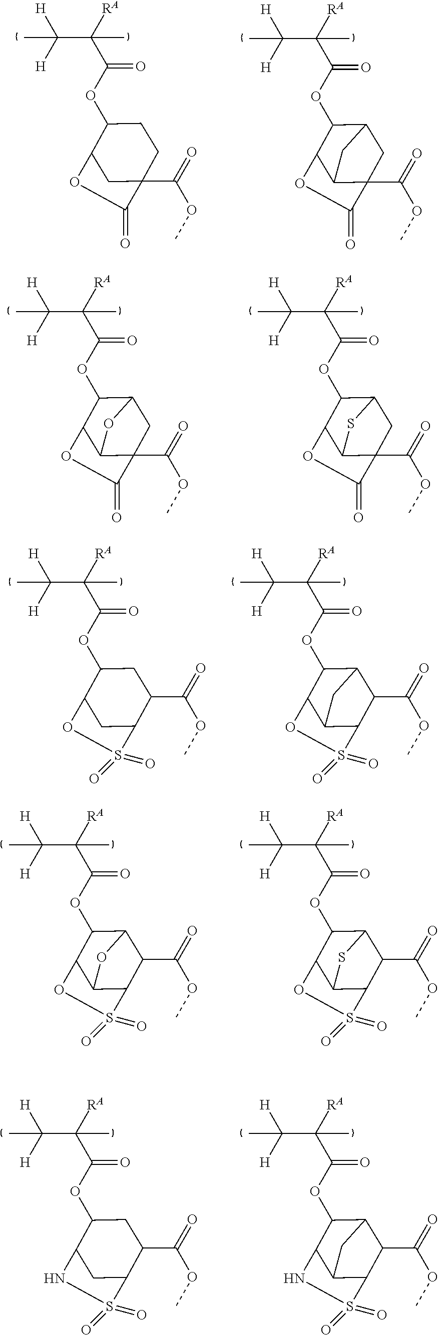

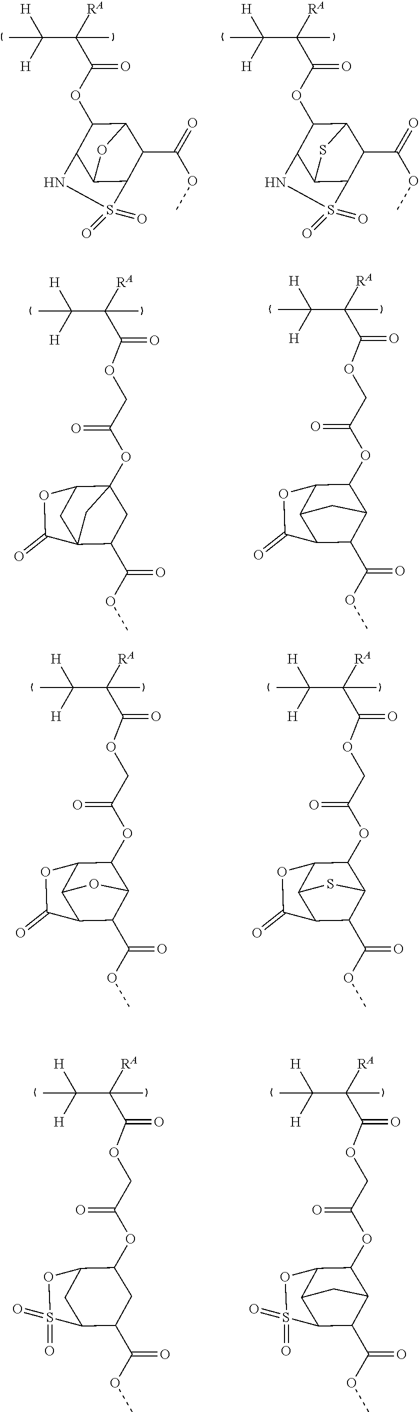

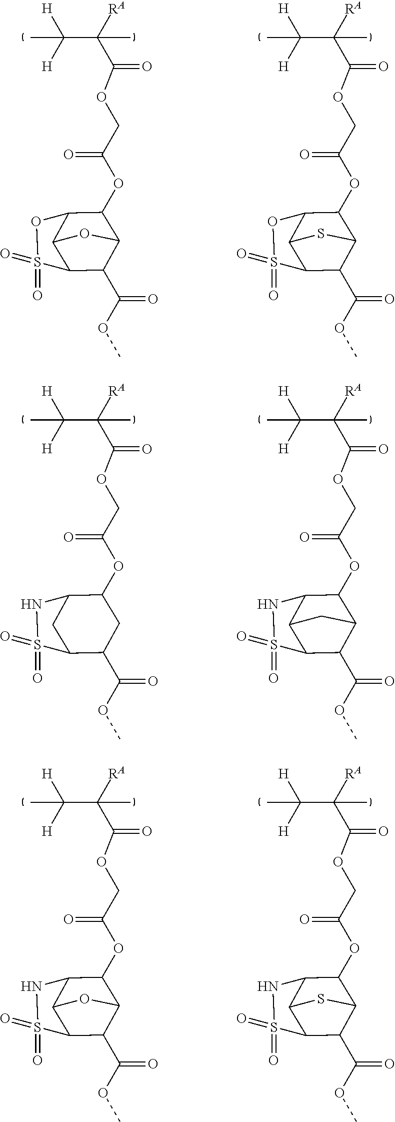

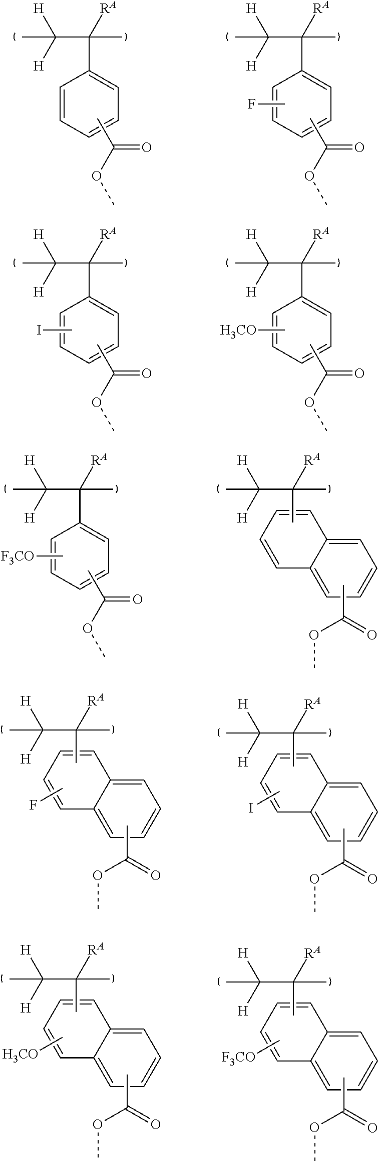

In formula (B), R^{B} to R^{C} are each independently a C₁-C₁₀ hydrocarbyl group which may contain a heteroatom. The hydrocarbyl group may be saturated or unsaturated and straight, branched or cyclic. Examples thereof include alkyl groups such as methyl, ethyl, n-propyl, isopropyl, n-butyl, sec-butyl, tert-butyl, 2-ethylhexyl and n-octyl groups; and cyclic saturated hydrocarbyl groups such as cyclopentyl, cyclohexyl, norbornyl, tricyclodecyl and adamantyl groups.

R^{B} and R^{C} may bond together to form a ring with the carbon atom to which they are attached. Examples of the ring include cyclopropane, cyclobutane, cyclopentane, and adamantane rings. Of these, cyclopentane and cyclohexane rings are preferred.

In formula (B), R¹¹ is a fluorine atom, a C₁-C₅ fluorinated saturated hydrocarbyl group, or a C₁-C₅ fluorinated saturated hydrocarbyloxy group. Examples of the fluorinated saturated hydrocarbyl group include fluoromethyl, difluoromethyl, trifluoromethyl, 2,2,2-trifluoroethyl, pentafluoroethyl, pentafluoropropyl, 1,1,1,3,3,3-hexafluoro-2-propyl, and nonafluorobutyl groups. Examples of the fluorinated saturated hydrocarbyl group include fluoromethoxy, difluoromethoxy, trifluoromethoxy, 2,2,2-trifluoroethoxy, pentafluoroethoxy, pentafluoropropoxy, 1,1,1,3,3,3-hexafluoro-2-propoxy, and nonafluorobutoxy groups. Inter alia, R¹¹ is preferably a fluorine atom or a C₁-C₅ fluorinated saturated hydrocarbyl group, more preferably a fluorine atom or a trifluoromethyl group.

In formula (B), R¹² is a C₁-C₁₀ hydrocarbyl group which may contain a heteroatom. The hydrocarbyl group may be saturated or unsaturated and straight, branched or cyclic. Examples thereof are as exemplified above as hydrocarbyl groups R^{B} and R^{C}.

In formula (B), b1 is an integer of 0 to 2. b2 is an integer of 0 to 5, preferably 0 or 1. b3 is an integer of 0 to 2. The polymer has a benzene ring when b3 is 0, a naphthalene ring when b3 is 1, and an anthracene ring when b3 is 2, and b3 is preferably 0 from the aspect of solvent solubility.

The repeat unit B is preferably a repeat unit having the following formula (B1).

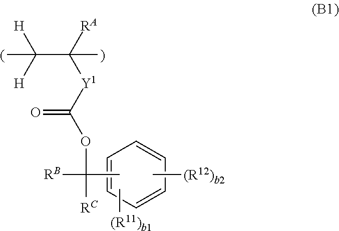

Herein R^{A}, Y¹, R^{B}, R^{C}, R¹¹, R¹², b1 and b2 are as defined above.

A monomer MB from which repeat unit B is derived may be prepared, for example, according to the following scheme although the preparation route is not limited thereto.

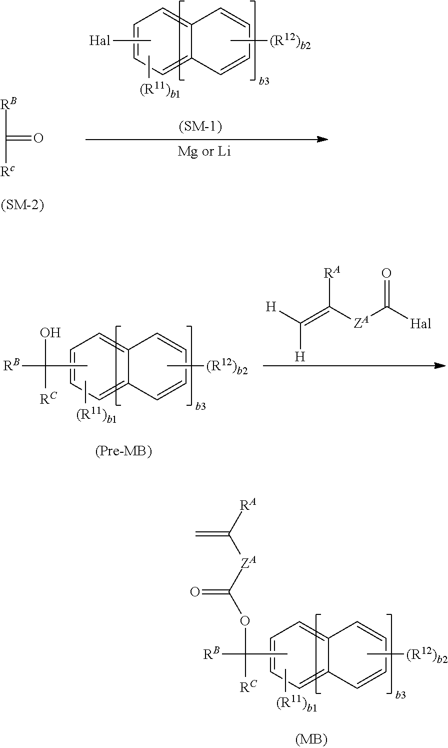

Herein R^{A}, Y, R^{B}, R^{C}, R¹¹, R¹², b1, b2 and b3 are as defined above. Hal is a halogen atom other than a fluorine atom.

The first step is to react a ketone compound SM-2, which is commercially available or synthesized by a well-known synthesis technique, with a Grignard reagent or organic lithium reagent, which is prepared from halide SM-1, to form a monomer precursor Pre-MB.

The reaction may be performed by any well-known organic synthesis technique. Specifically, a Grignard reagent or organic lithium reagent is prepared by suspending metallic magnesium or metallic lithium in an ether solvent such as tetrahydrofuran (THF) or diethyl ether and adding dropwise a dilution of halide SM-1 in the same solvent to the suspension. In the preparation of Grignard reagent, when halide SM-1 is a chloride, it is recommended for efficient start of the reaction that a minor amount of 1,2-dibromoethane or iodine is added to the suspension before the start of dropwise addition of halide SM-1. To the Grignard reagent or organic lithium reagent thus prepared, a dilution of ketone compound SM-2 in the same solvent is added dropwise. The reaction temperature is from room temperature to approximately the boiling point of the solvent. While it is preferred in view of yield to drive the reaction to completion by monitoring the reaction by gas chromatography (GC) or silica gel thin-layer chromatography (TLC), the reaction time is typically about 30 minutes to about 2 hours. By ordinary aqueous work-up of the reaction mixture, monomer precursor Pre-B1 is obtained. If necessary, monomer precursor Pre-B1 may be purified by a standard technique such as distillation, chromatography or recrystallization.

The second step is to introduce a polymerizable group into monomer precursor Pre-MB or tertiary alcohol resulting from the first step, via an ester bond to form monomer MB.

The reaction may be performed by any well-known organic synthesis technique. Specifically, monomer precursor Pre-B1 or tertiary alcohol is dissolved in a solvent (e.g., toluene, hexane, THF or acetonitrile) in the presence of an organic base (e.g., triethylamine or pyridine). An acid halide (e.g., methacrylic chloride or acrylic chloride) is added dropwise to the solution for conducting reaction. For accelerating the reaction rate, 4-dimethylaminopyridine may be added to the solution. The reaction temperature is from 5° C. to approximately the boiling point of the solvent. While it is preferred in view of yield to drive the reaction to completion by monitoring the reaction by GC or TLC, the reaction time is typically about 1 to 24 hours. By ordinary aqueous work-up of the reaction mixture, monomer MB is obtained. If necessary, monomer MB may be purified by a standard technique such as distillation, chromatography or recrystallization.

Examples of repeat unit B are shown below, but not limited thereto. Herein, R^{A} is as defined above.

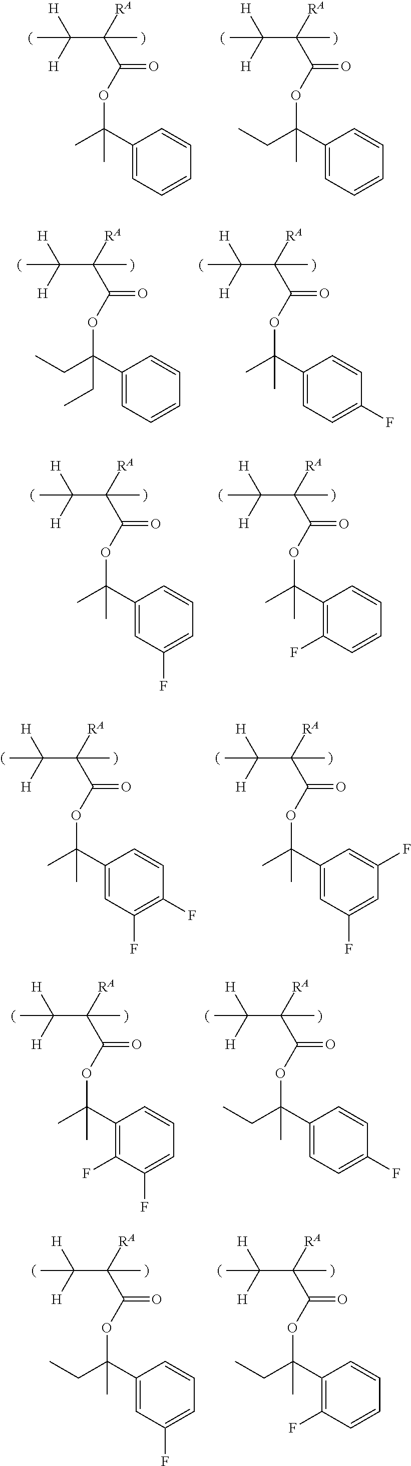

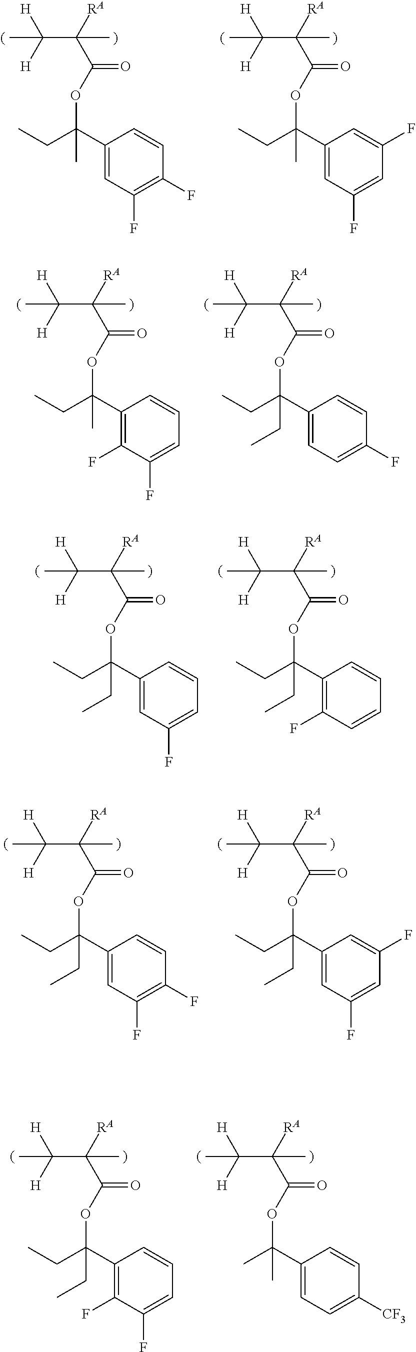

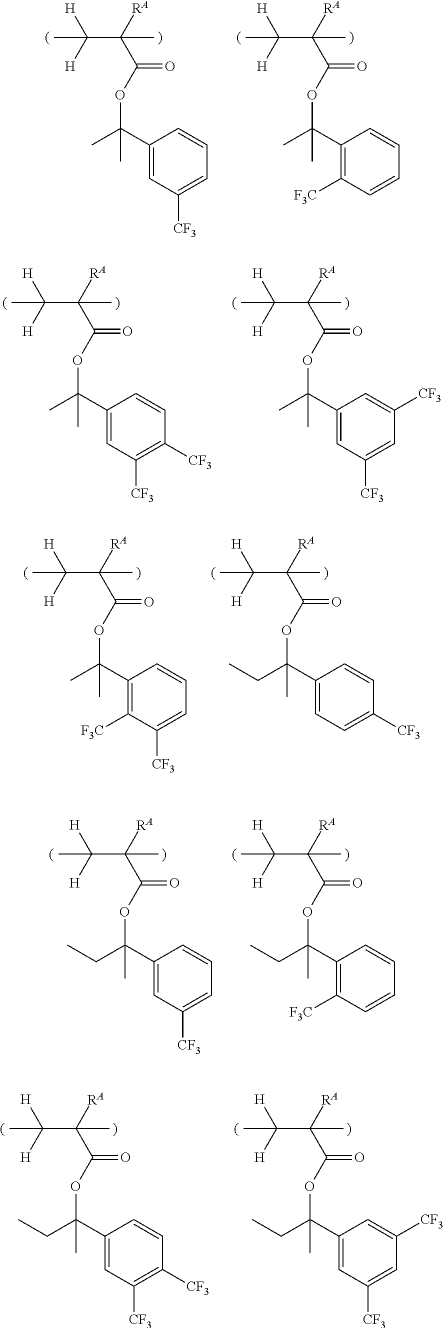

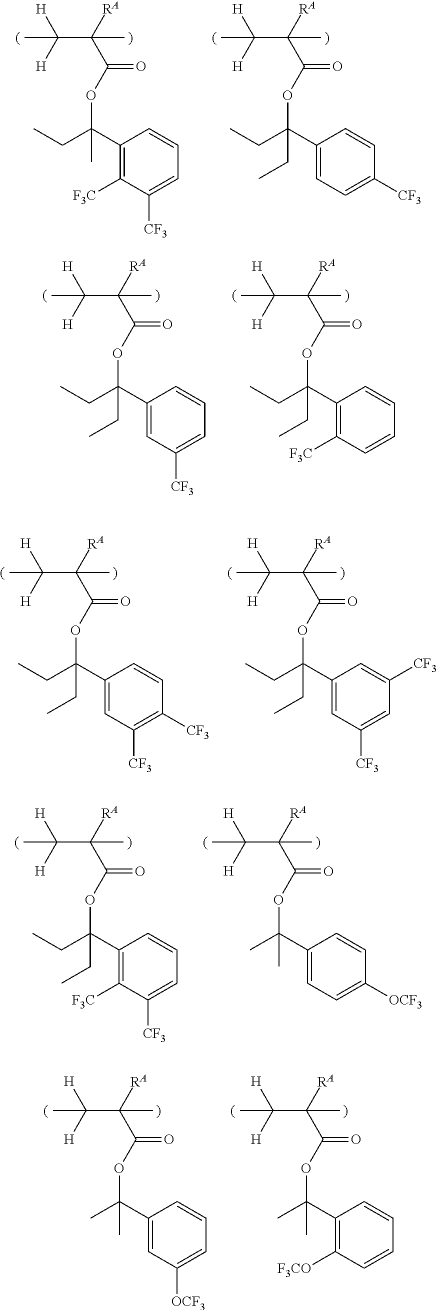

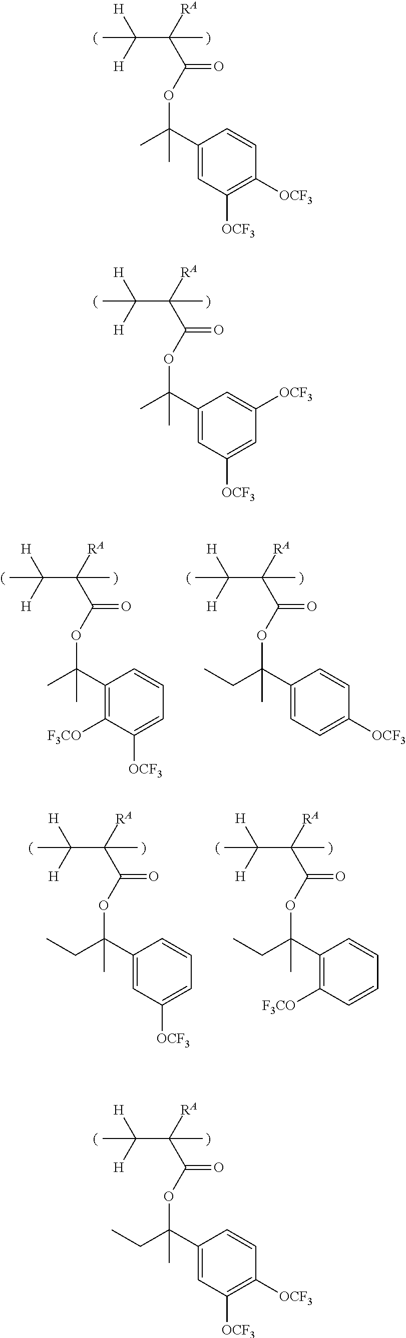

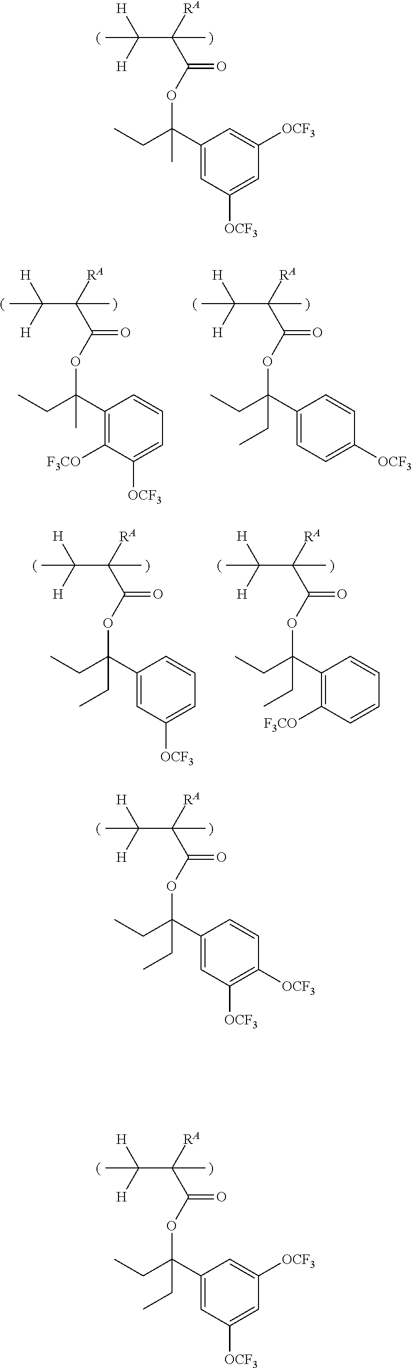

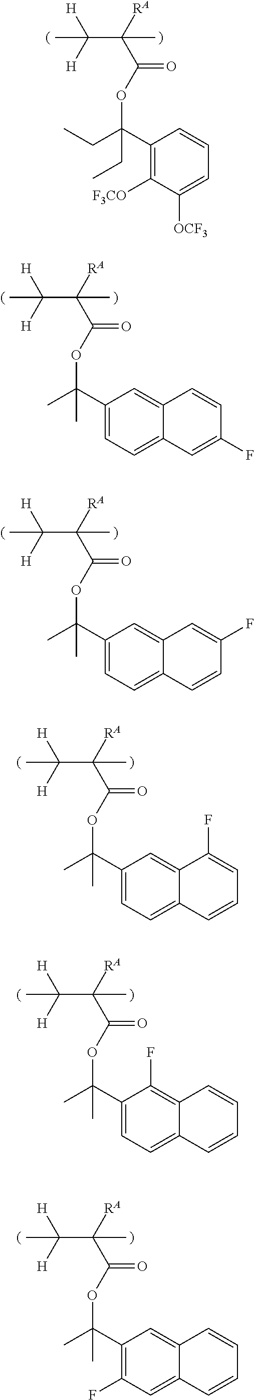

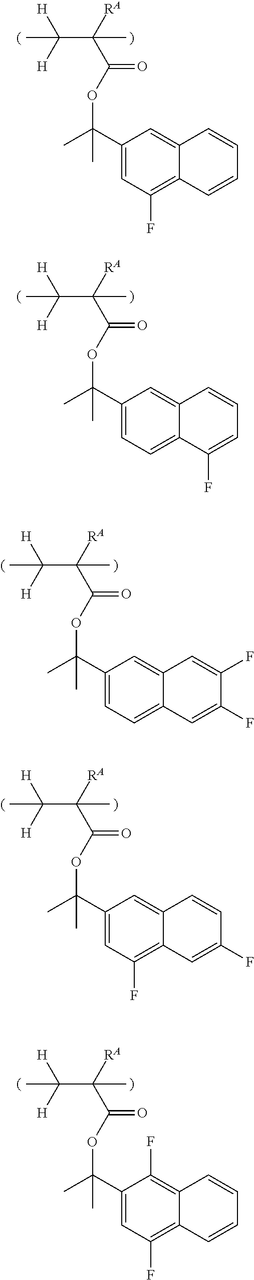

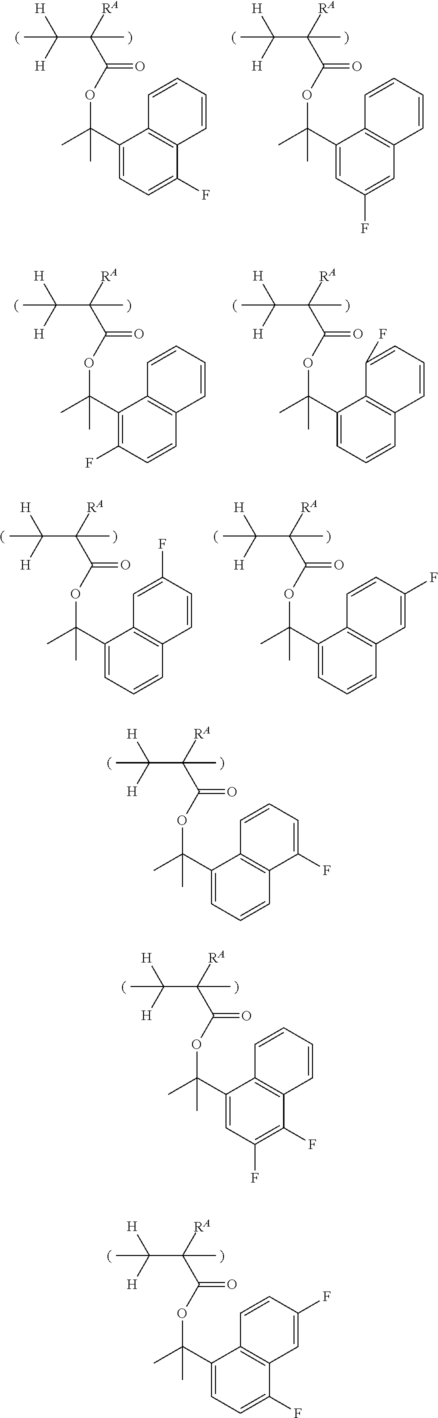

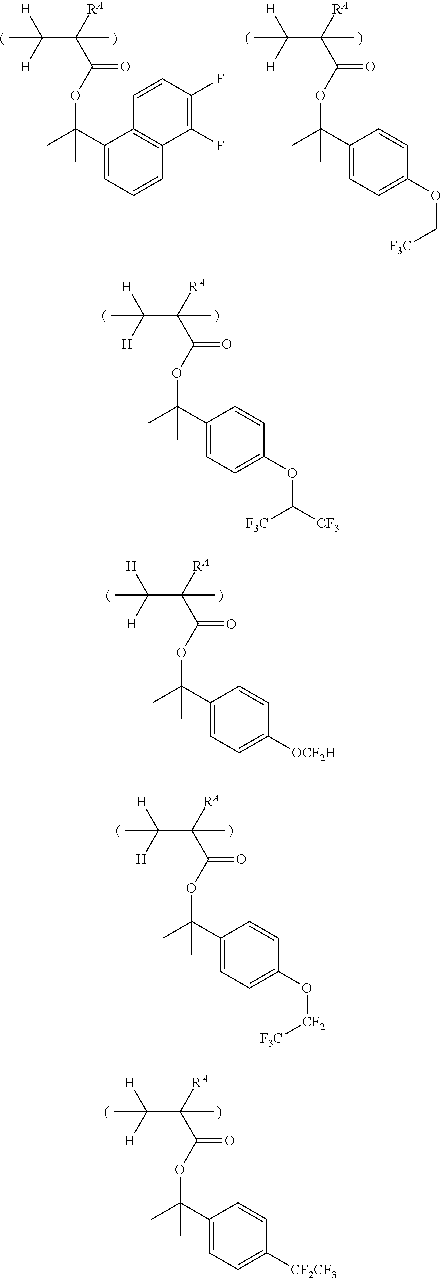

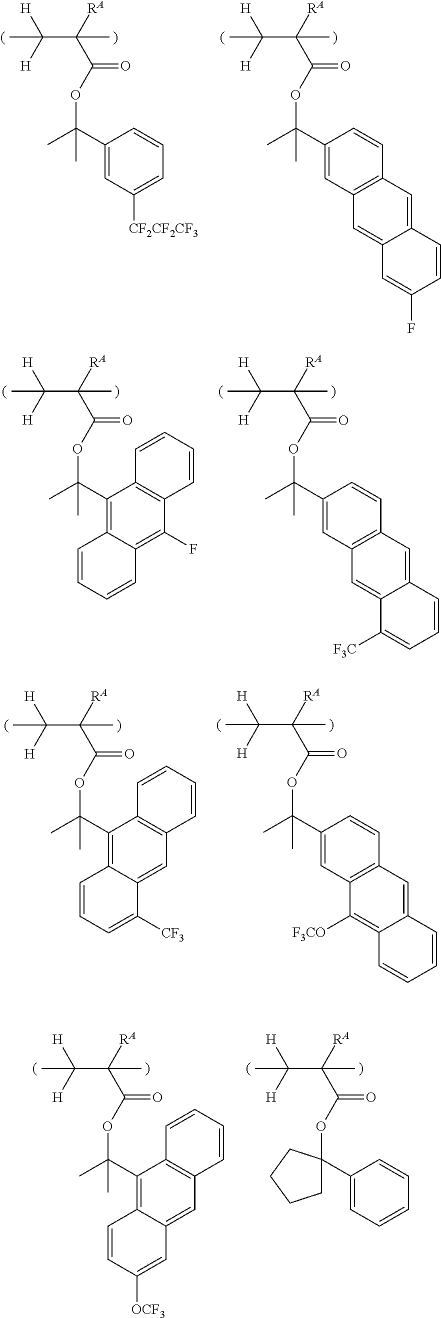

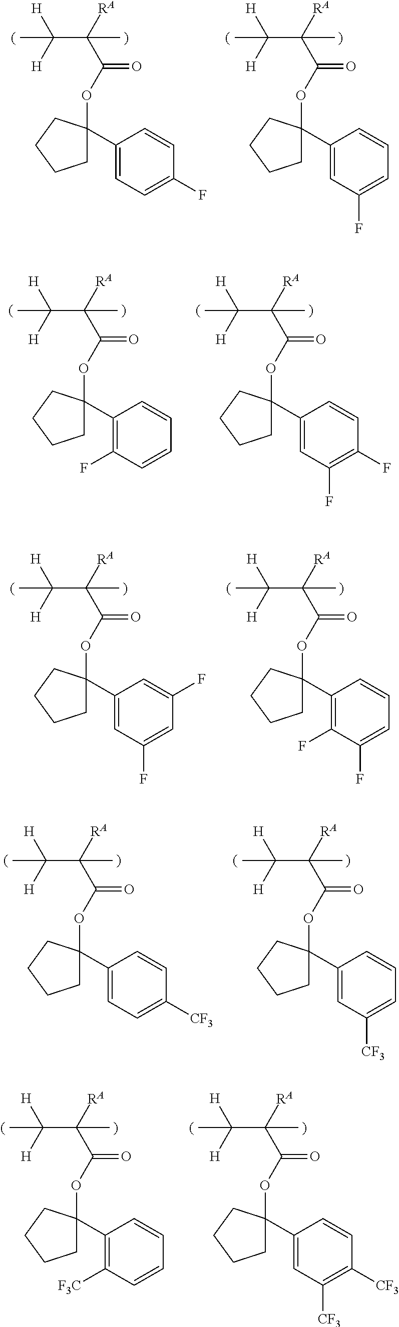

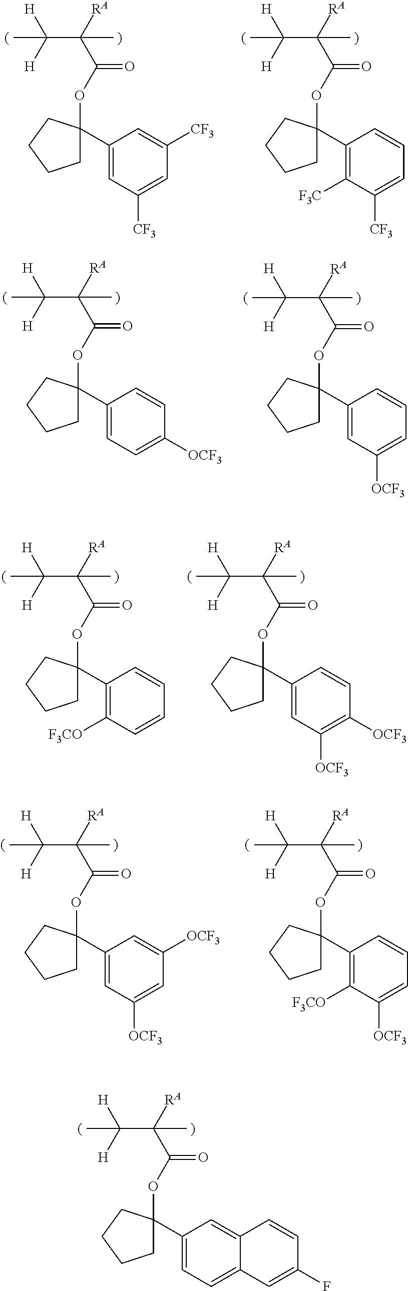

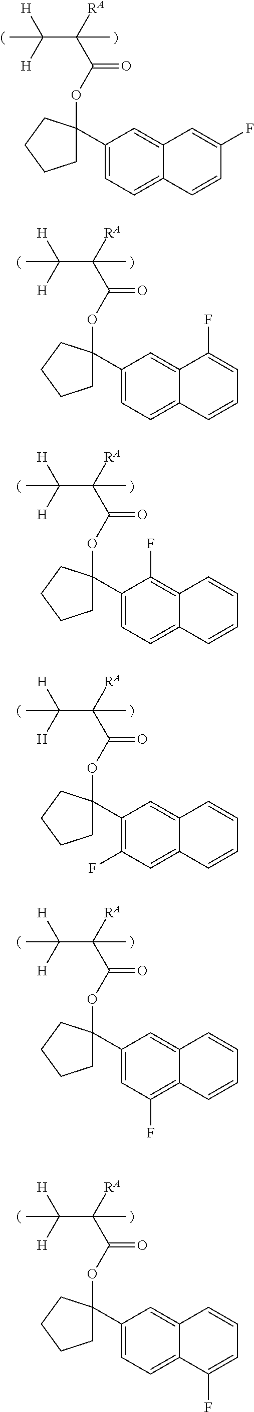

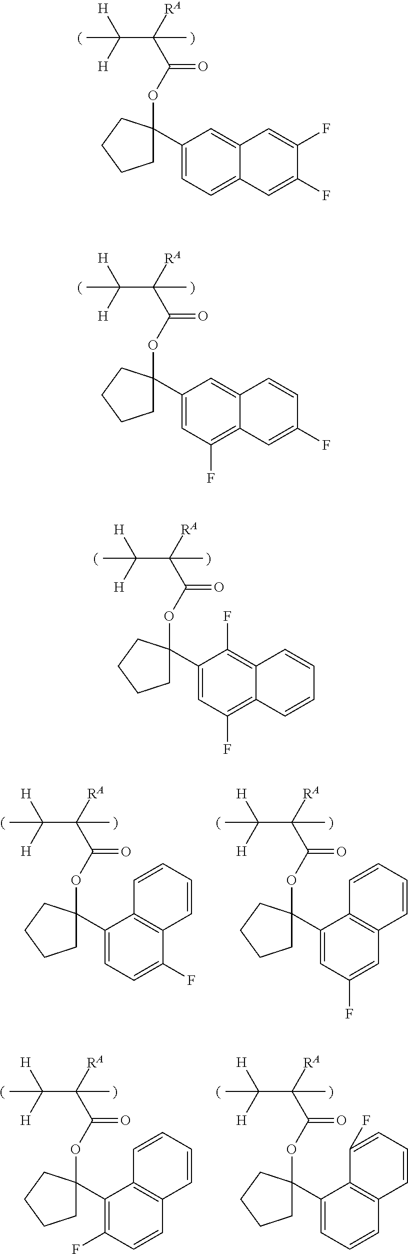

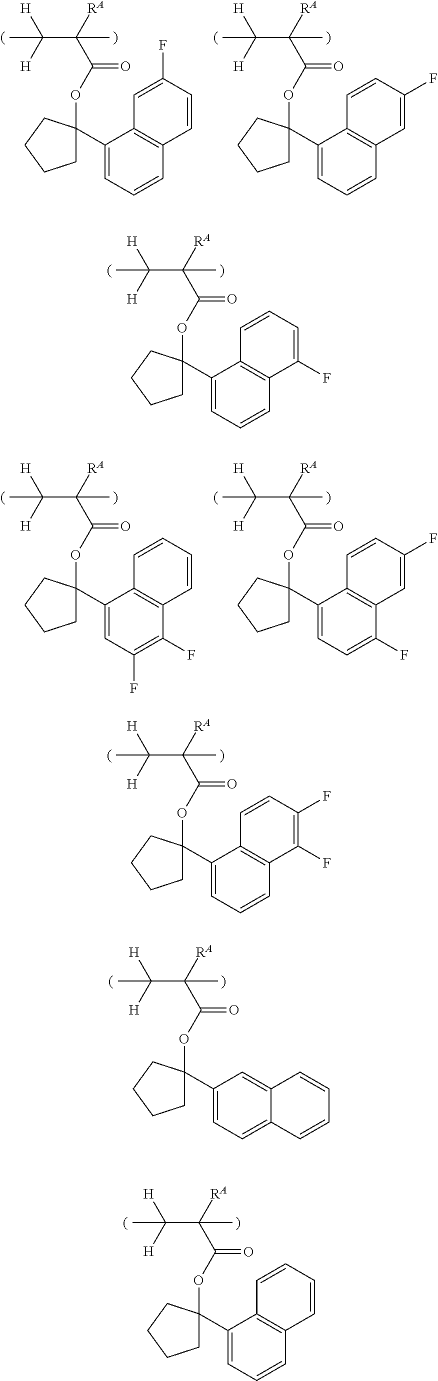

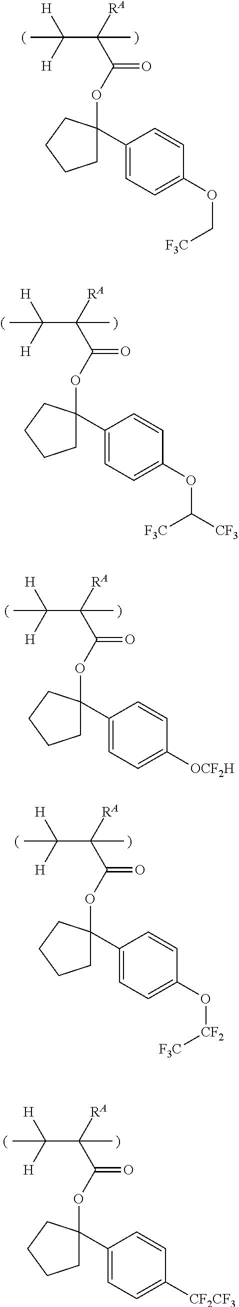

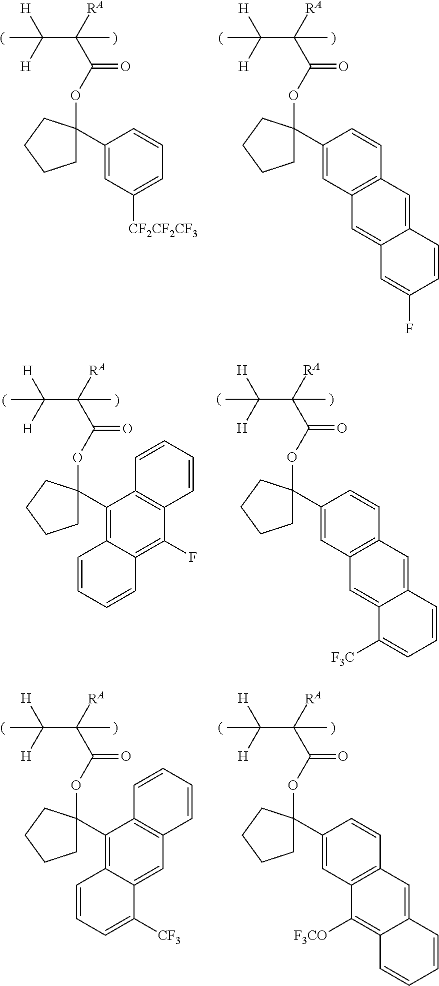

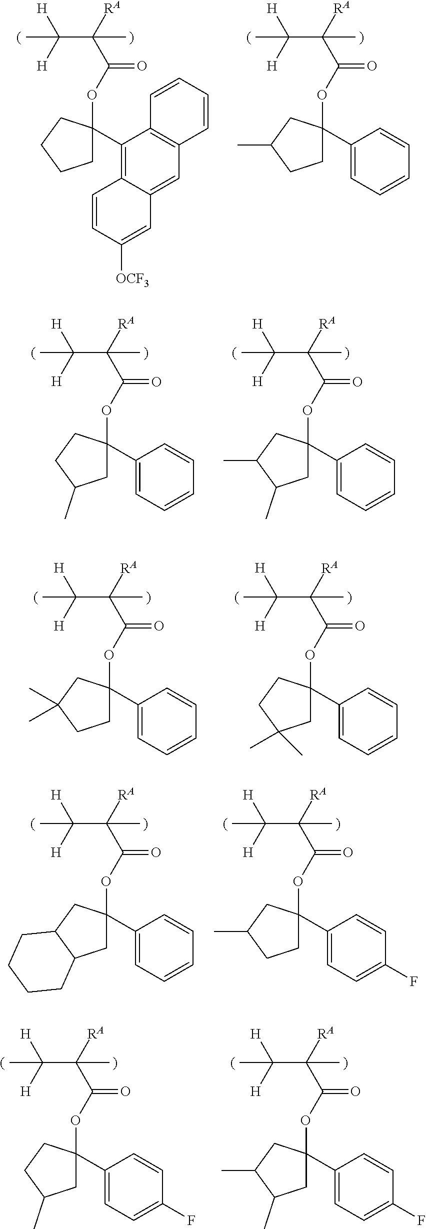

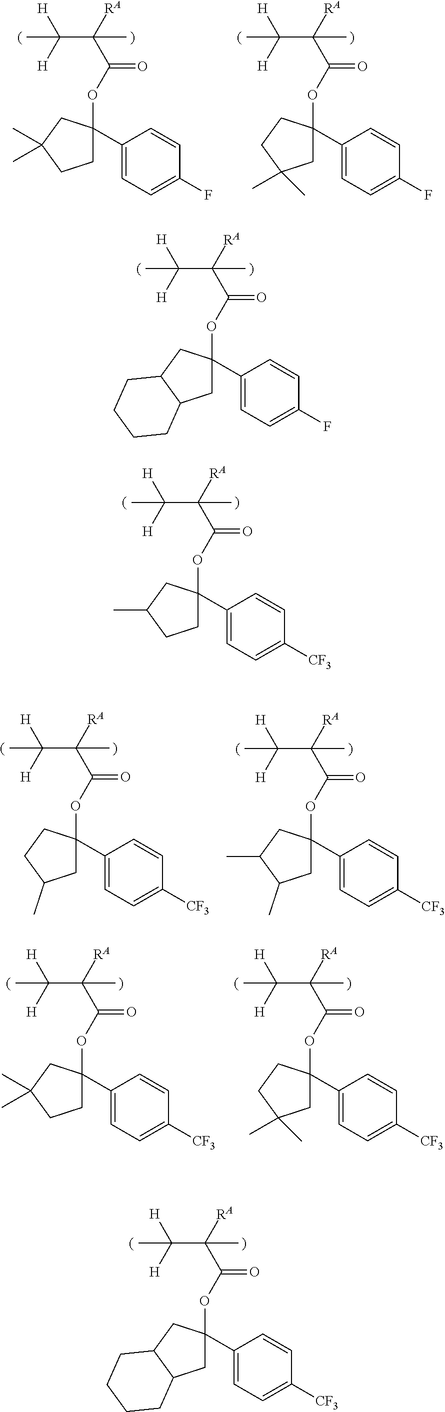

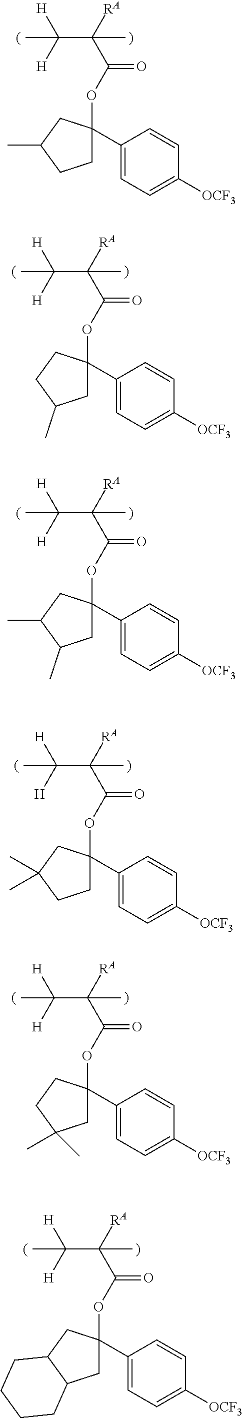

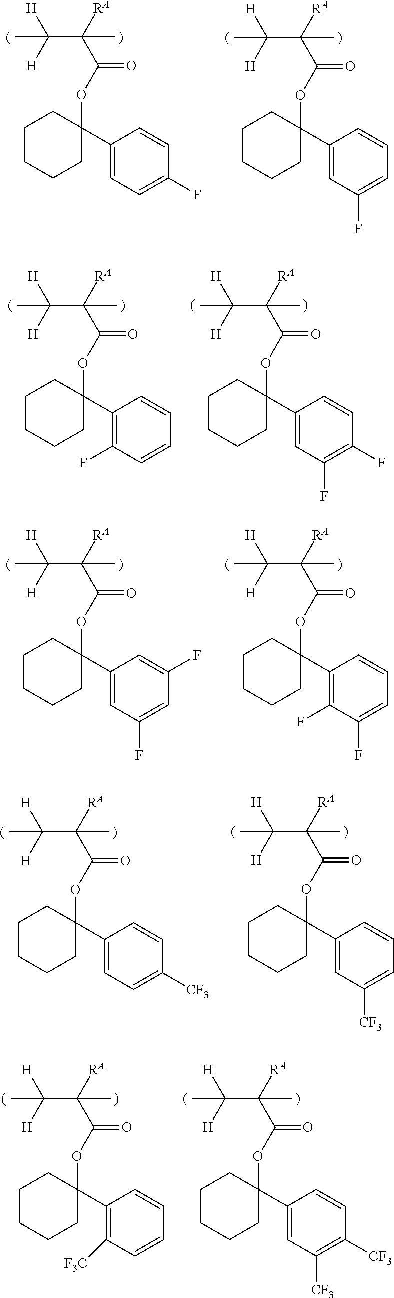

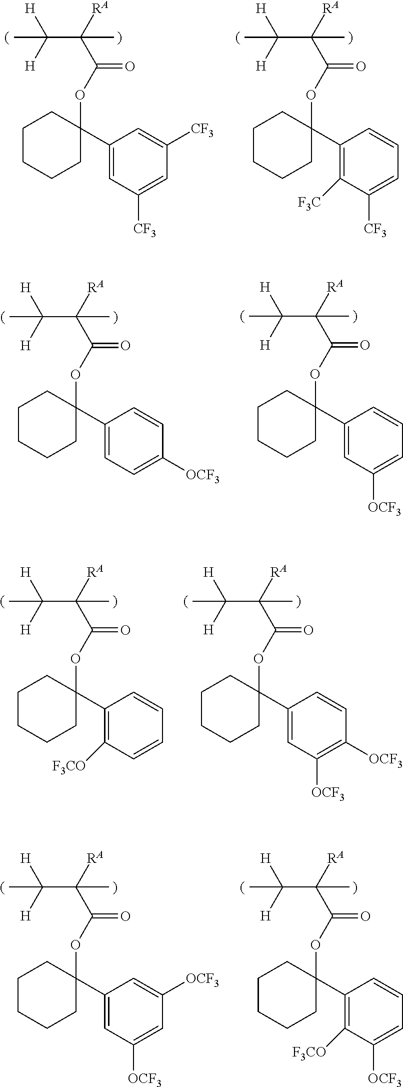

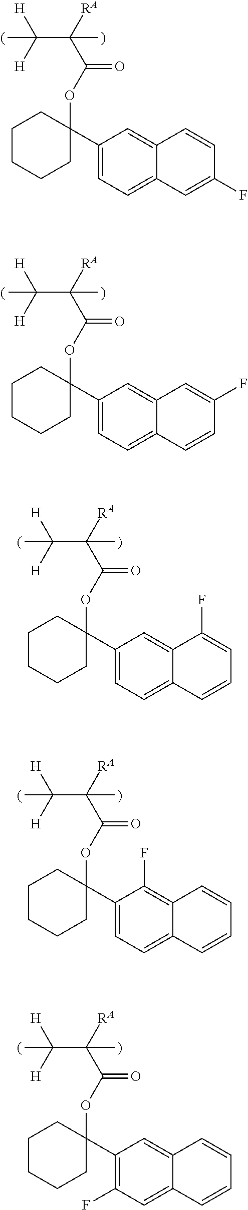

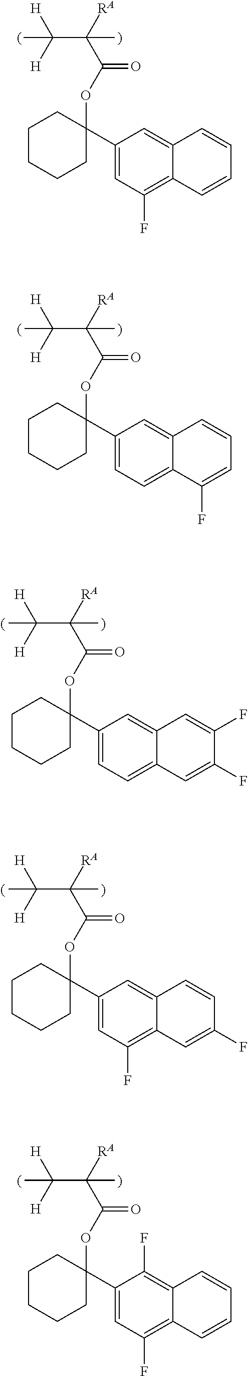

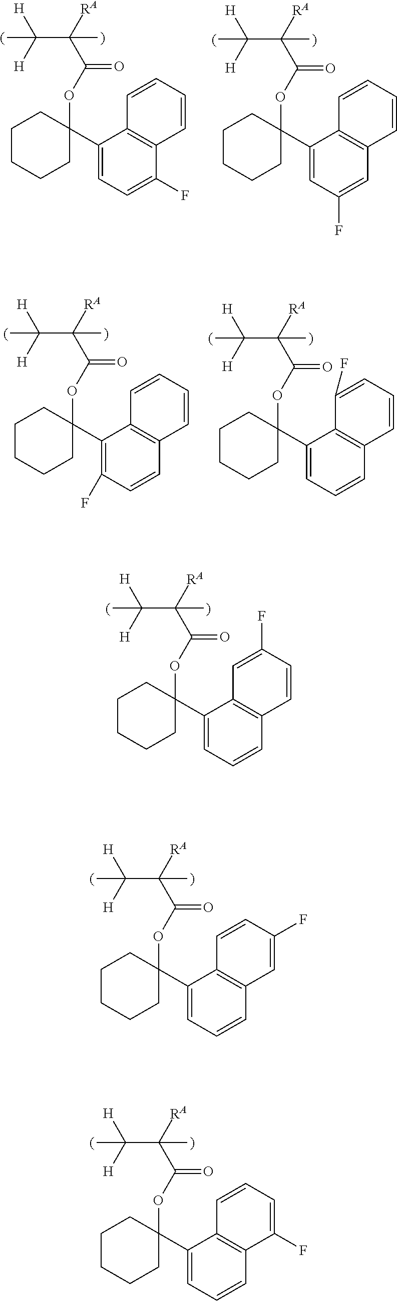

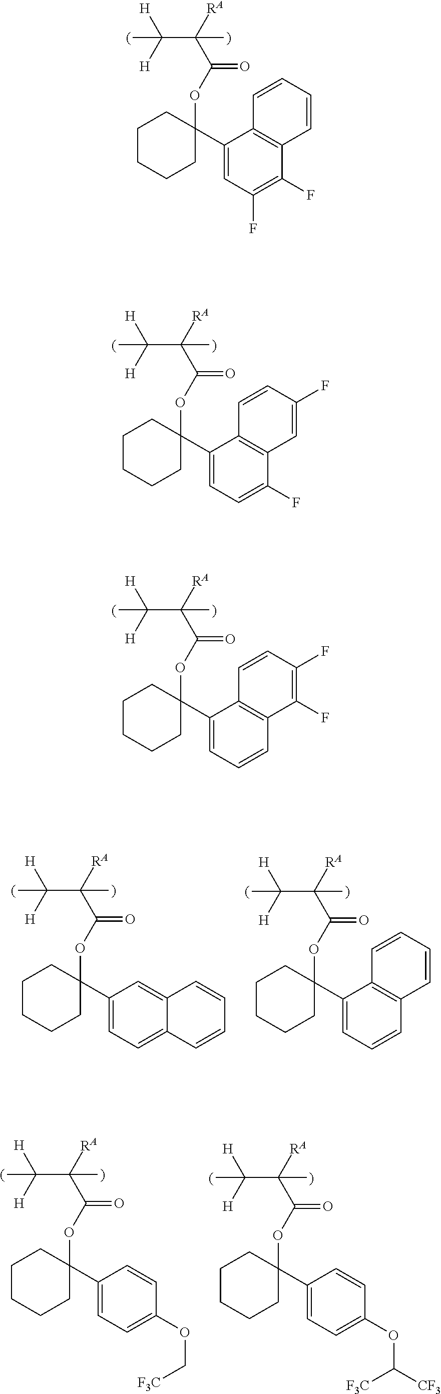

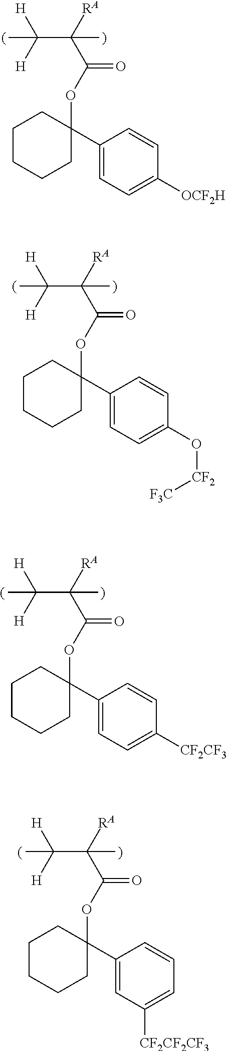

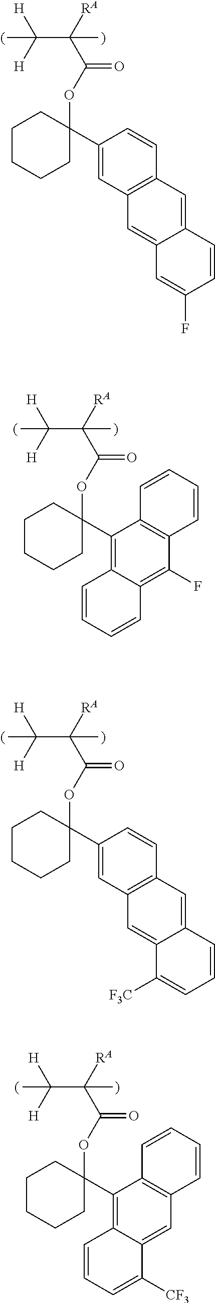

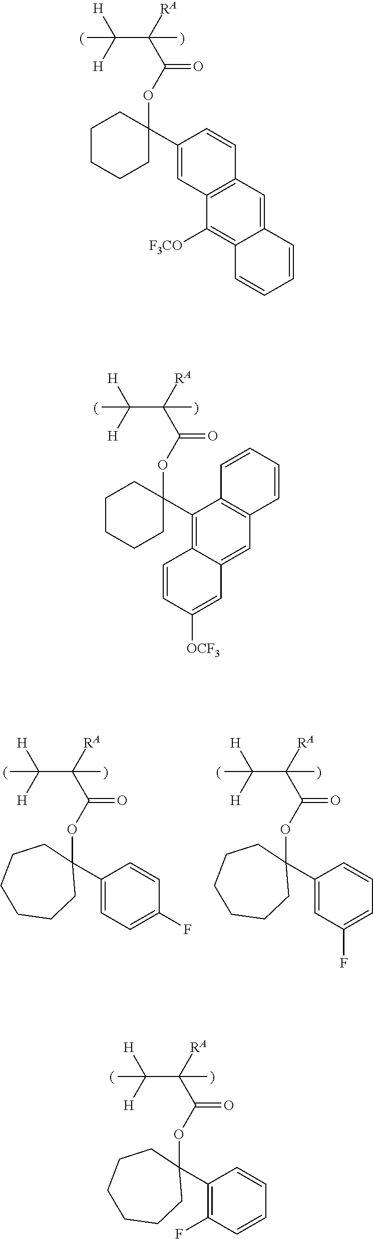

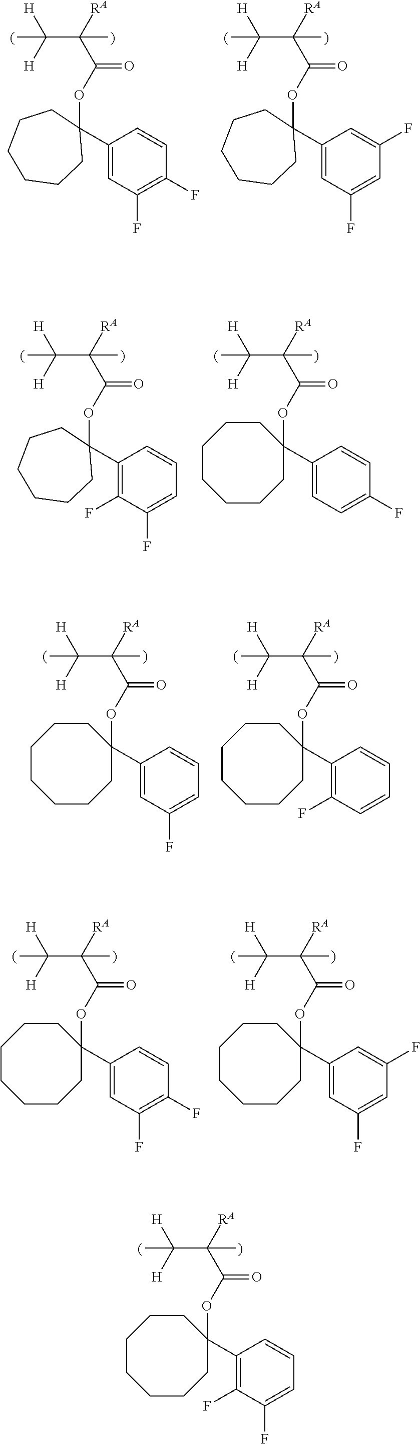

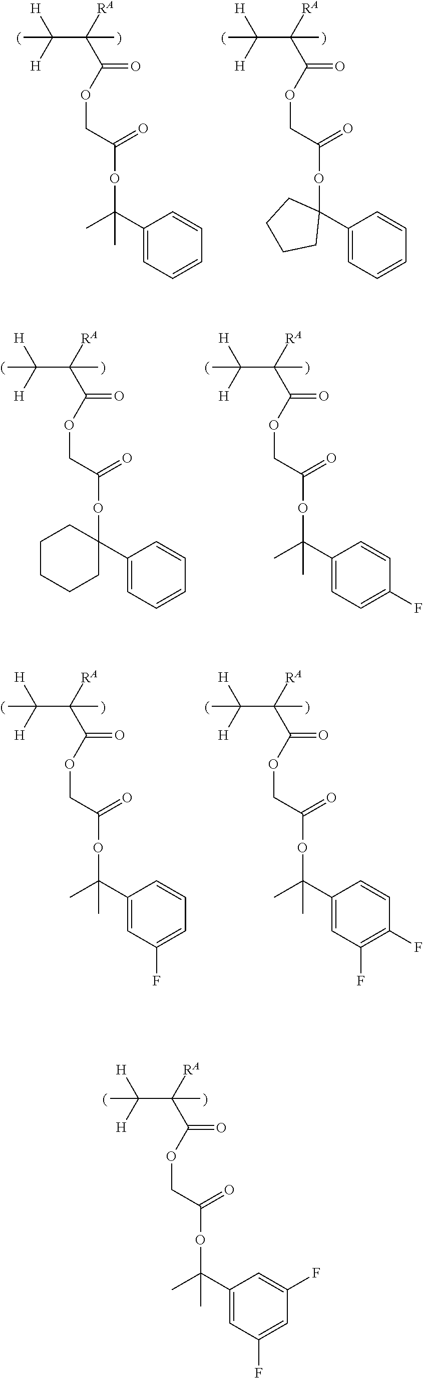

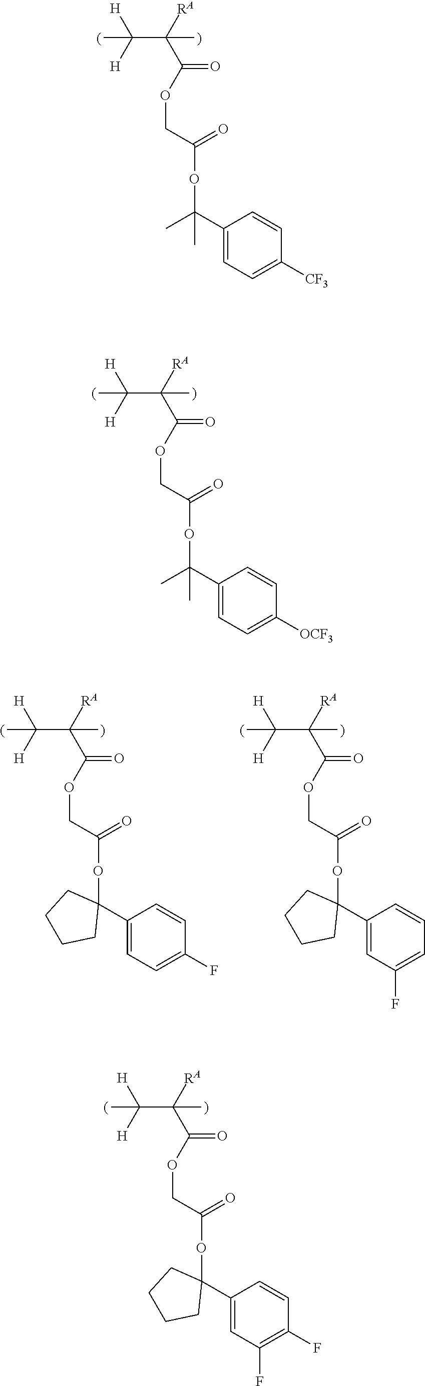

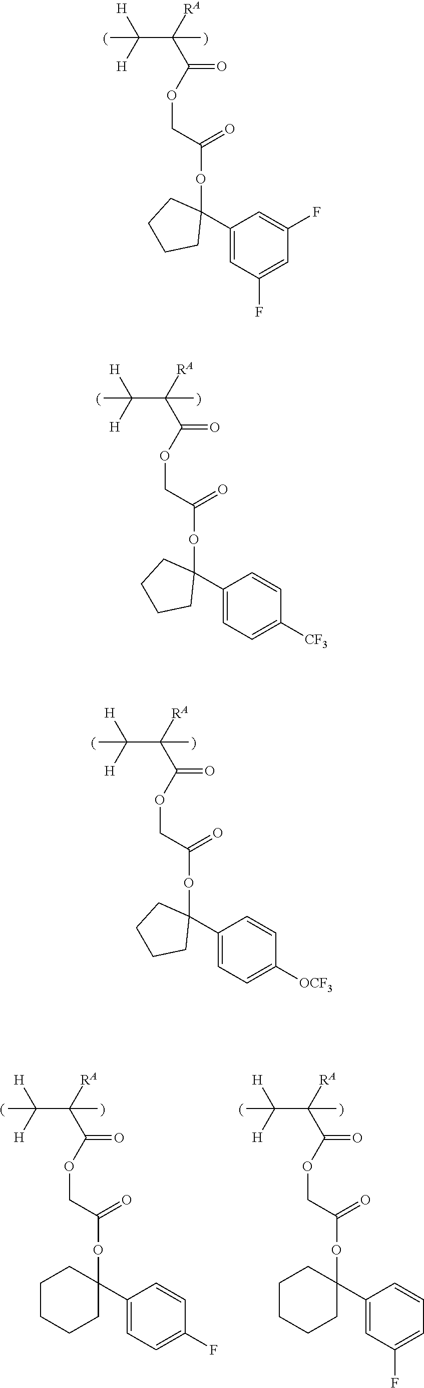

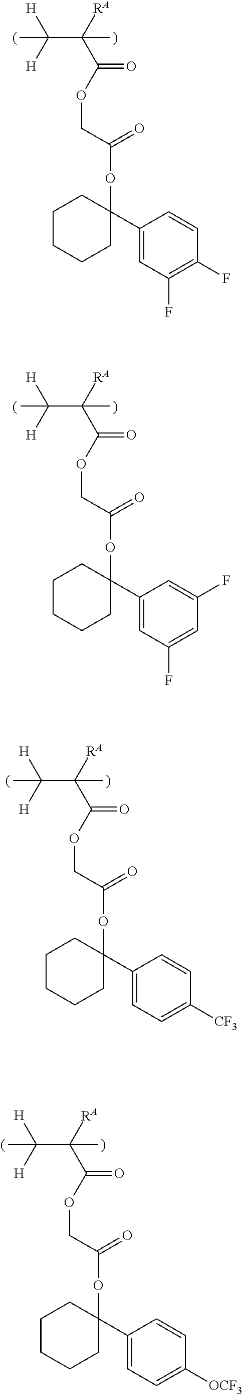

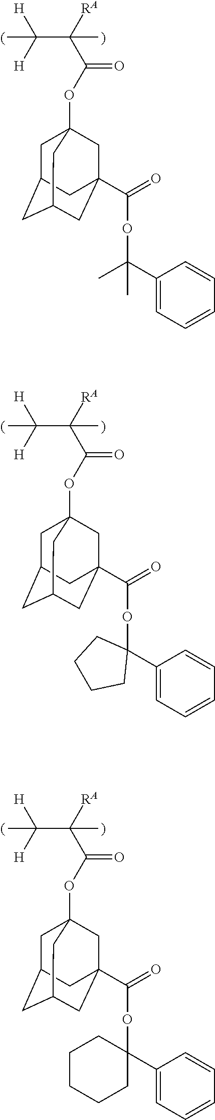

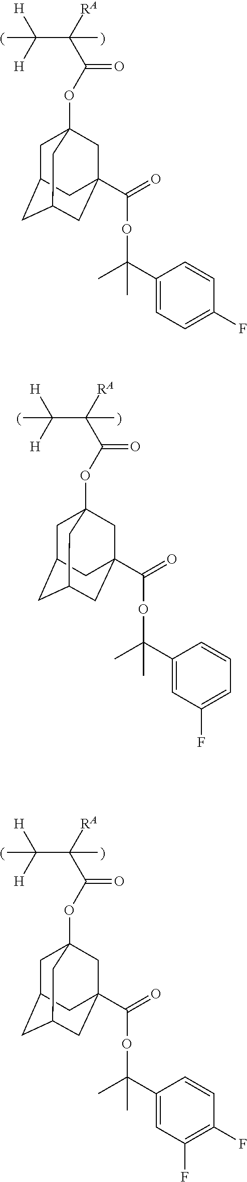

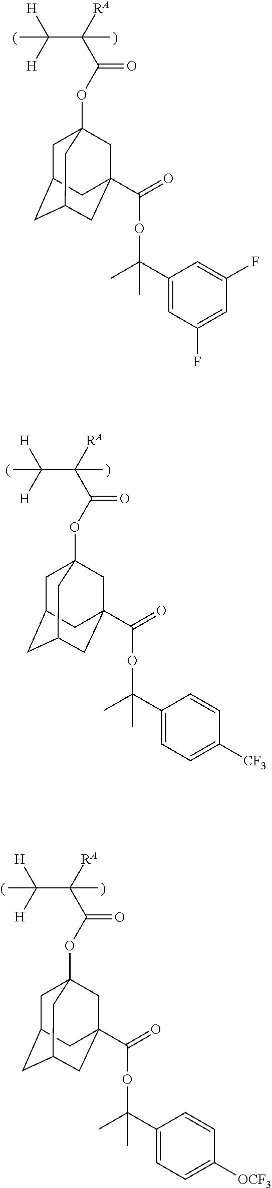

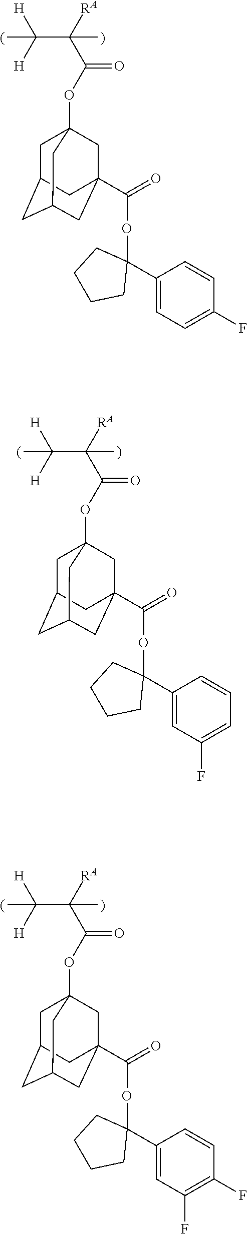

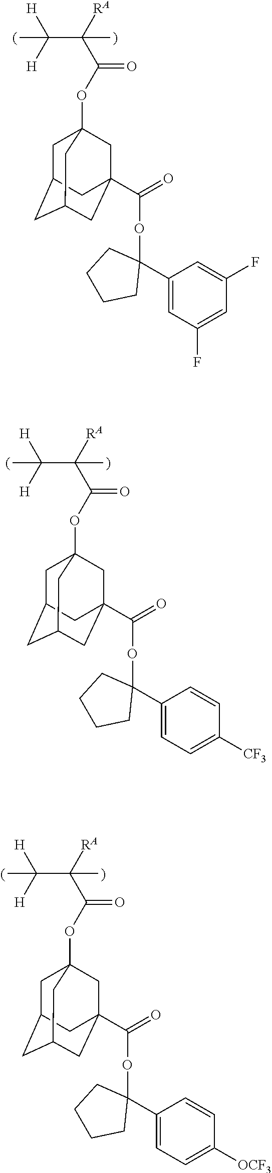

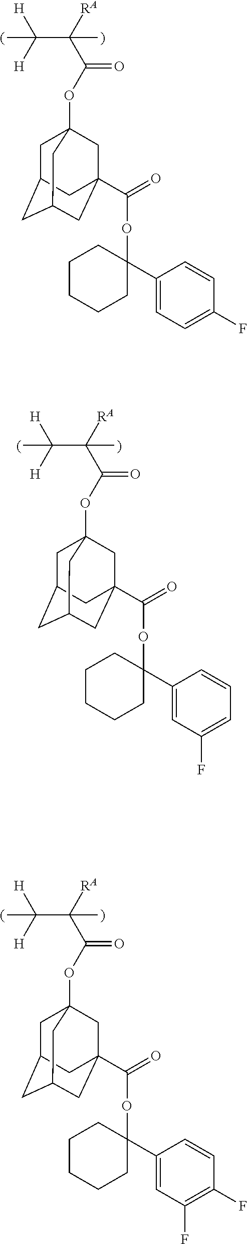

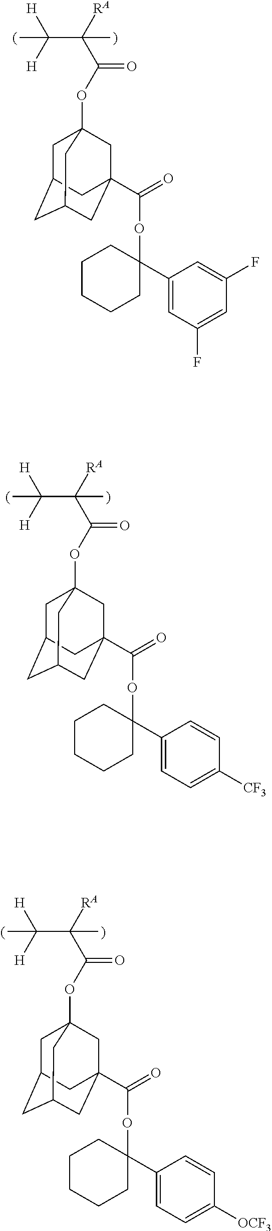

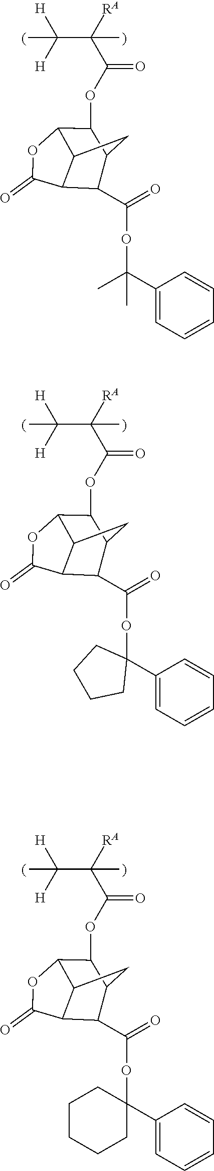

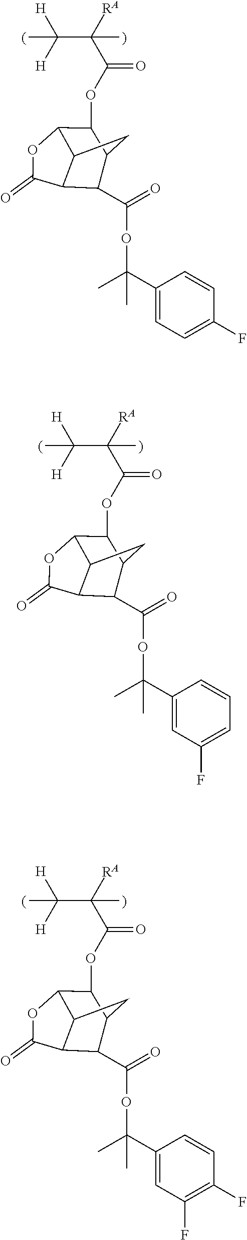

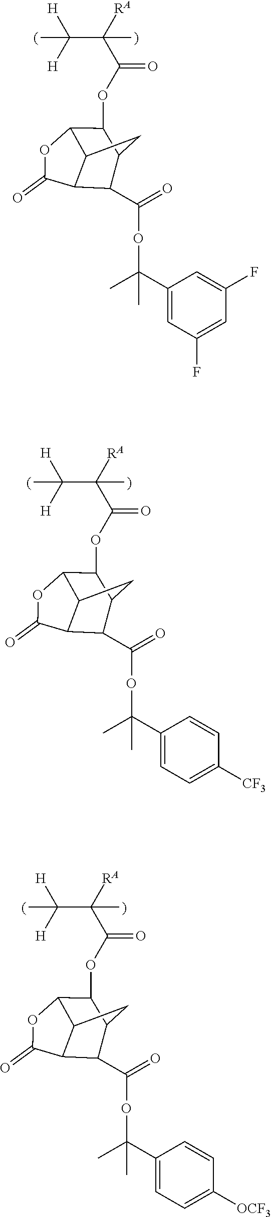

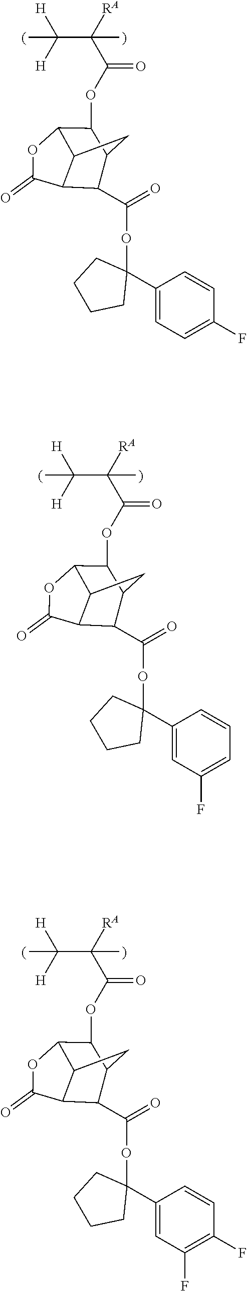

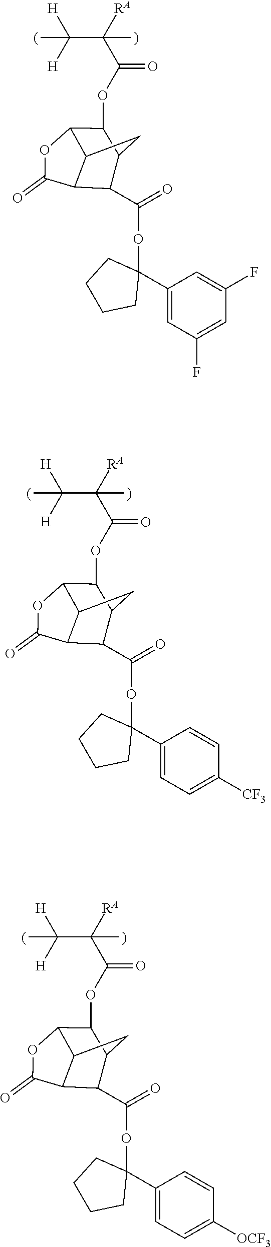

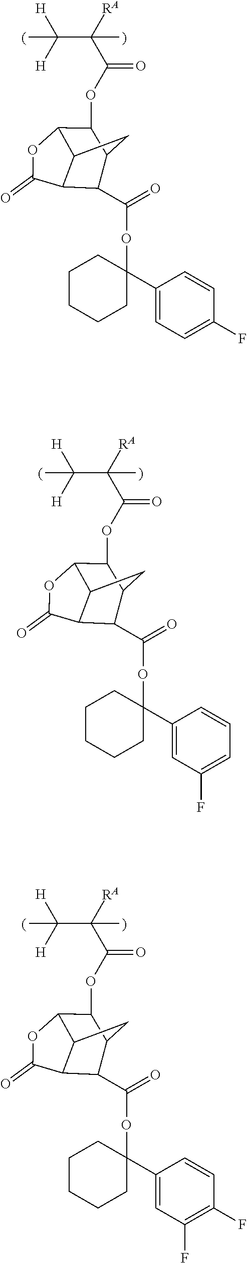

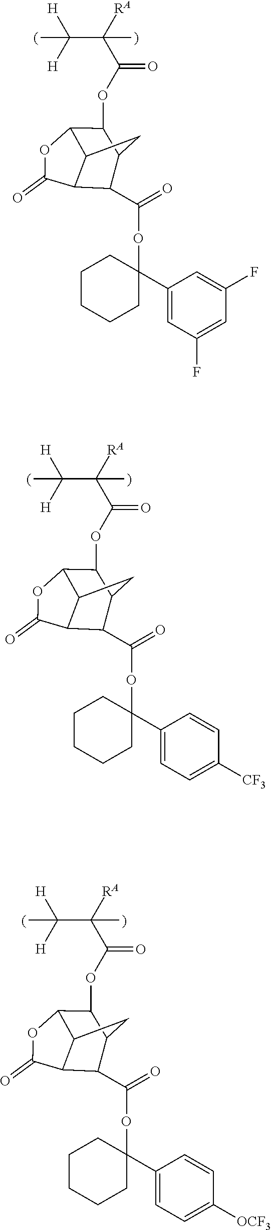

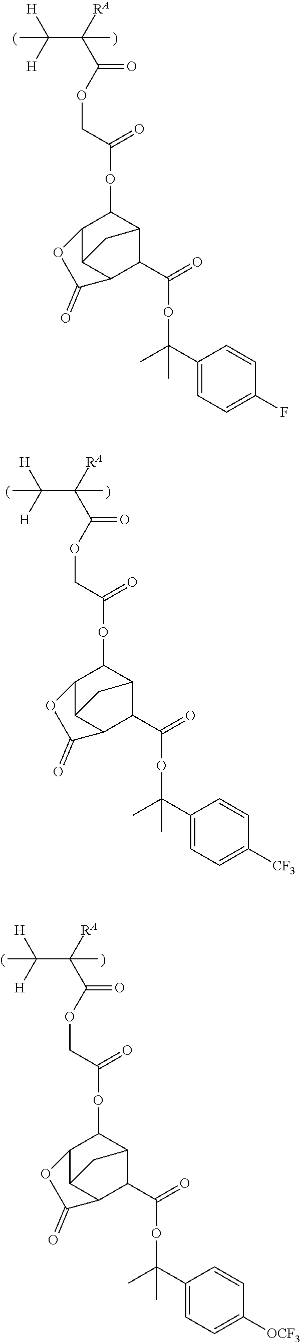

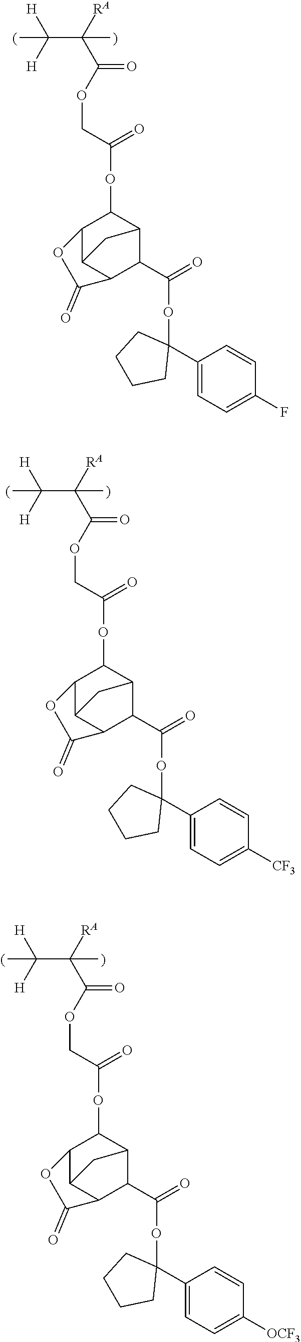

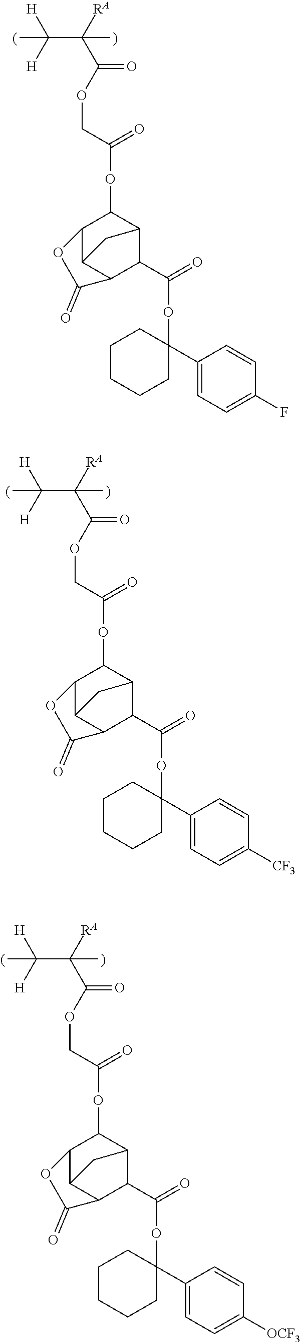

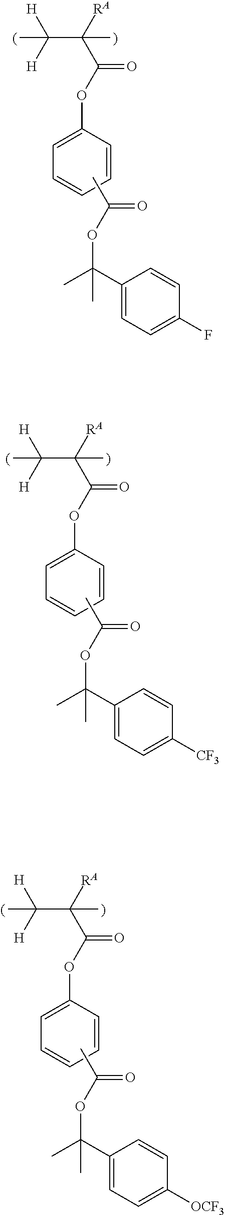

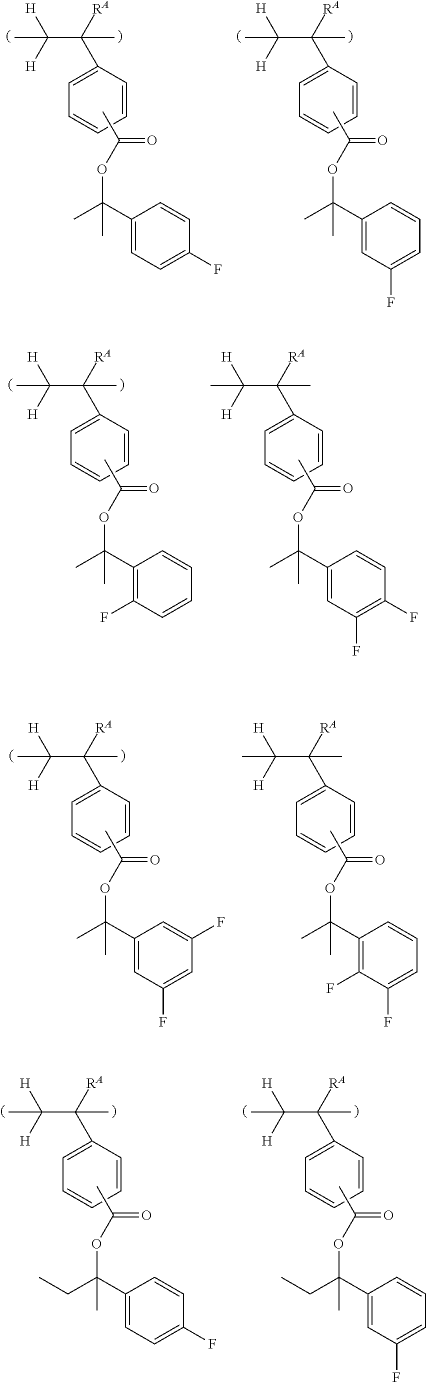

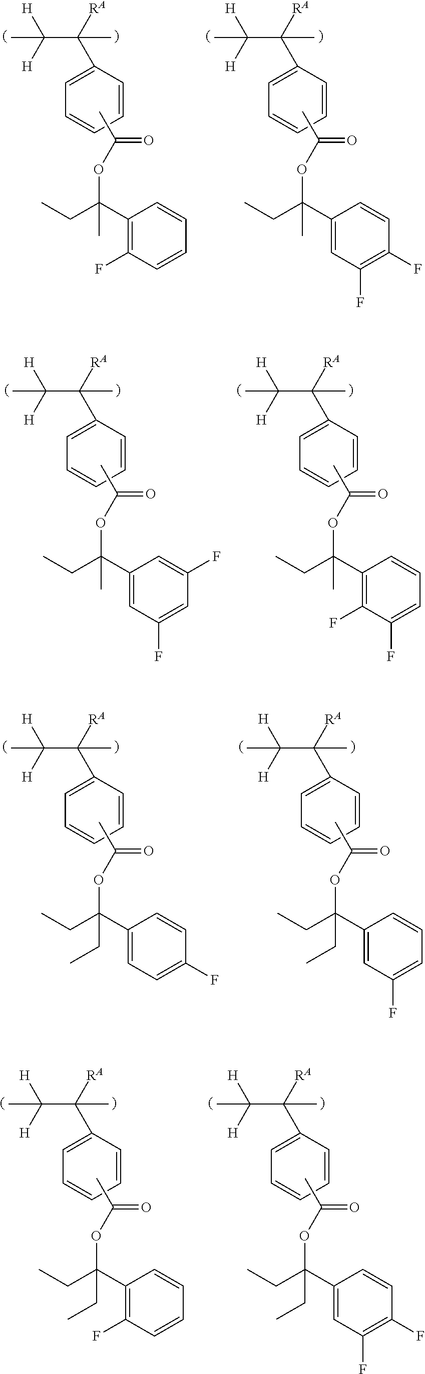

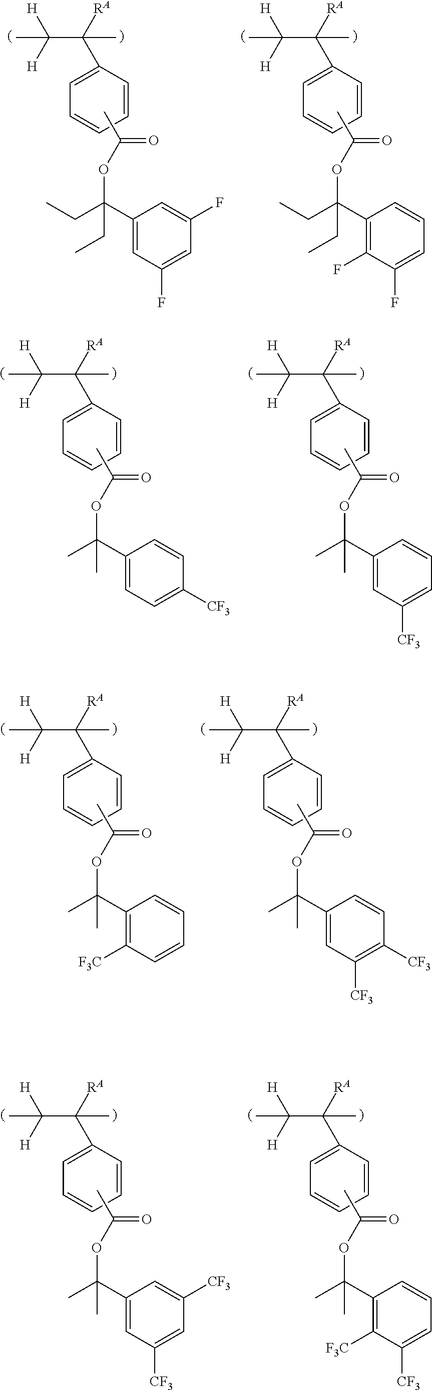

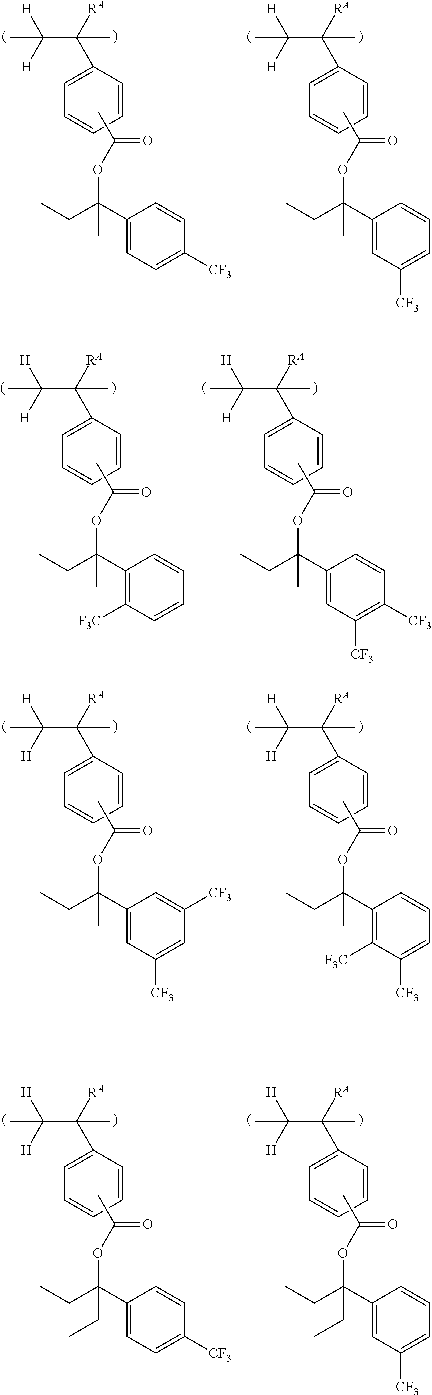

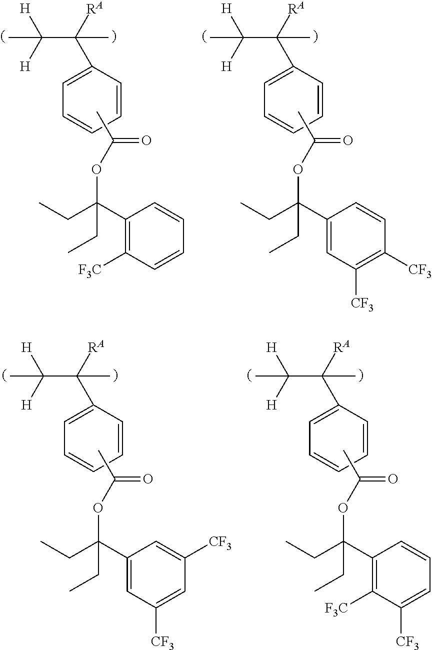

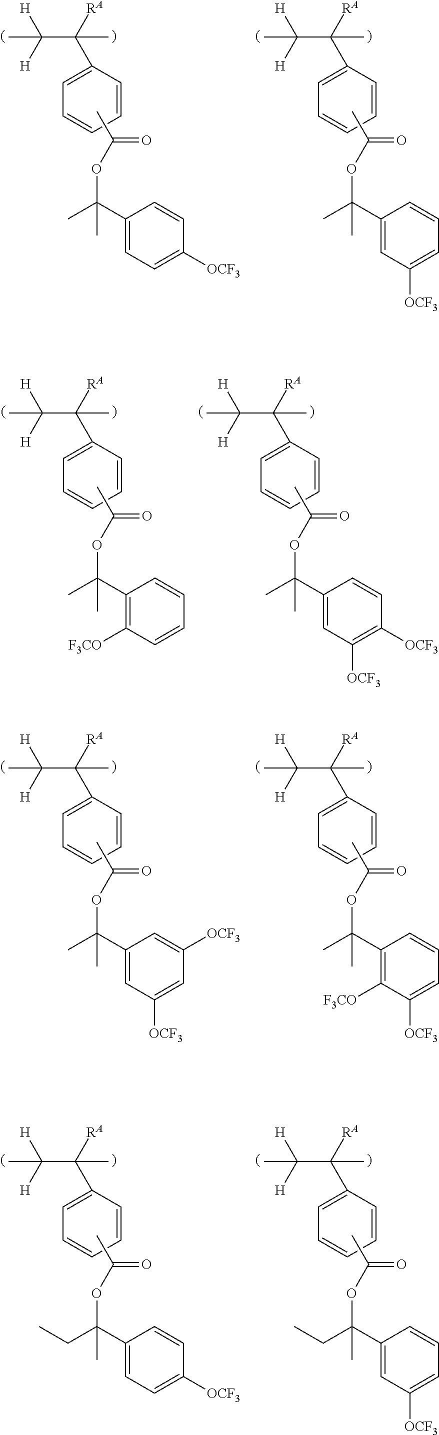

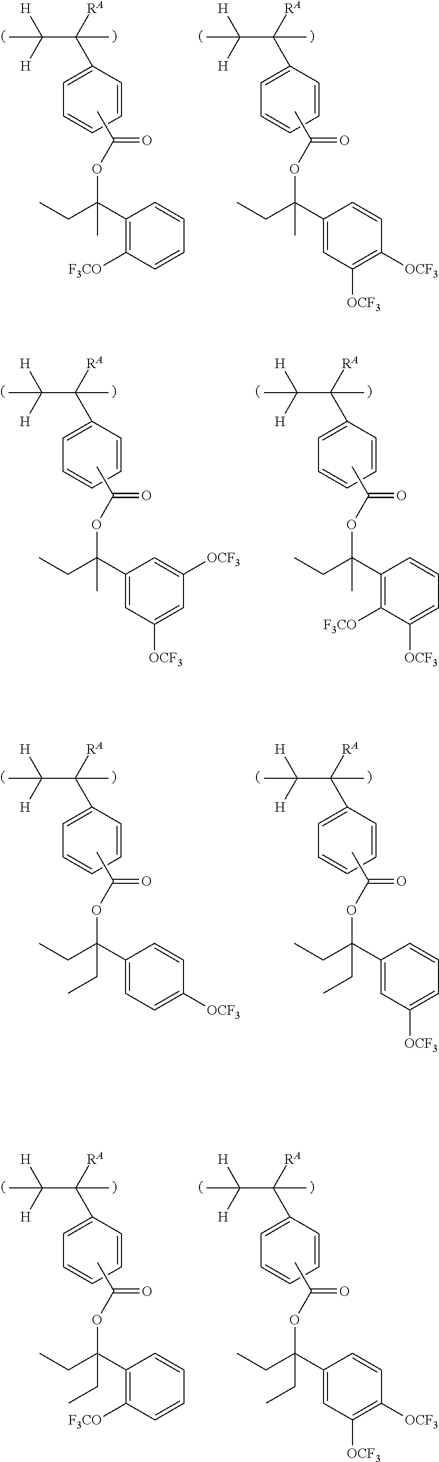

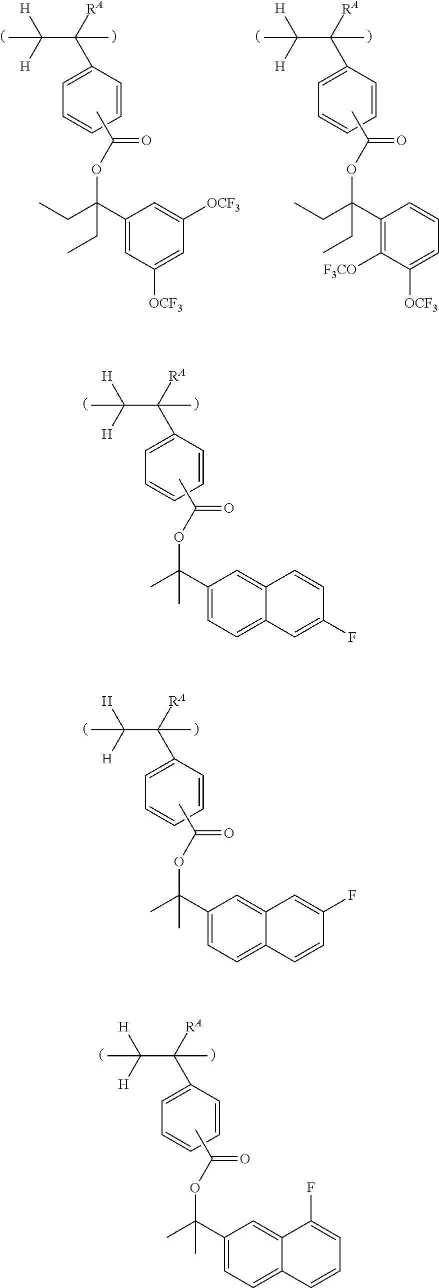

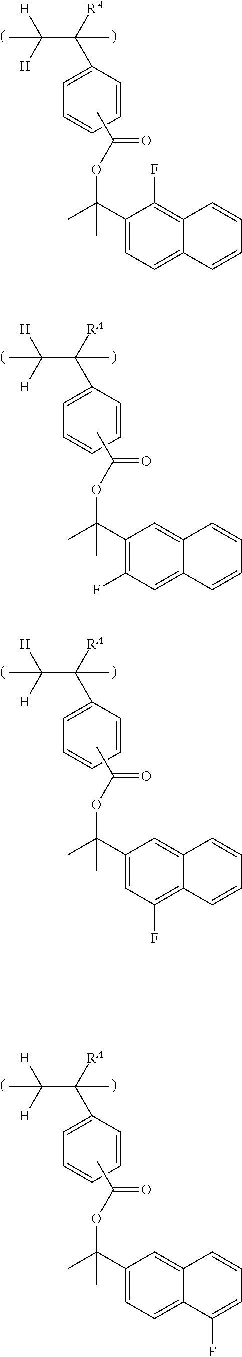

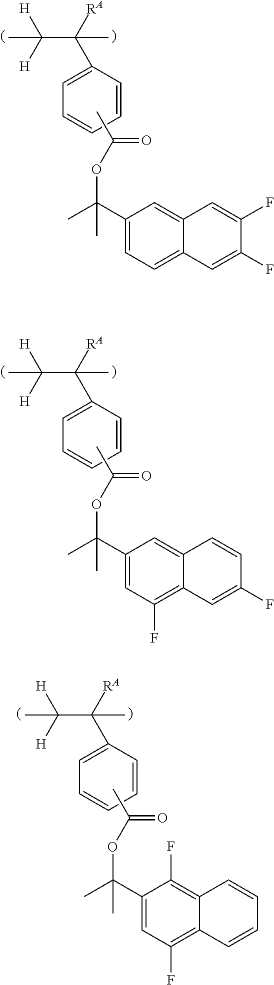

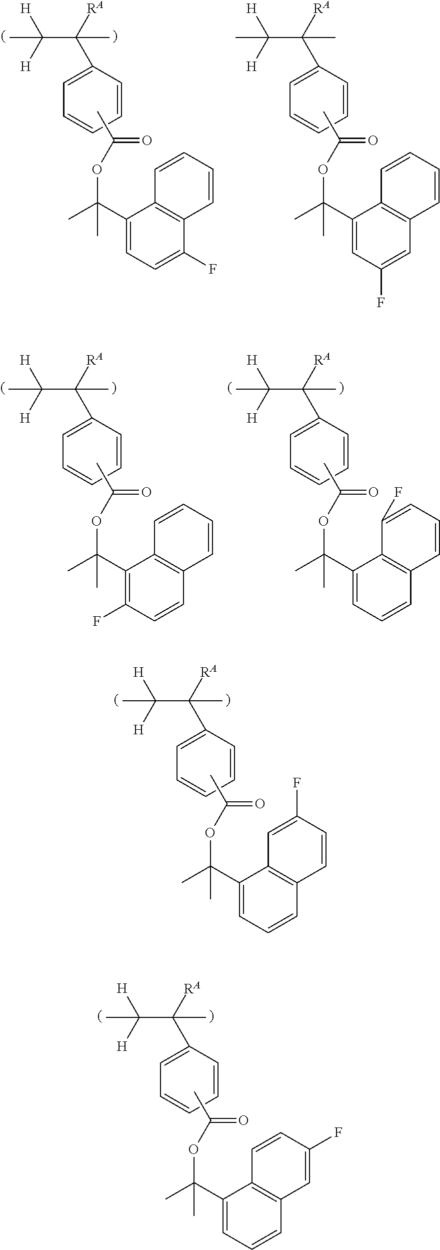

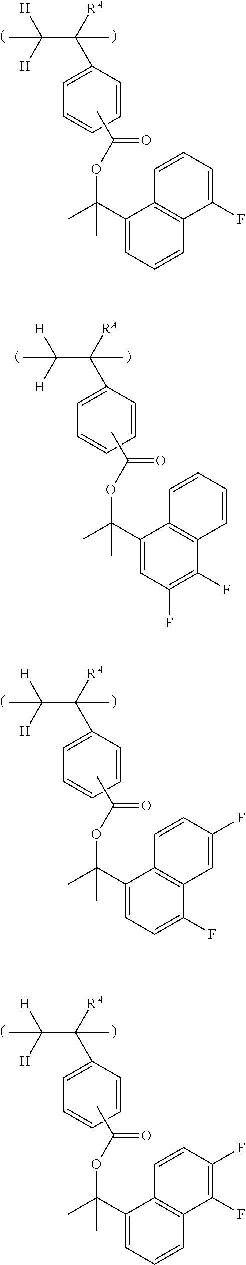

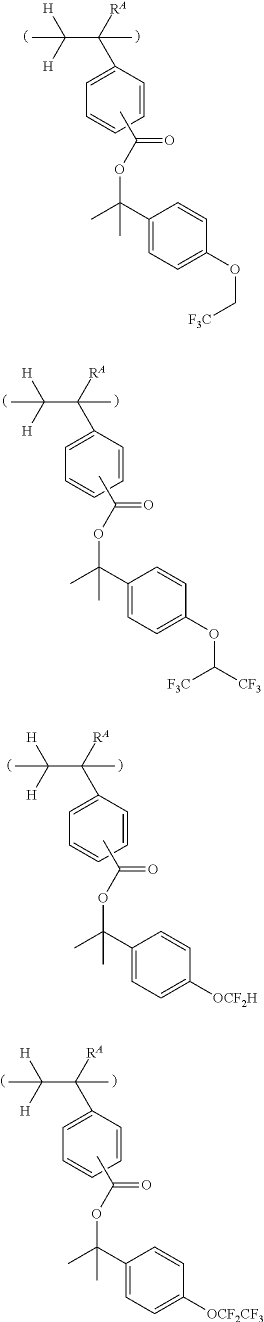

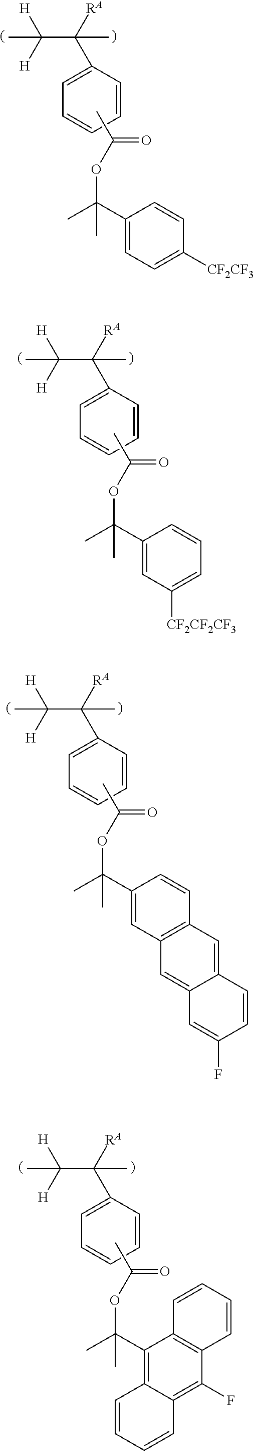

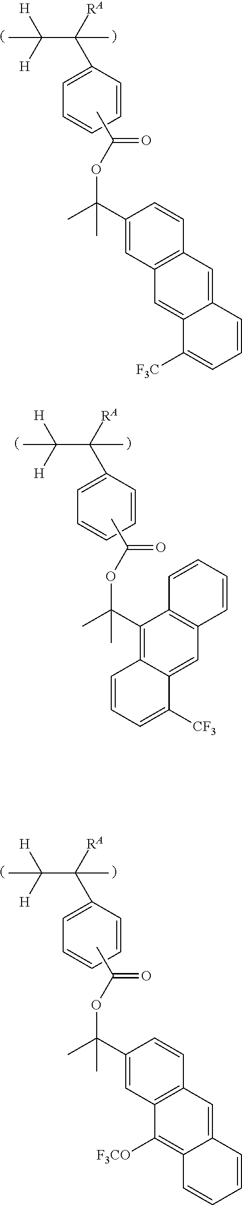

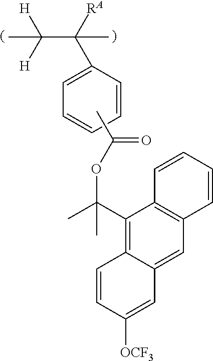

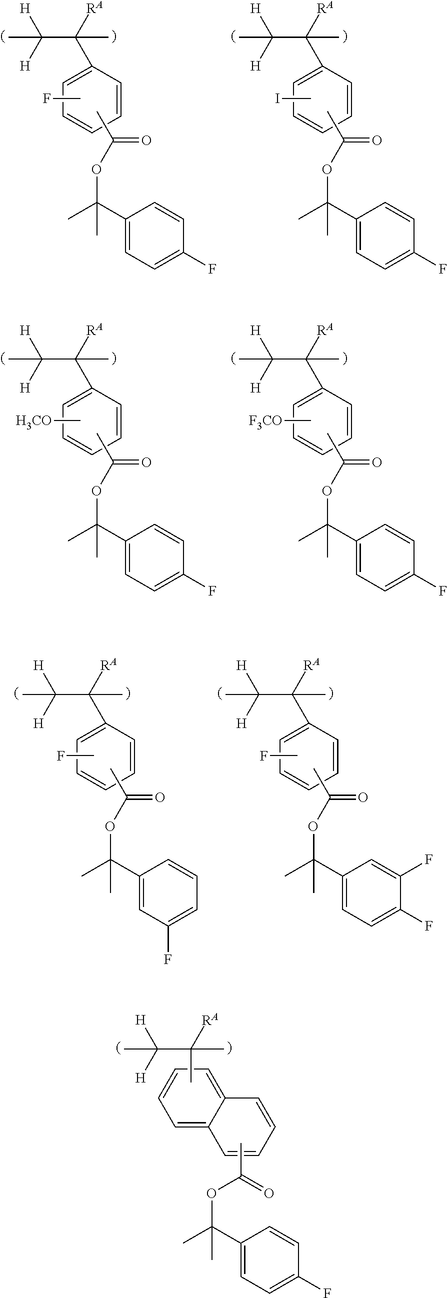

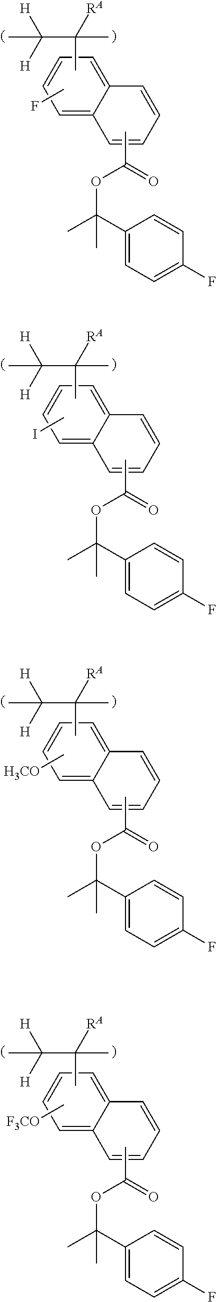

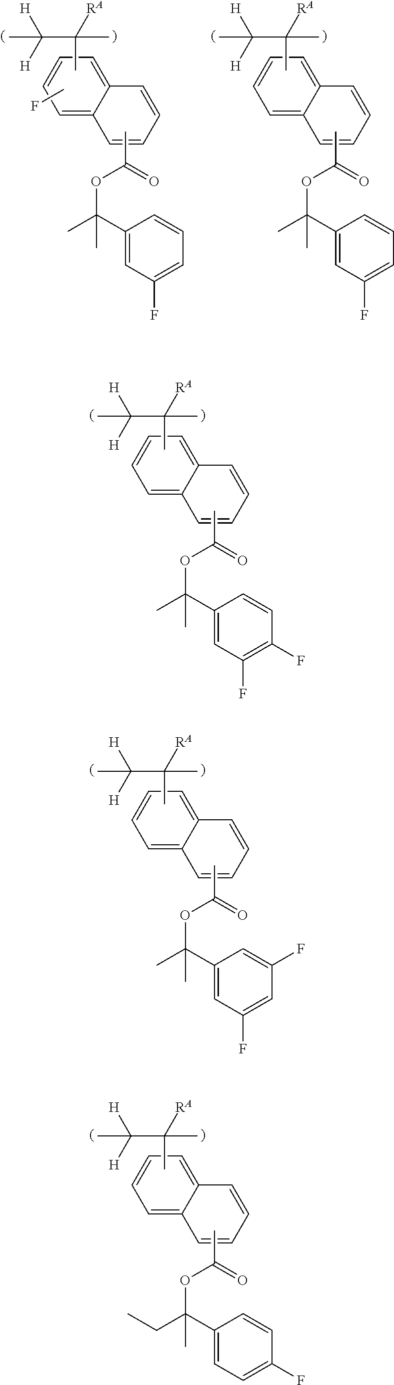

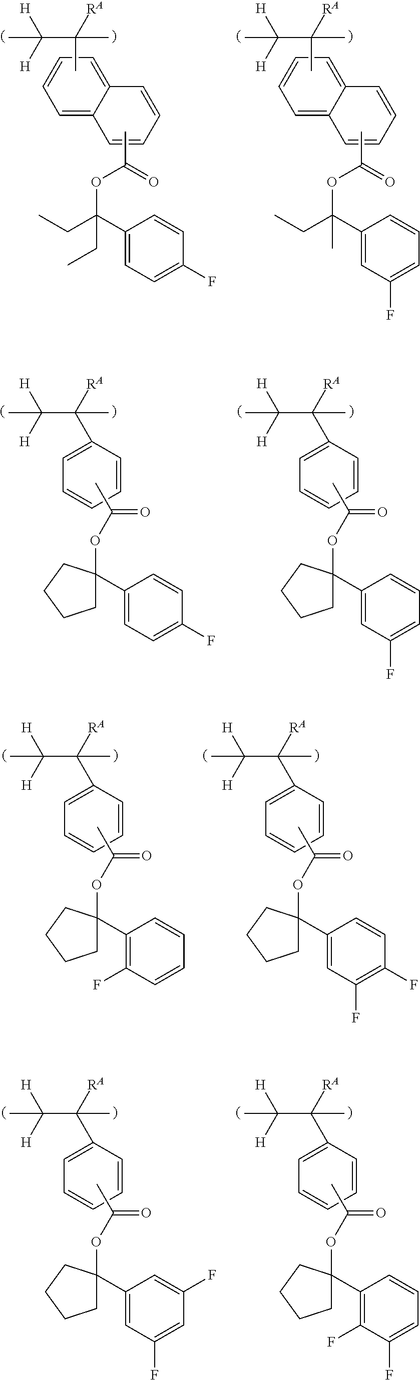

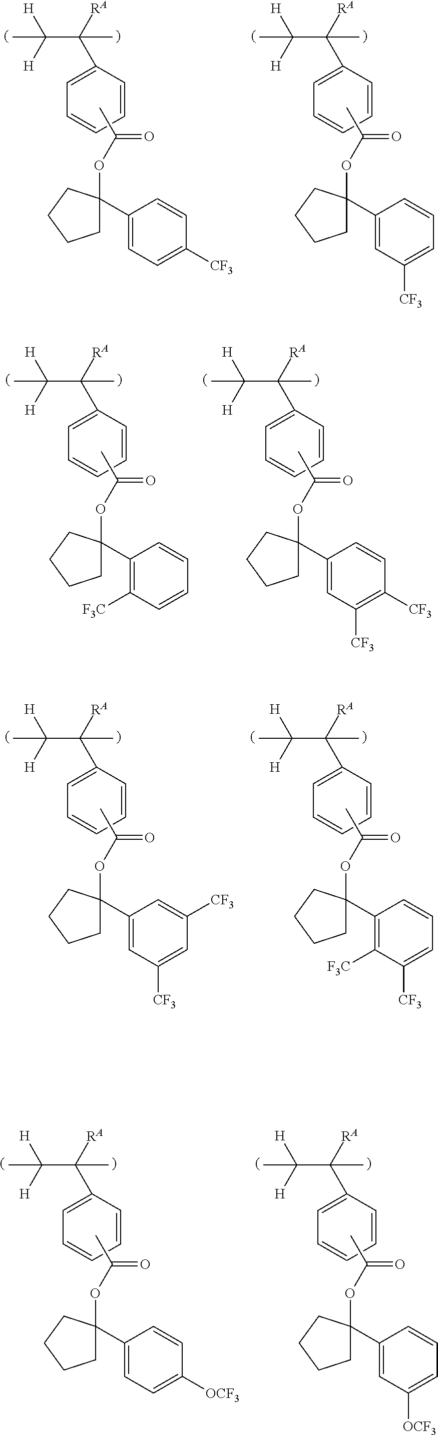

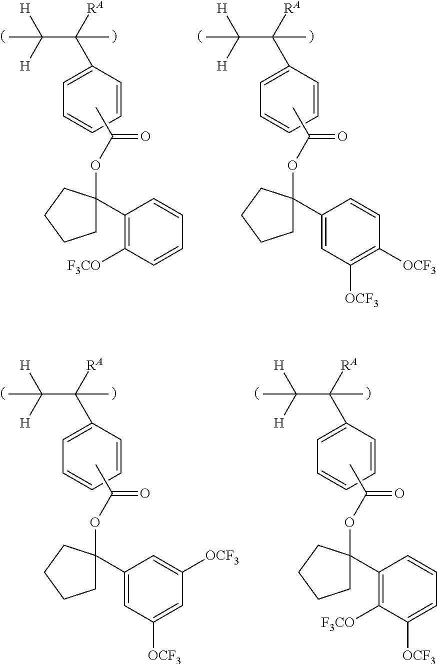

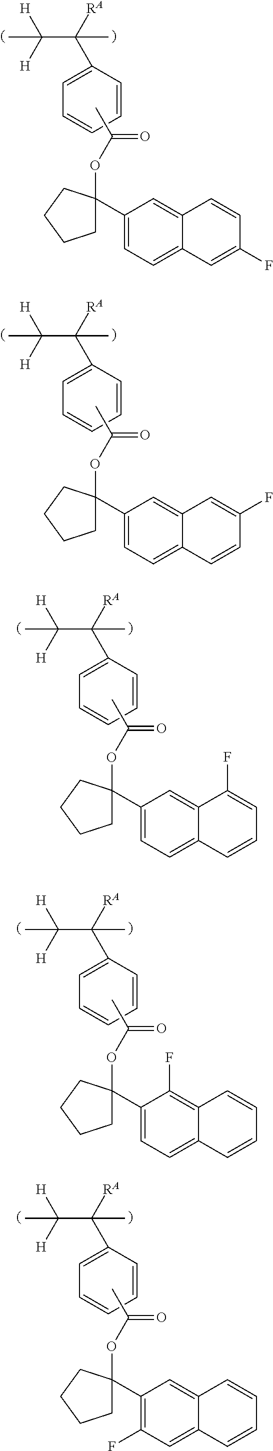

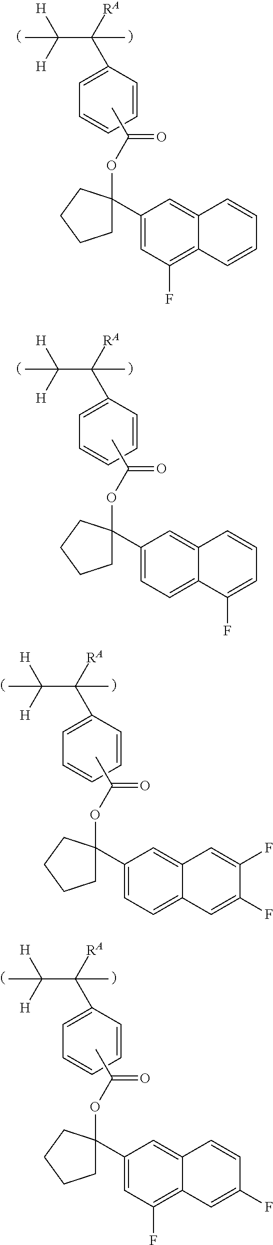

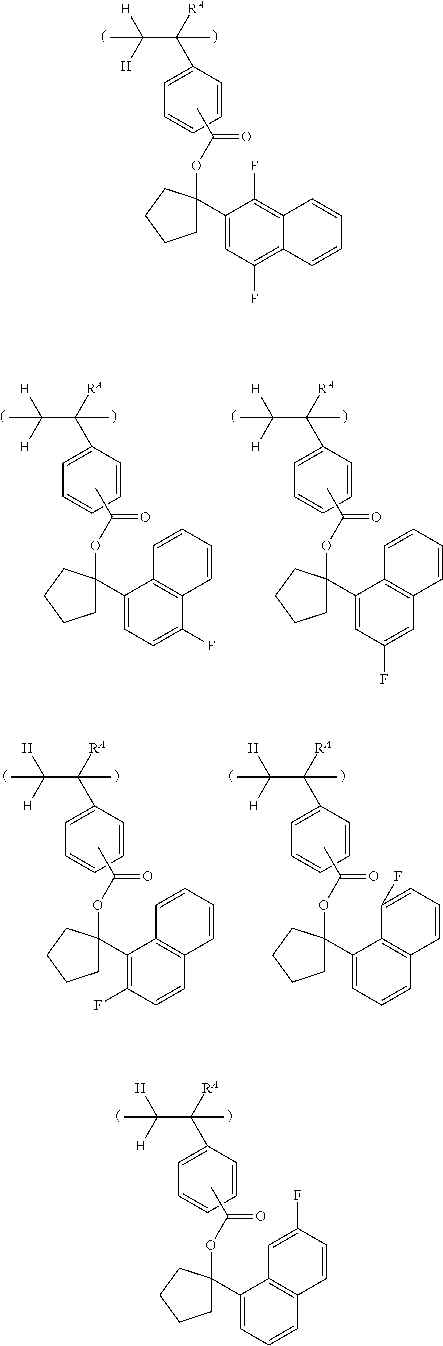

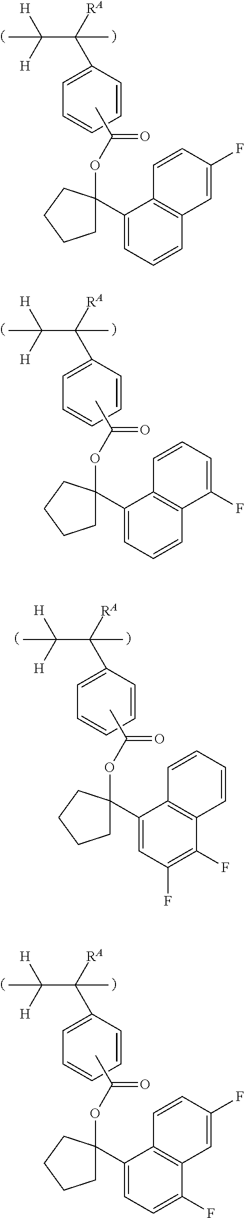

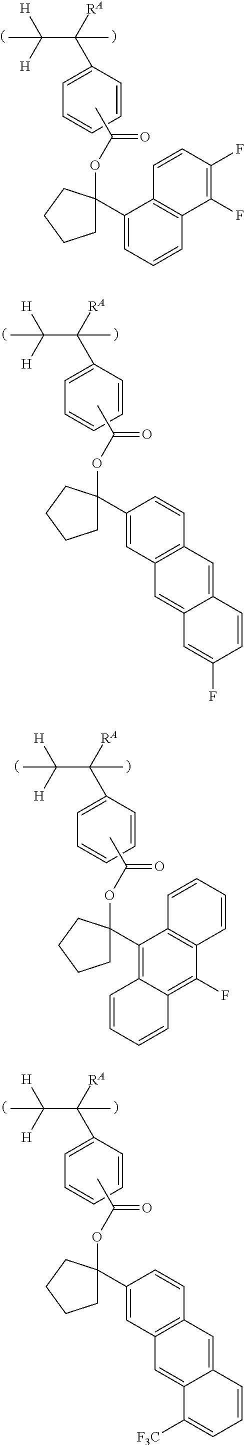

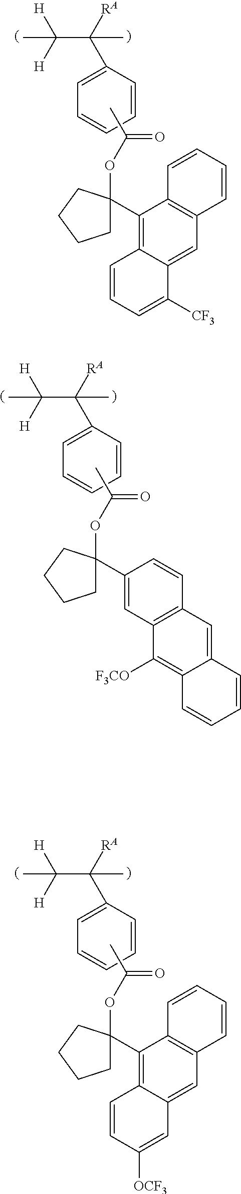

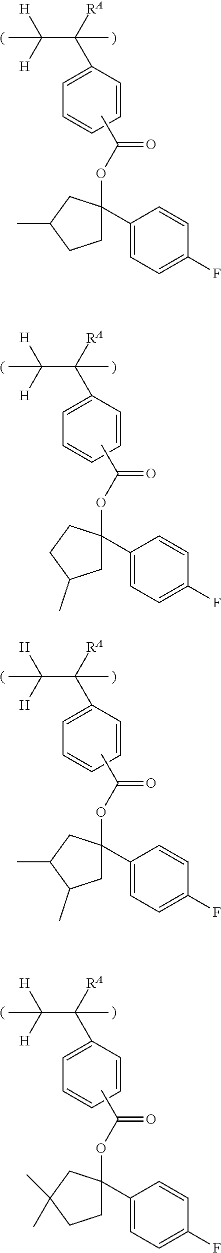

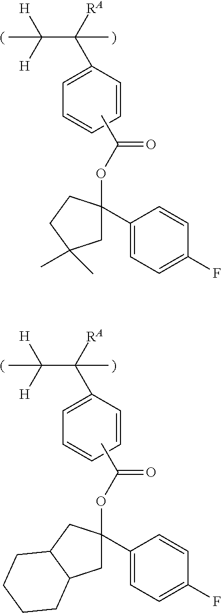

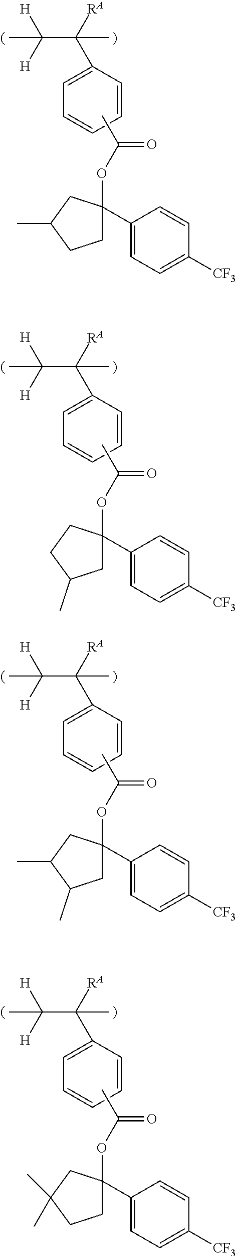

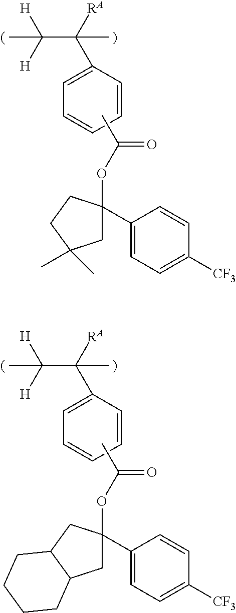

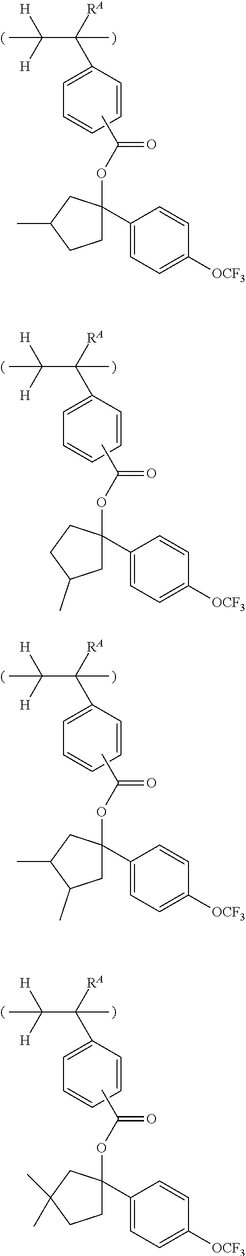

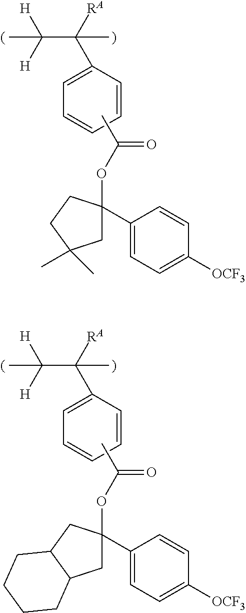

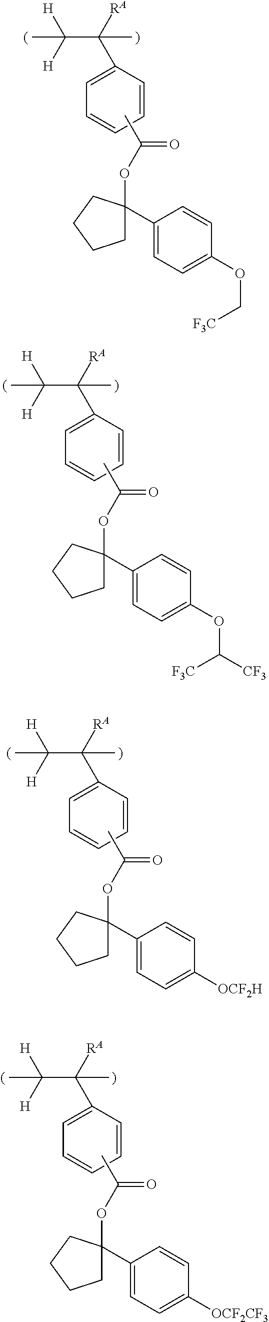

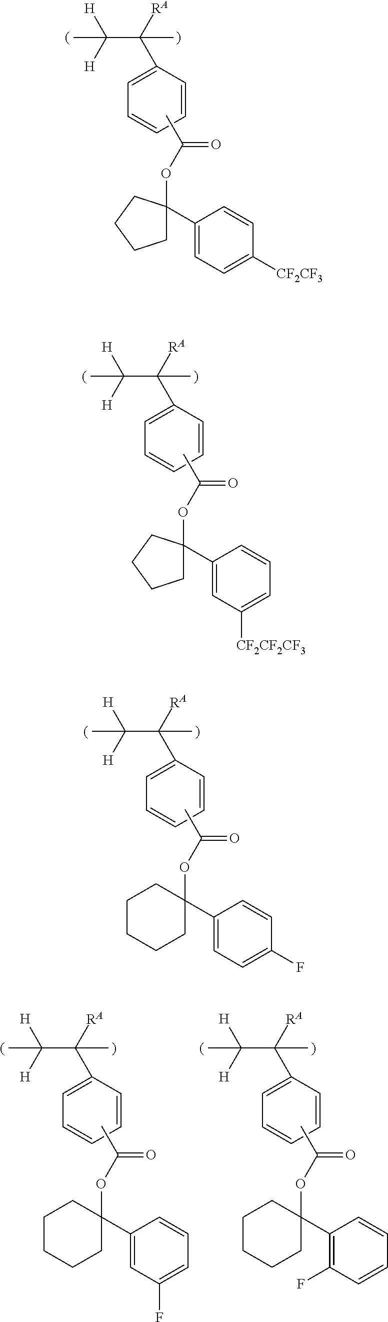

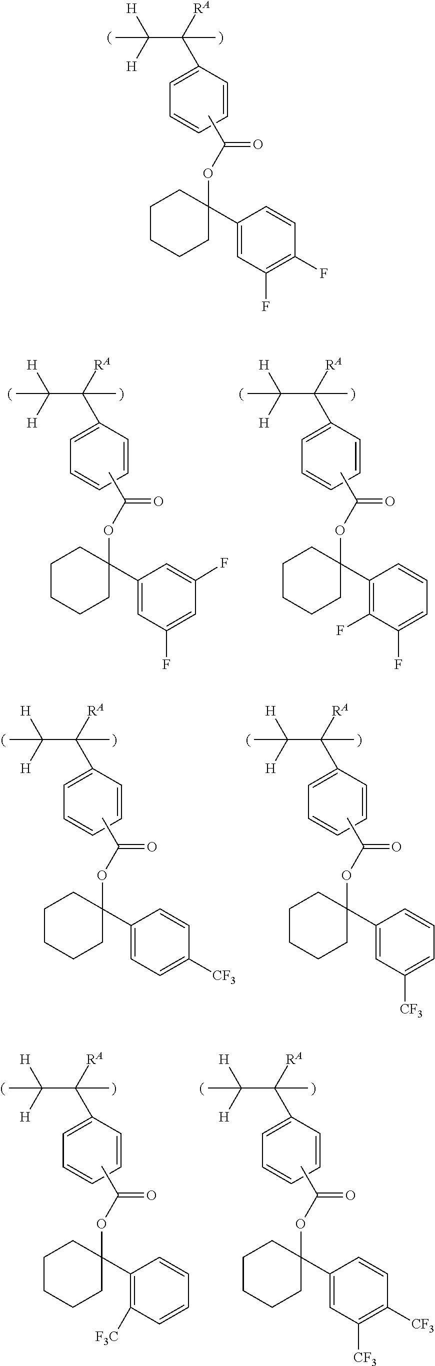

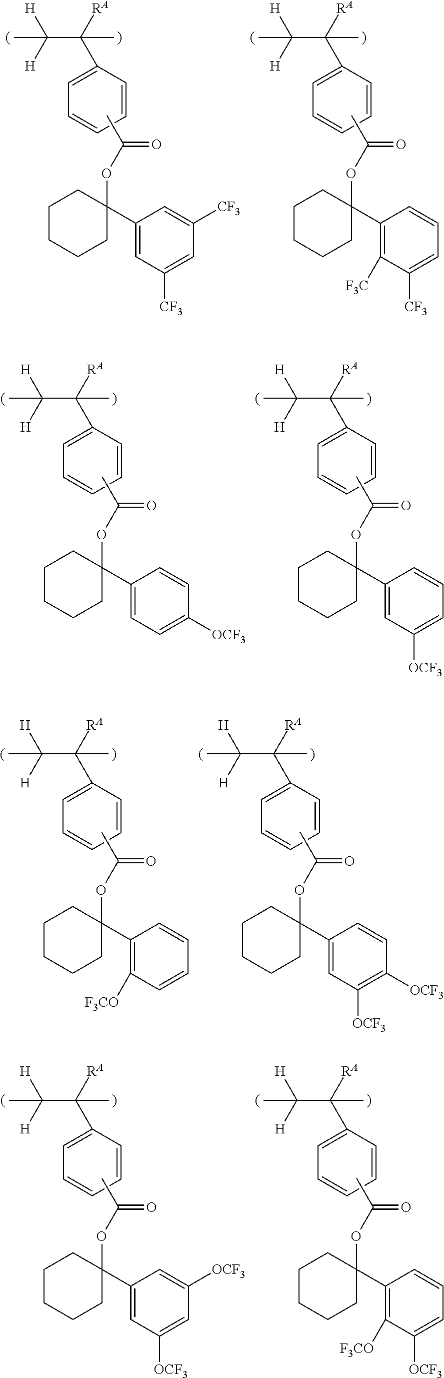

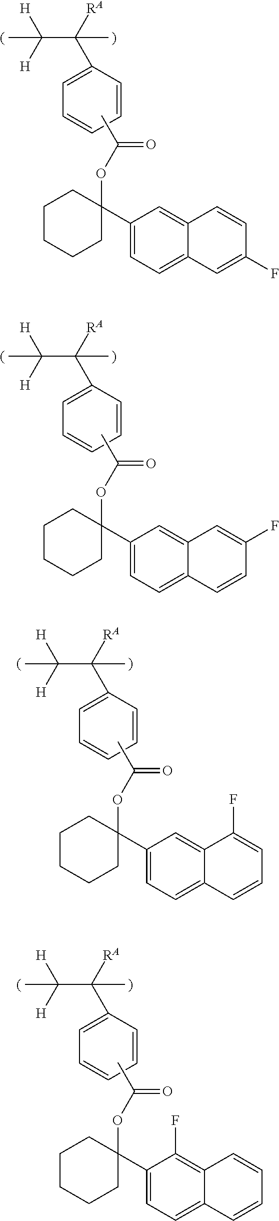

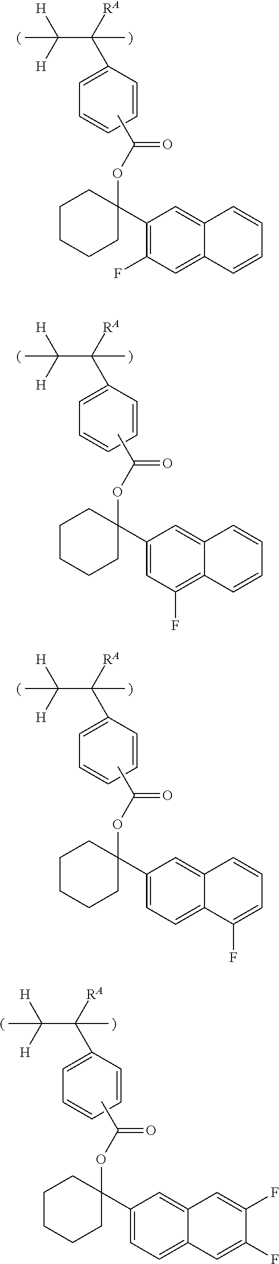

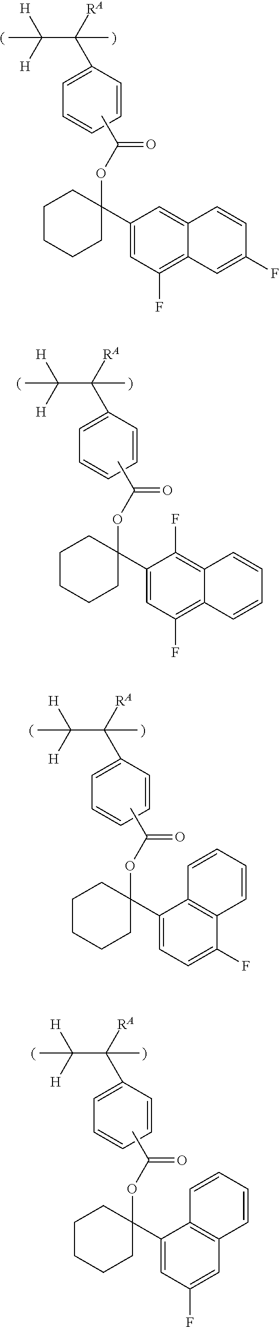

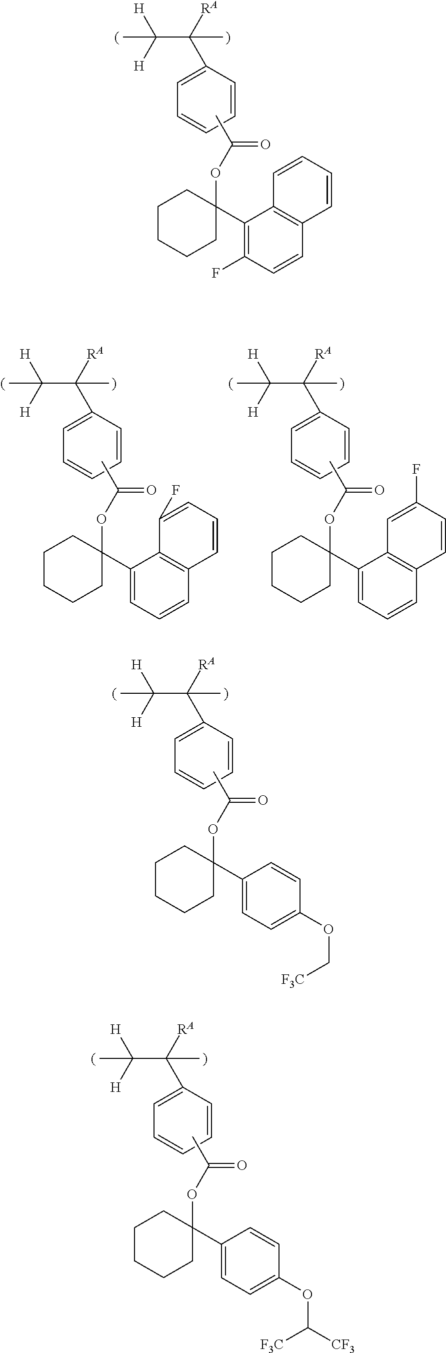

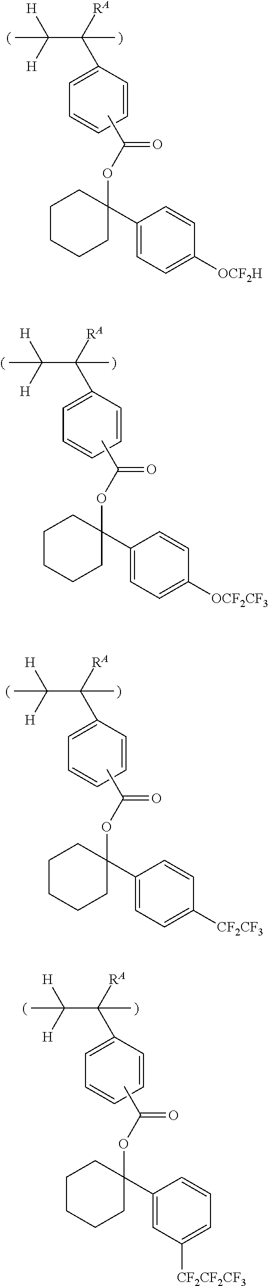

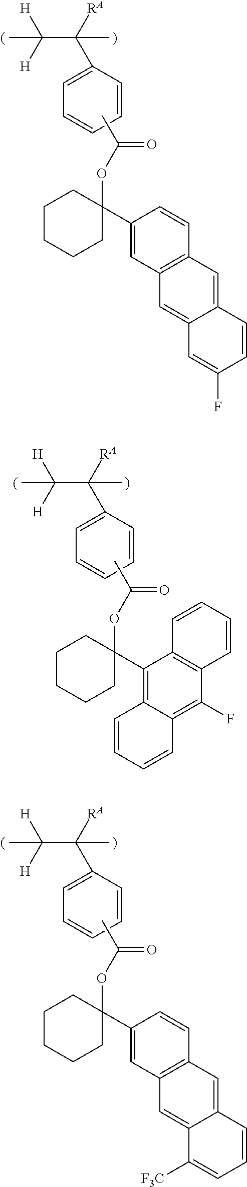

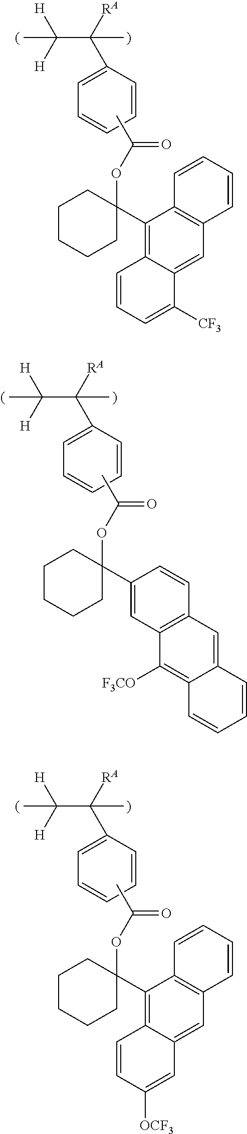

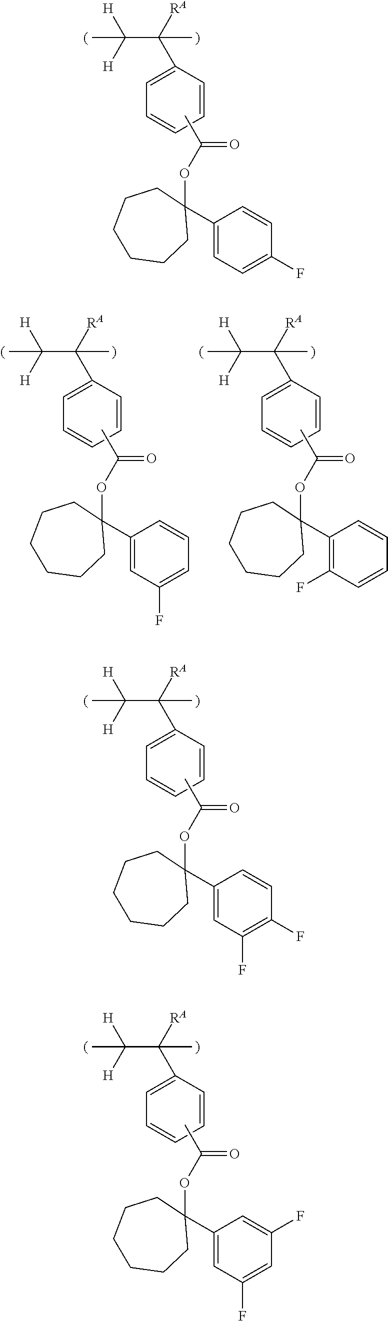

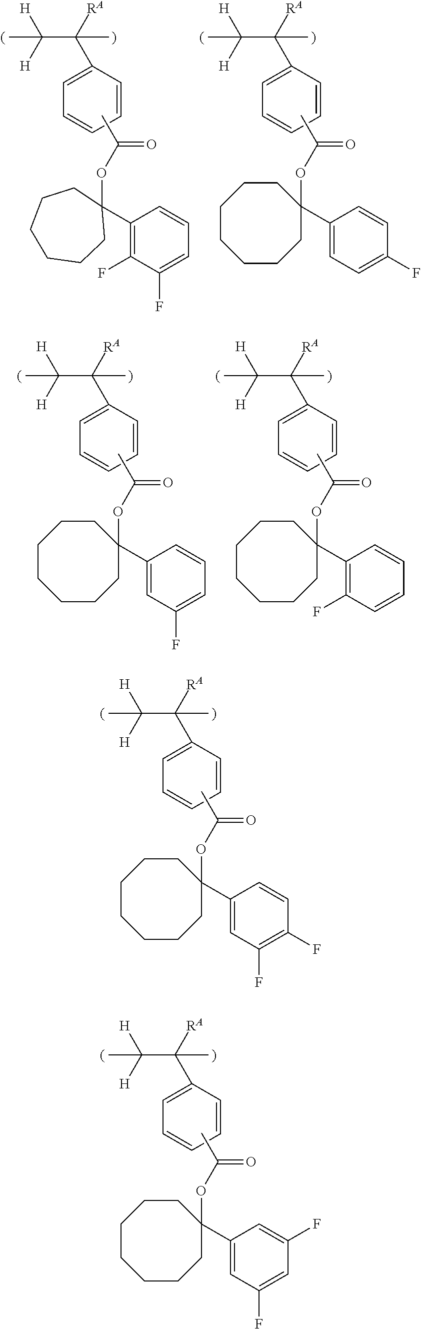

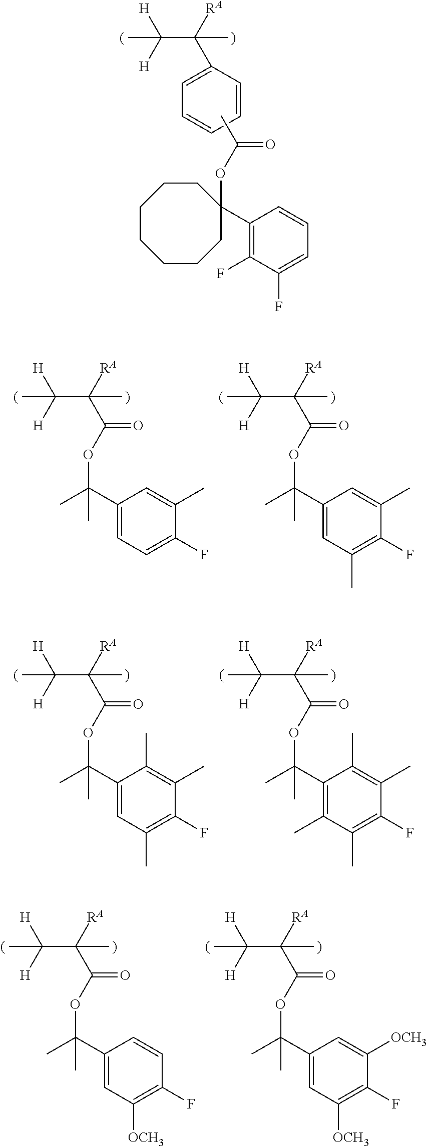

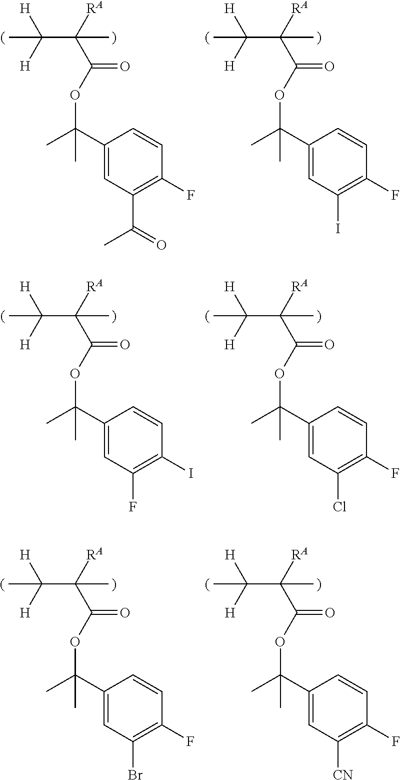

Since the acid labile group having carboxylic acid protected with a tertiary alcohol having an aryl group is extremely low in activation energy for acid-catalyzed deprotection reaction as compared with the acid labile group in the form of tertiary alkyl group, typically tert-butyl, deprotection reaction takes place even at a temperature around 50° C. When a polymer having an acid labile group with extremely low activation energy for deprotection reaction is used as the base polymer, the PEB temperature is too low, suggesting difficulty to control the temperature uniformity or difficulty to control the acid diffusion. If the distance of acid diffusion cannot be controlled, the CDU or maximum resolution of patterns after development is degraded. An adequate PEB temperature is necessary for acid diffusion control, and most often the range of 80 to 100° C. is adequate.

Another problem arising from the use of a low-activation energy protective group is possible elimination of the protective group during polymerization in the case of a polymer with which a photoacid generator is to be copolymerized. Although the photoacid generator in the form of onium salt is basically neutral, the onium salt can be partially dissociated by the heat during polymerization. When a repeat unit having a phenolic hydroxy group is concurrently copolymerized, an exchange reaction takes place between the proton of the phenolic hydroxy group and the cation of the photoacid generator to generate an acid whereby deprotection of the protective group can occur. The deprotection during polymerization becomes outstanding particularly when a low-activation energy protective group is used.

As mentioned above, the acid labile group having carboxylic acid protected with a tertiary alcohol having an aryl group has the advantage of satisfactory etching resistance due to the benzene ring. When a photoacid generator is copolymerized, elimination of the protective group occurs during polymerization. When an electron attractive group is attached to a benzene ring, the activation energy for deprotection becomes high. It is believed that this is because the stability of a benzyl cation in a deprotection intermediate is lowered by the electron attractive group. It is possible to attach an electron attractive group to a protective group quite susceptible to deprotection to hold down the reactivity of deprotection reaction to an optimum level.

It is generally believed that fluorine atoms are highly absorptive to EUV of wavelength 13.5 nm and have a sensitizing effect of enhancing sensitivity. It is thus expected that sensitivity is enhanced by introducing fluorine into a protective group. However, when fluorine is introduced into an acid labile group of tertiary alkyl form, the stability of intermediate cation during deprotection reaction is largely reduced by the electron attractive effect of fluorine. As a result, creation of olefin does not occur and deprotection reaction does not occur. However, the tertiary acid labile group having a fluorinated aromatic group provides the intermediate cation with optimum stability and shows adequate reactivity for deprotection.

When repeat unit B is used as the base polymer in a chemically amplified negative resist composition for the purpose of controlling acid diffusion to improve the dissolution contrast and etching resistance, the chemically amplified negative resist composition shows a significantly high contrast of organic solvent developer dissolution rate before and after exposure, fully suppressed acid diffusion, a high resolution, satisfactory pattern profile and LWR after exposure, and high etching resistance.

The repeat units having a phenolic hydroxy group in polymer P, which are also referred to as repeat units C, hereinafter, are represented by the following formula (C).

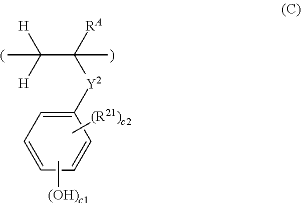

In formula (C), R^{A} is a hydrogen atom, a fluorine atom, a methyl group, or a trifluoromethyl group. Y² is a single bond or *—C(═O)—O—, the asterisk (*) designates a point of attachment to the carbon atom in the backbone, R²¹ is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, c1 is an integer of 1 to 4, and c2 is an integer of 0 to 4, provided that the sum of c1+c2 is 1 to 5.

The hydrocarbyl group and hydrocarbyl moiety of the hydrocarbyloxy, hydrocarbylcarbonyl, hydrocarbylcarbonyloxy and hydrocarbyloxycarbonyl groups, represented by R²¹, may be saturated or unsaturated and straight, branched or cyclic. Examples of the hydrocarbyl group are as exemplified above as a hydrocarbyl group R¹ and R² in formula (A1).

Examples of the repeat unit C are shown below, but not limited thereto. Herein, R^{A} is as defined above.

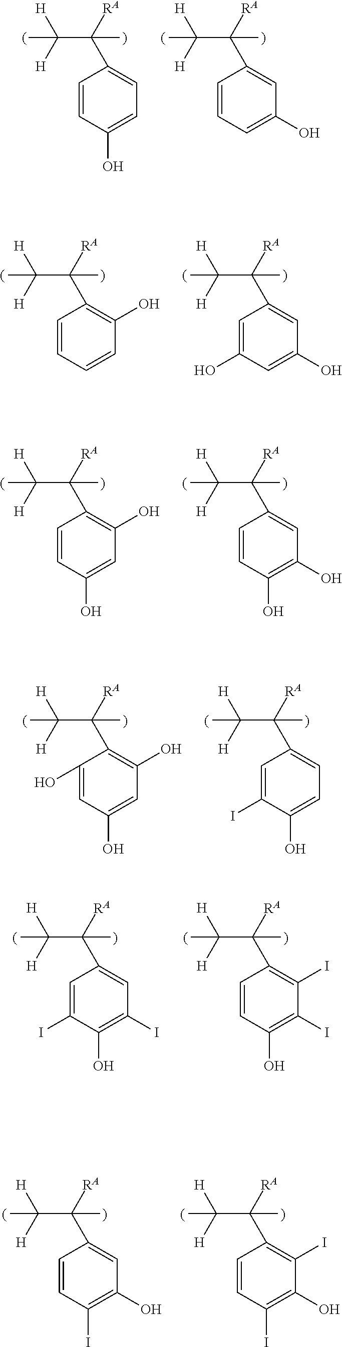

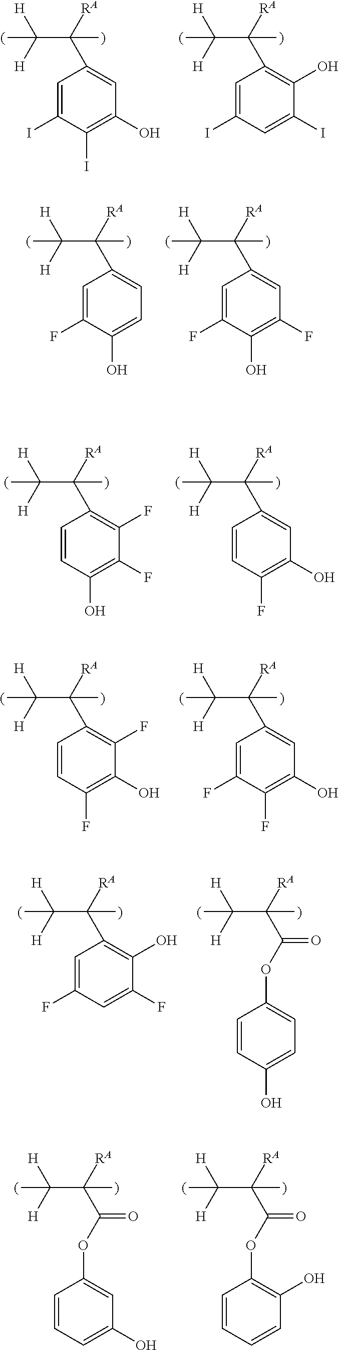

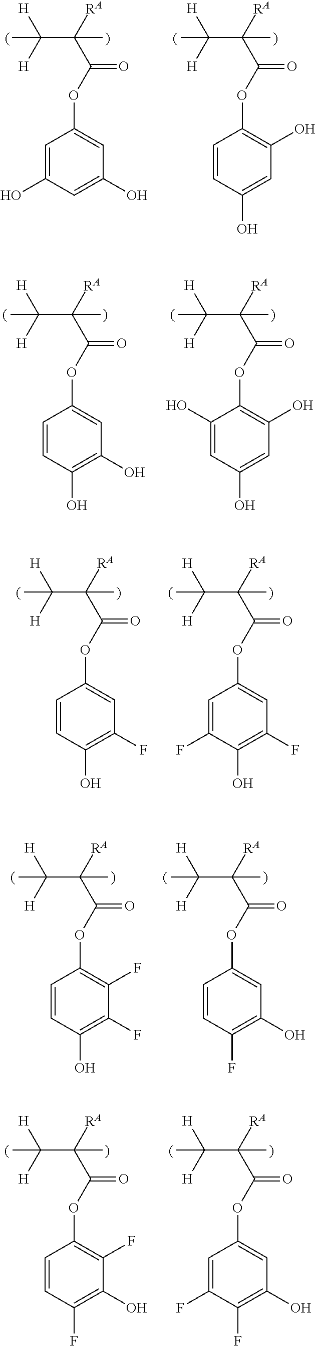

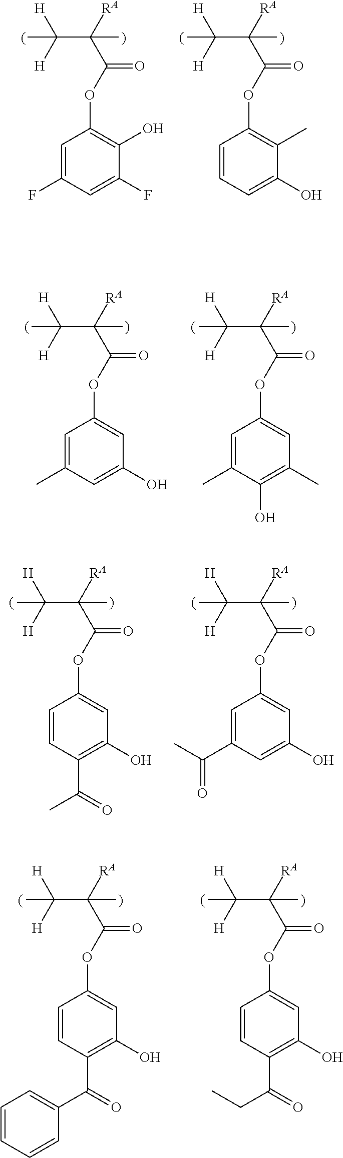

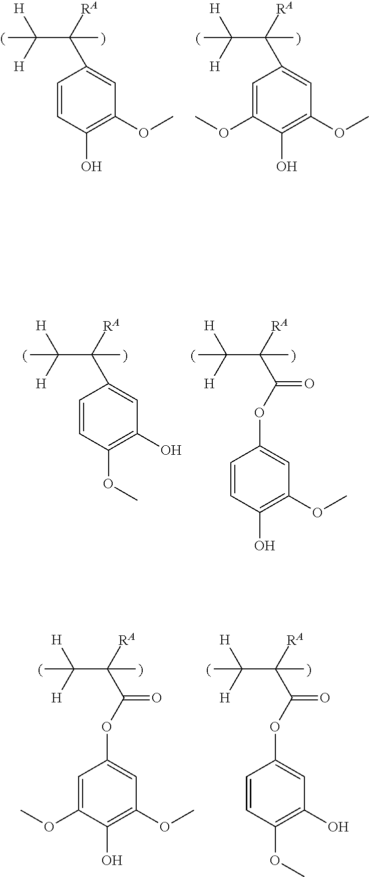

The polymer P may further comprise repeat units of at least one type selected from repeat units having the formula (a1) and repeat units having the formula (a2). These units are also referred to as repeat units (a1) and (a2), respectively.

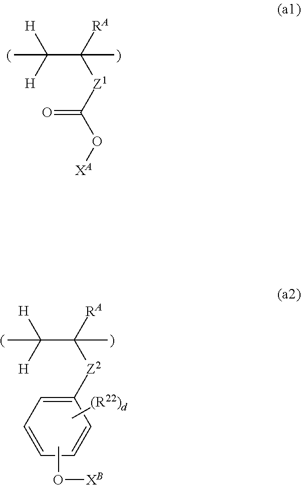

In formulae (a1) and (a2), R^{A} is hydrogen, fluorine, methyl, or trifluoromethyl. Z¹ is a single bond, a phenylene group, a naphthylene group or *—C(═O)—O—Z¹¹—. Z¹¹ is a C₁-C₂₀ saturated hydrocarbylene group, a phenylene group, or a naphthylene group, and the saturated hydrocarbylene group may contain at least one selected from a hydroxy group, an ether bond, an ester bond or a lactone ring. Z² is a single bond or *—C(═O)—O—. the asterisk (*) designates a point of attachment to the carbon atom in the backbone, R²² is a C₁-C₂₀ hydrocarbylene group which may contain a heteroatom. X^{A} and X^{B} are each independently an acid labile group free of an aromatic ring. d is an integer of 0 to 4.

Examples of the acid labile group represented by X^{A} and X^{B} in formulae (a1) and (a2) are as shown in JP-A 2013-80033 and JP-A 2013-83821.

Typical of the acid labile group are groups having the following formulae (AL-1) to (AL-3).

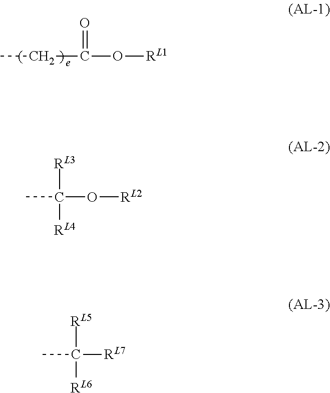

Herein the broken line denotes a valence bond.

In formulae (AL-1) and (AL-2), R^{L1} and R^{L2} are each independently a C₁-C₄₀ hydrocarbyl group, which may contain a heteroatom such as an oxygen atom, a sulfur atom, a nitrogen atom or a fluorine atom. The saturated hydrocarbyl group may be straight, branched or cyclic. The saturated hydrocarbyl group is preferably a C₁-C₂₀ hydrocarbyl group.

In formula (AL-1), e is an integer of 0 to 10, preferably an integer of 1 to 5.

In formulae (AL-2), R^{L3} and R^{L4} are each independently a hydrogen atom, a C₁-C₂₀ saturated hydrocarbyl group, and may contain a heteroatom such as an oxygen atom, a sulfur atom, a nitrogen atom or a fluorine atom. The hydrocarbyl group may be straight, branched or cyclic. Any two of R^{L2}, R^{L3} and R^{L4} may bond together to form a C₃-C₂₀ ring with a carbon atom to which they are attached, or a carbon atom or an oxygen atom. The ring is preferably a C₄-C₁₆ ring particularly preferably in an alicyclic form.

In formula (AL-3), R^{L5}, R^{L6} and R^{L7} are each independently a C₁-C₂₀ saturated hydrocarbyl group, and may contain a heteroatom such as an oxygen atom, a sulfur atom, a nitrogen atom or a fluorine atom. The saturated hydrocarbyl group may be straight, branched or cyclic. Any two of R^{L5}, R^{L6} and R^{L7} may bond together to form a C₃-C₂₀ ring with a carbon atom to which they are attached. The ring is preferably a C₄-C₁₆ ring particularly preferably in an alicyclic form.

Examples of repeat unit a1 are shown below, but not limited thereto. Herein, R^{A} and X^{A} are as defined above.

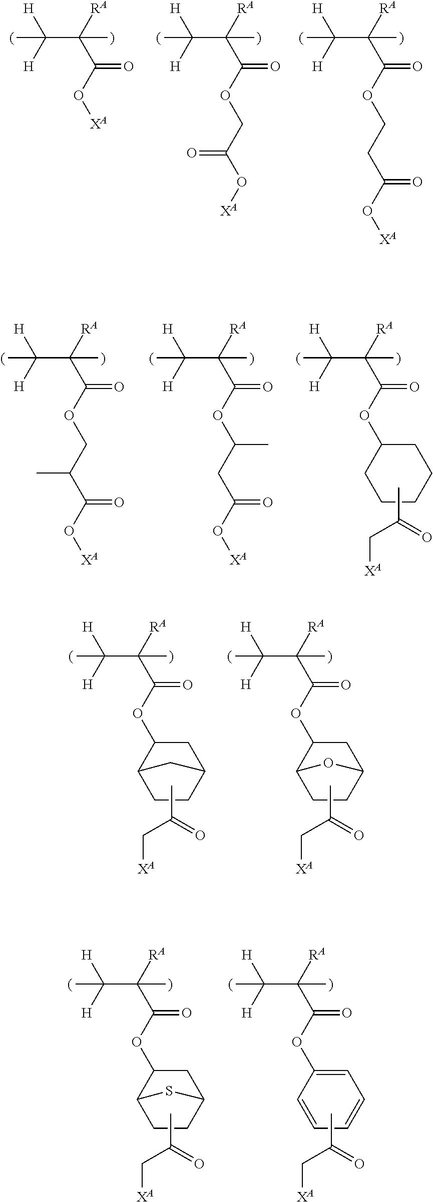

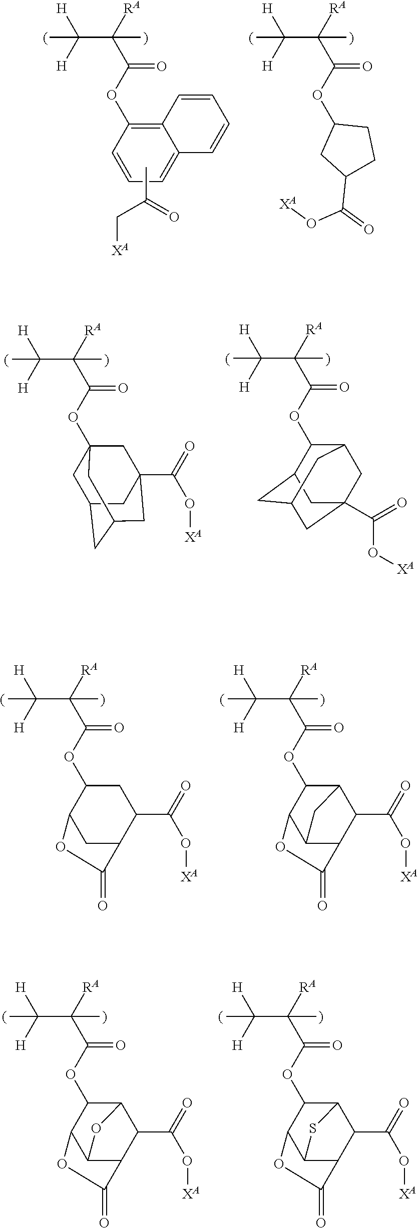

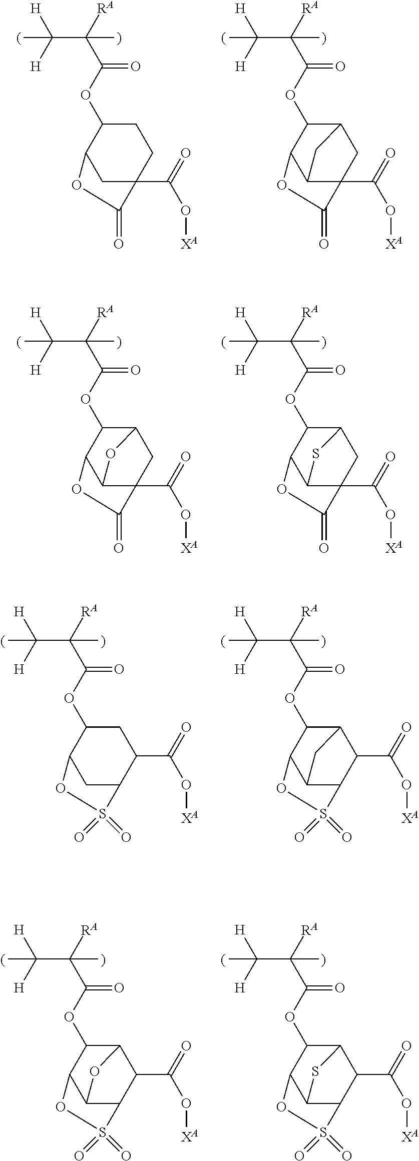

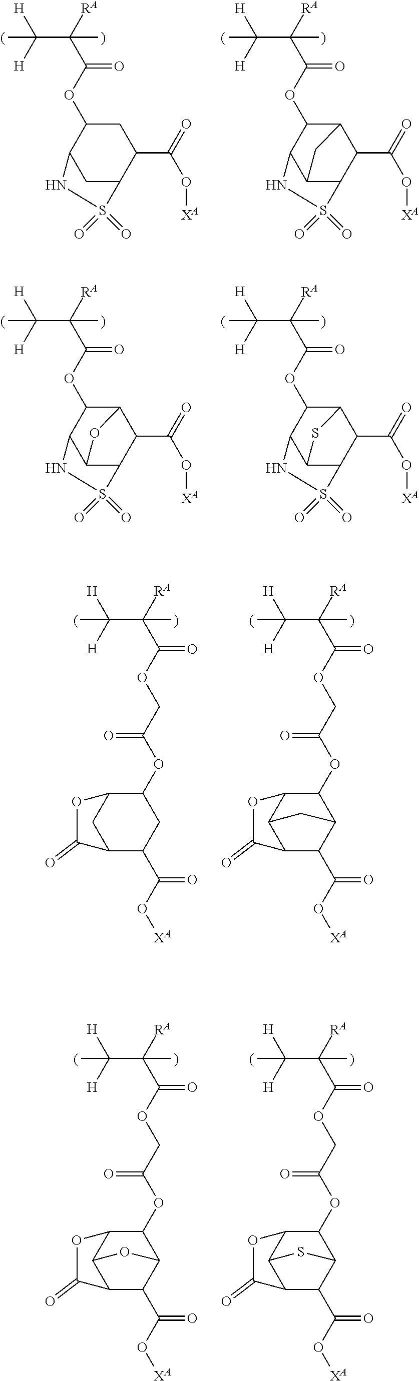

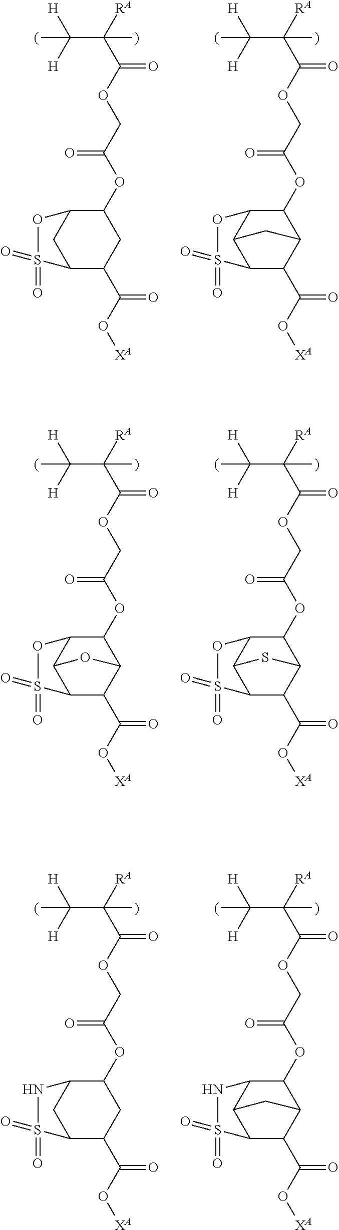

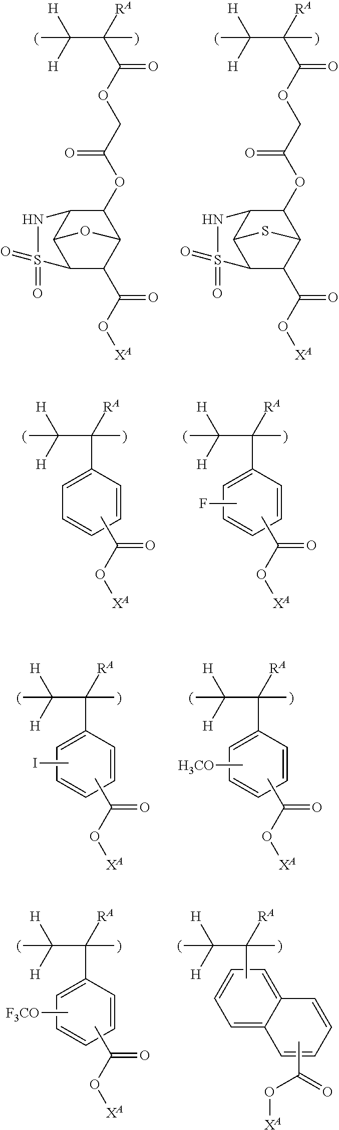

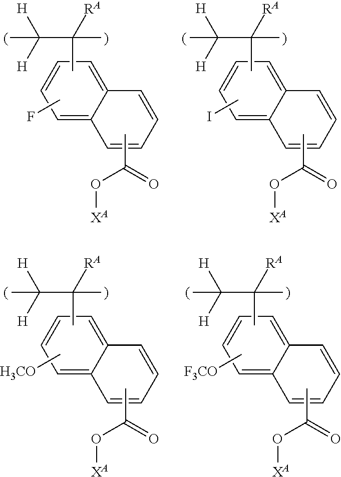

Examples of repeat unit a2 are shown below, but not limited thereto. Herein, R^{A} and X^{B} are as defined above.

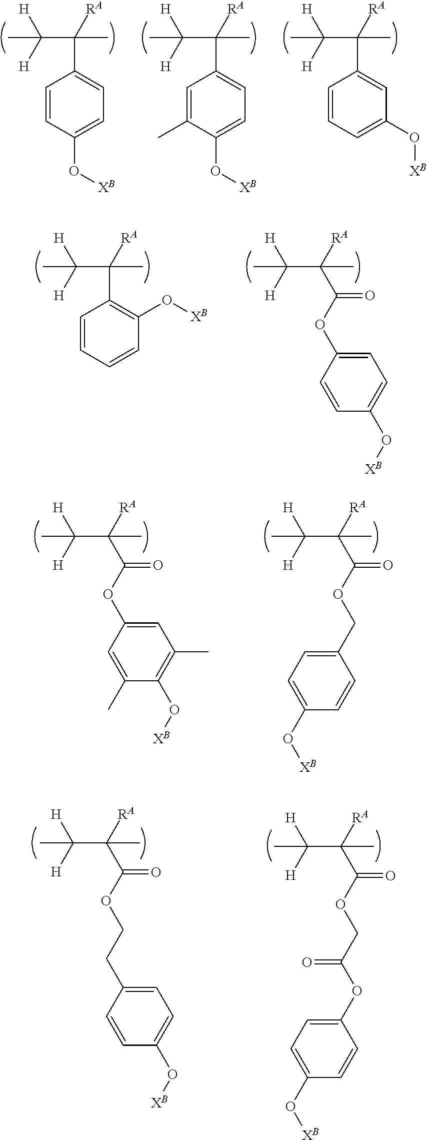

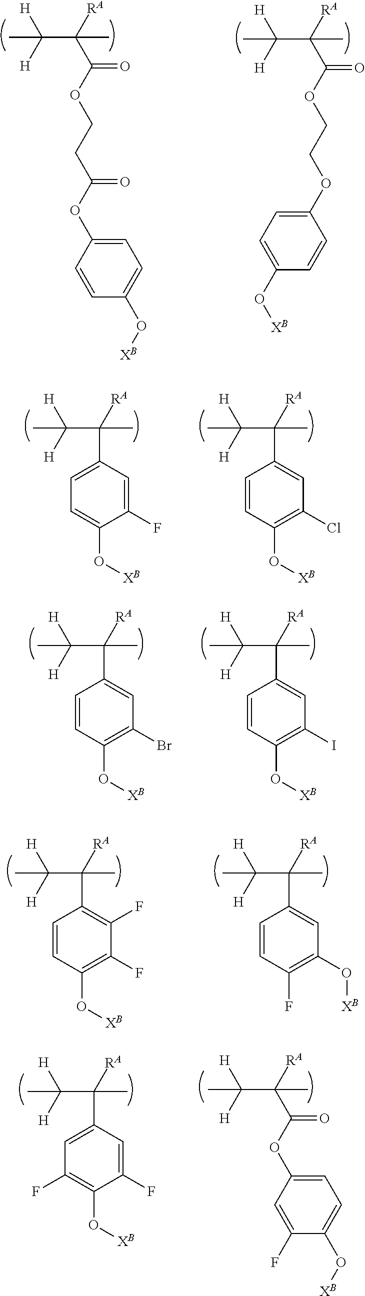

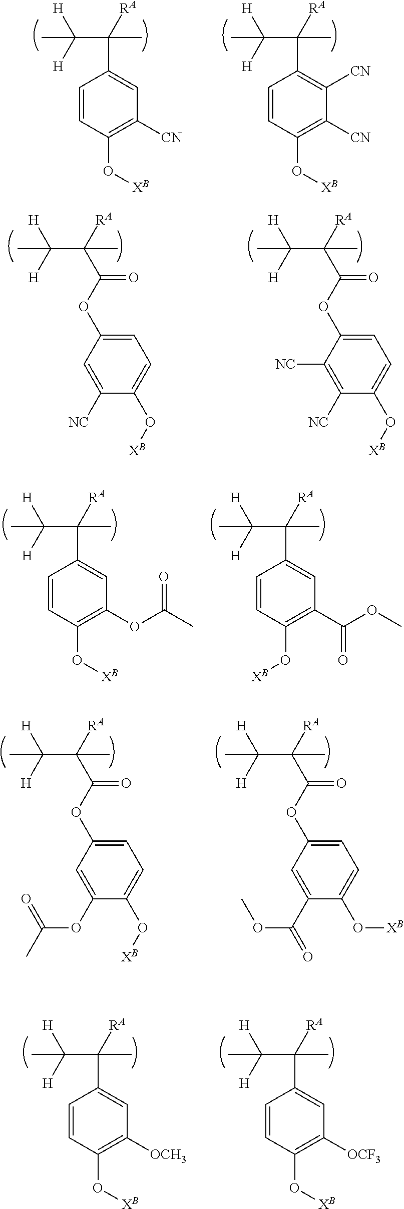

Polymer P may further comprise repeat units represented by the following formula (D), which are also referred to as repeat units D, hereinafter.

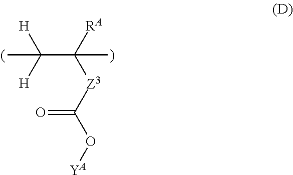

In formula (D1), R^{A} is a hydrogen atom, a fluorine atom, a methyl group, or a trifluoromethyl group. Z³ is a single bond, a phenylene group, a naphthylene group or *—C(═O)—O—Z³¹—. Z³¹ is a C₁-C₂₀ saturated hydrocarbylene group, a phenylene group, or a naphthylene group, and the saturated hydrocarbylene group may contain at least one selected from a hydroxy group, an ether bond, an ester bond or a lactone ring. the asterisk (*) designates a point of attachment to the carbon atom in the backbone, Y^{A} is a hydrogen atom, or a C₁-C₂₀ group containing at least one structure selected from a hydroxy group, a cyano group, a carbonyl group, a carboxy group, an ether bond, an ester bond, a sulfonic ester bond, a carbonate bond, a lactone ring, a sultone ring, and a carboxylic anhydride (—C(═O)—O—C(═O)—).

Examples of the repeat unit D are shown below, but not limited thereto. Herein, R^{A} is as defined above.

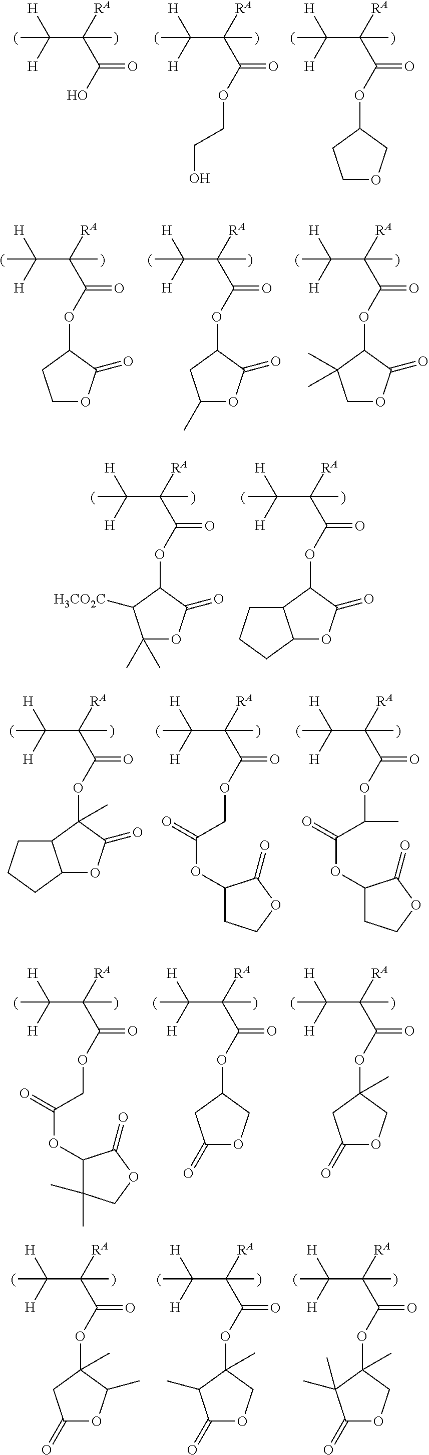

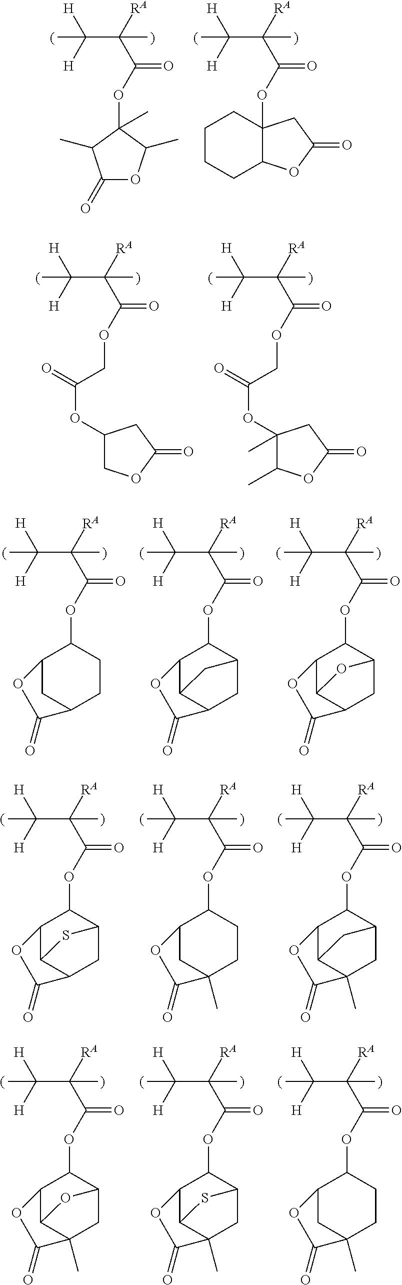

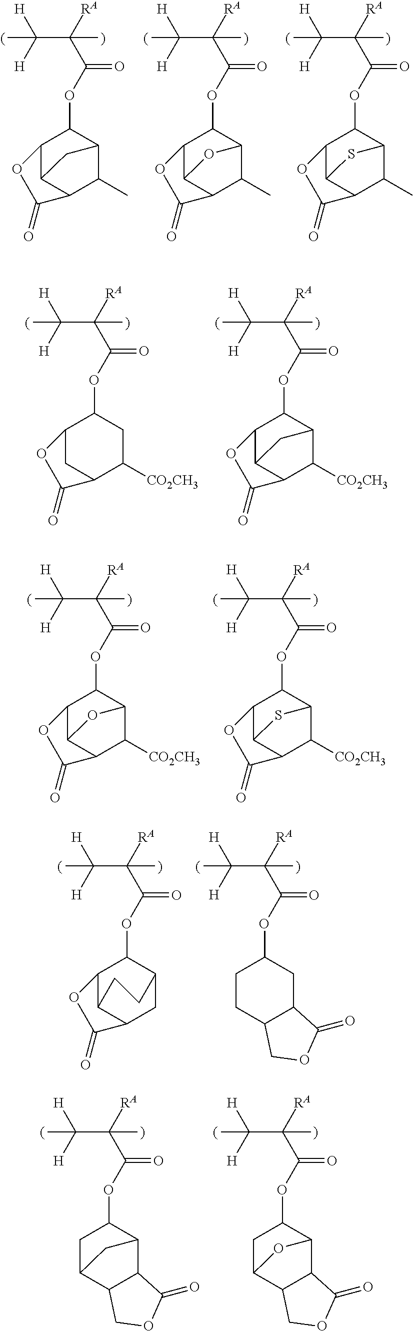

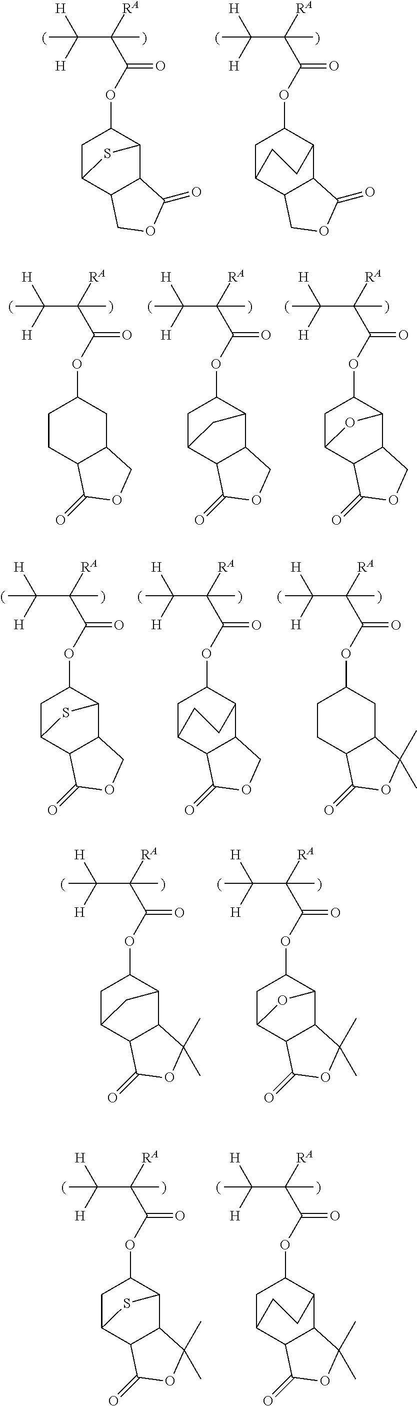

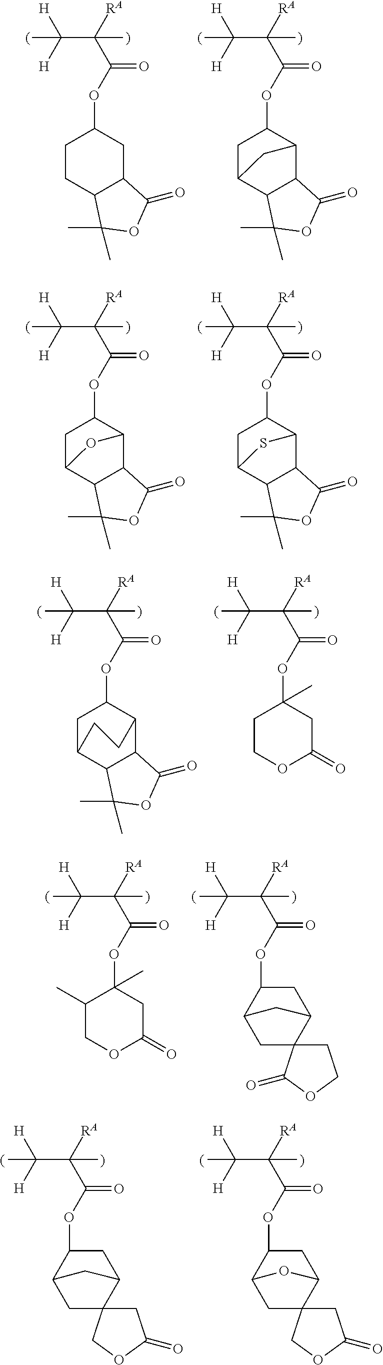

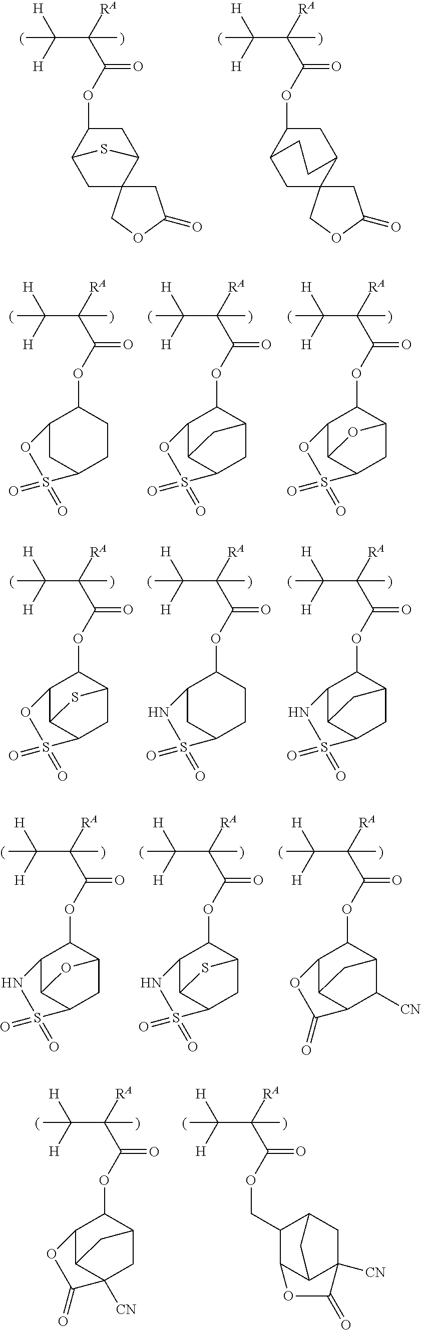

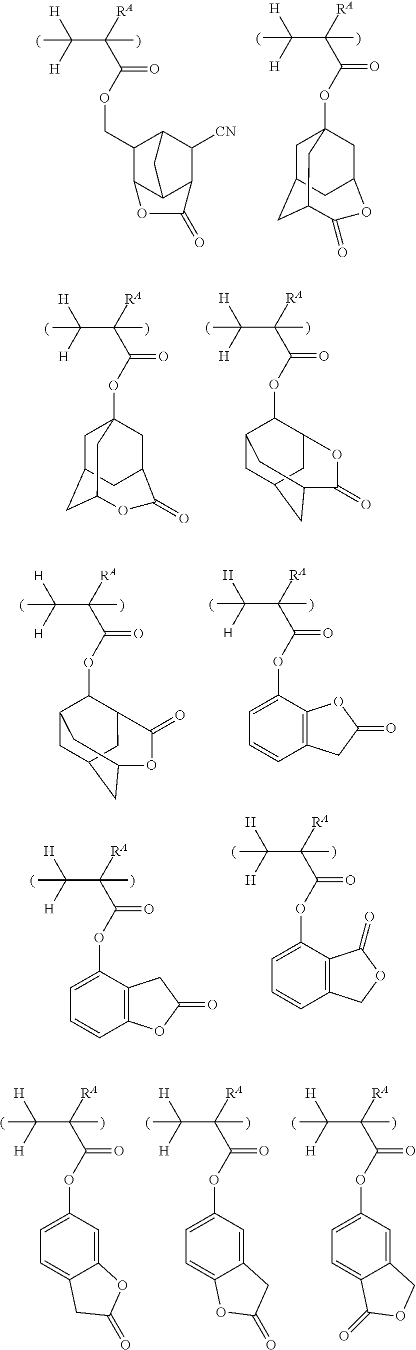

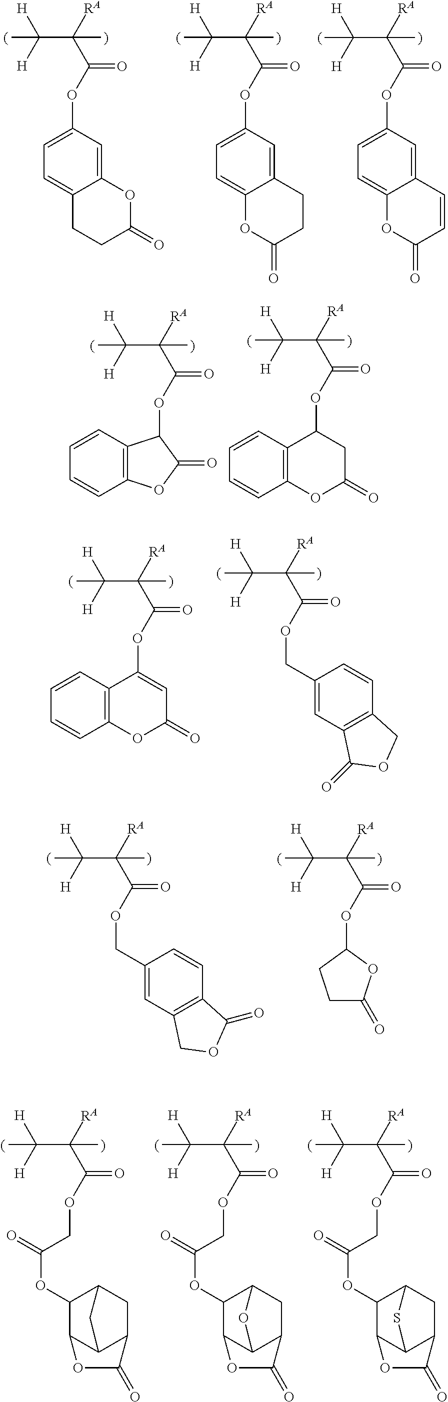

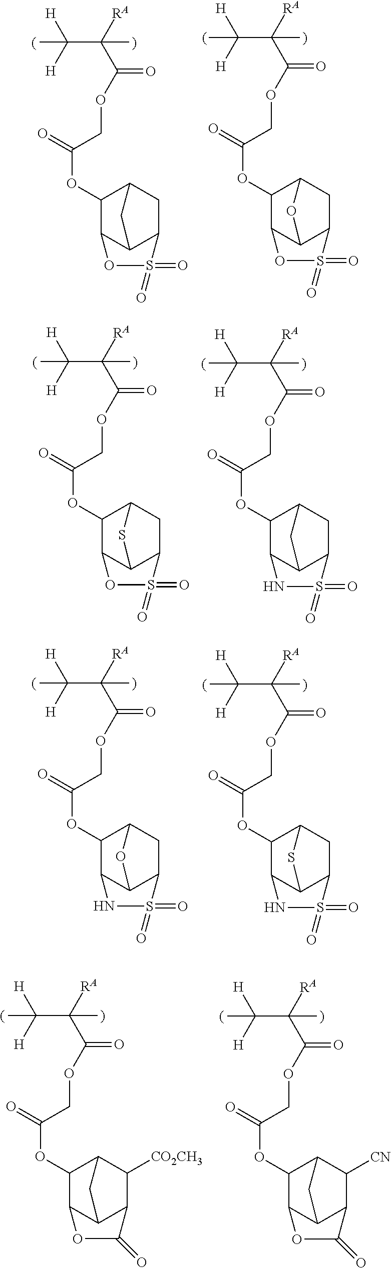

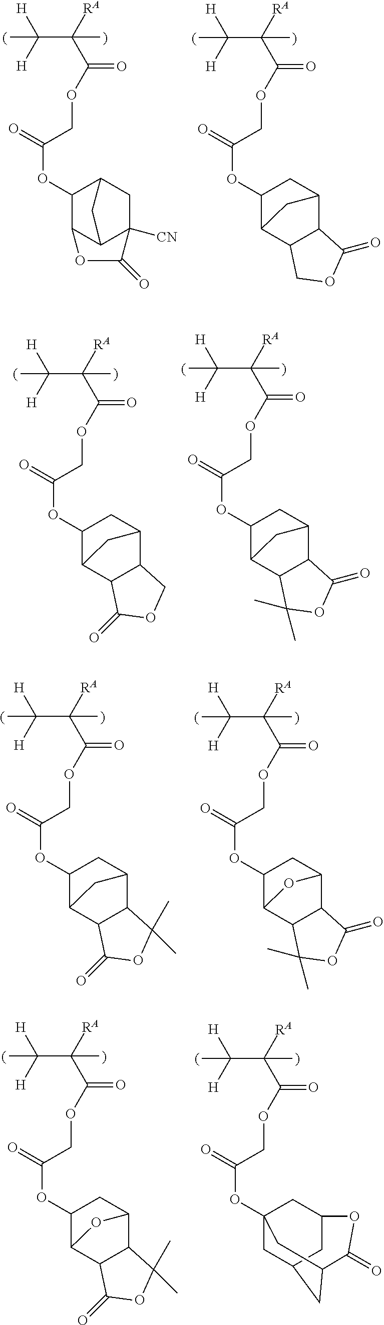

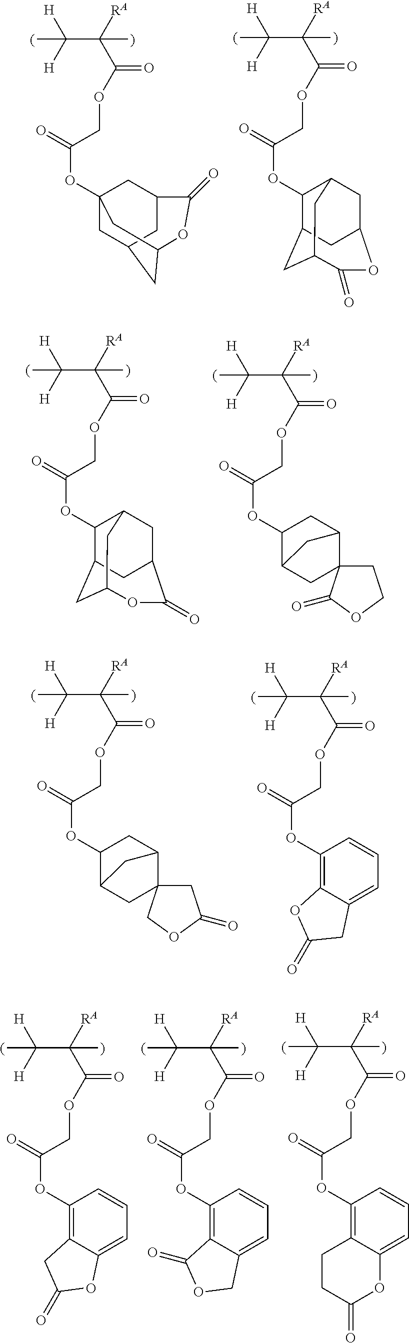

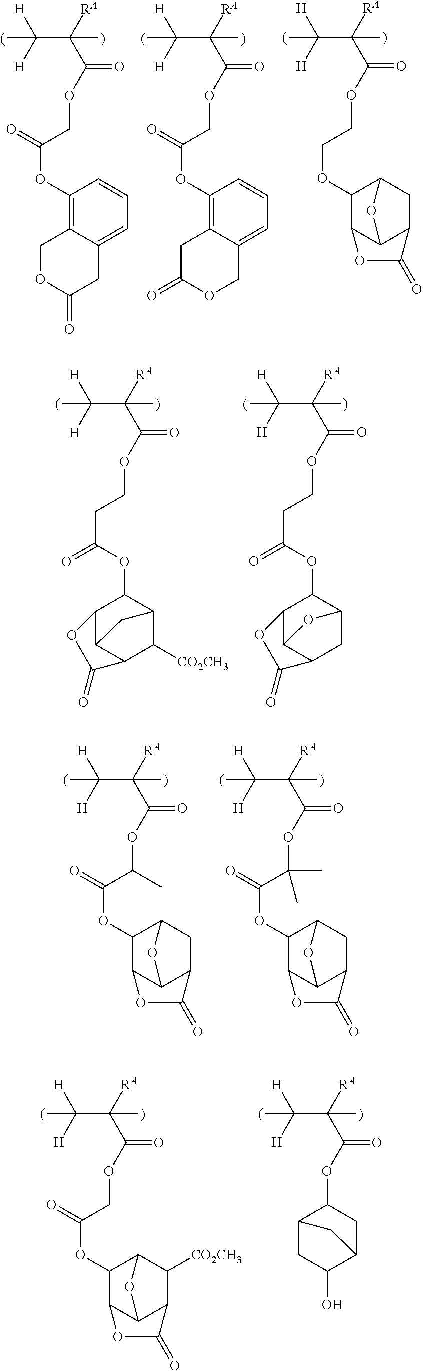

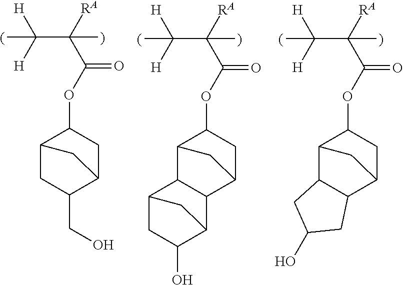

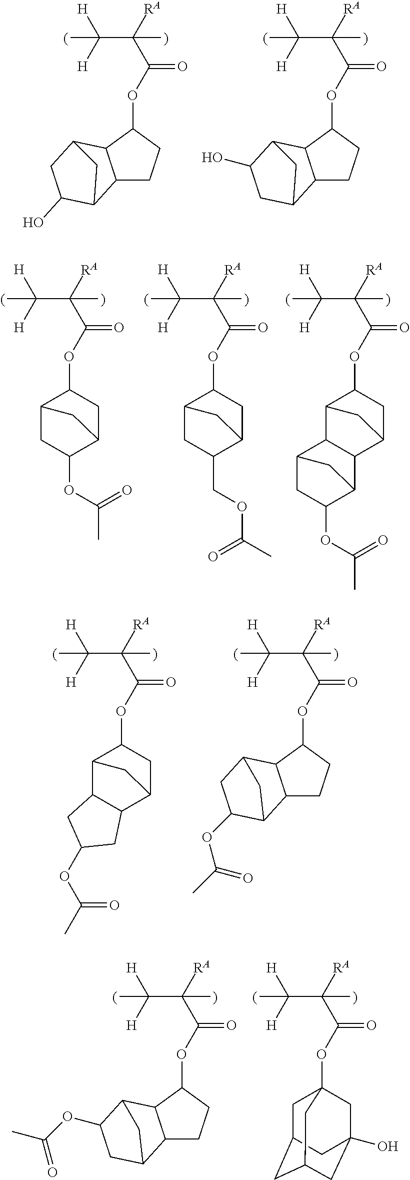

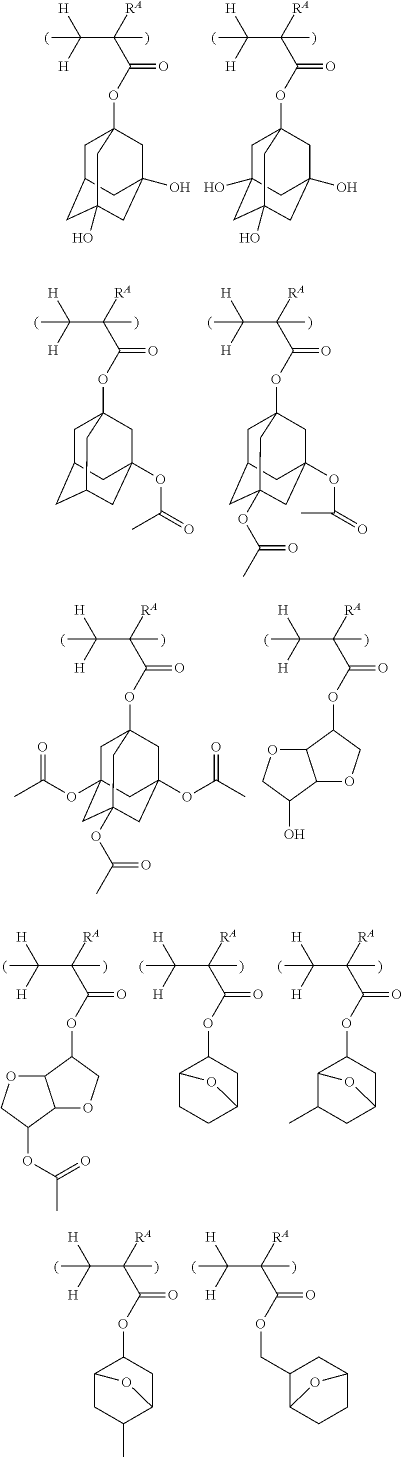

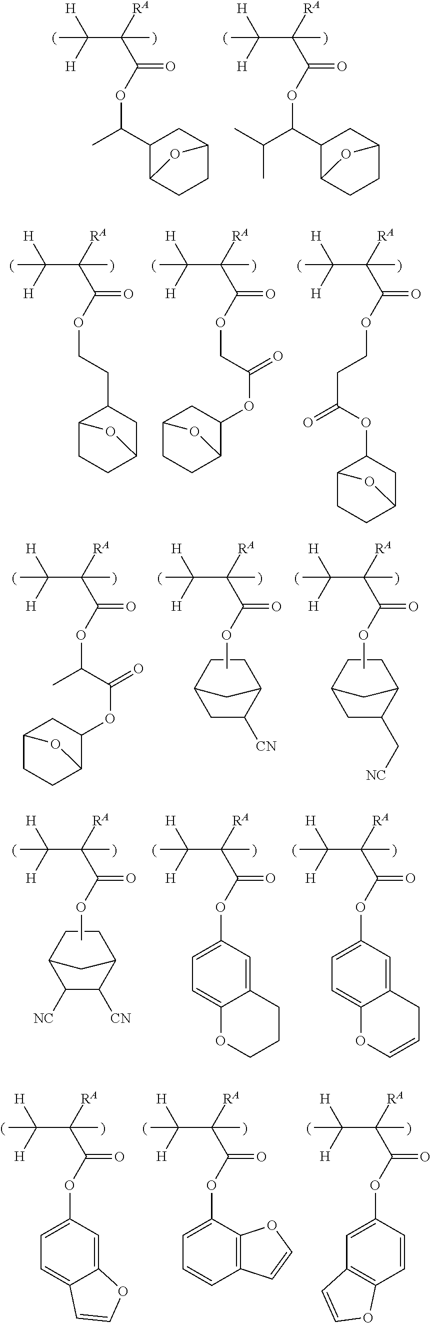

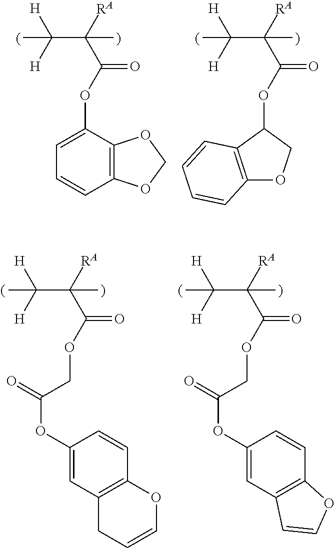

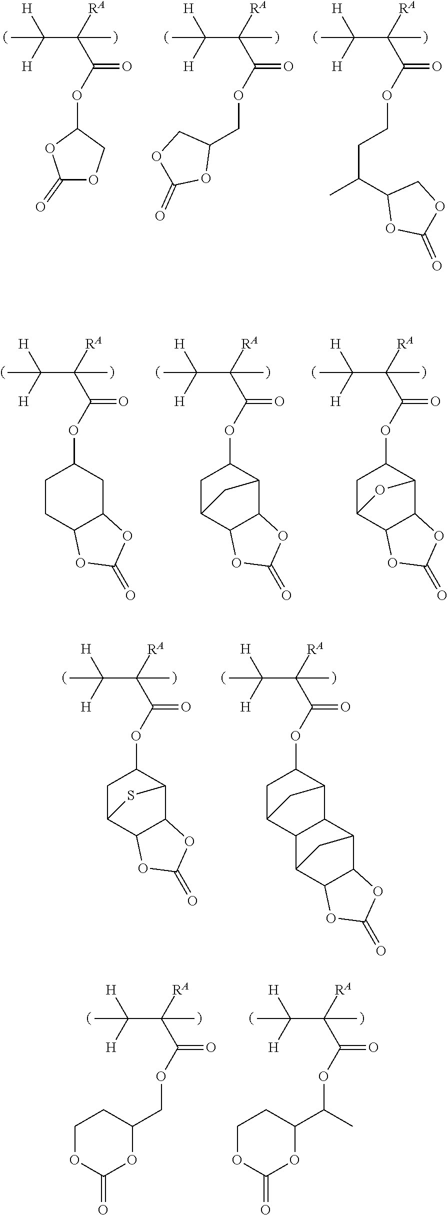

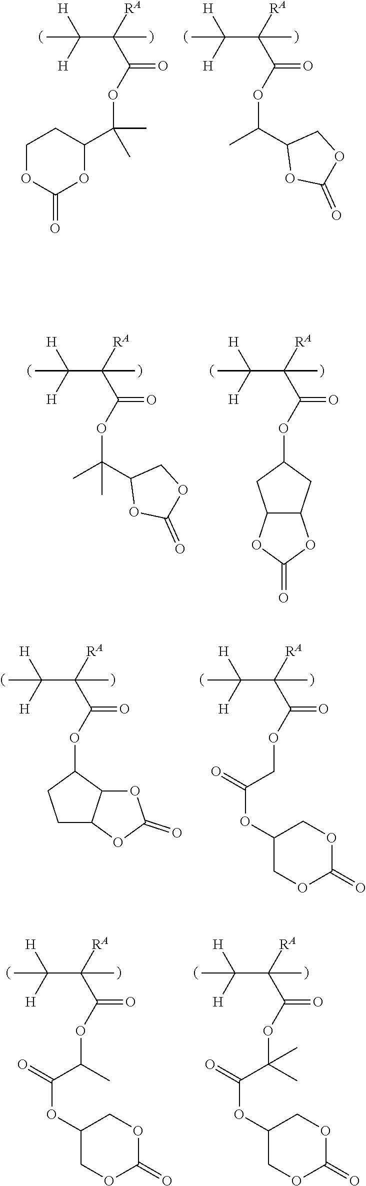

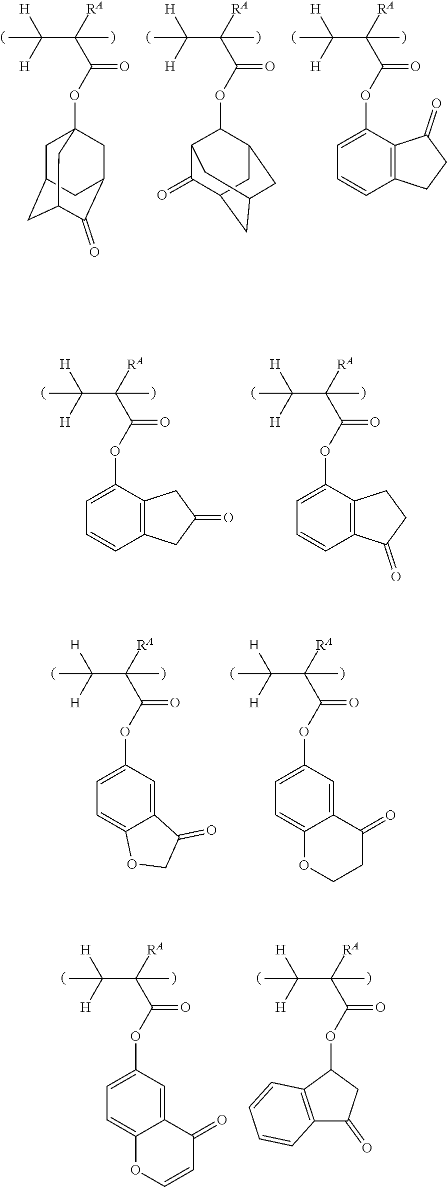

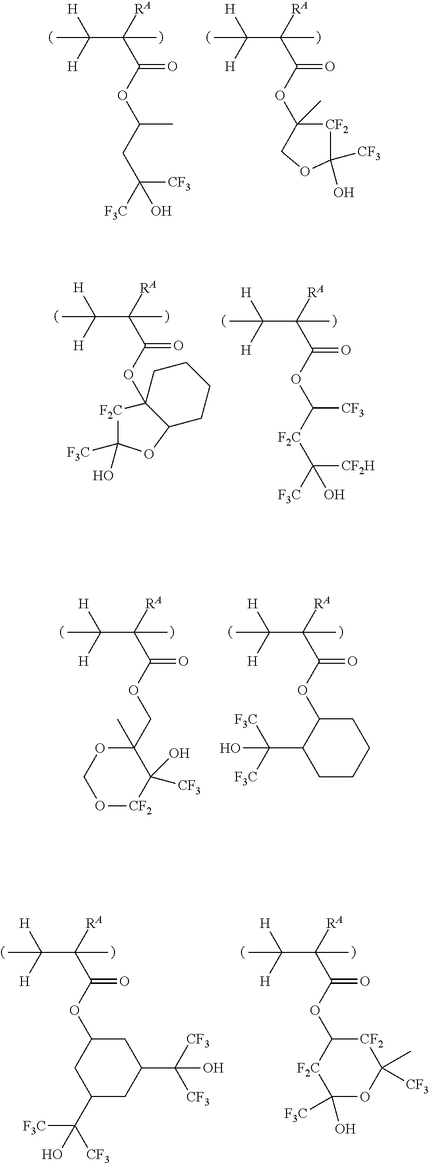

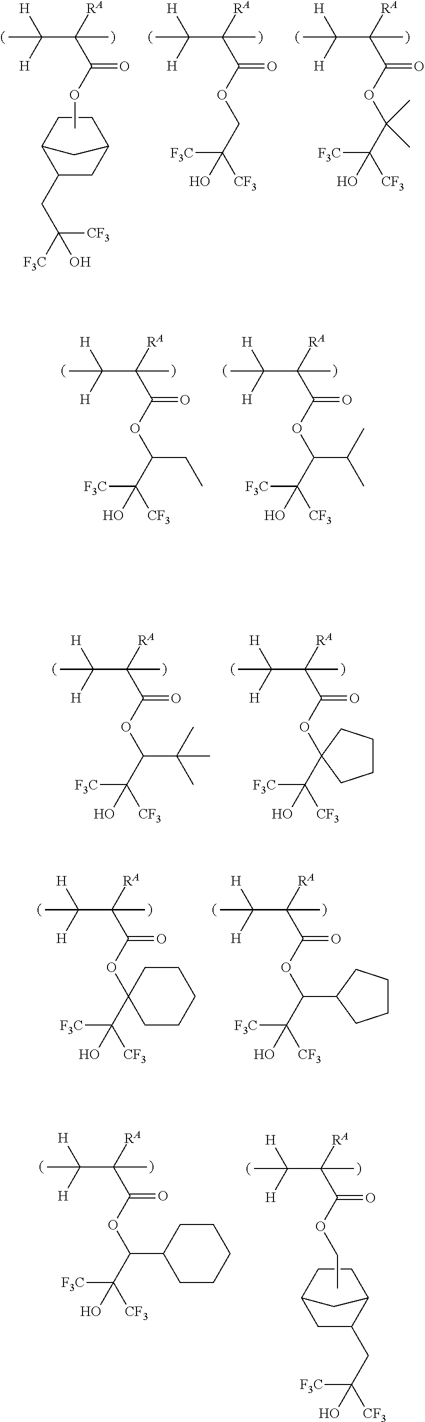

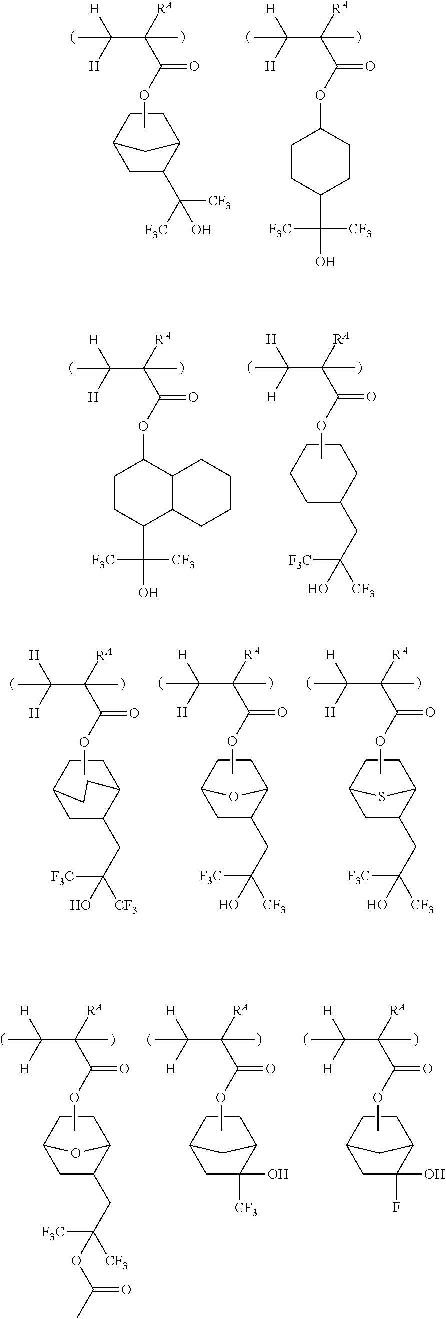

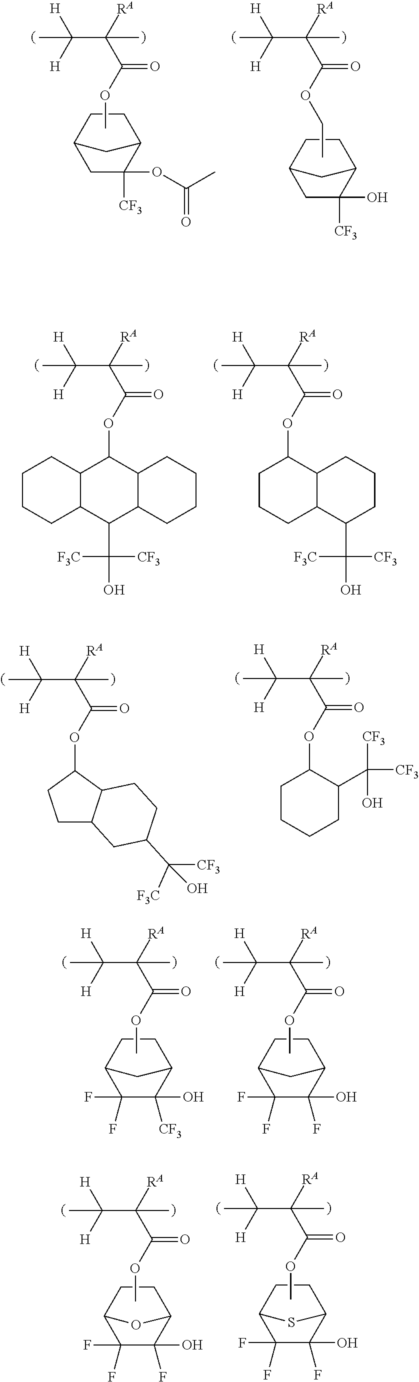

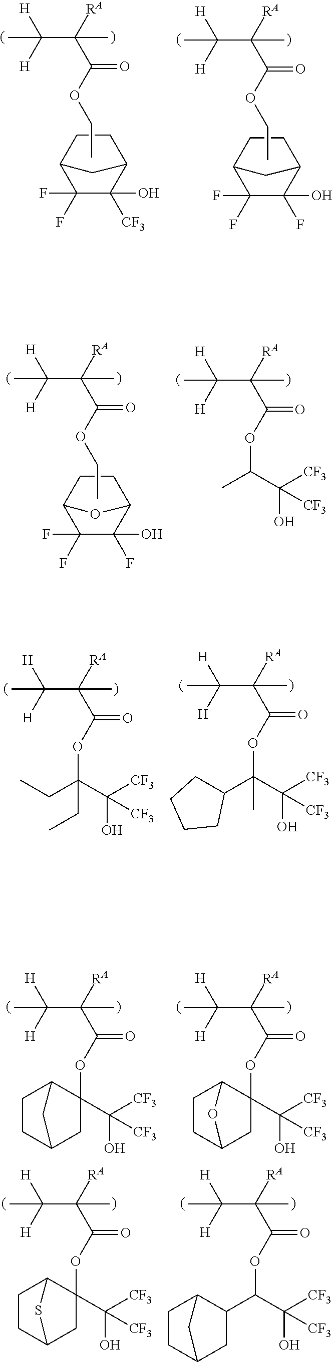

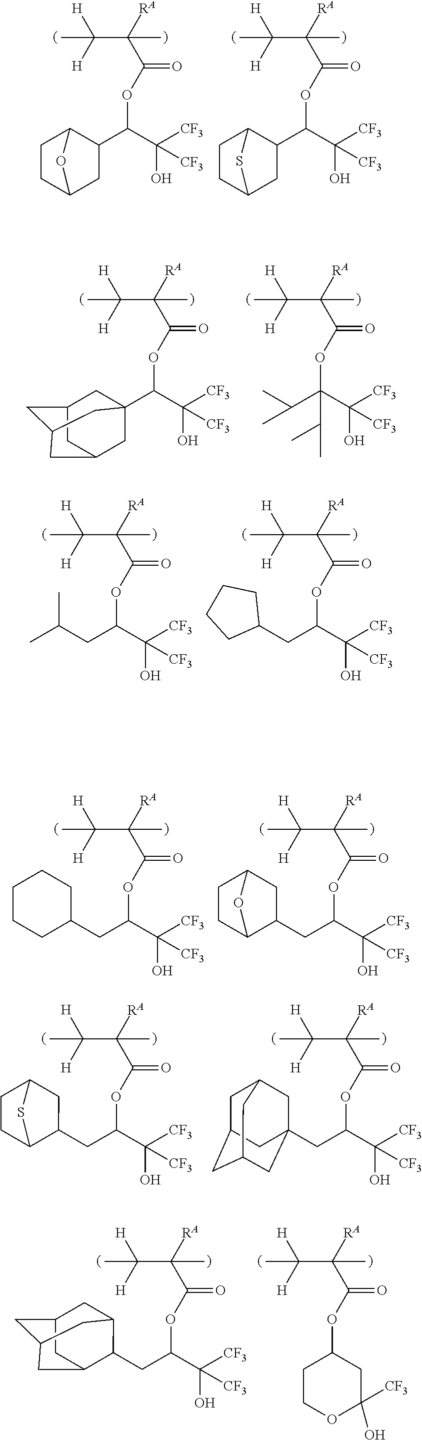

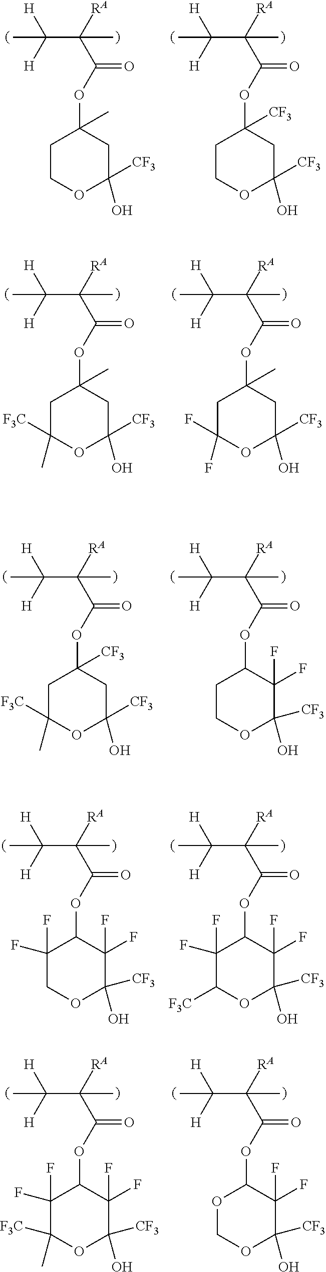

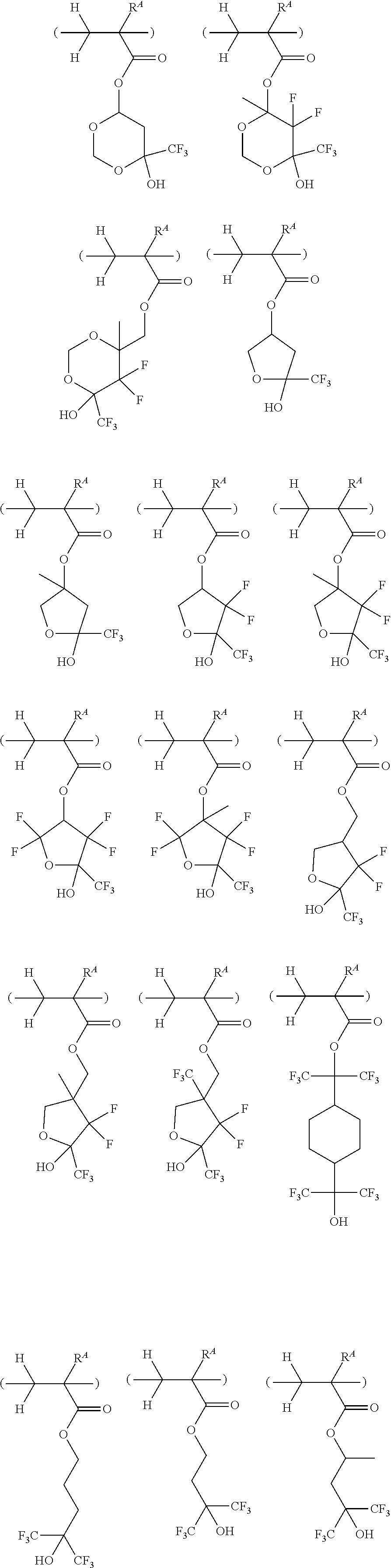

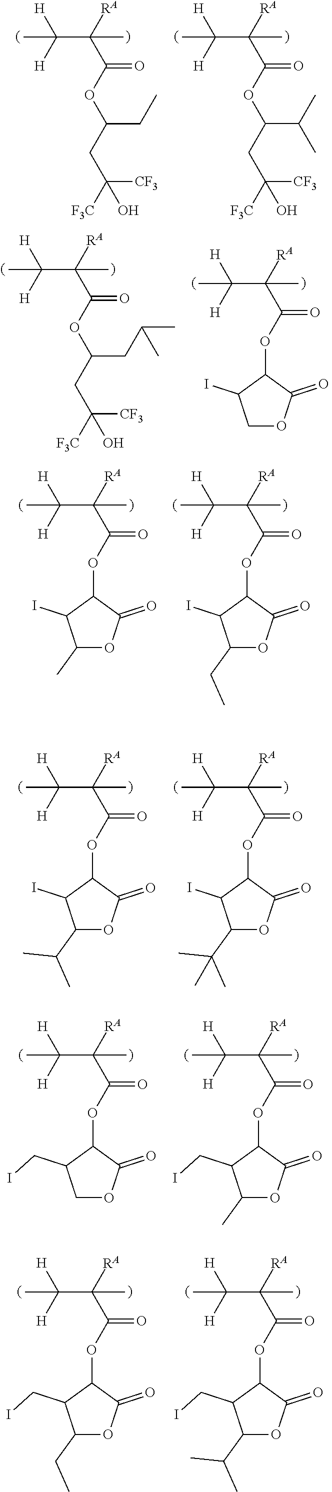

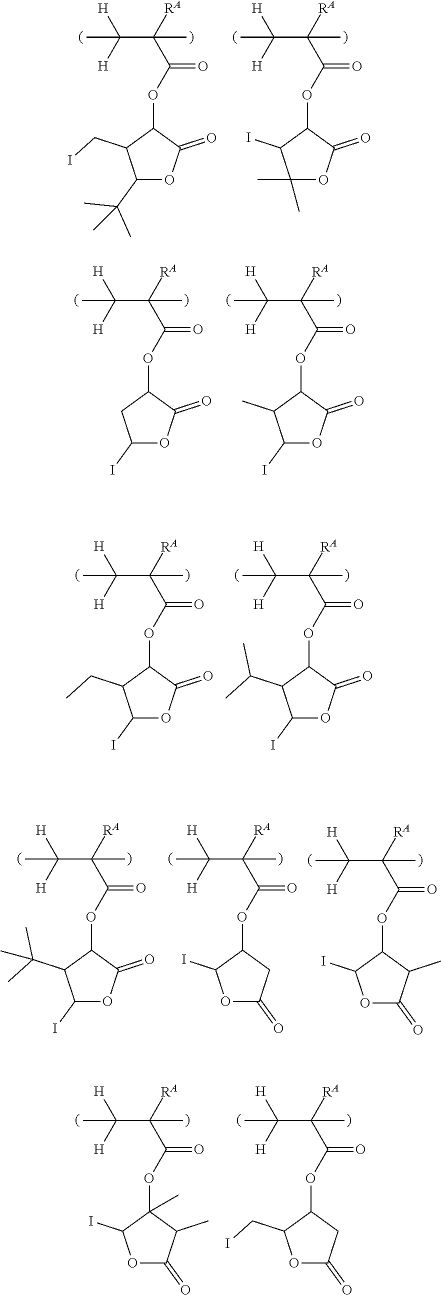

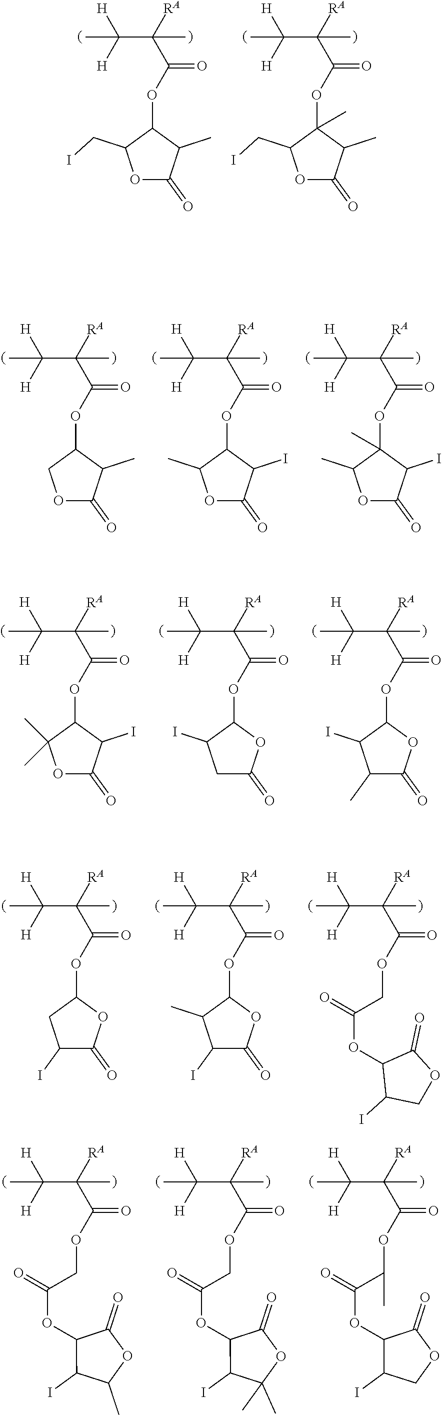

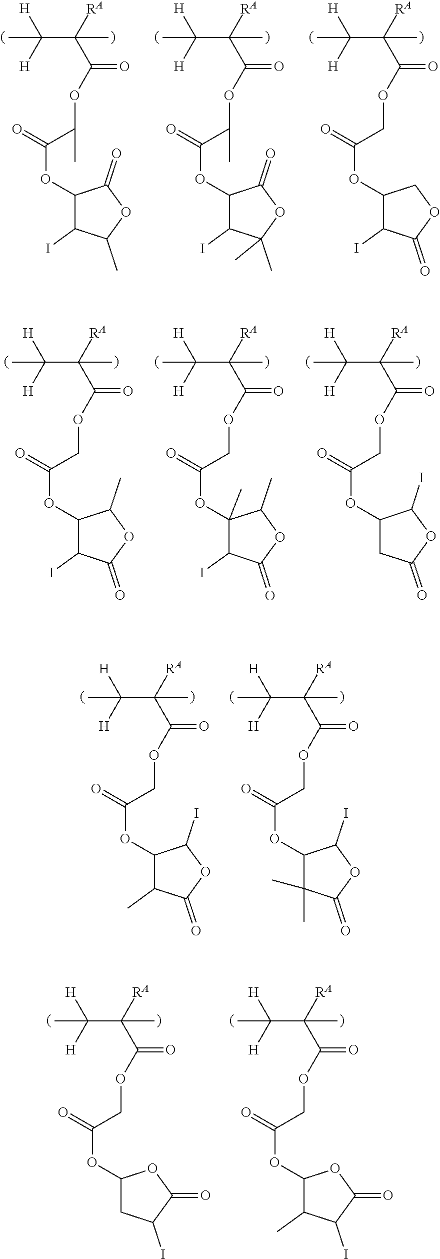

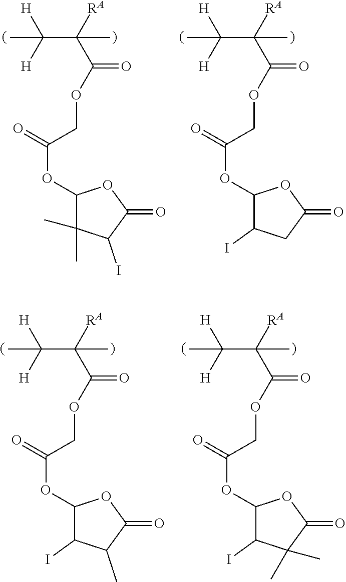

Polymer P may further comprise repeat units E derived from indene, benzofuran, benzothiophene, acenaphthylene, chromone, coumarin, and norbornadiene, or derivatives thereof. Examples of the monomer from which repeat units E are derived are shown below, but not limited thereto.

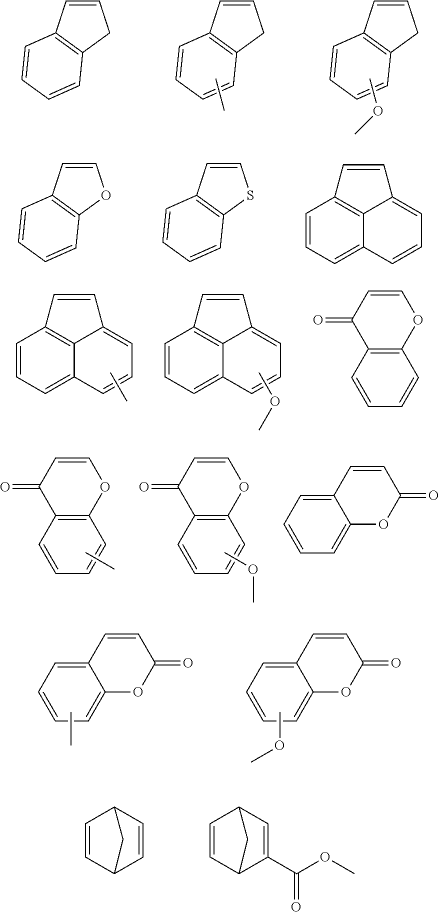

Polymer P may comprise repeat units F derived from indane, vinylpyridine or vinylcarbazole.

While polymer P comprises repeat units A1, A2, A3, A4, a1, a2, B, C, D, E, and F, a fraction of units is: preferably

0≤A1<1.0, 0≤A2<1.0, 0≤A3<1.0, 0≤A4<1.0, 0<A1+A2+A3+A4<1.0, 0≤a1≤0.8, 0≤a2≤0.8, 0<B<1.0, 0<C<1.0, 0≤D≤0.8, 0≤E≤0.8 and 0≤F≤0.4; more preferably 0.05≤A1≤0.9, 0.05≤A2≤0.9, 0.05≤A3≤0.9, 0.05≤A4≤0.9, 0.05≤A1+A2+A3+A4≤0.9, 0≤a1≤0.7, 0≤a2≤0.7, 0≤a1+a2≤0.7, 0.09≤B≤0.7, 0.01≤C≤0.4, 0≤D≤0.7, 0≤E≤0.7 and 0≤F≤0.3; even more preferably 0.1≤A1≤0.8, 0.1≤A2≤0.8, 0.1≤A3≤0.8, 0.1≤A4≤0.8, 0.1≤A1+A2+A3+A4≤0.8, 0≤a1≤0.6, 0≤a2≤0.6, 0≤a1+a2≤0.4, 0.1≤B≤0.6, 0.1≤C≤0.45, 0≤D≤0.6, 0≤E≤0.6 and 0≤F≤0.2. Notably, A1+A2+A3+A4+a1+a2+B+C+D+E+F=1.

Polymer P should preferably have a weight average molecular weight (Mw) in the range of 1,000 to 500,000, and more preferably 3,000 to 100,000. A Mw in the range ensures satisfactory etch resistance and eliminates the risk of resolution being lowered due to a failure to acquire a difference in dissolution rate before and after exposure. In the invention, Mw is a value measured by gel permeation chromatography (GPC) with THF or N,N-dimethylformamide (DMF) as a solvent, and calculated as polystyrene.

If polymer P has a wide molecular weight distribution or dispersity (Mw/Mn), which indicates the presence of lower and higher molecular weight polymer fractions, there is a possibility that foreign matter is left on the pattern or the pattern profile is degraded. The influence of Mw/Mn becomes stronger as the pattern rule becomes finer. Therefore, the polymer should preferably have a narrow dispersity (Mw/Mn) of 1.0 to 2.0 in order to provide a resist composition suitable for micropatterning to a small feature size.

Polymer P may be synthesized by any desired methods, for example, by dissolving monomers corresponding to the foregoing repeat units in an organic solvent, adding a radical polymerization initiator thereto, and heating for polymerization.

Examples of the organic solvent which can be used for polymerization include toluene, benzene, tetrahydrofuran THF, diethyl ether, dioxane, cyclohexane, cyclopentane, methyl ethyl ketone (MEK), propylene glycol monomethyl ether acetate (PGMEA), and γ-butyrolactone (GBL). Examples of the polymerization initiator used herein include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the initiator added is preferably 0.01 to 25 mol % based on the total of monomers. The reaction temperature is preferably 50 to 150° C., more preferably 60 to 100° C. The reaction time is preferably 2 to 24 hours, a time of 2 to 12 hours being more preferred in view of production efficiency.

The polymerization initiator may be added to the monomer solution, which is fed to the reactor. Alternatively, a solution of the polymerization initiator is prepared separately from the monomer solution, and the monomer and initiator solutions be independently fed to the reactor. Since there is a possibility that the initiator generates a radical in the standby time, by which polymerization reaction takes place to form an ultrahigh molecular weight compound, it is preferred from the standpoint of quality control that the monomer solution and the initiator solution be independently prepared and added dropwise. The acid labile group that has been incorporated in the monomer may be kept as such, or the polymerization may be followed by protection or partial protection. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, one method is by dissolving hydroxystyrene or hydroxyvinylnaphthalene and other monomers in an organic solvent, adding a radical polymerization initiator thereto, and heating the solution for polymerization. In an alternative method, acetoxystyrene or acetoxyvinylnaphthalene is used instead, and after polymerization, the acetoxy group is deprotected by alkaline hydrolysis, for thereby converting the polymer product to polyhydroxystyrene or polyhydroxyvinylnaphthalene.

For alkaline hydrolysis, a base such as aqueous ammonia or triethylamine may be used. Preferably the reaction temperature is −20° C. to 100° C., more preferably 0° C. to 60° C. The reaction time is 0.2 to 100 hours, more preferably 0.5 to 20 hours.

The amounts of monomers in the monomer solution may be determined appropriate so as to provide the preferred fractions of repeat units as mentioned above.

The reaction solution resulting from polymerization reaction may be used as the final product. Alternatively, the polymer may be recovered in powder form through a purifying step such as re-precipitation step of adding the reaction solution to a poor solvent and letting the polymer precipitate as powder, after which the polymer powder is used as the final product. It is preferred from the standpoints of operation efficiency and consistent quality to handle a polymer solution which is obtained by dissolving the powder polymer resulting from the purifying step in a solvent, as the final product. The solvents which can be used herein are described in JP-A 2008-111103, paragraphs [0144]-[0145]. Exemplary solvents include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; ketoalcohols such as diacetone alcohol (DAA); and high-boiling alcohols such as diethylene glycol, propylene glycol, glycerol, 1,4-butanediol, and 1,3-butanediol, which may be used alone or in admixture.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign matter and gel which can cause defects are removed.

Suitable materials of which the filter is made include fluorocarbon, cellulose, nylon, polyester, and hydrocarbon base materials. Preferred for the filtration of an amplified resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 nm, more preferably up to 20 nm. A single filter may be used or a plurality of filters may be used in combination. Although the filtering method may be single pass of the solution, preferably the filtering step is repeated by flowing the solution in a circulating manner. In the polymer preparation process, the filtering step may be carried out any times, in any order and in any stage. The reaction solution as polymerized or the polymer solution may be filtered, preferably both are filtered.

Polymer P may be a blend of two or more polymers which differ in compositional ratio, Mw or molecular weight distribution.

### [(B) Crosslinker X]

The crosslinker X as component (B) is a melamine compound, a glycoluril compound, a urea compound or an epoxy compound substituted with at least one selected from a methylol group, an alkoxymethyl group and an acyloxymethyl group. These compounds may be used as an additive or introduced into a polymer side chain as a pendant.

Examples of the melamine compound include hexamethylol melamine, hexamethoxymethyl melamine, hexamethylol melamine compounds having 1 to 6 methylol groups methoxymethylated and mixtures thereof, hexamethoxyethyl melamine, hexaacyloxymethyl melamine, hexamethylol melamine compounds having 1 to 6 methylol groups acyloxymethylated and mixtures thereof.

Examples of the glycoluril compound include tetramethylol glycoluril, tetramethoxyglycoluril, tetramethoxymethyl glycoluril, tetramethylol glycoluril compounds having 1 to 4 methylol groups methoxymethylated and mixtures thereof, tetramethylol glycoluril compounds having 1 to 4 methylol groups acyloxymethylated and mixtures thereof.

Examples of the urea compound include tetramethylol urea, tetramethoxymethyl urea, tetramethylol urea compounds having 1 to 4 methylol groups methoxymethylated and mixtures thereof, and tetramethoxyethyl urea.

Examples of the epoxy compound include tris(2,3-epoxypropyl)isocyanurate, trimethylolmethane triglycidyl ether, trimethylolpropane triglycidyl ether, and triethylolethane triglycidyl ether.

The content of crosslinker X in the inventive chemically amplified negative resist composition is preferably 0.1 to 50 parts by weight, more preferably 1 to 40 parts by weight per 100 parts by weight of the base polymer.

### [(C) Onium Salt Type Quencher]

The inventive chemically amplified negative resist composition may comprise (C) an onium salt type quencher. Examples of the (C) onium salt type quencher include onium salts having the following formula (Q1) or (Q2). In the invention, the quencher refers to a compound capable of trapping the acid, which is generated by the photoacid generator in the chemically amplified resist composition upon light exposure, to prevent the acid from diffusing to the unexposed region and to assist in forming the desired pattern.

R³¹—SO₃⁻Mq⁺ (Q1)

R³²—CO₂⁻Mq⁺ (Q2)

In formula (Q1), R³¹ is hydrogen or a C₁-C₄₀ hydrocarbyl group which may contain a heteroatom, exclusive of the hydrocarbyl group in which the hydrogen atom bonded to the carbon atom at α-position of the sulfo group is substituted by fluorine atom or fluoroalkyl group. In formula (Q2), R³² is a hydrogen atom, or a C₁-C₄₀ hydrocarbyl group which may contain a heteroatom.

Examples of the C₁-C₄₀ hydrocarbyl group R³¹ include C₁-C₄₀ alkyls such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl and n-decyl groups; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl and adamantyl groups; C₆-C₄₀ aryl groups such as phenyl, naphthyl and anthracenyl groups; and combinations thereof. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like.

Examples of the hydrocarbyl group R³² include those exemplified above for R³¹, fluorinated saturated hydrocarbyl groups such as trifluoromethyl and trifluoroethyl groups, and fluorinated aryl groups such as pentafluorophenyl and 4-trifluoromethylphenyl groups.

Examples of the anion in the onium salt having formula (Q1) are shown below, but not limited thereto.

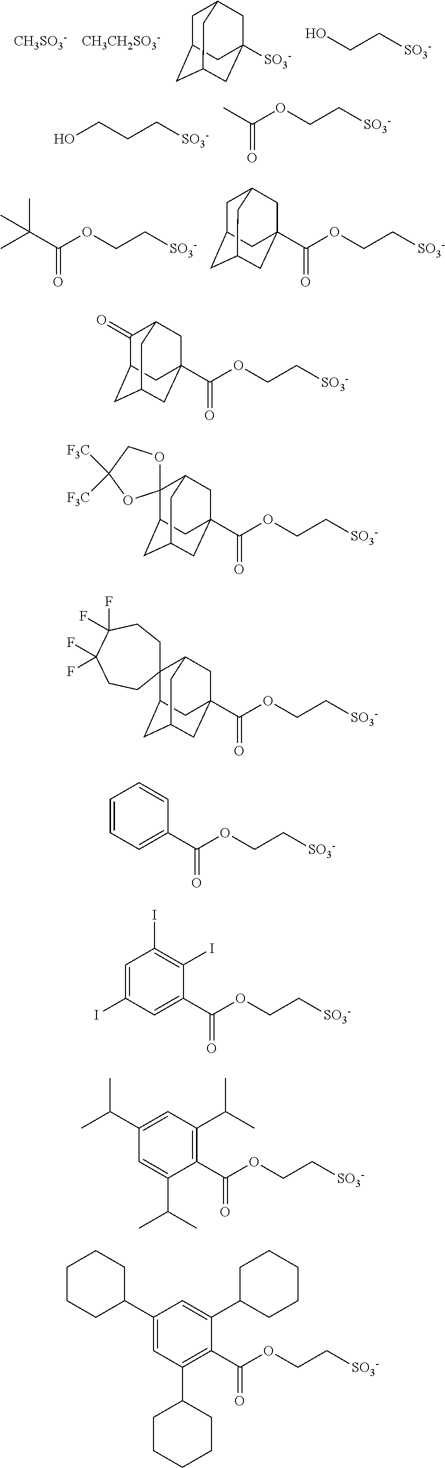

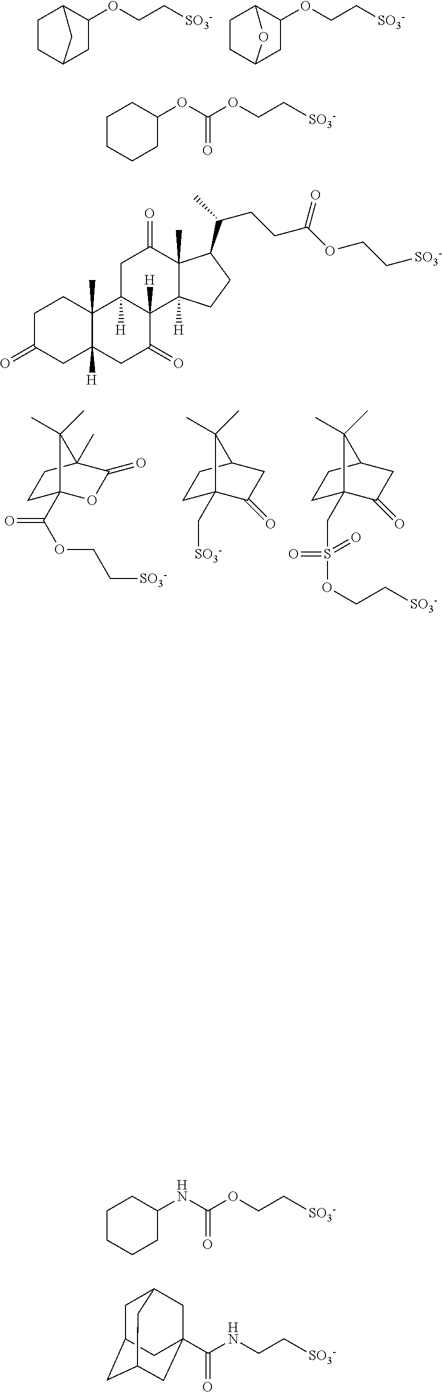

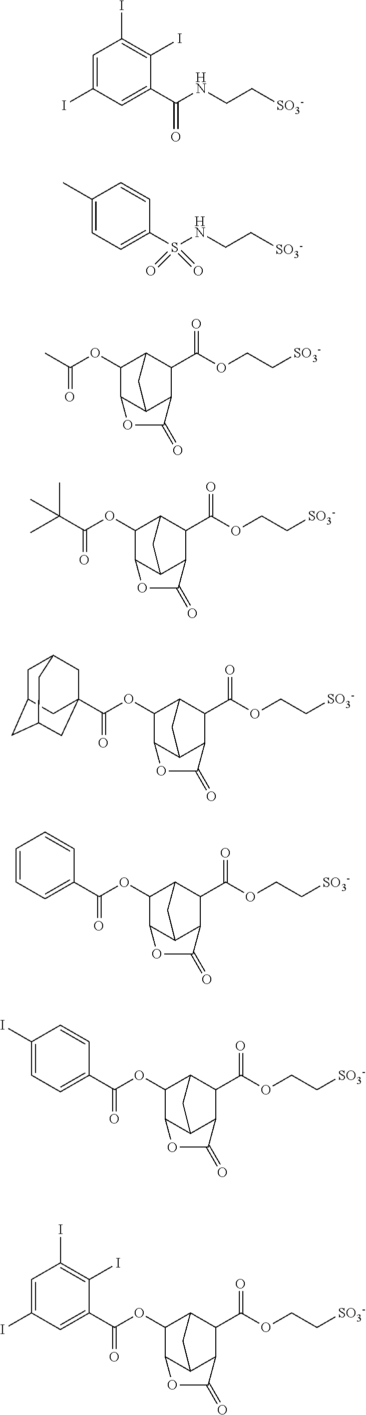

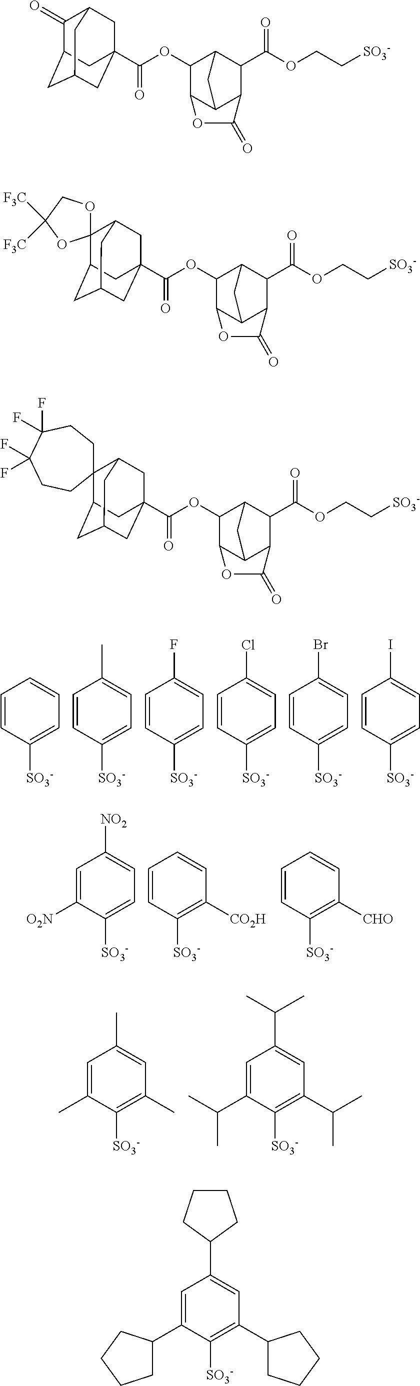

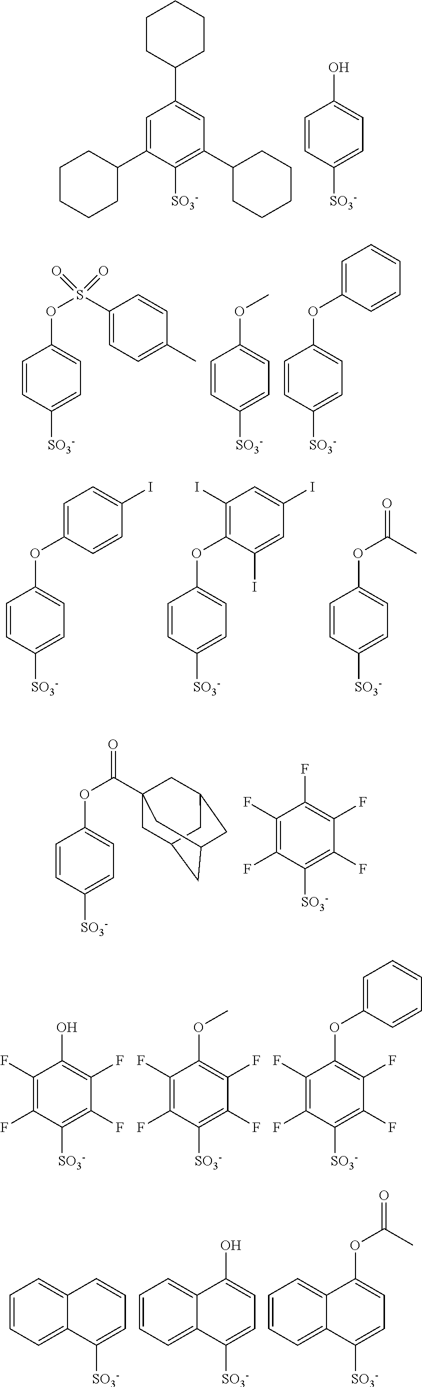

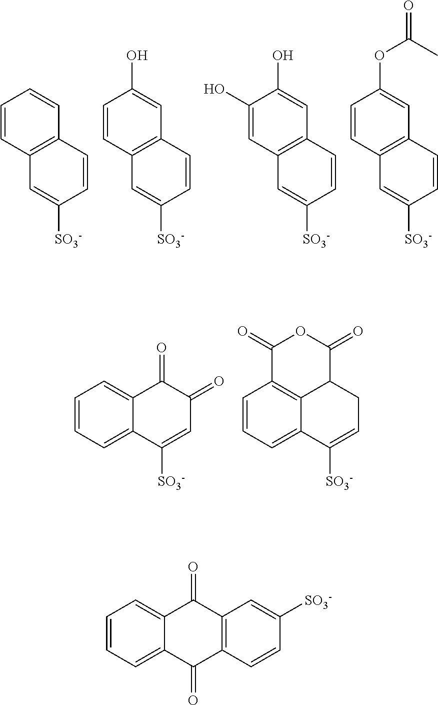

Examples of the anion in the onium salt having formula (Q2) are shown below, but not limited thereto.

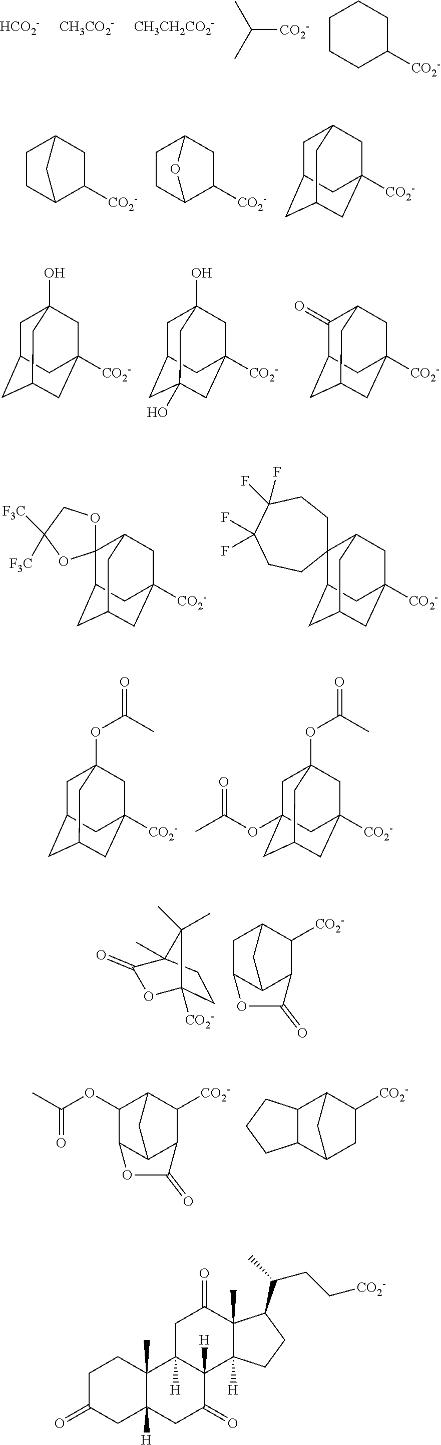

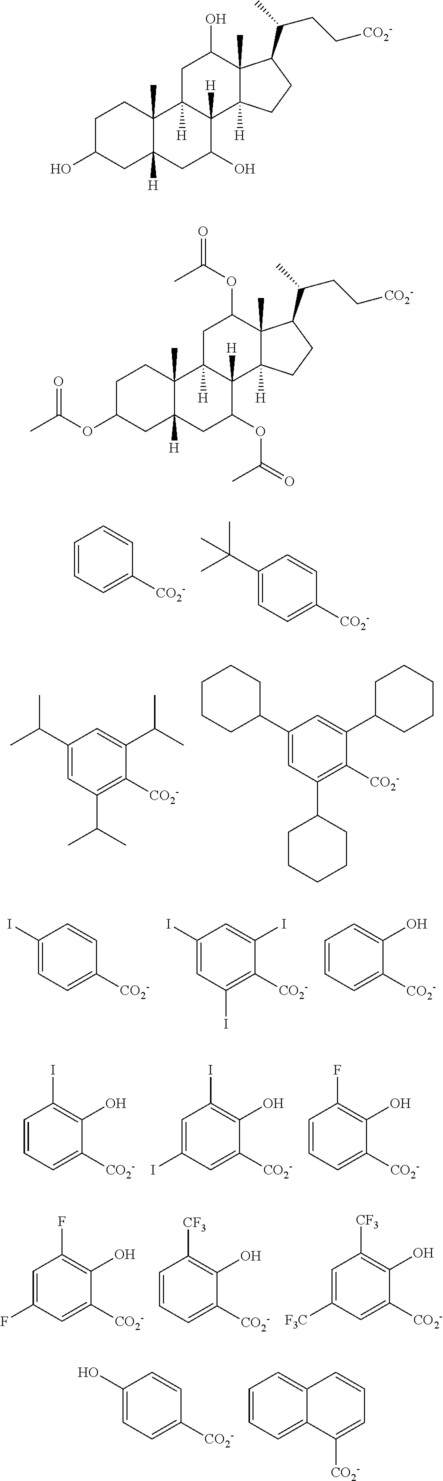

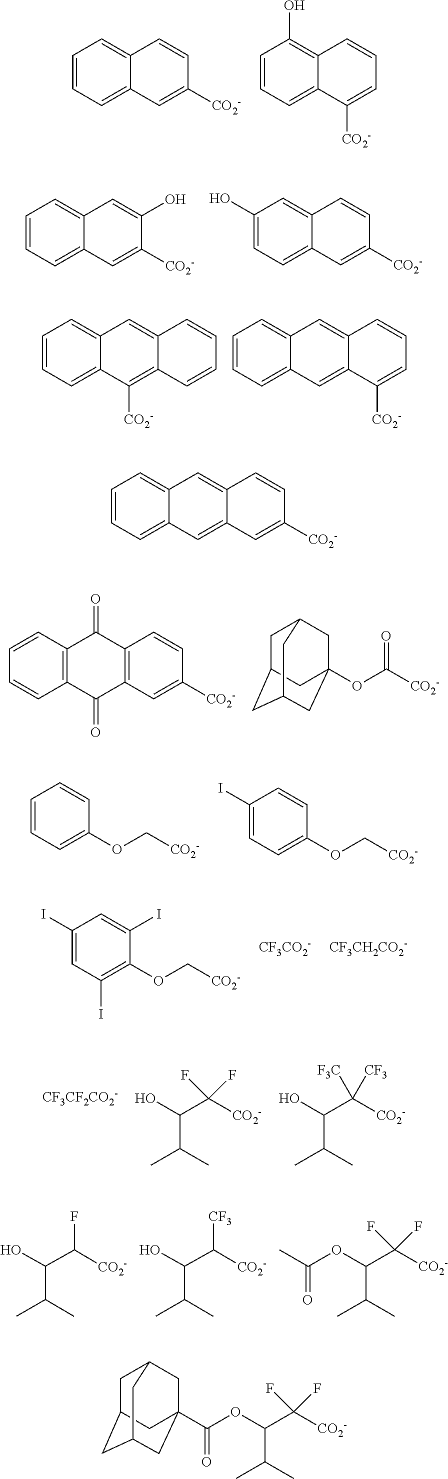

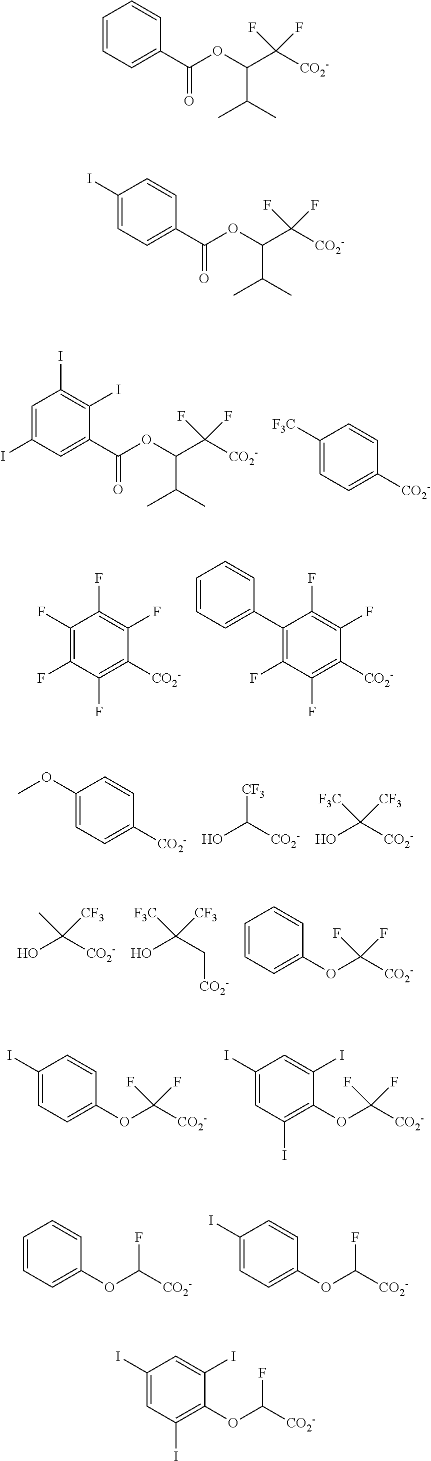

In formulae (Q1) and (Q2), Mq⁺ is an onium cation. The onium cation is preferably a sulfonium cation having the formula (cation-1), iodonium cation having the formula (cation-2) or ammonium cation having the following formula (cation-3).

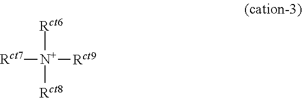

In formula (cation-3), R^{ct6} to R^{ct9} are each independently a C₁-C₄₀ hydrocarbyl group which may contain a heteroatom. R^{ct6} and R^{ct7} may bond together to form a ring with the nitrogen atom to which they are attached. Examples of the hydrocarbyl group are as exemplified above as hydrocarbyl groups R^{ct1} to R^{ct5} in formulae (cation-1) and (cation-2).

Examples of the ammonium cation having formula (cation-3) are shown below, but not limited thereto.

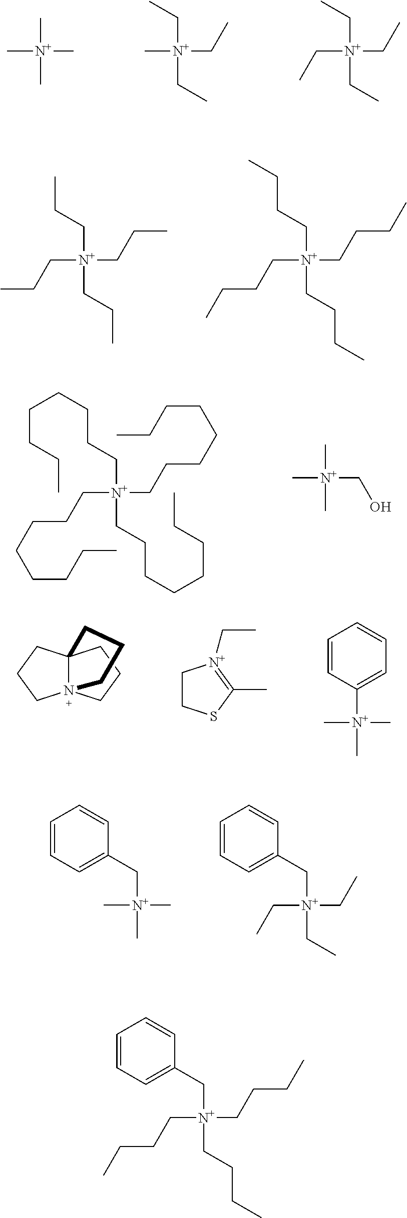

Examples of the onium salt represented by formula (Q1) or (Q2) include arbitrary combinations of anions with cations, both as exemplified above. These onium salts may be readily prepared by ion exchange reaction using any well-known organic chemistry technique. For the ion exchange reaction, reference may be made to JP-A 2007-145797, for example.

The onium salt having formula (Q1) or (Q2) functions as a quencher in the chemically amplified resist composition because the counter anion of the onium salt is a conjugated base of a weak acid. This is because the counter anion of the onium salt is a conjugated base of a weak acid. As used herein, the weak acid indicates an acidity insufficient to deprotect an acid labile group from an acid labile group-containing unit for the base polymer. The onium salt having formula (Q1) or (Q2) functions as a quencher when used in combination with an onium salt type PAG having a conjugated base of a strong acid (typically a sulfonic acid which is fluorinated at α-position) as the counter anion. In a system using a mixture of an onium salt capable of generating a strong acid (e.g., α-position fluorinated sulfonic acid) and an onium salt capable of generating a weak acid (e.g., non-fluorinated sulfonic acid or carboxylic acid), if the strong acid generated from the PAG upon exposure to high-energy radiation collides with the unreacted onium salt having a weak acid anion, then a salt exchange occurs whereby the weak acid is released and an onium salt having a strong acid anion is formed. In this course, the strong acid is exchanged into an acid having a low catalysis, incurring apparent deactivation of the acid for enabling to control acid diffusion.

If a PAG capable of generating a strong acid is an onium salt, an exchange from the strong acid generated upon exposure to high-energy radiation to a weak acid as above can take place, but it rarely happens that the weak acid generated upon exposure to high-energy radiation collides with the unreacted onium salt capable of generating a strong acid to induce a salt exchange. This is because of a likelihood of an onium cation forming an ion pair with a stronger acid anion.

When the inventive chemically amplified resist composition comprises onium salt type quencher (C), the content thereof is preferably 0.1 to 30 parts by weight, more preferably 0.1 to 20 parts by weight per 80 parts by weight of the polymer P as component (A). As long as the content of onium salt type quencher (C) is in the range, a satisfactory resolution is available without a substantial lowering of sensitivity. The onium salt type quencher (C) may be used alone or in admixture.

### [(D) Organic Solvent]

The inventive chemically amplified negative resist composition may comprise an organic solvent as component (D). The organic solvent as component (D) is not particularly limited as long as components described above and components described later are soluble therein. Suitable solvents include ketones such as cyclopentanone, cyclohexanone and methyl-2-n-pentyl ketone; alcohols such as 3-methoxybutanol, 3-methyl-3-methoxybutanol, 1-methoxy-2-propanol, 1-ethoxy-2-propanol; keto-alcohols such as DAA, ethers such as PGME, ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; and mixtures thereof. When a polymer containing an acid labile group of acetal form is used, a high-boiling alcohol solvent may be added for accelerating the deprotection reaction of acetal, for example, diethylene glycol, propylene glycol, glycerol, 1,4-butanediol or 1,3-butanediol.

Of the foregoing organic solvents, 1-ethoxy-2-propanol, PGMEA, cyclohexanone, GBL, DAA and mixtures thereof are preferred because polymer P as component (A) is most soluble therein.

When the inventive chemically amplified resist composition comprises organic solvent (D), the content thereof is preferably 200 to 5,000 parts by weight, more preferably 400 to 3,000 parts by weight per 80 parts by weight of polymer P as component (A). The organic solvent (D) may be used alone or in admixture.

### [(E) Surfactant]

The inventive chemically amplified negative resist composition may further comprise a surfactant as component (E) in addition to the components described above. Exemplary surfactants are described in JP-A 2008-111103, paragraphs [0165]-[0166]. Inclusion of a surfactant may improve or control the coating characteristics of the resist composition. When the inventive chemically amplified negative resist composition comprises surfactant (E), the content thereof is preferably 0.0001 to 10 parts by weight per 100 parts by weight of the base polymer. The surfactant may be used alone or in admixture.

The inventive chemically amplified negative resist composition has advantages including a high dissolution contrast of a resist film due to optimum deprotection reaction, acid diffusion controlling effect, high resolution, exposure latitude, process adaptability, satisfactory pattern profile after light exposure, and high etching resistance. By virtue of these advantages, the resist composition is fully useful in commercial application and suited as a mask pattern-forming material.

### [Process]

Another embodiment of the invention is a pattern forming process using the chemically amplified negative resist composition defined above. The process comprises steps of applying the chemically amplified negative resist composition to a substrate to form a resist film thereon, exposing the resist film to high-energy radiation, and developing the exposed resist film in a developer.

The substrate used herein may be a substrate for integrated circuitry fabrication, e.g., Si, SiO₂, SiN, SiON, TiN, WSi, BPSG, SOG, organic antireflective film, etc. or a substrate for mask circuitry fabrication, e.g., Cr, CrO, CrON, MoSi₂, SiO₂, etc.

The chemically amplified resist composition is applied by a suitable coating technique such as spin coating. The coating is prebaked on a hot plate preferably at a temperature of 60 to 150° C. for 1 to 10 minutes, more preferably at 80 to 140° C. for 1 to 5 minutes. The resulting resist film preferably has a thickness of preferably 0.05 to 2 μm.

The resist film is exposed to high-energy radiation, for example, i line, KrF or ArF excimer laser, electron beams (EB), or EUV. On use of i line, KrF excimer laser, ArF excimer laser or EUV, the resist film is exposed through a mask having a desired pattern, preferably in a dose of 1 to 200 mJ/cm², more preferably 10 to 100 mJ/cm². On use of EB, a pattern may be written directly or through a mask having the desired pattern, preferably in a dose of 1 to 300 μC/cm², more preferably 10 to 200 μC/cm².

The exposure may be performed by conventional lithography whereas the immersion lithography of holding a liquid having a refractive index of at least 1.0 between the resist film and the projection lens may be employed if desired. The liquid is typically water, and in this case, a protective film which is insoluble in water may be formed on the resist film.

After the exposure, the resist film may be baked (PEB), for example, on a hotplate at 60 to 150° C. for 1 to 5 minutes, preferably at 90 to 130° C. for 1 to 3 minutes.

Preferably, a solvent having a solubility parameter (SP value) close to that of the base polymer is selected as the organic solvent developer. Polar solvents such as ketone-based solvents, ester-based solvents, alcohol-based solvents, ether-based solvents, and amide-based solvents, and hydrocarbon-based solvents may be used.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methyl cyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, and propylene carbonate.

Examples of the ester-based solvent include methyl acetate, butyl acetate, ethyl acetate, isopropyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate.

Examples of the alcohol-based solvent include alcohols such as methyl alcohol, ethyl alcohol, n-propyl alcohol, isopropyl alcohol, n-butyl alcohol, sec-butyl alcohol tert-butyl alcohol, isobutyl alcohol, n-hexyl alcohol, 4-methyl-2-pentanol, n-heptyl alcohol, n-octyl alcohol, and n-decanol; glycol-based solvents such as ethylene glycol, diethylene glycol, and triethylene glycol; and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include dioxane and tetrahydrofuran in addition to the glycol ether-based solvents.

Examples of the amide-based solvent that can be used include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, and decane.

The organic solvents may be used alone or in admixture.

Examples of the applicable development method include a method in which a substrate is immersed for a certain period of time in a tank filled with a developer (dipping method); a method in which a developer is deposited on a substrate surface by surface tension and placed still for a certain period of time (paddle method); a method in which a developer is sprayed to a substrate surface (spraying method); and a method in which by running a developer discharge nozzle at a constant speed, a developer is continuously discharged onto a substrate rotating at a constant speed. The pattern development time is not limited, and is preferably 10 to 90 seconds.

### EXAMPLES

Synthesis Examples, Examples and Comparative Examples are given below by way of illustration and not by way of limitation.

### [1] Synthesis of Monomers

### [Synthesis Example 1-1] Synthesis of Monomer MB-1

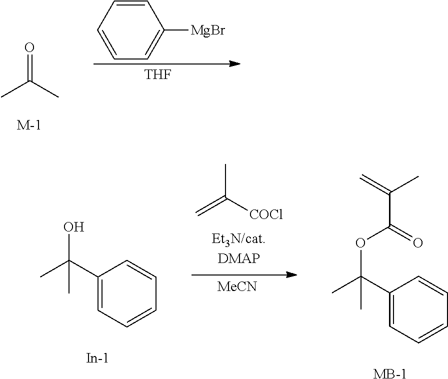

### (1) Synthesis of Intermediate In-1

In nitrogen atmosphere, a Grignard reagent was prepared using 160.5 g of magnesium, 1,155 g of 4-bromofluorobenzene, and 3,300 g of THF. While the internal temperature was kept below 45° C., a solution of 348.5 g of Reactant M-1 in 700 g of THF was added dropwise to the Grignard reagent. The solution was stirred for 2 hours at an internal temperature of 50° C. The reaction solution was ice cooled, after which a mixture of 660 g of ammonium chloride and 3,960 g of 3.0 wt % hydrochloric acid aqueous solution was added dropwise to quench the reaction. 4,500 mL of toluene was added to the solution, followed by ordinary aqueous work-up, solvent stripping, and distillation for purification. There was obtained 865 g of Intermediate In-1 as colorless oily matter (yield 94%).

### (2) Synthesis of Monomer MB-1

In nitrogen atmosphere, 821 g of methacrylic chloride was added dropwise to a solution of 865 g of Intermediate In-1, 1,022 g of triethylamine, 68.5 g of dimethylaminopyridine, and 3,150 mL of acetonitrile at an internal temperature below 60° C. The solution was aged for 20 hours at an internal temperature of 55° C. The reaction solution was ice cooled, after which 2,000 mL of saturated sodium hydrogencarbonate solution was added dropwise to quench the reaction. This was followed by extraction with 4,200 mL of toluene, ordinary aqueous work-up, solvent stripping, and vacuum distillation. There was obtained 1,012 g of Monomer MB-1 as colorless transparent oily matter (yield 81%).

### [Synthesis Example 1-2] Synthesis of Monomer MB-2

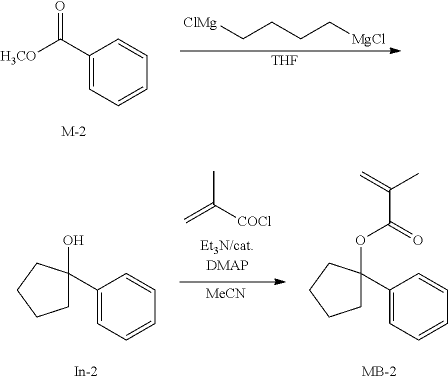

### (1) Synthesis of Intermediate In-2

In nitrogen atmosphere, a Grignard reagent was prepared using 59 g of magnesium, 146 g of 1,4-dichlorobutane, and 1,000 mL of THF. While the internal temperature was kept below 50° C., a solution of 154 g of Reactant M-2 in 150 mL of THF was added dropwise to the Grignard reagent. The solution was stirred for 2 hours at an internal temperature of 50° C. The reaction solution was ice cooled, after which a mixture of 240 g of ammonium chloride and 1,450 g of 3.0 wt % hydrochloric acid aqueous solution was added dropwise to quench the reaction. 800 mL of toluene was added to the solution, followed by ordinary aqueous work-up, solvent stripping, vacuum distillation. There was obtained 175 g of Intermediate In-2 as colorless oily matter (yield 98%).

### (2) Synthesis of Monomer MB-2

Synthesis was performed by the same procedure as Synthesis Example 1-1 (2) aside from using Intermediate In-2 instead of Intermediate In-1. There was obtained Monomer MB-2 as colorless transparent oily matter (yield 82%).

### [Synthesis Examples 1-3 and 1-4] Synthesis of Monomers MB-3 and MB-4

Monomers MB-3 and MB-4 were similarly synthesized using the corresponding reactants.

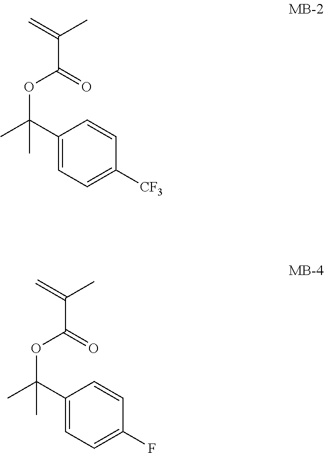 [SMILES: C=C(C)C(=O)OC(C)(C)c1ccc(C(F)(F)F)cc1 ; C=C(C)C(=O)OC(C)(C)c1ccc(F)cc1]

### [Comparative Synthesis Examples 1-1 to 1-3] Synthesis of Comparative Monomers MBX-1 to MBX-3

Comparative Monomers MBX-1 to MBX-3 were similarly synthesized using the corresponding reactants.

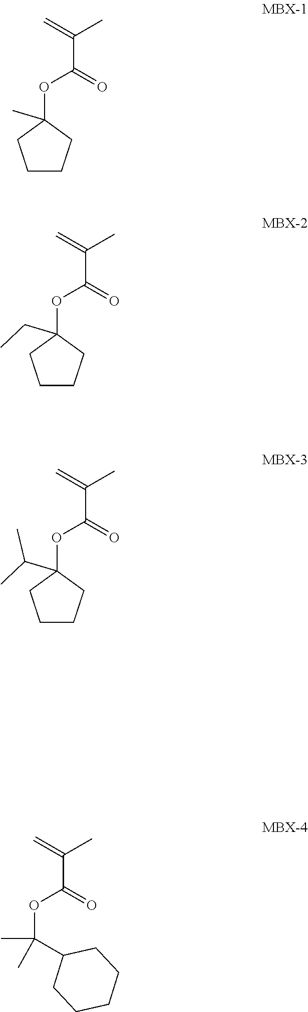

### [2] Synthesis of Polymers

Monomers MB-1 to MB-4, Comparative Monomers MBX-1 to MBX-4, and the monomers shown below were used in the synthesis of polymers.

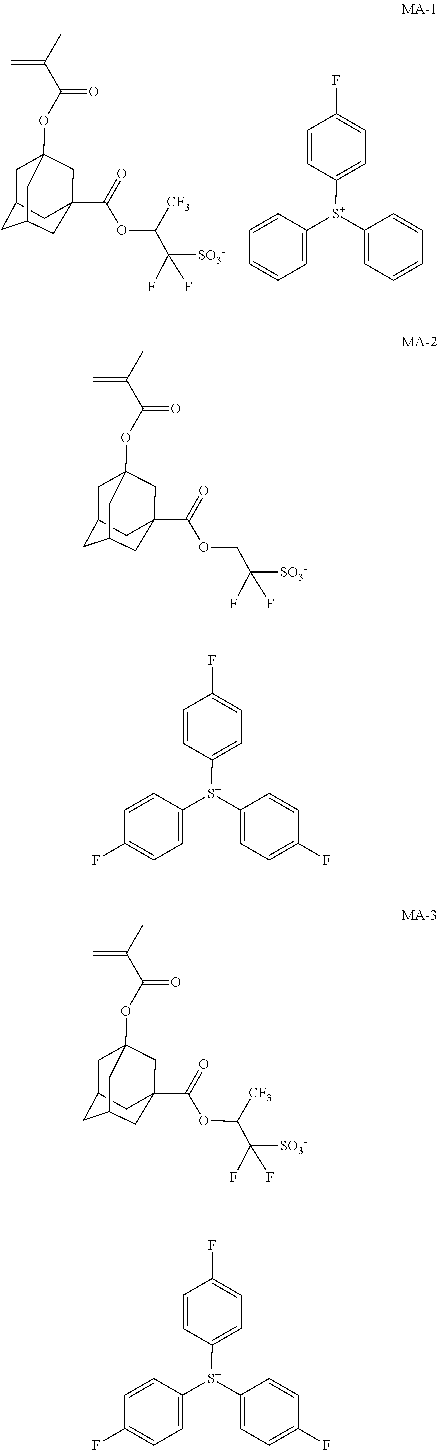

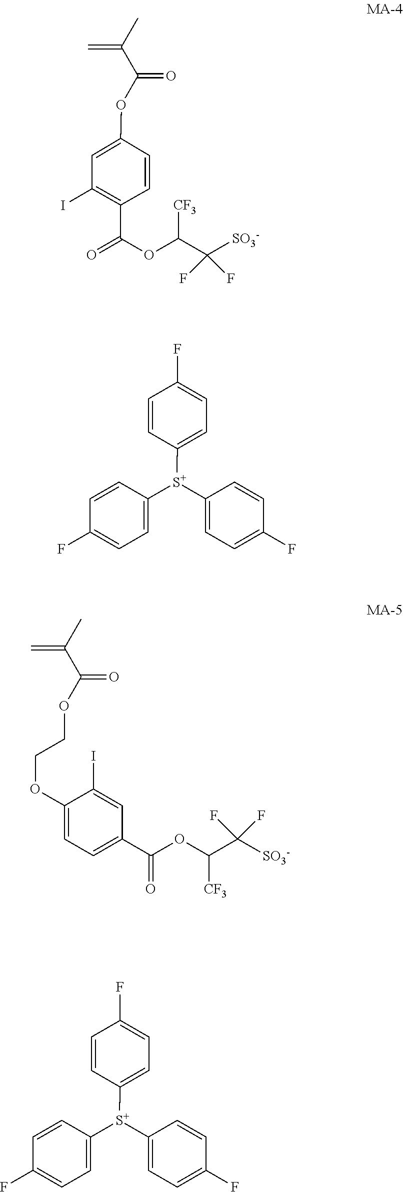

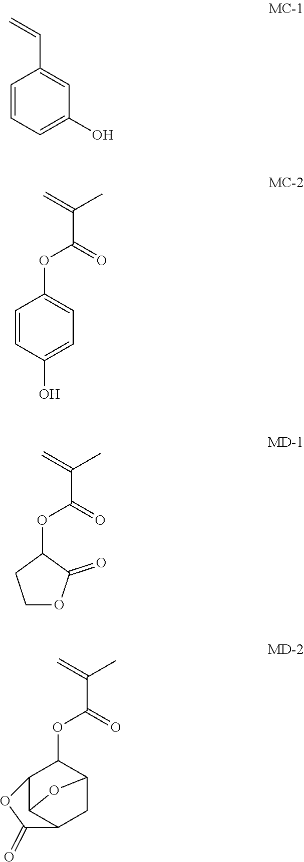

### [Synthesis Example 2-1] Synthesis of Polymer P-1

A flask under nitrogen atmosphere was charged with 50.1 g of Monomer MB-1, 24.8 g of Monomer MC-1, 38.0 g of Monomer MA-1, 3.96 g of V-601 (manufactured by Fujifilm Wako Pure Chemical Corp.), and 127 g of MEK to prepare a monomer/initiator solution. Another flask under nitrogen atmosphere was charged with 46 g of MEK, which was heated to 80° C. with stirring. The monomer/initiator solution was added dropwise to the MEK over 4 hours. At the end of addition, the polymerization solution was continuously stirred for 2 hours while maintaining the temperature at 80° C. The polymerization solution was cooled to room temperature, after which it was added dropwise to 2,000 g of hexane with vigorous stirring. The solid precipitate was collected by filtration. The precipitate was washed twice with 600 g of hexane and vacuum dried at 50° C. for 20 hours to obtain Polymer P-1 as white powder (amount 98.1 g, yield 98%). Polymer P-1 had a Mw of 10,900 and a Mw/Mn of 1.82. It is noted that Mw is as measured by GPC versus polystyrene standards using DMF solvent.

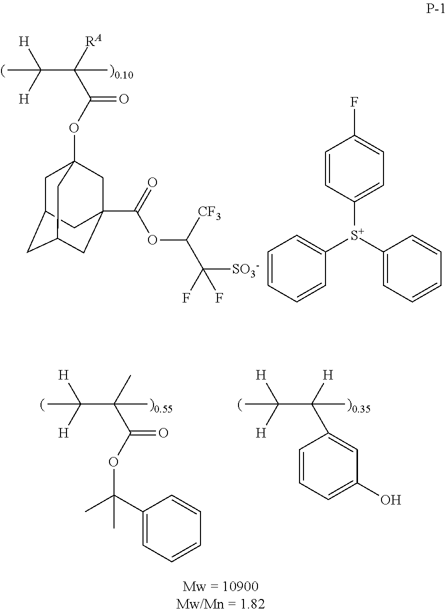

### [Synthesis Examples 2-2 to 2-13 and Comparative Synthesis Examples 2-1 to 2-6] Synthesis of Polymers P-2 to P-13 and Comparative Polymers CP-1 to CP-6

Polymers as shown in Tables 1 and 2 were synthesized by the same procedure as in Synthesis Example 2-1 aside from changing the type and amount of monomers. The introduction ratio in Tables 1 and 2 designates mol % of the relevant unit.

TABLE 1

| | Monomer A | Monomer B | Monomer C | Monomer D | | |
|---|---|---|---|---|---|---|
| Polymer | (ratio) | (ratio) | (ratio) | (ratio) | Mw | Mw/Mn |
| P-1 | MA-1 | MB-4 | MC-1 | — | 10,277 | 1.83 |
| | (10) | (55) | (35) | | | |
| P-2 | MA-2 | MB-4 | MC-1 | — | 10,240 | 1.84 |
| | (10) | (55) | (35) | | | |
| P-3 | MA-3 | MB-4 | MC-1 | — | 10,288 | 1.86 |
| | (10) | (55) | (35) | | | |
| P-4 | MA-4 | MB-4 | MC-1 | — | 10,384 | 1.85 |
| | (10) | (55) | (35) | | | |
| P-5 | MA-5 | MB-4 | MC-1 | — | 10,453 | 1.87 |
| | (10) | (55) | (35) | | | |
| P-6 | MA-3 | MB-1 | MC-1 | — | 10,232 | 1.80 |
| | (10) | (55) | (35) | | | |
| P-7 | MA-3 | MB-2 | MC-1 | — | 10,484 | 1.80 |
| | (10) | (55) | (35) | | | |
| P-8 | MA-3 | MB-3 | MC-1 | — | 10,459 | 1.87 |
| | (10) | (55) | (35) | | | |
| P-9 | MA-3 | MB-4 | MC-1 | — | 10,024 | 1.87 |
| | (10) | (55) | (35) | | | |
| P-10 | MA-2 | MB-1 | MC-1 | — | 10,294 | 1.83 |
| | (10) | (55) | (35) | | | |
| P-11 | MA-2 | MB-1 | MC-2 | — | 10,245 | 1.90 |
| | (10) | (55) | (35) | | | |
| P-12 | MA-3 | MB-4 | MC-1 | MD-1 | 10,284 | 1.85 |
| | (10) | (55) | (25) | (10) | | |
| P-13 | MA-3 | MB-4 | MC-1 | MD-2 | 10,173 | 1.82 |
| | (10) | (55) | (25) | (10) | | |

TABLE 2

| | Monomer A | Monomer B | Monomer C | Monomer D | | |
|---|---|---|---|---|---|---|
| Polymer | (ratio) | (ratio) | (ratio) | (ratio) | Mw | Mw/Mn |
| CP-1 | MA-3 | MBX-1 | MC-1 | — | 10,432 | 1.84 |
| | (10) | (55) | (35) | | | |
| CP-2 | MA-3 | MBX-2 | MC-1 | — | 10,483 | 1.84 |
| | (10) | (55) | (35) | | | |
| CP-3 | MA-3 | MBX-3 | MC-1 | — | 10,008 | 1.83 |
| | (10) | (55) | (35) | | | |
| CP-4 | MA-3 | MBX-4 | MC-1 | — | 10,172 | 1.88 |
| | (10) | (55) | (35) | | | |
| CP-5 | — | MB-1 | MC-1 | — | 10,249 | 1.89 |
| | | (60) | (35) | | | |
| CP-6 | — | MB-4 | MC-1 | — | 10,156 | 1.83 |
| | | (60) | (35) | | | |

### [3] Preparation and Evaluation of Chemically Amplified Resist Composition

### (1) Preparation of Chemically Amplified Resist Composition

### Examples 1-1 to 1-22 and Comparative Examples 1-1 to 1-8

Chemically amplified resist compositions were prepared by dissolving polymer P (P-1 to P-13) or comparative polymer (CP-1 to CP-6), photoacid generator (PAG-1), and quencher (Q-1 to Q-4) in a solvent containing 50 ppm of surfactant PolyFox PF-636 (OMNOVA) in accordance with the formulation shown in Tables 3 and 4, and filtering the solution through a Teflon® filter with a pore size of 0.2 μm.

The components in Tables 3 and 4 are identified below.

### Photoacid Generator: PAG-1

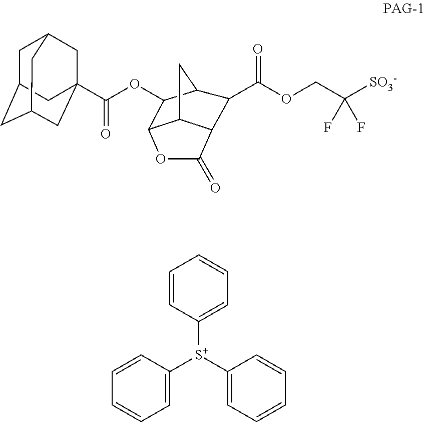

### Quencher: Q-1 to Q-4

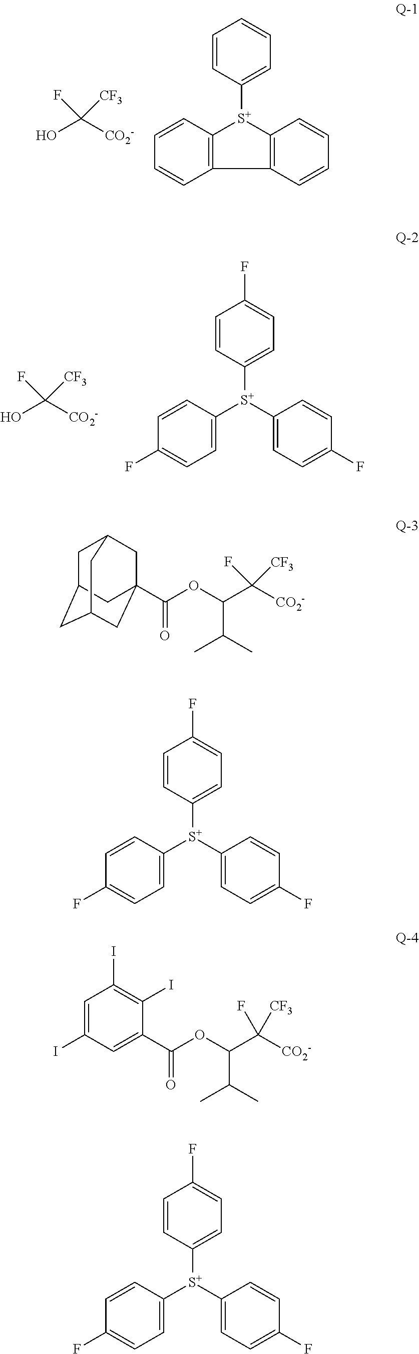

Crosslinker: X-1 to X-4

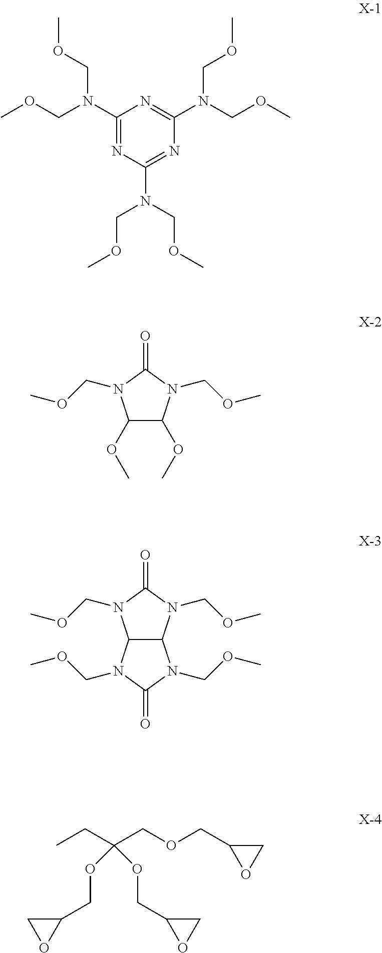

### Organic Solvent:

PGMEA (propylene glycol monomethyl ether acetate)
DAA (diacetone alcohol)
EL (ethyl lactate)

TABLE 3

| | | | Base | Photoacid | | | Organic |
|---|---|---|---|---|---|---|---|
| | | Resist | polymer | generator | Quencher | Crosslinker | solvent |
| | | composition | (pbw) | (pbw) | (pbw) | (pbw) | (pbw) |
| Example | 1-1 | R-1 | P-1 | — | Q-2 | X-1 | PGMEA/DAA/EL |
| | | | (80) | | (20) | (5) | (1236/309/1546) |
| | 1-2 | R-2 | P-2 | — | Q-2 | X-1 | PGMEA/DAA/EL |
| | | | (80) | | (20) | (5) | (1236/309/1546) |
| | 1-3 | R-3 | P-3 | — | Q-2 | X-1 | PGMEA/DAA/EL |
| | | | (80) | | (20) | (5) | (1236/309/1546) |
| | 1-4 | R-4 | P-4 | — | Q-2 | X-1 | PGMEA/DAA/EL |
| | | | (80) | | (20) | (5) | (1236/309/1546) |
| | 1-5 | R-5 | P-5 | — | Q-2 | X-1 | PGMEA/DAA/EL |
| | | | (80) | | (20) | (5) | (1236/309/1546) |
| | 1-6 | R-6 | P-6 | — | Q-2 | X-1 | PGMEA/DAA/EL |
| | | | (80) | | (20) | (5) | (1236/309/1546) |
| | 1-7 | R-7 | P-7 | — | Q-2 | X-1 | PGMEA/DAA/EL |
| | | | (80) | | (20) | (5) | (1236/309/1546) |
| | 1-8 | R-8 | P-8 | — | Q-2 | X-1 | PGMEA/DAA/EL |
| | | | (80) | | (20) | (5) | (1236/309/1546) |
| | 1-9 | R-9 | P-9 | — | Q-2 | X-1 | PGMEA/DAA/EL |
| | | | (80) | | (20) | (5) | (1236/309/1546) |
| | 1-10 | R-10 | P-10 | — | Q-2 | X-1 | PGMEA/DAA/EL |
| | | | (80) | | (20) | (5) | (1236/309/1546) |
| | 1-11 | R-11 | P-11 | — | Q-2 | X-1 | PGMEA/DAA/EL |
| | | | (80) | | (20) | (5) | (1236/309/1546) |
| | 1-12 | R-12 | P-12 | — | Q-2 | X-1 | PGMEA/DAA/EL |
| | | | (80) | | (20) | (5) | (1236/309/1546) |
| | 1-13 | R-13 | P-13 | — | Q-2 | X-1 | PGMEA/DAA/EL |
| | | | (80) | | (20) | (5) | (1236/309/1546) |
| | 1-14 | R-14 | P-9 | — | Q-1 | X-3 | PGMEA/DAA/EL |
| | | | (80) | | (20) | (5) | (1236/309/1546) |
| | 1-15 | R-15 | P-9 | — | Q-2 | X-3 | PGMEA/DAA/EL |
| | | | (80) | | (20) | (5) | (1236/309/1546) |
| | 1-16 | R-16 | P-9 | — | Q-3 | X-3 | PGMEA/DAA/EL |
| | | | (80) | | (20) | (5) | (1236/309/1546) |
| | 1-17 | R-17 | P-9 | — | Q-4 | X-3 | PGMEA/DAA/EL |
| | | | (80) | | (20) | (5) | (1236/309/1546) |
| | 1-18 | R-18 | P-5 | — | Q-3 | X-1 | PGMEA/DAA/EL |
| | | | (80) | | (20) | (5) | (1236/309/1546) |
| | 1-19 | R-19 | P-5 | — | Q-3 | X-2 | PGMEA/DAA/EL |
| | | | (80) | | (20) | (5) | (1236/309/1546) |
| | 1-20 | R-20 | P-5 | — | Q-3 | X-3 | PGMEA/DAA/EL |
| | | | (80) | | (20) | (5) | (1236/309/1546) |
| | 1-21 | R-21 | P-5 | — | Q-3 | X-4 | PGMEA/DAA/EL |
| | | | (80) | | (20) | (5) | (1236/309/1546) |

TABLE 4

| | | | Base | Photoacid | | | |
|---|---|---|---|---|---|---|---|
| | | Resist | polymer | generator | Quencher | Crosslinker | Organic solvent |
| | | composition | (pbw) | (pbw) | (pbw) | (pbw) | (pbw) |
| Comparative | 1-1 | CR-1 | CP-1 | — | Q-3 | X-1 | PGMEA/DAA/EL |
| Example | | | (80) | | (20) | (5) | (1236/309/1546) |
| | 1-2 | CR-2 | CP-2 | — | Q-3 | X-1 | PGMEA/DAA/EL |
| | | | (80) | | (20) | (5) | (1236/309/1546) |
| | 1-3 | CR-3 | CP-3 | — | Q-3 | X-1 | PGMEA/DAA/EL |
| | | | (80) | | (20) | (5) | (1236/309/1546) |
| | 1-4 | CR-4 | CP-4 | — | Q-3 | X-1 | PGMEA/DAA/EL |
| | | | (80) | | (20) | (5) | (1236/309/1546) |
| | 1-5 | CR-5 | CP-5 | PAG-1 | Q-3 | X-1 | PGMEA/DAA/EL |
| | | | (80) | (25) | (20) | (5) | (1236/309/1546) |
| | 1-6 | CR-6 | CP-6 | PAG-1 | Q-3 | X-1 | PGMEA/DAA/EL |
| | | | (80) | (25) | (20) | (5) | (1236/309/1546) |
| | 1-7 | CR-7 | P-9 | — | Q-4 | — | PGMEA/DAA/EL |
| | | | (80) | | (20) | | (1236/309/1546) |
| | 1-8 | CR-8 | CP-6 | PAG-1 | Q-3 | — | PGMEA/DAA/EL |
| | | | (80) | (25) | (20) | | (1236/309/1546) |

### (2) Crosslinking Reactivity Test

### Examples 2-1 to 2-23 and Comparative Examples 2-1 to 2-2

Each of resist compositions R-1 to R-21, CR-7 and CR-8 was spin coated on a silicon substrate, and prebaked on a hotplate for 60 seconds at the temperature shown in Tables 5 and 6, thereby preparing a resist film of 50 nm thick. The resist film was exposed with a KrF exposure machine (S206D manufactured by Nikon Corporation) at an exposure dose of 50 mJ/cm², and baked (PEB) on a hotplate for 60 seconds at the temperature shown in Tables 5 and 6. Thereafter, the film was peeled from the substrate, and dissolved in an organic solvent. Thereafter, a weight average molecular weight was measured in terms of polystyrene by gel permeation chromatography (GPC) using DMF as a solvent. The results are shown in Tables 5 and 6.

TABLE 5

| | | | Prebaking | Molecular |
|---|---|---|---|---|
| | | | temperature (° C.)/ | weight after |
| | | Resist | PEB temperature | exposure |
| | | composition | (° C.) | (×10⁴) |
| Example | 2-1 | R-1 | 105/100 | 5.7 |
| | 2-2 | R-2 | 105/100 | 5.3 |
| | 2-3 | R-3 | 105/100 | 5.3 |
| | 2-4 | R-4 | 105/100 | 6.8 |
| | 2-5 | R-5 | 105/100 | 6.0 |
| | 2-6 | R-6 | 105/100 | 6.9 |
| | 2-7 | R-7 | 105/100 | 5.2 |
| | 2-8 | R-8 | 105/100 | 6.9 |
| | 2-9 | R-9 | 105/100 | 5.4 |
| | 2-10 | R-10 | 105/100 | 5.0 |
| | 2-11 | R-11 | 105/100 | 6.7 |
| | 2-12 | R-12 | 105/100 | 6.2 |
| | 2-13 | R-13 | 105/100 | 6.9 |
| | 2-14 | R-14 | 105/100 | 6.0 |
| | 2-15 | R-15 | 105/100 | 4.7 |
| | 2-16 | R-16 | 105/100 | 5.8 |
| | 2-17 | R-17 | 105/100 | 5.1 |
| | 2-18 | R-18 | 105/100 | 6.5 |
| | 2-19 | R-19 | 105/100 | 3.4 |
| | 2-20 | R-20 | 105/100 | 5.5 |
| | 2-21 | R-21 | 105/100 | 3.0 |
| | 2-22 | R-17 | 105/110 | 10.5 |
| | 2-23 | R-17 | 105/120 | Insoluble |

TABLE 6

| | | | Prebaking | Molecular |
|---|---|---|---|---|
| | | | temperature (° C.)/ | weight after |
| | | Resist | PEB temperature | exposure |
| | | composition | (° C.) | (×10⁴) |
| Comparative | 2-1 | CR-7 | 105/100 | 0.8 |
| Example | 2-2 | CR-8 | 105/100 | 0.9 |

It is demonstrated in Tables 5 and 6 that the average molecular weight after exposure in Examples 2-1 to 2-23 using resist compositions R-1 to R-21 containing a crosslinker is larger than that in Comparative Examples 2-1 to 2-2 using resist compositions CR-7 to CR-8 free of a crosslinker. This shows that in Examples 2-1 to 2-23, the crosslinking reaction proceeded. It was shown that in Example 2-23 with a higher PEB temperature, crosslinking proceeded to the extent that the resist film after prebaking was insoluble in the GPC solvent.

### (3) Dissolution Contrast Test

### Examples 3-1 to 3-23 and Comparative Examples 3-1 to 3-8

Each of resist compositions R-1 to R-21 and CR-1 to CR-8 was spin coated on a 61 nm-thick film obtained by applying an antireflective coating DUV-42 (Nissan Chemical Corporation) onto an 8 inch-wafer. The film was prebaked on a hotplate for 60 seconds to form a resist film of 50 nm thick. The resist film was exposed with a KrF exposure machine (S206D manufactured by Nikon Corporation), and baked (PEB) on a hotplate for 60 seconds at the temperature shown in Tables 7 and 8, followed by development for 30 seconds using butyl acetate as a developer. The resist film thickness after the development was measured, the relationship between the exposure dose and the resist film thickness after the development processing was plotted, and the dissolution contrast was analyzed. Further, the contrast was evaluated according to the following criteria. For the measurement of the film thickness, a film thickness meter VM-2210 manufactured by Hitachi High-Technologies Corporation was used. In addition, after the development in butyl acetate, existence or non-existence of undissolved portions in unexposed regions was evaluated in accordance with the two criteria of existence and non-existence. The results are shown in Tables 7 and 8.

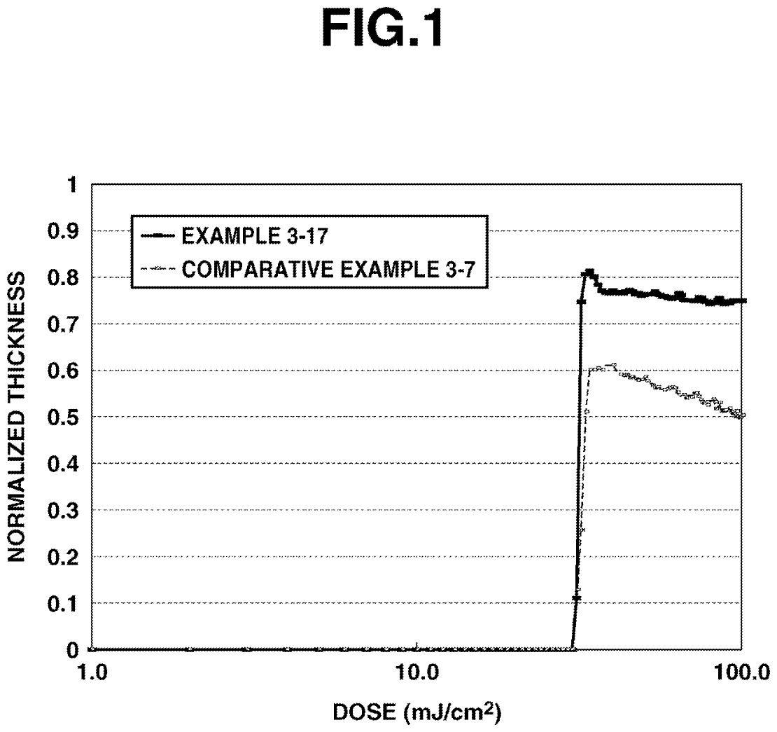

Contrast curves of the resist films of Example 3-17 and Comparative Example 3-7, whose formulations are representative in the dissolution contrast test, are shown in FIG. 1. The vertical axis in FIG. 1 represents a value obtained by normalizing a thickness after development to a thickness before the development. The contrast value in Table 7 represents a slope of a thickness change with respect to an exposure dose at a point where the solubility of the resist film in a developer abruptly changes. A slope determined from a logarithm of an exposure dose on the horizontal axis and a normalized thickness on the vertical axis in a section with a thickness of 8% or more and 60% or less of the initial thickness was set to a contrast value, and the contrast of the resist film formed from each resist composition was evaluated in accordance with the following criteria based on the absolute value of contrast.

### (Evaluation Criteria)

⊚: The absolute value of contrast is 10 or more.
◯: The absolute value of contrast is 5 or more and less than 10.
×: The absolute value of contrast is less than 5.

TABLE 7

| | | Resist | Prebaking temperature (° C.)/ | | | Undissolved |
|---|---|---|---|---|---|---|
| | | composition | PEB temperature (° C.) | Contrast | Evaluation | portion |
| Example | 3-1 | R-1 | 105/100 | 15.6 | ⊚ | None |
| | 3-2 | R-2 | 105/100 | 15.0 | ⊚ | None |
| | 3-3 | R-3 | 105/100 | 13.3 | ⊚ | None |
| | 3-4 | R-4 | 105/100 | 14.6 | ⊚ | None |
| | 3-5 | R-5 | 105/100 | 13.3 | ⊚ | None |
| | 3-6 | R-6 | 105/100 | 8.5 | ◯ | None |
| | 3-7 | R-7 | 105/100 | 8.8 | ◯ | None |
| | 3-8 | R-8 | 105/100 | 12.7 | ⊚ | None |
| | 3-9 | R-9 | 105/100 | 15.0 | ⊚ | None |
| | 3-10 | R-10 | 105/100 | 13.3 | ⊚ | None |
| | 3-11 | R-11 | 105/100 | 10.3 | ⊚ | None |
| | 3-12 | R-12 | 105/100 | 15.8 | ⊚ | None |
| | 3-13 | R-13 | 105/100 | 14.2 | ⊚ | None |
| | 3-14 | R-14 | 105/100 | 11.1 | ⊚ | None |
| | 3-15 | R-15 | 105/100 | 12.4 | ⊚ | None |
| | 3-16 | R-16 | 105/100 | 11.0 | ⊚ | None |
| | 3-17 | R-17 | 105/100 | 10.3 | ⊚ | None |
| | 3-18 | R-18 | 105/100 | 13.8 | ⊚ | None |
| | 3-19 | R-19 | 105/100 | 9.5 | ◯ | None |
| | 3-20 | R-20 | 105/100 | 11.8 | ⊚ | None |
| | 3-21 | R-21 | 105/100 | 6.5 | ◯ | None |
| | 3-22 | R-20 | 105/110 | 13.9 | ⊚ | None |
| | 3-23 | R-20 | 105/120 | 17.0 | ⊚ | None |

TABLE 8

| | | Resist | Prebaking temperature (° C.)/ | | | Undissolved |
|---|---|---|---|---|---|---|
| | | composition | PEB temperature (° C.) | Contrast | Evaluation | portion |
| Comparative | 3-1 | CR-1 | 105/100 | 9.7 | ◯ | Present |
| Example | 3-2 | CR-2 | 105/100 | 10.8 | ⊚ | Present |
| | 3-3 | CR-3 | 105/100 | 10.9 | ⊚ | Present |
| | 3-4 | CR-4 | 105/100 | 11.2 | ⊚ | Present |
| | 3-5 | CR-5 | 105/100 | 8.2 | ◯ | None |
| | 3-6 | CR-6 | 105/100 | 9.5 | ◯ | None |
| | 3-7 | CR-7 | 105/100 | 3.9 | X | None |
| | 3-8 | CR-8 | 105/100 | 4.8 | X | None |

It is demonstrated in FIG. 1 that in Example 3-17, there was a more significant difference in solubility between the exposed region and the unexposed portion as compared to Comparative Example 3-7. This shows a sharp thickness change with respect to an exposure dose after development. The organic solvent solubility of the exposed portion was also very low. This shows a significant improvement in film loss after exposure. The contrast value in Tables 7 and 8 represents the slope of the thickness change, which is a positive slope for a negative resist and a negative slope for a positive resist. The larger the absolute value, the better the dissolution contrast. In all of Examples 3-1 to 3-23, better contrast was exhibited. This may be because crosslinking between the polymers was promoted by the acid generated in the exposed region. Resists containing a crosslinker with a larger number of crosslinking sites were found to be capable of forming patterns having good contrast. In Comparative Examples 3-1 to 3-4, the film remaining undissolved was observed in the unexposed region. This suggests that the presence of repeat units B as an acid labile group is essential for improving solubility in an organic solvent developer.

### (5) EB Lithography Test

### Examples 4-1 to 4-23 and Comparative Examples 4-1 to 4-4

Each of resist compositions R-1 to R-21 and CR-5 to CR-8 was spin coated on a 61 nm-thick film obtained by applying an antireflective coating DUV-42 (Nissan Chemical Corporation) onto an 8 inch-wafer. The film was prebaked on a hotplate for 60 seconds to form a resist film of about 50 nm thick. The resist film was exposed with an electron beam lithography system (manufactured by ELIONIX INC.) (ELS-F125, accelerating voltage: 125 kV), and baked (PEB) on a hotplate for 60 seconds at a certain temperature, followed by development in butyl acetate for 30 seconds. The obtained 44 nmP line-and-space pattern was observed with a length measurement SEM (S9380) (manufactured by Hitachi High-Technologies Corporation), from which a 3-fold value (3a) of standard deviation (a) was computed and determined as pattern width variation (LWR). Further, the pattern width variation was evaluated in accordance with the following criteria. The results are shown in Tables 9 and 10.

### (Evaluation Criteria)

⊚: The value of LWR is less than 3.0.
◯: The value of LWR is 3.0 or more and less than 3.5.
×: The value of LWR is 3.5 or more.

TABLE 9

| | | | Prebaking | | |
|---|---|---|---|---|---|
| | | | temperature (° C.)/ | | |
| | | Resist | PEB temperature | LWR | |
| | | composition | (° C.) | (nm) | Evaluation |
| Example | 4-1 | R-1 | 105/100 | 3.44 | ◯ |
| | 4-2 | R-2 | 105/100 | 3.29 | ◯ |
| | 4-3 | R-3 | 105/100 | 2.89 | ⊚ |
| | 4-4 | R-4 | 105/100 | 2.78 | ⊚ |
| | 4-5 | R-5 | 105/100 | 2.75 | ⊚ |
| | 4-6 | R-6 | 105/100 | 3.02 | ◯ |
| | 4-7 | R-7 | 105/100 | 3.10 | ◯ |
| | 4-8 | R-8 | 105/100 | 2.88 | ⊚ |
| | 4-9 | R-9 | 105/100 | 2.74 | ⊚ |
| | 4-10 | R-10 | 105/100 | 3.31 | ◯ |
| | 4-11 | R-11 | 105/100 | 3.45 | ◯ |
| | 4-12 | R-12 | 105/100 | 2.64 | ⊚ |
| | 4-13 | R-13 | 105/100 | 2.71 | ⊚ |
| | 4-14 | R-14 | 105/100 | 3.39 | ◯ |
| | 4-15 | R-15 | 105/100 | 3.22 | ◯ |
| | 4-16 | R-16 | 105/100 | 2.95 | ⊚ |
| | 4-17 | R-17 | 105/100 | 2.78 | ⊚ |
| | 4-18 | R-18 | 105/100 | 2.76 | ⊚ |
| | 4-19 | R-19 | 105/100 | 3.15 | ◯ |
| | 4-20 | R-20 | 105/100 | 2.84 | ⊚ |
| | 4-21 | R-21 | 105/100 | 3.28 | ◯ |
| | 4-22 | R-20 | 105/110 | 2.75 | ⊚ |
| | 4-23 | R-20 | 105/120 | 2.58 | ⊚ |

TABLE 10

| | | | Prebaking | | |
|---|---|---|---|---|---|
| | | | temperature (° C.)/ | | |
| | | Resist | PEB temperature | LWR | |
| | | composition | (° C.) | (nm) | Evaluation |
| Comparative | 4-1 | CR-5 | 105/100 | 3.42 | ◯ |
| Example | 4-2 | CR-6 | 105/100 | 3.34 | ◯ |
| | 4-3 | CR-7 | 105/100 | 3.84 | X |
| | 4-4 | CR-8 | 105/100 | 3.51 | X |

In all of Examples 4-1 to 4-21, good LWR was exhibited. Resist films containing a crosslinker with a larger number of crosslinking sites gave better LWR. In Examples 4-22 to 4-23 with a higher PEB temperature, particularly excellent LWR performance was exhibited. In general, when the PEB temperature is as high as a glass transition point or higher, acid diffusion is promoted, and roughness is deteriorated. However, the use of the chemically amplified negative resist composition of the present invention is assumed to have considerably suppressed the acid diffusion property due to an improvement in glass transition point and an increase in molecular weight through crosslinking.

It is demonstrated from the above results that the chemically amplified negative resist composition of the present invention is capable of forming patterns exhibiting high dissolution contrast and good LWR, and thus having little edge roughness and size variation, excellent resolution, and a good pattern shape after exposure.

Japanese Patent Application No. 2023-071288 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A chemically amplified negative resist composition comprising (A) a polymer P comprising repeat units having one of the following formulae (A1) to (A4), which are adapted to generate an acid upon exposure, repeat units having formula (B) which are adapted to change its solubility in a developer by degrading under the action of an acid, and repeat units having the following formula (C) which have a phenolic hydroxy group, and
(B) a crosslinker X in the form of a melamine compound, a glycoluril compound, a urea compound or an epoxy compound substituted with at least one selected from a methylol group, an alkoxymethyl group and an acyloxymethyl group: 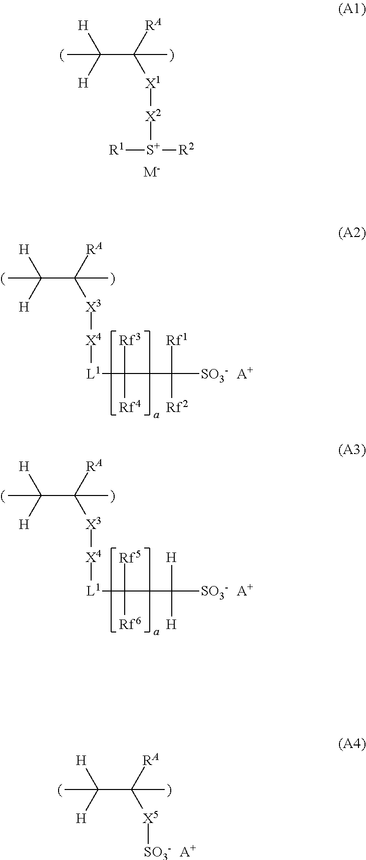
wherein R^{A} is each independently a hydrogen atom, a fluorine atom, a methyl group, or a trifluoromethyl group,
X¹ is a single bond or a phenylene group,
X² is *—C(═O)—O—X²—, *—C(═O)—NH—X²— or *—O—X²¹—, X²¹ is a C₁-C₆ aliphatic hydrocarbylene group, a phenylene group, or a divalent group obtained by combining the foregoing, which may contain a carbonyl group, an ester bond, an ether bond or a hydroxy group,
X³ is each independently a single bond, a phenylene group, a naphthylene group or *—C(═O)—O—X³—, X³¹ is a C₁-C₁₀ aliphatic hydrocarbylene group, a phenylene group, or a naphthylene group, and the aliphatic hydrocarbylene group may contain at least one selected from a hydroxy group, an ether bond, an ester bond or a lactone ring,
X⁴ is each independently a single bond or *—X⁴¹—C(═O)—O—, X⁴¹ is a C₁-C₂₀ hydrocarbylene group which may contain a heteroatom,
X⁵ is a single bond, a methylene group, an ethylene group, a phenylene group, a fluorinated phenylene group, a phenylene group substituted with a trifluoromethyl group, *—C(═O)—O—X⁵¹—, *—C(═O)—N(H)—X⁵¹-, or *—O—X⁵¹, X⁵¹ is a C₁-C₆ aliphatic hydrocarbylene group, a phenylene group, a fluorinated phenylene group, or a phenylene group substituted with a trifluoromethyl group, and may contain a carbonyl group, an ester bond, an ether bond or a hydroxy group,
the asterisk (*) designates a point of attachment to the carbon atom in the backbone,
R¹ and R² are each independently a C₁-C₂₀ hydrocarbyl group which may contain a heteroatom, R¹ and R² may bond together to form a ring with the sulfur atom to which they are attached,
L¹ is a single bond, an ether bond, an ester bond, a carbonyl group, a sulfonic ester bond, a carbonate bond, or a carbamate bond,
Rf¹ and Rf² are each independently a fluorine atom, or a C₁-C₆ fluorinated saturated hydrocarbyl group,
Rf³ and Rf⁴ are each independently a hydrogen atom, a fluorine atom, or a C₁-C₆ fluorinated saturated hydrocarbyl group,
Rf⁵ and Rf⁶ are each independently a hydrogen atom, a fluorine atom, or a C₁-C₆ fluorinated saturated hydrocarbyl group, excluding that all Rf⁵ and Rf^{P} are hydrogen atom at the same time,
M⁻ is a non-nucleophilic counter ion,
A⁺ is an onium cation, and
a is an integer of 0 to 3; 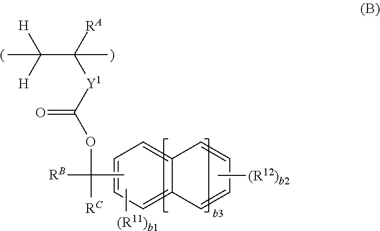
wherein R^{A} is a hydrogen atom, a fluorine atom, a methyl group, or a trifluoromethyl group,
Y¹ is a single bond, a phenylene group, a naphthylene group or *—C(═O)—O—Y¹¹—, Y¹¹ is a C₁-C₂₀ aliphatic hydrocarbylene group, a phenylene group, or a naphthylene group, and the hydrocarbylene group may contain at least one selected from a hydroxy group, an ether bond, an ester bond or a lactone ring, the asterisk (*) designates a point of attachment to the carbon atom in the backbone,
R^{B} and R^{C} are each independently a C₁-C₁₀ hydrocarbyl group which may contain a heteroatom, and R^{B} and R^{C} may bond together to form a ring with the carbon atom to which they are attached,
R¹¹ is a fluorine atom, a C₁-C₅ fluorinated saturated hydrocarbyl group, or a C₁-C₅ fluorinated saturated hydrocarbyloxy group,
R¹² is a C₁-C₁₀ hydrocarbyl group which may contain a heteroatom,
b1 is an integer of 0 to 2, b2 is an integer of 0 to 5, and b3 is an integer of 0 to 2; and 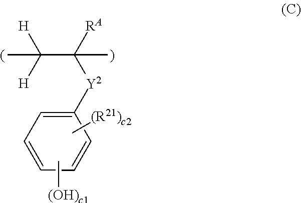
wherein R^{A} is a hydrogen atom, a fluorine atom, a methyl group, or a trifluoromethyl group,
Y² is a single bond or *—C(═O)—O—, the asterisk (*) designates a point of attachment to the carbon atom in the backbone,
R²¹ is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom,
c1 is an integer of 1 to 4, and c2 is an integer of 0 to 4, provided that the sum of c1+c2 is 1 to 5.

2. The chemically amplified negative resist composition according to claim 1, wherein b1 is 1 or 2.

3. The chemically amplified negative resist composition according to claim 1, wherein polymer P further comprises repeat units comprising a lactone ring.

4. The chemically amplified negative resist composition according to claim 1, further comprising an onium salt type quencher having the following formula (Q1) or (Q2):
R³¹—SO₃⁻Mq⁺ (Q1)
R³²—CO₂⁻Mq⁺ (Q2)
wherein R³¹ is a hydrogen atom or a C₁-C₄₀ hydrocarbyl group which may contain a heteroatom, exclusive of the hydrocarbyl group in which the hydrogen atom bonded to the carbon atom at α-position of the sulfo group is substituted by fluorine atom or fluoroalkyl group,
R³² is a hydrogen atom, or a C₁-C₄₀ hydrocarbyl group which may contain a heteroatom, and
Mq⁺ is an onium cation.

5. The chemically amplified negative resist composition according to claim 1, further comprising an organic solvent.

6. The chemically amplified negative resist composition according to claim 1, further comprising a surfactant.

7. A process for forming a pattern, comprising steps of applying the chemically amplified negative resist composition according to claim 1 to a substrate to form a resist film thereon, exposing the resist film to high-energy radiation, and developing the exposed resist film in a developer including an organic solvent.

8. The process according to claim 7, comprising a step of heating the resist film after the exposure and before the development.
